(19) United States
(12) Patent Application Publication
(10) Pub. No.: US 2014/0106119 A1
(43) Pub. Date: Apr. 17, 2014

(54) PATTERN FORMING METHOD, METHOD FOR MANUFACTURING ELECTRONIC DEVICE BY USING THE SAME, AND ELECTRONIC DEVICE

(71) Applicant: FUJIFILM Corporation, Tokyo (JP)

(72) Inventor: Ryosuke UEBA, Haibara-gun (JP)

(73) Assignee: FUJIFILM Corporation, Tokyo (JP)

(21) Appl. No.: 14/106,910

(22) Filed: Dec. 16, 2013

Related U.S. Application Data
(63) Continuation of application No. PCT/JP2012/065298, filed on Jun. 8, 2012.

(30) Foreign Application Priority Data
Jun. 17, 2011 (JP) 2011-135777

(51) Int. Cl. H05K 3/00

(52) U.S. Cl. CPC H05K 3/0023
USPC 428/131; 216/17

(57) ABSTRACT

There is provided a pattern forming method for forming hole patterns in a substrate, comprising pattern forming steps each including, in order, the steps (1) to (6): (1) forming a resist film on the substrate by using a chemical amplification resist composition containing (A) a resin capable of increasing the polarity by the action of an acid to decrease the solubility for an organic solvent-containing developer and (B) a compound capable of generating an acid upon irradiation with an actinic ray or radiation; (2) exposing the resist film to form a first line-and-space latent image; (3) exposing the resist film to form a second line-and-space latent image; (4) developing the resist film by using an organic solvent-containing developer to form a hole pattern group in the resist film; (5) applying an etching treatment to the substrate with the resist film; and (6) removing the resist film.

### CROSS REFERENCE TO RELATED APPLICATION

This is a continuation of International Application No. PCT/JP2012/065298 filed on Jun. 8, 2012, and claims priority from Japanese Patent Application No. 2011-135777, filed on Jun. 17, 2011, the entire disclosures of which are incorporated therein by reference.

### TECHNICAL FIELD

The present invention relates to a pattern forming method, a method for manufacturing an electronic device by using the same, and an electronic device. More specifically, the present invention relates to a pattern forming method suitable for the process of producing a semiconductor such as IC or the production of a liquid crystal device or a circuit board such as thermal head and further for the lithography in other photo-fabrication processes, a method for manufacturing an electronic device by using the same, and an electronic device. In particular, the present invention relates to a pattern forming method suitable for exposure by an ArF exposure apparatus, an ArF immersion-type projection exposure apparatus or an EUV exposure apparatus each using a light source that emits far ultraviolet light at a wavelength of 300 nm or less, a method for manufacturing an electronic device by using the same, and an electronic device.

### BACKGROUND ART

Since the advent of a resist for KrF excimer laser (248 nm), an image forming method called chemical amplification is used as an image forming method for a resist so as to compensate for sensitivity reduction caused by light absorption. For example, the image forming method by positive chemical amplification is an image forming method of decomposing an acid generator in the exposed area upon exposure to produce an acid, converting an alkali-insoluble group into an alkali-soluble group by using the generated acid as a reaction catalyst in the baking after exposure (PEB: Post Exposure Bake), and removing the exposed area by alkali development.

At present, as for the developer used in the g-line, i-line, KrF, ArF, EB or EUV lithography, various developers have been proposed, but an aqueous alkali developer of 238 mass % TMAH (tetramethylammonium hydroxide) is being used for general purposes.

In the production of a semiconductor device or the like, patterns having various profiles such as line, trench and hole need to be formed and at the same time, more miniaturization of the pattern obtained is demanded.

To meet such a requirement, not only the currently predominant positive resist but also a negative chemical amplification resist composition in the pattern formation by alkali development are being developed. Because, there exist patterns that are difficult to form by the current positive resist.

With the growing miniaturization of a semiconductor device, the trend is moving toward a shorter wavelength of the exposure light source and a higher numerical aperture (higher NA) of the projection lens, and a so-called immersion method of filling the space between the projection lens and the sample with a high refractive-index liquid (hereinafter sometimes referred to as an “immersion liquid”) is being aggressively studied. The immersion method can be combined with the super-resolution technology under study at present, such as phase-shift method and modified illumination method.

As for the technique to more enhance the resolution, double exposure technology or double patterning technology has been proposed.

In conventional pattern formation of an electronic device such as semiconductor device, a mask or reticle pattern enlarged to 4 to 5 times the size of a pattern intended to form is size-reduced and transferred on an exposure target such as wafer by using a reduction projection exposure apparatus.

However, the dimensional miniaturization brings about a problem that in the conventional exposure system, the pitch becomes below the resolution limit. Therefore, in the double exposure technology, many approaches for dividing the exposure mask design into two or more parts and synthesizing an image by independently exposing these masks have been also proposed.

With the progress of such a technology, there is known a technique where a resist film is formed using a negative chemical amplification resist composition, the resist film is subjected to double exposure by ArF dry exposure using an ArF excimer laser as the exposure light source, and subsequently, a hole pattern is formed by alkali development (see, JP-A-2010-40849 (the term “JP-A” as used herein means an “unexamined published Japanese patent application”)).

Furthermore, in recent years, a technique where after exposure using the double exposure technology, a hole pattern is formed by performing development using an organic solvent-containing developer has been also introduced (see, Proc. of SPIE, Vol. 7274, 72740N. (2009) and Proc. of SPIE, Vol. 7640, 764011. (2010)).

### SUMMARY OF INVENTION

However, more reduction in the pattern dimension is required and to meet this requirement, a lithography technology capable of forming a hole pattern with a shorter center-to-center distance (pitch) than ever (specifically 80 nm or less) is demanded.

Miniaturization in the lithography technology is proceeding by using a light source whose wavelength becomes shorter with the present day approaching, like g-line (wavelength: 436 nm), i-line (wavelength: 365 nm), KrF excimer layer (wavelength: 248 nm) and ArF excimer laser (wavelength: 193 nm), and at the same time, increasing the numerical aperture (NA) of the projection lens in an exposure machine. And, as described above, since the introduction of an ArF excimer laser, an immersion method using an ArF excimer laser as the light source (ArF immersion exposure) is progressing, and in the ArF immersion exposure, an exposure machine with NA of 1.35 has been developed.

Here, the resolution limit can be expressed by the following generally well-known Rayleigh's equation:

(Resolution Limit)=k₁·(λ/NA)

wherein λ is the wavelength in air of the exposure light source, NA is the numerical aperture of the projection lens, and k₁ is a factor related to the process.

In the case of performing ArF immersion exposure though a line-and-space mask to form a line-and-space pattern consisting of alternately arranged lines and spaces, k₁ is estimated to be about 0.27 and therefore, the resolution limit becomes about 39 nm.

On this account, in the techniques disclosed, for example, in JP-A-2010-40849, Proc. of SPIE, Vol. 7274, 72740N. (2009), and Proc. of SPIE, Vol. 7640, 764011. (2010), as described above, double exposure (specifically, two exposures each using a line-and-space mask) is performed. However, considering the above-described resolution limit (about 39 nm) in the ArF immersion exposure, a hole pattern with a half pitch of 40 nm or less (in other words, a pitch of 80 nm or less) is really difficult to form by these conventional techniques (even if, in JP-A-2010-40849, the ArF exposure is replaced by ArF immersion exposure); and what's more, formation of a hole pattern with a half pitch of less than about 39 nm is theoretically impossible.

Also, the negative chemical amplification resist composition of JP-A-2010-40849 contains a crosslinking agent, and by exposing a resist film formed of the resist composition, the exposed area becomes a crosslinked body and insolubilized in an alkali developer, as a result, a negative pattern is formed. However, the exposed area composed of a crosslinked body is liable to swell with an alkali developer and particularly in the case where the half pitch of hole patterns is near the above-described resolution limit, swelling of the exposed area with an alkali developer makes a significant effect, bringing about a problem that desired holes are not formed at all.

As for the technique using a reversal film disclosed in Proc. of SPIE, Vol. 7274, 72740N. (2009) or the technique of reducing the diameter of a hole pattern by using a shrink material, the process is cumbersome and at the same time, there readily occurs a problem that the processing accuracy of the hole pattern is not stabilized.

The present invention has been made by taking into account these problems, and an object of the present invention is to provide a pattern forming method capable of successfully and easily forming a plurality of hole patterns in a substrate with an ultrafine (for example, 80 nm or less) pitch, a method for manufacturing an electronic device by using the same, and an electronic device.

The present invention has the following configurations, and the above-described object of the present invention is attained by these configurations.

[1] A pattern forming method for forming a plurality of hole patterns in a substrate,

wherein the pattern forming method comprises a plurality of pattern forming steps each including, in order, the following steps (1) to (6):

(1) a step of forming a resist film on the substrate by using a chemical amplification resist composition containing:
(A) a resin capable of increasing the polarity by the action of an acid to decrease the solubility for an organic solvent-containing developer and,
(B) a compound capable of generating an acid upon irradiation with an actinic ray or radiation,

(2) a step of performing an exposure of the resist film to form a first line-and-space latent image wherein a first line group and a first space group are alternately arranged,

(3) a step of performing an exposure of the resist film that the first line-and-space latent image is formed to form a second line-and-space latent image wherein a second line group and a second space group are alternately arranged, such that the line direction of the second line-and-space intersects the line direction in the first line-and-space latent image,

(4) a step of developing the resist film wherein the first and second line-and-space latent images are formed, by using an organic solvent-containing developer to form a hole pattern group in the resist film,

(5) a step of applying an etching treatment to the substrate with the resist film that the hole pattern group is formed to form a hole pattern group in the substrate at the position corresponding to the hole pattern group in the resist film, and

(6) a step of removing the resist film wherein the hole pattern group is formed,

wherein in each of the plurality of pattern forming steps, all of the hole patterns constituting the hole pattern group formed in the substrate are formed at positions different from all positions of the hole patterns constituting the hole pattern group formed in other pattern forming steps.

[2] The pattern forming method as described in [1] above, wherein in each of the step of forming the first line-and-space latent image and the step of forming the second line-and-space latent image, an ArF excimer laser is used and the resist film is exposed through an immersion liquid.
[3] The pattern forming method as described in [1] or [2] above, wherein each center-to-center distance of the plurality of hole patterns formed in the substrate through the plurality of pattern forming steps is 80 nm or less.
[4] The pattern forming method as described in [3] above, wherein each center-to-center distance of the plurality of hole patterns formed in the substrate through the plurality of pattern forming steps is 70 nm or less.
[5] The pattern forming method as described in any one of [1] to [4] above, wherein the widths of the plurality of spaces constituting the first space group are equal to each other and the widths of the plurality of spaces constituting the second space group are equal to each other.
[6] The pattern forming method as described in [5] above, wherein in the step of forming the second line-and-space latent image, the second line-and-space latent image is formed such that the line direction of the second line-and-space runs at right angles to the line direction in the first line-and-space latent image.
[7] The pattern forming method as described in [5] or [6] above, wherein the width of the space in the first space group is the same as the width of the space in the second space group.
[8] The pattern forming method as described in [7] above, wherein in each of the plurality of hole patterns formed in the substrate through the plurality of pattern forming steps, the diameter of the circular cross-section in the plane direction of the substrate is 28 nm or less.
[9] The pattern forming method as described in [8] above, wherein in each of the plurality of hole patterns formed in the substrate through the plurality of pattern forming steps, the diameter of the circular cross-section in the plane direction of the substrate is 25 nm or less.
[10] The pattern forming method as described in [5] above, wherein in the step of forming the second line-and-space latent image, the second line-and-space latent image is formed such that the line direction of the second line-and-space obliquely intersects the line direction in the first line-and-space latent image.
[11] The pattern forming method as described in any one of [1] to [10] above, comprising:

performing the pattern forming step three or more times.

[12] The pattern forming method as described in any one of [1] to [11] above, wherein the exposure in each of the step of forming the first line-and-space latent image and the step of forming the second line-and-space latent image is an exposure using dipole illumination.
[13] The pattern forming method as described in any one of [1] to [12] above, wherein the exposure in each of the step of forming the first line-and-space latent image and the step of forming said second line-and-space latent image is an exposure using a photomask selected from a binary mask and a phase shift mask.
[14] A manufacturing method of an electronic device, comprising:

the pattern forming method as described in any one of [1] to [13] above.

[15] An electronic device manufactured by the manufacturing method of an electronic device as described in [14] above.

The present invention preferably further includes the following configurations.

[16] The pattern forming method as described in any one of [1] to [13] above, wherein the pattern forming step comprises:

a step of heating the resist film wherein the first line-and-space latent image is formed after forming the first line-and-space latent image but before forming the second line-and-space latent image.

[17] The pattern forming method as described in any one of [1] to [13], and [16] above, wherein the resin (A) contains a repeating unit represented by the following formula (AI):

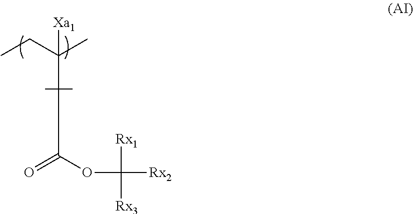

wherein Xa₁ represents a hydrogen atom, a methyl group which may have a substituent, or a group represented by —CH₂—R₉, R₉ represents a hydroxyl group or a monovalent organic group,

T represents a single bond or a divalent linking group,

each of Rx₁ to Rx₃ independently represents an alkyl group or a cycloalkyl group, and

two members out of Rx₁ to Rx₃ may combine to form a cycloalkyl group.

[18] The pattern forming method as described in [17] above, wherein in formula (AI), T represents a single bond and each of Rx₁ to Rx₃ independently represents a linear or branched alkyl group (provided that two members of Rx₁ to Rx₃ do not combine to form a cycloalkyl group).
[19] The pattern forming method as described in any one of [1] to [13], [16] and [17] above, wherein the resin (A) contains a repeating unit capable of decomposing by the action of an acid to produce a carboxyl group, represented by the following formula (I):

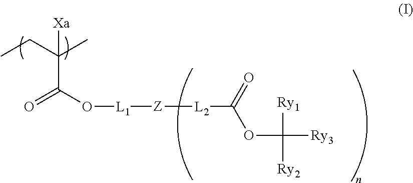

wherein Xa represents a hydrogen atom, an alkyl group, a cyano group or a halogen atom;

each of Ry₁ to Ry₃ independently represents an alkyl group or a cycloalkyl group, and two members out of Ry₁ to Ry₃ may combine to form a ring;

Z represents a (n+1)-valent linking group having a polycyclic hydrocarbon structure which may have a heteroatom as a ring member;

each of L₁ and L₂ independently represents a single bond or a divalent linking group;

n represents an integer of 1 to 3; and

when n is 2 or 3, each L₂, each Ry₁, each Ry₂ and each Ry₃ may be the same as or different from every other L₂, Ry₁, Ry₂ and Ry₃, respectively.

According to the present invention, a pattern forming method capable of successfully and easily forming a plurality of hole patterns in a substrate with an ultrafine (for example, 80 nm or less) pitch, a method for manufacturing an electronic device by using the same, and an electronic device, can be provided.

### BRIEF DESCRIPTION OF DRAWINGS

FIG. 1 is a flow chart for explaining a first embodiment of the present invention.

FIGS. 2A and 2B are a schematic perspective view and a schematic top view, respectively, partially illustrating the state after performing step S1 of FIG. 1.

FIG. 3A is a schematic top view illustrating a part of the mask used in step S2 of FIG. 1, and FIGS. 3B and 3C are a schematic perspective view and a schematic top view, respectively, partially illustrating the state after performing step S2 of FIG. 1.

FIG. 4A is a schematic top view illustrating a part of the mask used in step S3 of FIG. 1, and FIGS. 4B and 4C are a schematic perspective view and a schematic top view, respectively, partially illustrating the state after performing step S3 of FIG. 1.

FIGS. 5A and 5B are a schematic perspective view and a schematic top view, respectively, partially illustrating the state after performing step S5 of FIG. 1.

FIGS. 6A and 6B are a schematic perspective view and a schematic top view, respectively, partially illustrating the state after performing steps S6 and S7 of FIG. 1.

FIGS. 7A and 7B are a schematic perspective view and a schematic top view, respectively, partially illustrating the state after performing step S8 of FIG. 1.

FIG. 8A is a schematic top view illustrating a part of the mask used in step S9 of FIG. 1, and FIGS. 8B and 8C are a schematic perspective view and a schematic top view, respectively, partially illustrating the state after performing step S9 of FIG. 1.

FIG. 9A is a schematic top view illustrating a part of the mask used in step S10 of FIG. 1, and FIGS. 9B and 9C are a schematic perspective view and a schematic top view, respectively, partially illustrating the state after performing step S10 of FIG. 1.

FIGS. 10A and 10B are a schematic perspective view and a schematic top view, respectively, partially illustrating the state after performing step S12 of FIG. 1.

FIGS. 11A and 11B are a schematic perspective view and a schematic top view, respectively, partially illustrating the state after performing steps S13 and S14 of FIG. 1.

FIG. 12A is a view for explaining the pattern forming method according to Comparative Example, FIG. 12B is a view for explaining a first embodiment of the present invention, FIG. 12C is a view for explaining a second embodiment of the present invention, and FIG. 12D is a view for explaining a third embodiment of the present invention.

FIGS. 13A to 13G are views for explaining the pattern forming method according to a fourth embodiment of the present invention.

FIGS. 14A to 14J are views for explaining the pattern forming method according to a fifth embodiment of the present invention.

### DESCRIPTION OF EMBODIMENTS

The mode for carrying out the present invention is described in detail below.

In the description of the present invention, when a group (atomic group) is denoted without specifying whether substituted or unsubstituted, the group encompasses both a group having no substituent and a group having a substituent. For example, “an alkyl group” encompasses not only an alkyl group having no substituent (unsubstituted alkyl group) but also an alkyl group having a substituent (substituted alkyl group).

In the description of the present invention, the term “actinic ray” or “radiation” indicates, for example, a bright line spectrum of mercury lamp, a far ultraviolet ray typified by excimer laser, an extreme-ultraviolet ray (EUV light), an X-ray or an electron beam (EB). Also, in the present invention, the “light” means an actinic ray or radiation.

In the description of the present invention, unless otherwise indicated, the “exposure” encompasses not only exposure to a mercury lamp, a far ultraviolet ray typified by excimer laser, an X-ray, extreme-ultraviolet light, EUV light or the like but also lithography with a particle beam such as electron beam and ion beam.

Furthermore, in the description of the present invention, the “runs at right angles” encompasses not only intersection strictly at right angles but also intersection at such an angle as being regarded as a right angle in practice (in view of instrument precision).

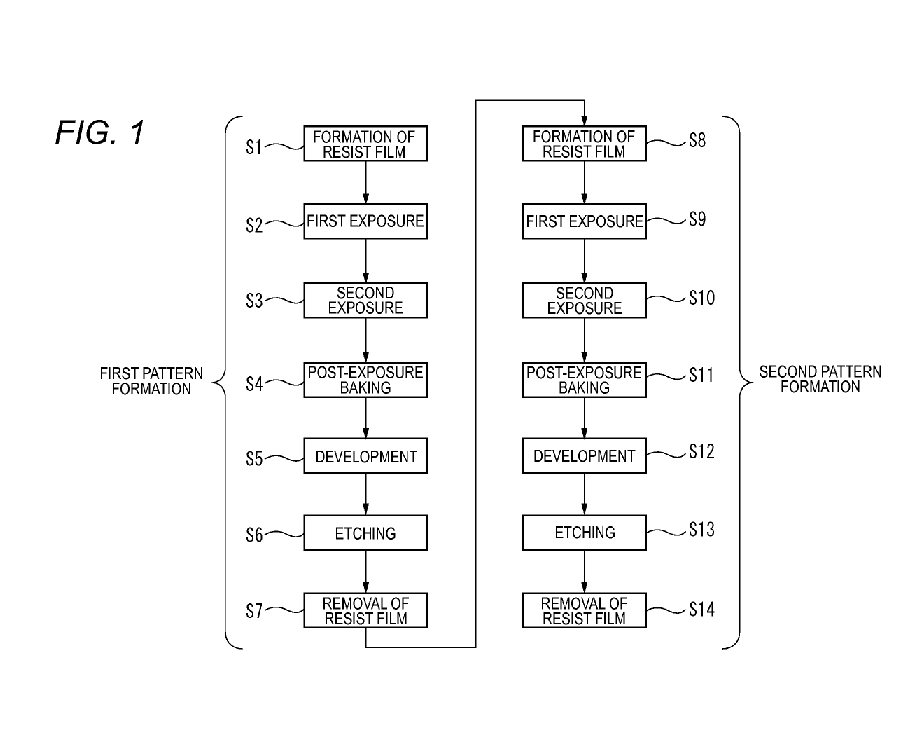

FIG. 1 is a flow chart for explaining the pattern forming method according to a first embodiment of the present invention.

In the pattern forming method according to a first embodiment of the present invention, as show in FIG. 1, first of all, first pattern formation (steps S1 to S7) is performed.

In the first pattern formation, first of all, a resist film is formed (step S1, “Formation of Resist Film” of FIG. 1).

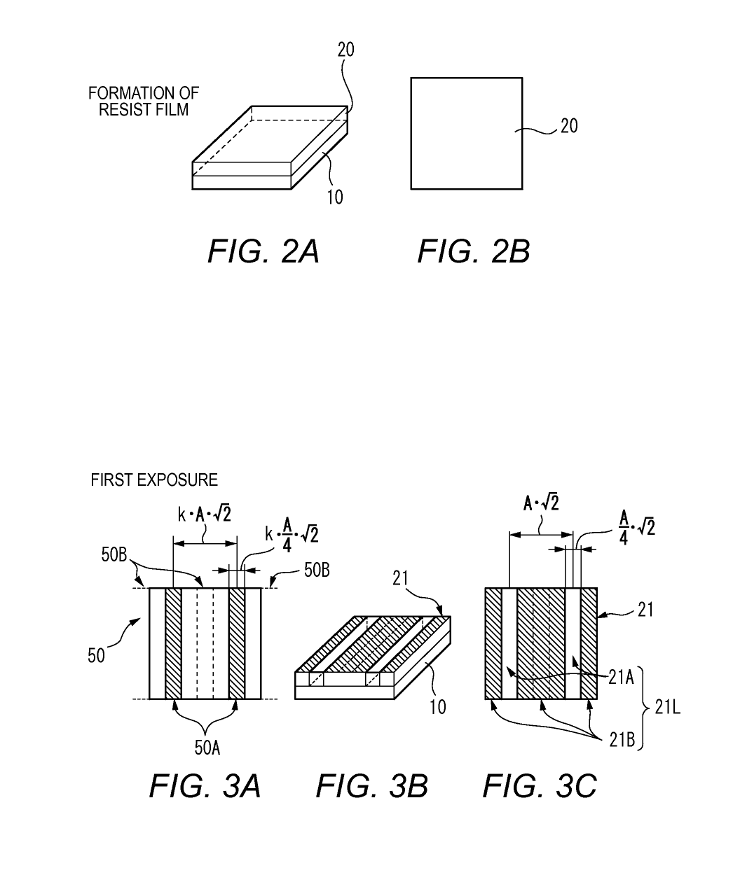

FIGS. 2A and 2B are a schematic perspective view and a schematic top view, respectively, partially illustrating the state after performing step S1 of FIG. 1.

More specifically, as shown in FIGS. 2A and 2B, in step S1, a resist film 20 is formed on a substrate 10 by using a chemical amplification resist composition (more specifically, a negative resist composition).

The substrate 10 is selected according to usage and is not particularly limited, but an inorganic substrate such as silicon, SiN, SiO₂ and SiN, a coating-type inorganic substrate such as SOG, or a substrate generally used in the process of producing a semiconductor such as IC or producing a liquid crystal device or a circuit board such as thermal head or in the lithography of other photo-fabrication processes can be used.

A substrate having previously provided thereon an antireflection film may be also used. The antireflection film which can be used may be either an inorganic film type such as titanium, titanium dioxide, titanium nitride, chromium oxide, carbon and amorphous silicon, or an organic film type composed of a light absorber and a polymer material. In addition, a commercially available organic antireflection film such as DUV30 Series and DUV-40 Series produced by Brewer Science, Inc., AR-2, AR-3 and AR-5 produced by Shipley Co., Ltd., or ARC Series such as ARC29A produced by Nissan Chemical Industries, Ltd., may be also used as the organic antireflection film.

In forming the resist film 20 from a resist composition, as long as the resist composition can be coated on the substrate 10, any method may be used, and a conventionally known method such as spin coating method, spraying method, roller coating method, flow coating method, doctor coating method and dipping method may be used. Preferably, the resist composition is coated by a spin coating method to form a coating film.

The thickness of the coating film is preferably from 10 to 200 nm, more preferably from 20 to 150 nm.

After coating the resist composition, the substrate may be heated (Prebake; PB), if desired. Thanks to this heating, a film deprived of insoluble residual solvent can be uniformly formed. The prebaking temperature is not particularly limited but is preferably from 50 to 160° C., more preferably from 60 to 140° C.

The heating time is preferably from 30 to 300 seconds, more preferably from 30 to 180 seconds, still more preferably from 30 to 90 seconds.

The prebake can be performed using a device attached to an ordinary exposure machine or may be performed using a hot plate or the like.

As the resist composition, a chemical amplification resist composition containing (A) a resin capable of increasing the polarity by the action of an acid to decrease the solubility for an organic solvent-containing developer and (B) a compound capable of generating an acid upon irradiation with an actinic ray or radiation is used.

This chemical amplification resist composition is described in detail later.

Next, first exposure is performed (step S2, “First Exposure” of FIG. 1).

FIG. 3A is a schematic top view illustrating a part of the mask used in step S2 of FIG. 1.

As shown in FIG. 3A, the mask 50 has a mask line group 50A consisting of a plurality of light-shielding mask lines and a mask space group 50B consisting of a plurality of light-transmitting spaces such that a mask line and a space are alternately arranged.

The plurality of light-shielding mask lines constituting the mask line group 50A each has a width expressed by k·(A/4)·(√2). Also, the distances between respective adjacent light-shielding mask lines (pitch of light-shielding mask lines) are equal to each other and are expressed by k·A·(√2).

That is, in the mask 50, the ratio between the width of the light-shielding mask line and the width of the light-transmitting space is 1:3.

k is a factor related to demagnification exposure, and A is a center-to-center distance (pitch) of hole patterns formed in the substrate 10 after first pattern formation and second pattern formation.

k can be appropriately set and becomes 1 in the case of equi-magnification exposure, but usually, demagnification exposure is preferred and in this case, k becomes a value larger than 1.

FIGS. 3B and 3C are a schematic perspective view and a schematic top view, respectively, partially illustrating the state after performing step S2 of FIG. 1.

First exposure is, more specifically, performed on the surface of the resist film 20 through the mask 50 shown in FIG. 3A.

As shown in FIGS. 3B and 3C, by the first exposure, the resist film 20 shown in FIG. 2 is reformed into a resist film 21 wherein a first line-and-space latent image 21L is formed. Here, in the first line-and-space latent image 21L, a first space group 21A formed by blocking light by the mask line group 50A and a first line group 21B formed by transmitting light through the mask space group 50B are alternately arranged.

The width of each of a plurality of first spaces constituting the first space group 21A and the distance between adjacent first spaces (pitch of spaces) correspond to the width of each of the plurality of light-shielding mask lines constituting the mask line group 50A and the distance between adjacent light-shielding mask lines, respectively.

That is, the width of the first space is expressed by (A/4)·(√2), and the distance between adjacent first spaces is expressed by A·(√2).

Subsequently, second exposure is performed (step S3, “Second Exposure” of FIG. 1).

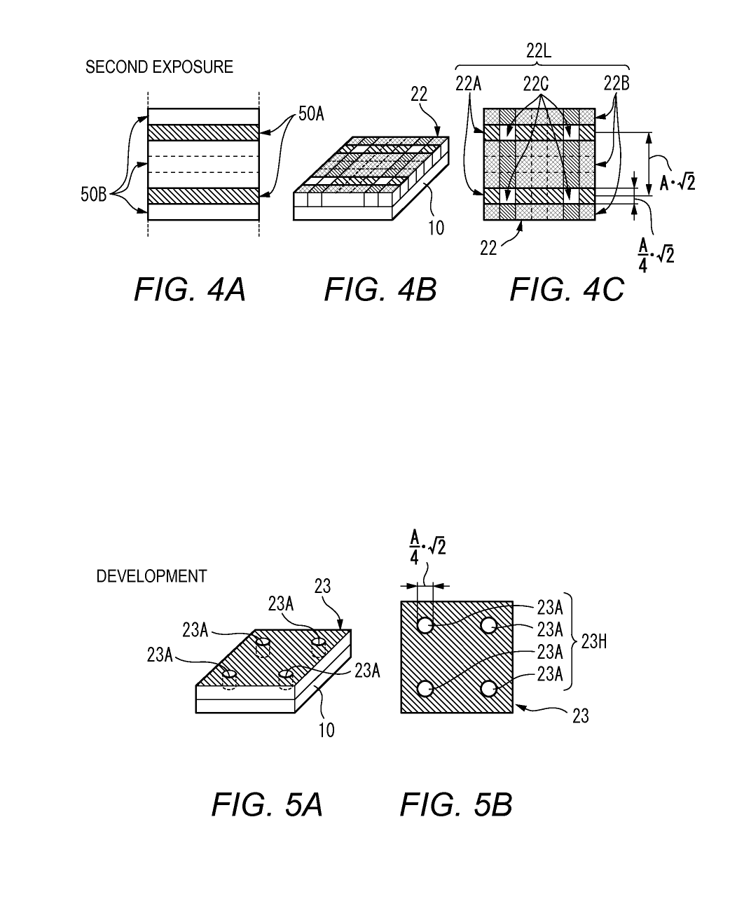

FIG. 4A is a schematic top view illustrating a part of the mask used in step S3 of FIG. 1, and FIGS. 4B and 4C are a schematic perspective view and a schematic top view, respectively, partially illustrating the state after performing step S3 of FIG. 1.

The second exposure is, more specifically, performed through the mask 50 shown in FIG. 4A. Here, the mask 50 is used in a state of the mask 50 shown in FIG. 3A being rotated by 90° (in a state where the light-shielding mask line of the mask 50 shown in FIG. 4A in step S3 runs at right angles to the light-shielding mask line of the mask 50 shown in FIG. 3A in step S2).

As shown in FIGS. 4B and 4C, by the second exposure, the resist film 21 shown in FIGS. 3B and 3C is reformed into a resist film 22 in which a second line-and-space latent image 22L is formed in addition to the first line-and-space latent image 21L. Here, in the second line-and-space latent image 22L, a second space group 22A formed by blocking light by the mask line group 50A and a second line group 22B formed by transmitting light through the mask space group 50B are alternately arranged. The second line-and-space latent image 22L is provided so that its line direction (defining also a longitudinal direction of the space) runs at right angles to the line direction (defining also a longitudinal direction of the space) in the first line-and-space latent image 21L.

The width of each of a plurality of second spaces constituting the second space group 22A and the distance between adjacent second spaces (pitch of spaces) correspond to the width of each of the plurality of light-shielding mask lines constituting the mask line group 50A and the distance between adjacent light-shielding mask lines, respectively.

That is, the width of the second space is expressed by (A/4)·(√2), and the distance between adjacent second spaces is expressed by A·(√2).

In other words, by the above-described first exposure and second exposure, a plurality of unexposed areas 22C that are not exposed in either the first exposure or the second exposure are formed at intervals of A·(√2) in a square grid pattern in the resist film 22. Here, the cross-section of the unexposed area 22C in the plane direction of the resist film 22 has a square profile with one side being (A/4)·(√2).

In the first exposure and the second exposure, the light source used in the exposure apparatus is not limited and includes, for example, an infrared light, a visible light, an ultraviolet light, a far ultraviolet light, an extreme-ultraviolet light, a X-ray and an electron beam but is preferably a far ultraviolet light at a wavelength of 250 nm or less, more preferably 220 nm or less, still more preferably from 1 to 200 nm. Specific examples thereof include a KrF excimer laser (248 nm), an ArF excimer laser (193 nm), a F₂ excimer laser (157 nm), a X-ray, an EUV (13 nm) and an electron beam. Among these, a KrF excimer laser, an ArF excimer laser, an EUV and electron beam are preferred.

For achieving miniaturization of the pattern, use of an EUV light or an electron beam as the exposure light source appears promising, but EUV lithography has a problem that stable supply of high-power EUV light is difficult and a resist composition for EUV exposure, satisfying required performances, is still under development, and also, the electron beam lithography has a problem in the productivity. Accordingly, it is more preferred to use an ArF excimer laser as the light source.

Particularly, in the case of forming a hole pattern with a half pitch of 40 nm or less (that is, a pitch of 80 nm or less), an immersion exposure method is preferably employed.

The immersion exposure method is, as the technology to increase the resolution, a technique of performing the exposure by filling a space between the projection lens and the sample with a high refractive-index liquid (hereinafter, sometimes referred to as an “immersion liquid”).

As described above, the resolution limit is expressed by the formula: k₁·(λ/NA) (wherein λ is the wavelength in air of the exposure light source, NA is the numerical aperture of the projection lens, and k₁ is a factor related to the process), and assuming that n is the refractive index of the immersion liquid for air, θ is the convergence half-angle of beam and NA₀=sin θ, the resolution limit can be expressed by the following formulae:

(Resolution limit)=k₁·[λ/(n·NA₀)]=k₁·(λ/n)/NA₀

That is, the effect of immersion is equal to enabling the numerical aperture of the projection lens to be n times larger (in other words, in the case of a projection optical system with the same NA, the effect of immersion is equal to use of an exposure wavelength of 1/n).

In the case of performing immersion exposure, a step of washing the film surface with an aqueous chemical solution may be performed (1) after forming the film on a substrate but before the step of performing the first exposure and/or (2) after performing the second exposing but before heating the film (post-exposure baking).

The immersion liquid is preferably a liquid being transparent to light at the exposure wavelength and having as small a temperature coefficient of refractive index as possible in order to minimize the distortion of an optical image projected on the film. Particularly, when the exposure light source is an ArF excimer laser (wavelength: 193 nm), water is preferably used in view of availability and easy handleability in addition to the above-described aspects.

In the case of using water, an additive (liquid) capable of decreasing the surface tension of water and at the same time, increasing the interfacial activity may be added in a small ratio. This additive preferably does not dissolve the resist layer on the wafer and gives only a negligible effect on the optical coat at the undersurface of the lens element.

Such an additive is preferably, for example, an aliphatic alcohol having a refractive index substantially equal to that of water, and specific examples thereof include methyl alcohol, ethyl alcohol and isopropyl alcohol. Thanks to addition of an alcohol having a refractive index substantially equal to that of water, even when the alcohol component in water is evaporated and its content concentration is changed, the change in the refractive index of the liquid as a whole can be advantageously made very small.

On the other hand, if a substance opaque to light at 193 nm or an impurity greatly differing in the refractive index from water is mingled, this incurs distortion of the optical image projected on the resist. For this reason, the water used is preferably distilled water. Furthermore, pure water after filtration through an ion exchange filter or the like may be also used.

The electrical resistance of water used as the immersion liquid is preferably 18.3 MQcm or more, and TOC (total organic carbon) is preferably 20 ppb or less. The water is preferably subjected to a deaeration treatment.

Also, the lithography performance can be enhanced by raising the refractive index of the immersion liquid. From such a standpoint, an additive for raising the refractive index may be added to water, or heavy water (D₂O) may be used in place of water.

In the case where the film formed using the composition of the present invention is exposed through an immersion medium, the later-described hydrophobic resin (E) may be further added, if desired. The receding contact angle on the surface is enhanced by the addition of the hydrophobic resin (E). The receding contact angle of the film is preferably from 60 to 90°, more preferably 70° or more.

In the immersion exposure step, the immersion liquid must move on a wafer following the movement of an exposure head that is scanning the wafer at a high speed and forming an exposure pattern. Therefore, the contact angle of the immersion liquid for the resist film in a dynamic state is important, and the resist is required to have a performance of allowing the immersion liquid to follow the high-speed scanning of an exposure head with no remaining of a liquid droplet.

In order to prevent the film from directly contacting with the immersion liquid, a film (hereinafter, sometimes referred to as a “topcoat”) sparingly soluble in the immersion liquid may be provided between the film formed using the composition of the present invention and the immersion liquid. The functions required of the topcoat are suitability for coating as a resist overlayer, transparency to radiation, particularly, radiation having a wavelength of 193 nm, and sparing solubility in immersion liquid. The topcoat is preferably unmixable with the resist and capable of being uniformly coated as a resist overlayer.

In view of transparency to light at 193 nm, the topcoat is preferably an aromatic-free polymer.

Specific examples thereof include a hydrocarbon polymer, an acrylic acid ester polymer, a polymethacrylic acid, a polyacrylic acid, a polyvinyl ether, a silicon-containing polymer, and a fluorine-containing polymer. The later-described hydrophobic resin (E) is suitable also as the topcoat. If impurities are dissolved out into the immersion liquid from the topcoat, the optical lens is contaminated. For this reason, residual monomer components of the polymer are preferably little contained in the topcoat.

On peeling off the topcoat, a developer may be used, or a releasing agent may be separately used. The releasing agent is preferably a solvent less likely to permeate the film. From the standpoint that the peeling step can be performed simultaneously with the development step of the film, the topcoat is preferably peelable with an alkali developer and in view of peeling with an alkali developer, the topcoat is preferably acidic, but in consideration of non-intermixing with the film, the topcoat may be neutral or alkaline.

The difference in the refractive index between the topcoat and the immersion liquid is preferably null or small. In this case, the resolution can be enhanced. In the case where the exposure light source is an ArF excimer laser (wavelength: 193 nm), water is preferably used as the immersion liquid and therefore, the topcoat for ArF immersion exposure preferably has a refractive index close to the refractive index (1.44) of water. Also, in view of transparency and refractive index, the topcoat is preferably a thin film.

The topcoat is preferably unmixable with the film and further unmixable also with the immersion liquid. From this standpoint, when the immersion liquid is water, the solvent used for the topcoat is preferably a medium that is sparingly soluble in the solvent used for the composition of the present invention and is insoluble in water. Furthermore, when the immersion liquid is an organic solvent, the topcoat may be either water-soluble or water-insoluble.

Thereafter, heating after exposure (PEB; Post Exposure Bake) is performed (step S4, “Post-Exposure Bake” of FIG. 1).

The heating temperature in the post-exposure bake is preferably from 70 to 130° C., more preferably from 80 to 120° C.

The heating time is preferably from 30 to 300 seconds, more preferably from 30 to 180 seconds, still more preferably from 30 to 90 seconds.

The heating can be performed using a device attached to an ordinary exposure or developing machine or may be performed using a hot plate or the like.

Thanks to this heating, the reaction in the exposed area is accelerated, and the sensitivity and pattern profile are improved.

Incidentally, such heating may be performed after forming the first line-and-space latent image 21L but before forming the second line-and-space latent image 22L (that is, after the first exposure but before the second exposure).

Thereafter, development is performed (step S5, “Development” of FIG. 1).

The development is performed by using an organic solvent-containing developer (hereinafter, sometimes referred to as an “organic developer”).

The resist film is, as described above, formed from a chemical amplification resist composition containing (A) a resin capable of increasing the polarity by the action of an acid to decrease the solubility for an organic solvent-containing developer and (B) a compound capable of generating an acid upon irradiation with an actinic ray or radiation.

In the exposed area of the resist film, the acid generated from the compound (B) reacts with the resin (A) to increase the polarity of the resin (A) and decrease the solubility for an organic solvent-containing developer, as a result, the exposed area of the resist film can made sparingly soluble or insoluble for an organic solvent-containing developer. On the other hand, in the unexposed area of the resist film, increase in the polarity of the resin (A) as observed in the exposed area does not occur and therefore, the solubility for an organic solvent-containing developer is not changed, so that the unexposed area of the resist film can be made soluble for an organic solvent-containing developer.

By such development, a negative pattern is formed.

FIGS. 5A and 5B are a schematic perspective view and a schematic top view, respectively, partially illustrating the state after performing step S5 of FIG. 1.

More specifically, as shown in FIGS. 5A and 5B, by the development, the resist film 22 shown in FIGS. 4B and 4C is reformed into a resist film 23 having formed therein a first resist hole pattern group 23H consisting of a plurality of first resist hole patterns 23A. Here, each of the plurality of first resist hole patterns 23A is a through hole formed after the unexposed area 22C shown in FIG. 4C is dissolved in the developer and removed.

Also, the dimension of the first resist hole pattern 23A corresponds to the dimension of the unexposed area 22C shown in FIG. 4C, and the first resist hole pattern 23A is in a cylindrical form where the diameter of the circular cross-section in the plane direction of the resist film 23 is (A/4)·(√2).

Suitable organic developers include a polar solvent such as ketone-based solvent, ester-based solvent, alcohol-based solvent, amide-based solvent and ether-based solvent, and a hydrocarbon-based solvent.

Examples of the ketone-based solvent include 1-octanone, 2-octanone, 1-nonanone, 2-nonanone, acetone, 2-heptanone (methyl amyl ketone), 4-heptanone, 1-hexanone, 2-hexanone, diisobutyl ketone, cyclohexanone, methylcyclohexanone, phenylacetone, methyl ethyl ketone, methyl isobutyl ketone, acetyl acetone, acetonyl acetone, ionone, diacetonyl alcohol, acetyl carbinol, acetophenone, methyl naphthyl ketone, isophorone, and propylene carbonate.

Examples of the ester-based solvent include methyl acetate, butyl acetate, ethyl acetate, isopropyl acetate, pentyl acetate, isopentyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, methyl formate, ethyl formate, butyl formate, propyl formate, ethyl lactate, butyl lactate and propyl lactate.

Examples of the alcohol-based solvent include an alcohol such as methyl alcohol, ethyl alcohol, n-propyl alcohol, isopropyl alcohol, n-butyl alcohol, sec-butyl alcohol, tert-butyl alcohol, isobutyl alcohol, n-hexyl alcohol, n-heptyl alcohol, n-octyl alcohol and n-decanol; a glycol-based solvent such as ethylene glycol, diethylene glycol and triethylene glycol; and a glycol ether-based solvent such as ethylene glycol monomethyl ether, propylene glycol monomethyl ether, ethylene glycol monoethyl ether, propylene glycol monoethyl ether, diethylene glycol monomethyl ether, triethylene glycol monoethyl ether, and methoxymethyl butanol.

Examples of the ether-based solvent include, in addition to the glycol ether-based solvents above, dioxane and tetrahydrofuran.

Examples of the amide-based solvent which can be used include N-methyl-2-pyrrolidone, N,N-dimethylacetamide, N,N-dimethylformamide, hexamethylphosphoric triamide, and 1,3-dimethyl-2-imidazolidinone.

Examples of the hydrocarbon-based solvent include an aromatic hydrocarbon-based solvent such as toluene and xylene, and an aliphatic hydrocarbon-based solvent such as pentane, hexane, octane and decane.

A plurality of these solvents may be mixed, or the solvent may be used by mixing it with a solvent other than those described above or with water. However, in order to sufficiently bring out the effects of the present invention, the water content ratio in the entire developer is preferably less than 10 mass %, and it is more preferred to contain substantially no water.

That is, the amount of the organic solvent used in the organic developer is preferably from 90 to 100 mass %, more preferably from 95 to 100 mass %, based on the entire amount of the developer.

In particular, the organic developer is preferably a developer containing at least one kind of an organic solvent selected from the group consisting of a ketone-based solvent, an ester-based solvent, an alcohol-based solvent, an amide-based solvent and an ether-based solvent.

The vapor pressure at 20° C. of the organic developer is preferably 5 kPa or less, more preferably 3 kPa or less, still more preferably 2 kPa or less. By setting the vapor pressure of the organic developer to 5 kPa or less, evaporation of the developer on a substrate or in a development cup is suppressed and the temperature uniformity in the wafer plane is enhanced, as a result, the dimensional uniformity in the wafer plane is improved.

Specific examples of the solvent having a vapor pressure of 5 kPa or less include a ketone-based solvent such as 1-octanone, 2-octanone, 1-nonanone, 2-nonanone, 2-heptanone (methyl amyl ketone), 4-heptanone, 2-hexanone, diisobutyl ketone, cyclohexanone, methylcyclohexanone, phenylacetone and methyl isobutyl ketone; an ester-based solvent such as butyl acetate, pentyl acetate, isopentyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, butyl formate, propyl formate, ethyl lactate, butyl lactate and propyl lactate; an alcohol-based solvent such as n-propyl alcohol, isopropyl alcohol, n-butyl alcohol, sec-butyl alcohol, tert-butyl alcohol, isobutyl alcohol, n-hexyl alcohol, n-heptyl alcohol, n-octyl alcohol and n-decanol; a glycol-based solvent such as ethylene glycol, diethylene glycol and triethylene glycol; a glycol ether-based solvent such as ethylene glycol monomethyl ether, propylene glycol monomethyl ether, ethylene glycol monoethyl ether, propylene glycol monoethyl ether, diethylene glycol monomethyl ether, triethylene glycol monoethyl ether and methoxymethylbutanol; an ether-based solvent such as tetrahydrofuran; an amide-based solvent such as N-methyl-2-pyrrolidone, N,N-dimethylacetamide and N,N-dimethylformamide; an aromatic hydrocarbon-based solvent such as toluene and xylene; and an aliphatic hydrocarbon-based solvent such as octane and decane.

Specific examples of the solvent having a vapor pressure of 2 kPa or less that is a particularly preferred range include a ketone-based solvent such as 1-octanone, 2-octanone, 1-nonanone, 2-nonanone, 4-heptanone, 2-hexanone, diisobutyl ketone, cyclohexanone, methylcyclohexanone and phenylacetone; an ester-based solvent such as butyl acetate, amyl acetate, propylene glycol monomethyl ether acetate, ethylene glycol monoethyl ether acetate, diethylene glycol monobutyl ether acetate, diethylene glycol monoethyl ether acetate, ethyl-3-ethoxypropionate, 3-methoxybutyl acetate, 3-methyl-3-methoxybutyl acetate, ethyl lactate, butyl lactate and propyl lactate; an alcohol-based solvent such as n-butyl alcohol, sec-butyl alcohol, tert-butyl alcohol, isobutyl alcohol, n-hexyl alcohol, n-heptyl alcohol, n-octyl alcohol and n-decanol; a glycol-based solvent such as ethylene glycol, diethylene glycol and triethylene glycol; a glycol ether-based solvent such as ethylene glycol monomethyl ether, propylene glycol monomethyl ether, ethylene glycol monoethyl ether, propylene glycol monoethyl ether, diethylene glycol monomethyl ether, triethylene glycol monoethyl ether and methoxymethylbutanol; an amide-based solvent such as N-methyl-2-pyrrolidone, N,N-dimethylacetamide and N,N-dimethylformamide; an aromatic hydrocarbon-based solvent such as xylene; and an aliphatic hydrocarbon-based solvent such as octane and decane.

In the organic developer, an appropriate amount of a surfactant may be added, if desired.

The surfactant is not particularly limited but, for example, ionic or nonionic fluorine-containing and/or silicon-containing surfactants can be used. Examples of such fluorine-containing and/or silicon-containing surfactants include surfactants described in JP-A-62-36663, JP-A-61-226746, JP-A-61-226745, JP-A-62-170950, JP-A-63-34540, JP-A-7-230165, JP-A-8-62834, JP-A-9-54432, JP-A-9-5988 and U.S. Pat. Nos. 5,405,720, 5,360,692, 5,529,881, 5,296,330, 5,436,098, 5,576,143, 5,294,511 and 5,824,451. A nonionic surfactant is preferred. The nonionic surfactant is not particularly limited, but use of a fluorine-containing surfactant or a silicon-containing surfactant is more preferred.

The amount of the surfactant used is usually from 0.001 to 5 mass %, preferably from 0.005 to 2 mass %, more preferably from 0.01 to 0.5 mass %, based on the entire amount of the developer.

As regards the developing method, for example, a method of dipping the substrate in a bath filled with the developer for a fixed time (dipping method), a method of raising the developer on the substrate surface by the effect of a surface tension and keeping it still for a fixed time, thereby performing development (puddle method), a method of spraying the developer on the substrate surface (spraying method), and a method of continuously ejecting the developer on the substrate spinning at a constant speed while scanning the developer ejecting nozzle at a constant rate (dynamic dispense method) may be applied.

In the case where the above-described various developing methods include a step of ejecting the developer toward the resist film from a development nozzle of a developing apparatus, the ejection pressure of the developer ejected (the flow velocity per unit area of the developer ejected) is preferably 2 mL/sec/mm² or less, more preferably 1.5 mL/sec/mm² or less, still more preferably 1 mL/sec/mm² or less. The flow velocity has no particular lower limit but in view of throughput, is preferably 0.2 mL/sec/mm² or more.

By setting the ejection pressure of the ejected developer to the range above, pattern defects attributable to the resist scum after development can be greatly reduced.

Details of this mechanism are not clearly known, but it is considered that thanks to the ejection pressure in the above-described range, the pressure imposed on the resist film by the developer becomes small and the resist film/resist pattern is kept from inadvertent chipping or collapse.

Here, the ejection pressure (mL/sec/mm²) of the developer is the value at the outlet of the development nozzle in the developing apparatus.

Examples of the method for adjusting the ejection pressure of the developer include a method of adjusting the ejection pressure by a pump or the like, and a method of supplying the developer from a pressurized tank and adjusting the pressure to change the ejection pressure.

After the step of performing development by using an organic solvent-containing developer, a step of stopping the development by replacing the solvent with another solvent may be practiced.

A step of rinsing the film by using a rinsing solution (rinsing step) is preferably performed after the development using an organic developer.

The rinsing solution used in the rinsing step is not particularly limited as long as it does not dissolve the resist pattern, and a solution containing a general organic solvent may be used. A rinsing solution containing at least one kind of an organic solvent selected from the group consisting of a hydrocarbon-based solvent, a ketone-based solvent, an ester-based solvent, an alcohol-based solvent, an amide-based solvent and an ether-based solvent is preferably used as the rinsing solution.

Specific examples of the hydrocarbon-based solvent, ketone-based solvent, ester-based solvent, alcohol-based solvent, amide-based solvent and ether-based solvent are the same as those described for the organic solvent-containing developer.

After the development using an organic developer, more preferably, a step of rinsing the film by using a rinsing solution containing at least one kind of an organic solvent selected from the group consisting of a ketone-based solvent, an ester-based solvent, an alcohol-based solvent and an amide-based solvent is preformed; still more preferably, a step of rinsing the film by using a rinsing solution containing an alcohol-based solvent or an ester-based solvent is performed; yet still more preferably, a step of rinsing the film by using a rinsing solution containing a monohydric alcohol is performed; and most preferably, a step of rinsing the film by using a rinsing solution containing a monohydric alcohol having a carbon number of 5 or more is performed.

The monohydric alcohol used in the rinsing step includes a linear, branched or cyclic monohydric alcohol, and specific examples of the monohydric alcohol which can be used include 1-butanol, 2-butanol, 3-methyl-1-butanol, tert-butyl alcohol, 1-pentanol, 2-pentanol, 1-hexanol, 4-methyl-2-pentanol, 1-heptanol, 1-octanol, 2-hexanol, cyclopentanol, 2-heptanol, 2-octanol, 3-hexanol, 3-heptanol, 3-octanol and 4-octanol. As the particularly preferred monohydric alcohol having a carbon number of 5 or more, 1-hexanol, 2-hexanol, 4-methyl-2-pentanol, 1-pentanol, 3-methyl-1-butanol and the like can be used.

A plurality of these components may be mixed, or the solvent may be used by mixing it with an organic solvent other than those described above.

The water content ratio in the rinsing solution is preferably 10 mass % or less, more preferably 5 mass % or less, still more preferably 3 mass % or less (In this specification, mass ratio is equal to weight ratio.). By setting the water content ratio to 10 mass % or less, good development characteristics can be obtained.

The vapor pressure at 20° C. of the rinsing solution used after the step of performing development by using an organic solvent-containing developer is preferably from 0.05 to 5 kPa, more preferably from 0.1 to 5 kPa, and most preferably from 0.12 to 3 kPa. By setting the vapor pressure of the rinsing solution to the range from 0.05 to 5 kPa, the temperature uniformity in the wafer plane is enhanced and furthermore, swelling due to permeation of the rinsing solution is suppressed, as a result, the dimensional uniformity in the wafer plane is improved.

The rinsing solution may be also used after adding thereto an appropriate amount of a surfactant.

In the rinsing step, the wafer after development using an organic solvent-containing developer is rinsed by using the above-described organic solvent-containing rinsing solution. The method for rinsing treatment is not particularly limited but, for example, a method of continuously ejecting the rinsing solution on the substrate spinning at a constant speed (spin coating method), a method of dipping the substrate in a bath filled with the rinsing solution for a fixed time (dipping method), and a method of spraying the rinsing solution on the substrate surface (spraying method) can be applied. Above all, it is preferred to perform the rinsing treatment by the spin coating method and after the rinsing, remove the rinsing solution from the substrate surface by spinning the substrate at a rotational speed of 2,000 to 4,000 rpm. It is also preferred to include a heating step (Post Bake) after the rinsing step. Thanks to the baking, the developer and rinsing solution remaining between patterns and in the inside of the pattern are removed. The heating step after the rinsing step is performed at usually from 40 to 160° C., preferably from 70 to 95° C., for usually from 10 seconds to 3 minutes, preferably from 30 to 90 seconds.

Thereafter, etching is performed (step S6, “Etching” of FIG. 1).

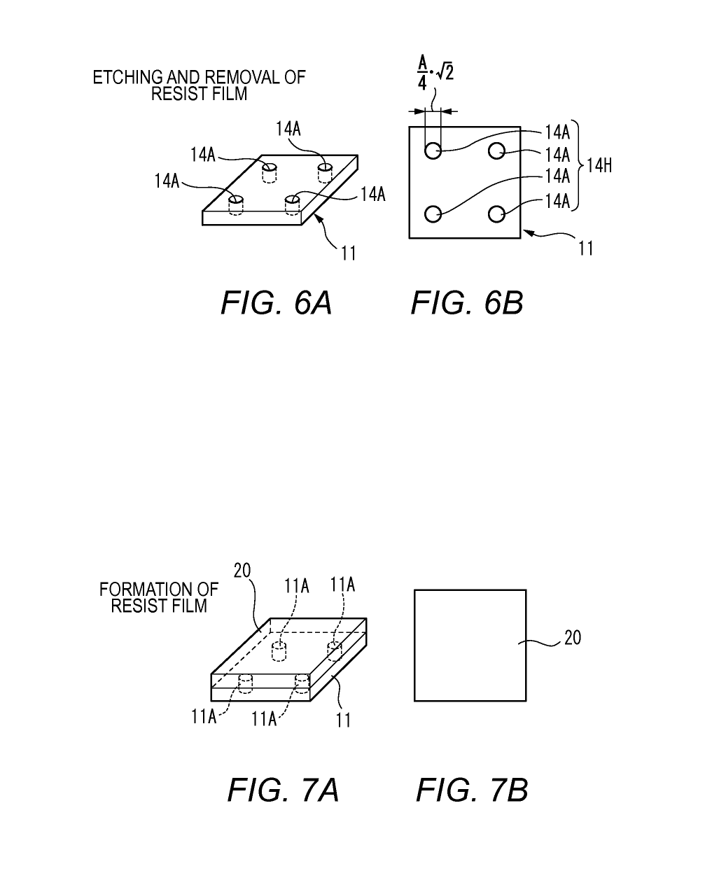

FIGS. 6A and 6B are a schematic perspective view and a schematic top view, respectively, partially illustrating the state after performing steps S6 and S7 of FIG. 1.

By performing etching, as shown in FIGS. 6A and 6B, the substrate 10 shown in FIG. 5A is perforated at positions corresponding to the first resist hole pattern group 23H of the resist film 23 to form a substrate 11 in which a first hole pattern group 14H consisting of a plurality of first hole patterns 14A is formed. The first hole pattern 14A may be a through hole or a non-through hole according to usage, but in this embodiment, a through hole is formed.

The etching method is not particularly limited, and any known method can be used. Various conditions and the like are appropriately determined according to the kind of the substrate, the usage, and the like. Etching can be performed, for example, in accordance with Proc. of SPIE, Vol. 6924, 692420 (2008) and JP-A-2009-267112.

Thereafter, the resist film is removed (step S7, “Removal of Resist Film” of FIG. 1).

The method for removing the resist film is not particularly limited, and any known method may be used. For example, the removal can be performed by a wet method described in JP-A-2002-158200, JP-A-2003-249477, and Tsuyoshi Hattori, “Chapter 6. Sheet-by-Sheet Cleaning Technique”, Electronics Cleaning Technology, Technical Information Institute Co., Ltd., pp. 157-193 (2007).

By performing the thus-described first pattern formation shown in FIG. 1 (steps S1 to S7), a substrate 11 having formed therein a first hole pattern group 14H consisting of a plurality of first hole patterns 14A that are arranged in a square grid pattern, is produced.

The diameter of the circular cross-section of the first hole pattern 14A in the plane direction of the substrate 11 and the center-to-center distance (pitch) of the first hole pattern 14A correspond to the diameter of the circular cross-section of the first resist hole pattern 23A in the plane direction of the resist film 23 shown in FIGS. 5A and 5B and the center-to-center distance (pitch) of the first resist hole pattern 23A, respectively, and specifically, are expressed by (A/4)·(√2) and A·(√2), respectively.

After the first pattern formation, as shown in FIG. 1, second pattern formation (steps S8 to S14) is performed.

In the second pattern formation, first of all, a resist film is formed (step S8, “Formation of Resist Film” of FIG. 1) by the same method as in step S1.

FIGS. 7A and 7B are a schematic perspective view and a schematic top view, respectively, partially illustrating the state after performing step S8 of FIG. 1.

More specifically, as shown in FIGS. 7A and 7B, in step S8, a resist film 20 is formed on the substrate 11 by using a chemical amplification resist composition. The chemical amplification resist composition in step S8 may be the same as or different from the composition used in step S1 as long as it contains (A) a resin capable of increasing the polarity by the action of an acid to decrease the solubility for an organic solvent-containing developer and (B) a compound capable of generating an acid upon irradiation with an actinic ray or radiation, but the composition is preferably the same composition as that used in step S1.

The method for forming the resist film 20 from the resist composition and the preferred range of the thickness of the resist film 20 are the same as those described in step S1.

Also, similarly to step S1, after coating the resist composition, the substrate may be heated (Prebake (PB)), if desired.

Next, first exposure is performed (step S9, “First Exposure” of FIG. 1).

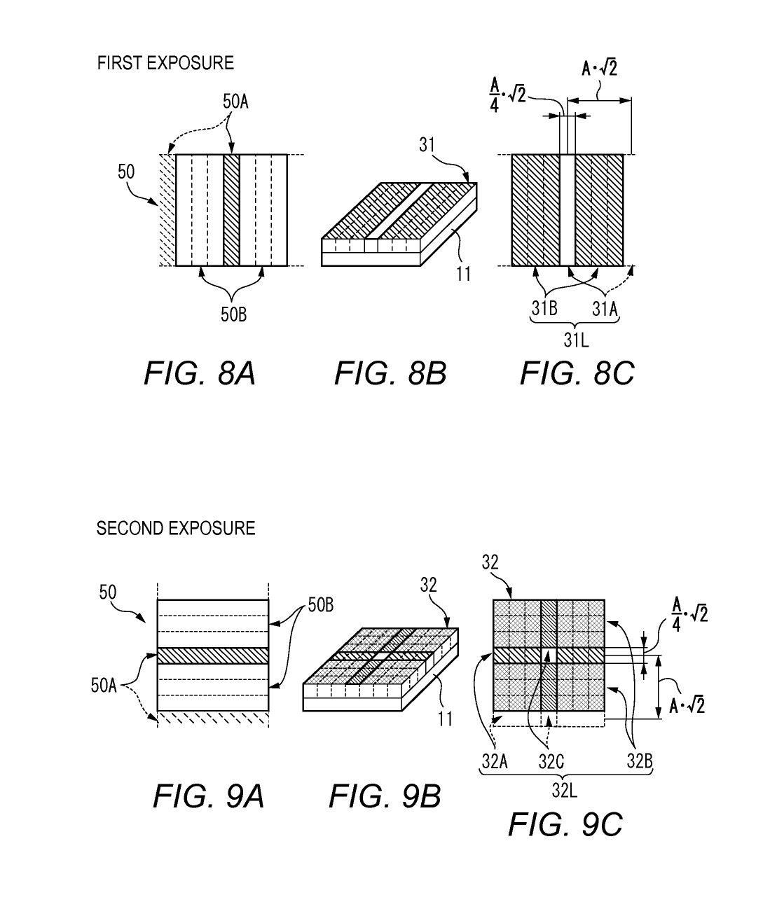

FIG. 8A is a schematic top view illustrating a part of the mask used in step S9 of FIG. 1, and FIGS. 8B and 8C are a schematic perspective view and a schematic top view, respectively, partially illustrating the state after performing step S9 of FIG. 1.

As shown in FIG. 8A, the mask 50 is the same as the mask 50 shown in FIG. 3A, but in step S9, the mask 50 shown in FIG. 3A in step S2 is used in a state of being shifted in the direction perpendicular to the longitudinal direction of the light-shielding mask line by a distance corresponding to ½ of the pitch of light-shielding mask lines (half pitch), that is, by a distance expressed by (½)·k·A·(√2).

First exposure is, more specifically, performed on the surface of the resist film 20 through the mask 50 shown in FIG. 8A.

As shown in FIGS. 8B and 8C, by the first exposure, the resist film 20 shown in FIGS. 7A and 7B is reformed into a resist film 31 having formed therein a first line-and-space latent image 31L. Here, in the first line-and-space latent image 31L, a first space group 31A formed by blocking light by the mask line group 50A and a first line group 31B formed by transmitting light through the mask space group 50B are alternately arranged.

The width of each of a plurality of first spaces constituting the first space group 31A and the distance between adjacent first spaces (pitch) correspond to the width of each of the plurality of light-shielding mask lines constituting the mask line group 50A and the distance between adjacent light-shielding mask lines, respectively.

That is, the width of the first space is expressed by (A/4)·(√/2), and the distance between adjacent first spaces is expressed by A·(√2).

Subsequently, second exposure is performed (step S10, “Second Exposure” of FIG. 1).

FIG. 9A is a schematic top view illustrating a part of the mask used in step S10 of FIG. 1, and FIGS. 9B and 9C are a schematic perspective view and a schematic top view, respectively, partially illustrating the state after performing step S10 of FIG. 1.

The second exposure is, more specifically, performed through the mask 50 shown in FIG. 9A. Here, the mask 50 is used in a state of the mask 50 shown in FIG. 8A being rotated by 90° (in a state where the light-shielding mask line of the mask 50 shown in FIG. 9A in step S10 runs at right angles to the light-shielding mask line of the mask 50 shown in FIG. 8A in step S9). In other words, in step S10, the mask 50 shown in FIG. 4A in step S3 is used in a state of being shifted in the direction perpendicular to the longitudinal direction of the light-shielding mask line by a distance corresponding to ½ of the pitch of light-shielding mask lines (half pitch), that is, by a distance expressed by (½)·k·A·(√2).

As shown in FIGS. 9B and 9C, by the second exposure, the resist film 31 shown in FIGS. 8B and 8C is reformed into a resist film 32 in which a second line-and-space latent image 32 is formed in addition to the first line-and-space latent image 31L. Here, in the second line-and-space latent image 32L, a second space group 32A formed by blocking light by the mask line group 50A and a second line group 32B formed by transmitting light through the mask space group 50B are alternately arranged. The second line-and-space latent image 32L is provided so that its line direction (defining also a longitudinal direction of the space) runs at right angles to the line direction (defining also a longitudinal direction of the space) in the first line-and-space latent image 31L.

The width of each of a plurality of second spaces constituting the second space group 32A and the distance between adjacent second spaces (pitch) correspond to the width of each of the plurality of light-shielding mask lines constituting the mask line group 50A and the distance between adjacent light-shielding mask lines, respectively.

That is, the width of the second space is expressed by (A/4)·(√2), and the distance between adjacent second spaces is expressed by A·(√2).

In other words, by the above-described first exposure and second exposure, a plurality of unexposed areas 32C that are not exposed in either the first exposure or the second exposure are formed at intervals of A·(√2) in a square grid pattern in the resist film 32. Here, the cross-section of the unexposed area 32C in the plane direction of the resist film 32 has a square profile with one side being (A/4)·(√2).

The methods for first exposure and second exposure (steps S9 and S10 of FIG. 1) in the second pattern formation are the same as those described for first exposure and second exposure (steps S2 and S3 of FIG. 1) in the first pattern formation.

Thereafter, heating after exposure (PEB; Post Exposure Bake) is performed (step S11, “Post-Exposure Bake” of FIG. 1).

The conditions and the like of the post-exposure bake are the same as those described for the post-exposure bake (step S4 of FIG. 1) in the first pattern formation.

Incidentally, similarly to first pattern formation, such heating may be performed after forming the first line-and-space latent image 31L but before forming the second line-and-space latent image 32L (that is, after the first exposure but before the second exposure).

Thereafter, development is performed (step S12, “Development” of FIG. 1). By the development, a negative pattern is formed.

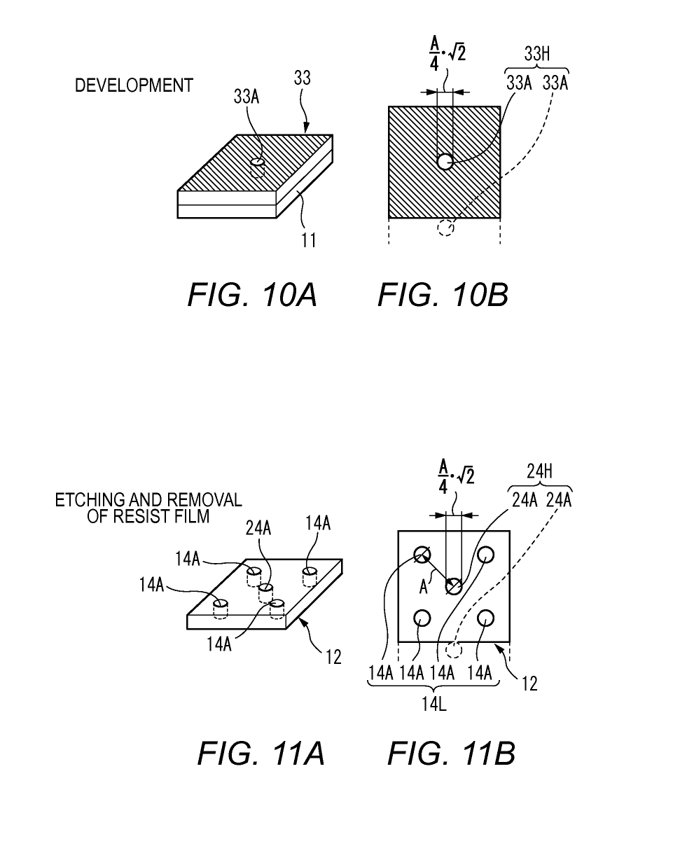

FIGS. 10A and 10B are a schematic perspective view and a schematic top view, respectively, partially illustrating the state after performing step S12 of FIG. 1.

More specifically, as shown in FIGS. 10A and 10B, by the development, the resist film 32 shown in FIGS. 9B and 9C is reformed into a resist film 33 having formed therein a second resist hole pattern group 33H consisting of a plurality of second resist hole patterns 33A. Here, each of the plurality of second resist hole patterns 33A is a through hole formed after the unexposed area 32C shown in FIG. 9C is dissolved in the developer and removed.

Also, the dimension of the second resist hole pattern 33A corresponds to the dimension of the unexposed area 22C shown in FIG. 9C, and the second resist hole pattern 33A is in a cylindrical form where the diameter of the circular cross-section in the plane direction of the resist film 33 is (A/4)·(√2).

The developer, developing method and the like in the development are the same as those described for the development (step S5 of FIG. 1) in the first pattern formation.

Furthermore, similarly to step S5, also in step S12, a rinsing step is preferably performed after development, and the rinsing solution, rinsing method and the like in the rinsing step are the same as those described for the development in the first pattern formation.

Thereafter, etching is performed (step S13, “Etching” of FIG. 1).

FIGS. 11A and 11B are a schematic perspective view and a schematic top view, respectively, partially illustrating the state after performing steps S13 and S14 of FIG. 1.

By performing etching, as shown in FIGS. 11A and 11B, the substrate 11 shown in FIG. 10A is perforated at positions corresponding to the second resist hole pattern group 33H of the resist film 33 to form a substrate 12 in which a second hole pattern group 24H consisting of a plurality of second hole patterns 24A is formed. The second hole pattern 24A may be a through hole or a non-through hole according to usage, but in this embodiment, a through hole is formed.

As described in the first pattern formation, the etching method is not particularly limited, and any known method can be used. Various conditions and the like are appropriately determined according to the kind of the substrate, the usage, and the like.

Thereafter, the resist film is removed (step S14, “Removal of Resist Film” of FIG. 1).

As described in the first pattern formation, the method for removing the resist film is not particularly limited, and any known method may be used.

By performing the thus-described second pattern formation shown in FIG. 1 (steps S8 to S14), a substrate 12 having formed therein, in addition to the first hole pattern group 14H, a second hole pattern group 24H consisting of a plurality of second hole patterns 24A that are arranged in a square grid pattern, is produced.

The diameter of the circular cross-section of the second hole pattern 24A in the plane direction of the substrate 11 and the center-to-center distance (pitch) of the second hole pattern 24A correspond to the diameter of the circular cross-section of the second resist hole pattern 33A in the plane direction of the resist film 33 shown in FIGS. 10A and 10B and the center-to-center distance (pitch) of the second resist hole pattern 33A, respectively, and specifically, are expressed by (A/4)·(√2) and A·(√2), respectively.

As described above, in the first exposure and the second exposure of the second pattern formation, the mask 50 is used in a state of being shifted in the direction perpendicular to the longitudinal direction of the light-shielding mask line by a distance corresponding to ½ of the pitch of light-shielding mask lines (half pitch), that is, by a distance expressed by (½)·k·A·(√2), with respect to the state in the first exposure and the second exposure of the first pattern formation.

Accordingly, the second resist hole pattern group 33H formed through development in the second pattern formation is formed such that the plurality of second resist hole patterns 33A constituting the group do not correspond to the plurality of first hole patterns 14A in the substrate 11 (in other words, when viewed from the top, all of the plurality of second resist hole patterns 33A do not overlap any of first hole patterns 14A).

In this way, all of the plurality of second hole patterns 24A formed in the substrate 12 by the etching step in the second pattern formation are formed at positions different from all positions of the plurality of first hole patterns 14A formed in the first pattern forming step.

As a result, a substrate 12 where the center-to-center distance (pitch) of the plurality of hole patterns 14A and 24A becomes the distance A between the first hole pattern 14A and the second hole pattern 24A is produced.

The distance A is not particularly limited but, considering further progress of miniaturization, is preferably 80 nm or less, more preferably 70 nm or less, still more preferably from 56 to 70 nm. That is, the half pitch of hole patterns is preferably 40 nm or less, more preferably 35 nm or less, still more preferably from 28 to 35 nm.

Accordingly, in each of the plurality of hole patterns 14A and 24A, the diameter of the circular cross-section in the plane direction of the substrate 11 is preferably 28 nm or less, more preferably 25 nm or less, still more preferably from 20 to 25 nm.

Even if the pitch of hole patterns is 56 nm that is the lower limit in the above-described preferred range, in the first exposure in each of the first and second pattern formations, the distance between first spaces (pitch) is 56×√2=about 79 nm. Similarly, in the second exposure in each of the first and second pattern formations, the distance between second spaces (pitch) is about 79 nm.

Accordingly, in each of the first exposure and the second exposure, the half pitch of spaces becomes about 40 nm, so that when the ArF immersion exposure technology having a resolution limit of about 39 nm as described above is employed, each of the distance A and the diameter of the hole pattern can be made to have a value in the preferred range above.

In this way, according to the pattern forming method of the first embodiment of the present invention, a plurality of hole patterns can be formed in the substrate with an ultrafine (for example, 80 nm or less) pitch.

Incidentally, in each of the first pattern formation and the second pattern formation, the first exposure and the second exposure are preferably performed under overlay control. As the method for overlay control, a known method (for example, J. Micro/Nanolith. MEMS MOEMS, 8, 011003 (2009)) can be employed without limitation. The overlay control is preferably performed such that the overlay precision (3σ) becomes less than 3 nm.

Also, according to the pattern forming method of the first embodiment (and the later-described second to fifth embodiments) of the present invention, the resist film 20 is formed from a chemical amplification resist composition containing (A) a resin capable of increasing the polarity by the action of an acid to decrease the solubility for an organic solvent-containing developer and (B) a compound capable of generating an acid upon irradiation with an actinic ray or radiation.

Therefore, as described above, in the exposed area of the resist film, the acid generated from the compound (B) reacts with the resin (A) to increase the polarity of the resin (A) and decrease the solubility for an organic solvent-containing developer, as a result, the exposed area becomes insoluble or sparingly soluble for an organic solvent-containing developer. That is, the exposed area in the pattern forming method according to the first embodiment (and the later-described second to fifth embodiments) of the present invention is, unlike Patent Document 1, not subjected to active formation of a crosslinked body and is less likely to swell with the developer, so that a resist hole pattern with a desired shape can be formed in a resist film and in turn, a hole pattern with a desired shape can be formed in the substrate.

Also, in the case of forming a hole pattern in a resist film by a positive image forming method, (1) a double exposure technique can be hardly employed unlike the present invention or (2) in the case where a mask having formed therein a hole pattern is used, only the region in which the hole pattern is formed works out to the exposed area, and therefore, when pattern formation is performed a plurality of times as in the present invention so as to form hole patterns in a substrate particularly with an ultrafine (for example, 80 nm or less) pitch, the exposed field area in one pattern formation is further restricted. Accordingly, in the formation of a hole pattern by a positive image forming method, the light transmittance of the mask must be low.

On the other hand, the pattern forming method according to the first embodiment (and the later-described second to fifth embodiments) is a negative image forming method, so that (1) a double exposure technique can be employed and (2) by performing the pattern formation a plurality of times, the exposed field area in one pattern formation can become large. Accordingly, the light transmittance of the mask can be high and this is advantageous in view of optical characteristics, so that a resist hole pattern with a desired shape can be more reliably formed in the resist film and in turn, a hole pattern with a desired shape can be formed in the substrate.

Furthermore, according to the pattern forming method of the first embodiment (and the later-described second to fifth embodiments) of the present invention, a reversal film disclosed in Proc. of SPIE, Vol. 7274, 72740N. (2009) or a separate member such as shrink material need not be used, so that a hole pattern can be easily formed in the substrate.

As described above, in the pattern forming method according to the first embodiment of the present invention, a pattern forming step is performed twice, but the pattern forming method according to the present invention may comprise three or more pattern forming steps and in this case, the pattern forming step is preferably performed 2ⁿ⁻¹ times (n represents an integer of 3 or more and is preferably 3 or 4).

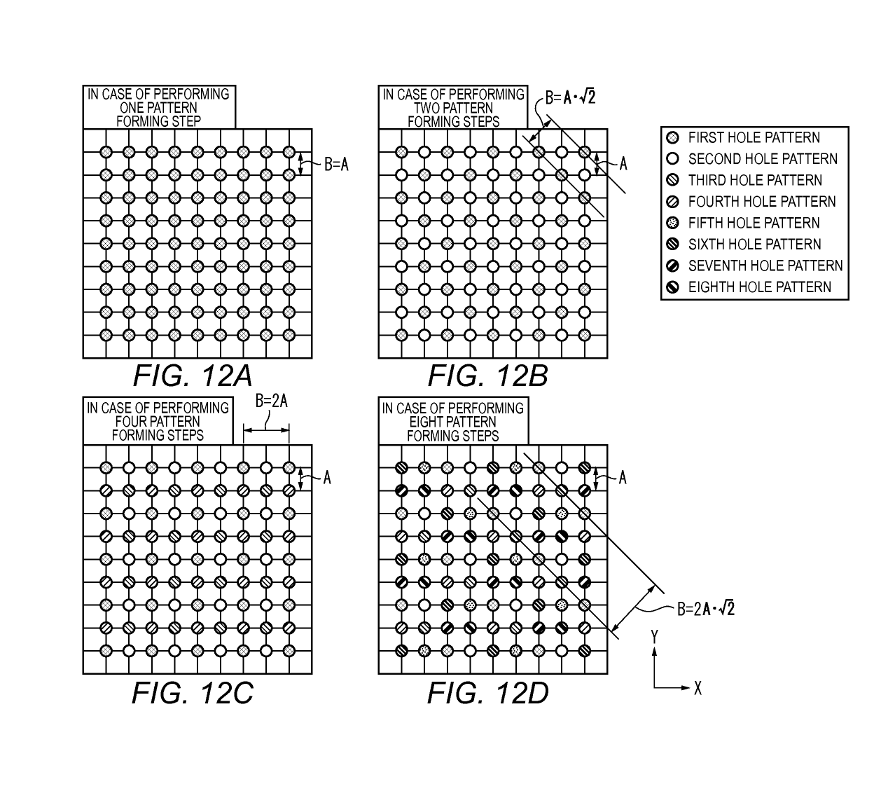

FIG. 12A is a view for explaining the pattern forming method according to Comparative Example, FIG. 12B is a view for explaining the pattern forming method according to a first embodiment of the present invention, FIG. 12C is a view for explaining the pattern forming method according to a second embodiment of the present invention, and FIG. 12D is a view for explaining the pattern forming method according to a third embodiment of the present invention.

Each of FIGS. 12A to 12D illustrates a top view of a substrate in which a plurality of hole patterns are formed with a pitch of distance A in a square grid pattern.

In the pattern forming method according to Comparative Example, as shown in FIG. 12A, a plurality of hole patterns are formed by one pattern forming step.

In the pattern forming method according to a first embodiment of the present invention, as described above and as shown in FIG. 12B, a plurality of hole patterns are formed by two pattern forming steps.

In the pattern forming method according to a second embodiment of the present invention, as shown in FIG. 12C, a plurality of hole patterns are formed by four pattern forming steps (n above is 3).

In the pattern forming method according to a third embodiment of the present invention, as shown in FIG. 12D, a plurality of hole patterns are formed by eight pattern forming steps (n above is 4).

Each pattern forming step in the pattern forming methods according to Comparative Example and the second and third embodiments of the present invention is performed in accordance with the methods for the first pattern formation and the second pattern formation described in the first embodiment of the present invention.

With respect to the pattern forming methods according to Comparative Example and the first to third embodiments of the present invention, the number of pattern forming steps, the number of exposures, the array direction and pitch of hole patterns in one pattern forming step, and the array direction and pitch of finally obtained hole patterns are shown together in Table 1 below.

TABLE 1

| | | | | Hole Pattern Group Formed in Substrate by | | | | |
|---|---|---|---|---|---|---|---|---|
| | Conditions of Pattern | | | One Pattern Forming Step | | A Plurality of Hole Patterns | | |
| | Forming Method | | | Pitch B of a | | Finally Formed in Substrate | | |
| | | Number of | | Array Direction of a Plurality of | Plurality of Hole | Array Direction of a | | |
| | | Pattern | | Hole Patterns Constituting a Hole | Patterns | Plurality of Hole | Pitch A of a | |
| | | Forming | Number of | Pattern Group (tilt angle away | Constituting a Hole | Patterns (tilt angle | Plurality of | Half |
| Embodiment | n | Steps | Exposures | from XY axis) | Pattern Group | away from XY axis) | Hole Patterns | Pitch |
| Embodiment | 1 | 2ⁿ⁻¹ = 1 | 2ⁿ = 2 | 0° because of odd n | B = Ax√2ⁿ⁻¹ = A | 0 | A | ½A |
| of | | | | | | | | |
| Comparative | | | | | | | | |
| Example | | | | | | | | |
| First | 2 | 2ⁿ⁻¹ = 2 | 2ⁿ = 4 | +45° because of even n | B = Ax√2ⁿ⁻¹ = A√2 | 0 | A | ½A |
| embodiment | | | | | | | | |
| Second | 3 | 2ⁿ⁻¹ = 4 | 2ⁿ = 8 | 0° because of odd n | B = Ax√2ⁿ⁻¹ = 2A | 0 | A | ½A |
| embodiment | | | | | | | | |
| Third | 4 | 2ⁿ⁻¹ = 8 | 2ⁿ = 16 | +45° because of even n | B = Ax√2ⁿ⁻¹ = 2A√2 | 0 | A | ½A |
| embodiment | | | | | | | | |

As seen from Table 1, even when the pitch of hole patterns to be finally formed in the substrate is the same, as the number of pattern forming steps is increased, the pitch of hole patterns formed in the substrate by one pattern forming step is enlarged and when resolving the resist hole pattern, the optical margin is increased.

For example, in the case of forming a plurality of hole patterns in a substrate with a pitch A of 70 nm in consideration of further progress of miniaturization, the relationship of Comparative Example and first to third embodiments of the present invention is as shown in Table 2 below.

TABLE 2

| | Hole Pattern Group Formed in | | | | |
|---|---|---|---|---|---|
| | Substrate by One Pattern Forming | | | | |
| | Step | | A Plurality of Hole Patterns Finally | | |
| | Array Direction of a | | Formed in Substrate | | |
| | Plurality of Hole | | Array Direction of | | |
| | Patterns Constituting a | | a Plurality of Hole | Pitch A of | |
| | Hole Pattern Group (tilt | | Patterns (tilt angle | a Plurality | |
| | angle away from XY | | away from XY | of Hole | Half |
| Embodiment | axis) | Pitch B | axis) | Patterns | Pitch |
| Embodiment of | 0° | 70 nm | 0 | 70 nm | 35 nm |
| Comparative Example | | | | | |
| First embodiment | +45° | 99 nm | 0 | 70 nm | 35 nm |
| Second embodiment | 0° | 140 nm | 0 | 70 nm | 35 nm |
| Third embodiment | +45° | 198 nm | 0 | 70 nm | 35 nm |

Here, in the pattern forming method according to the embodiment of Comparative Example, the pitch B (=pitch A) of hole patterns formed in the substrate by one pattern forming step is 70 nm, that is, the half pitch is 35 nm, and this half pitch falls below the resolution limit (approximately from 36 to 39 nm) in the above-described ArF immersion exposure (NA=1.35), as a result, even when ArF immersion exposure is used, resist hole patterns with a pitch B cannot be resolved in the pattern forming step. Accordingly, in this case, the pattern forming method according to the embodiment of Comparative Examples cannot be implemented.

On the other hand, in the pattern forming method according to the first embodiment of the present invention where two pattern forming steps are performed, the pitch B is 99 nm, that is, the half pitch is about 49.5 nm, and since this half pitch exceeds the resolution limit in the ArF immersion exposure (NA=1.35), resist hole patterns with a pitch B can be resolved in each pattern forming step. In turn, a plurality of hole patterns can be formed in the substrate to have a pitch A of 70 nm.

Furthermore, in the second and third embodiments of the present invention where four or eight pattern forming steps are performed, the pitch B is 140 nm and 198 nm, respectively, and therefore, optical margin is more increased when resolving the resist hole patterns.

In the case of forming, by one pattern forming step, hole patterns at a resolution limit (approximately from 36 to 39 nm) of ArF immersion exposure (NA=1.35), more specifically, in the case of a pitch B of 76 nm (half pitch of 38 nm), the relationship of Comparative Example and first to third embodiments of the present invention is as shown in Table 3.

TABLE 3

| | Hole Pattern Group Formed in | | | | |
|---|---|---|---|---|---|
| | Substrate by One Pattern Forming | | | | |
| | Step | | A Plurality of Hole Patterns Finally | | |
| | Array Direction of a | | Formed in Substrate | | |
| | Plurality of Hole | | Array Direction | | |
| | Patterns Constituting a | | of a Plurality of | Pitch A of a | |
| | Hole Pattern Group (tilt | | Hole Patterns (tilt | Plurality of | |
| | angle away from XY | | angle away from | Hole | |
| Embodiment | axis) | Pitch B | XY axis) | Patterns | Half Pitch |
| Embodiment of | 0° | 76 nm | 0 | 76 nm | 38 nm |
| Comparative Example | | | | | |
| First embodiment | +45° | 76 nm | 0 | 53.7 nm | 26.9 nm |
| Second embodiment | 0° | 76 nm | 0 | 38 nm | 19 nm |
| Third embodiment | +45° | 76 nm | 0 | 26.9 nm | 13.5 nm |

In this way, according to the pattern forming methods of first to third embodiments of the present invention, a plurality of hole patterns can be formed in the substrate with a center-to-center distance (pitch A) of 70 nm or less.

In light of the pattern forming methods according to the first to third embodiments of the present invention described above, in the pattern forming method of the present invention, each center-to-center distance of a plurality of hole patterns formed in the substrate is preferably 70 nm or less, more preferably 60 nm or less, still more preferably from 25 to 60 nm, that is, each half pitch of the plurality of hole patterns is preferably 35 nm or less, more preferably 30 nm or less, still more preferably from 12.5 to 30 nm.

The “each center-to-center distance of a plurality of hole patterns formed in the substrate is 70 nm or less” as used herein means that out of a plurality of hole patterns, whichever one hole pattern is taken note of, the distance between the center of the noted hole pattern and the center of another hole pattern having its center at a position nearest the center of the noted hole pattern is 70 nm or less.

In each of the plurality of hole patterns, when the cross-section in the plane direction of the substrate is a circular cross-section, the diameter of the circular cross-section of the hole pattern is preferably 25 nm or less, more preferably 21 nm or less, still more preferably from 9 to 21 nm.

In each pattern forming step of the pattern forming methods according to the first to third embodiments of the present invention, widths of a plurality of spaces constituting the first space group of the first line-and-space latent image are equal to each other and widths of a plurality of spaces constituting the second space group of the second line-and-space latent image are equal to each other.

Also, in the pattern forming methods according to the first to third embodiments of the present invention, the second line-and-space latent image is formed such that the line direction of the second line-and-space runs at right angles to the line direction in the first line-and-space latent image.

Furthermore, in the pattern forming methods according to the first to third embodiments of the present invention, the width of the space in the first space group is the same as the width of the space in the second space group.

Thanks to these configurations, a plurality of hole patterns formed in the substrate have the same size and at the same time, the cross-sectional profile of the hole pattern in the plane direction of the substrate becomes circular.

However, the present invention is not limited to these embodiments and may be, for example, in an embodiment where the width of the space in the first space group constituting the first line-and-space latent image is different from the width of the space in the second space group constituting the second line-and-space latent image, or an embodiment where the second line-and-space latent is formed such that the line direction of the second line-and-space obliquely intersects the line direction in the first line-and-space latent image. In these embodiments, the cross-section in the plane direction of the substrate, of the hole pattern formed in the substrate, has an elliptic profile.

An embodiment where at least either one space group of the first space group constituting the first line-and-space latent image and the second space group constituting the second line-and-space latent image contains a plurality of kinds of spaces differing in the width of the space, may be also employed.

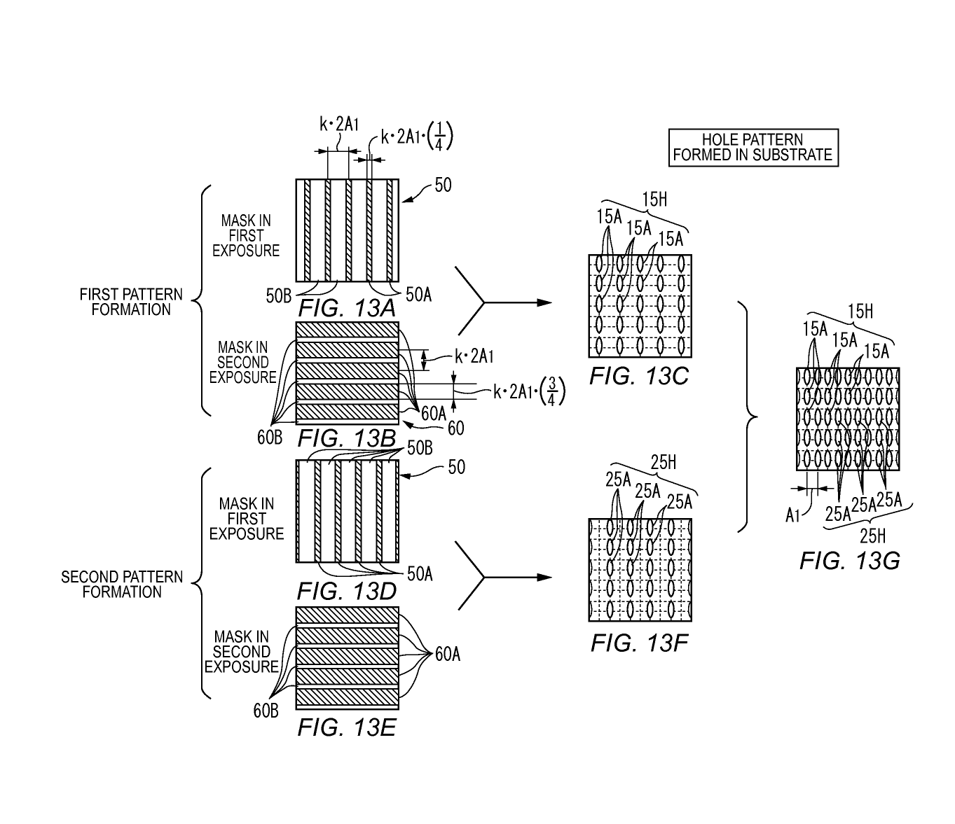

FIGS. 13A to 13G are views for explaining the pattern, forming method according to the fourth embodiment of the present invention.

More specifically, each of FIGS. 13A and 13B is a schematic top view illustrating a part of the mask used in the first exposure and the second exposure of the first pattern formation, and FIG. 13C is a schematic top view partially illustrating the state after performing the first pattern formation.

Each of FIGS. 13D and 13E is a schematic top view illustrating a part of the mask used in the first exposure and the second exposure of the second pattern formation, FIG. 13F is a schematic top view partially illustrating the state after performing the second pattern formation.

FIG. 13G is a schematic top view partially illustrating the state after performing the first and second pattern formations.

In the pattern forming method according to the fourth embodiment of the present invention, the first pattern formation and the second pattern formation are performed in the same manner as in the pattern forming method according to the first embodiment.

In the first exposure of the first pattern formation, the mask 50 shown in FIG. 13A is used. Here, the mask 50 is the same as the mask 50 shown in FIG. 3A used in the first embodiment. That is, in the mask 50, the ratio between the width of the light-shielding mask line and the width of the light-transmitting space is 1:3, but for the sake of convenience to explain the pitch of finally obtained hole patterns as A₁, in FIG. 13A, the width of the light-shielding line and the distance between adjacent light-shielding mask lines (pitch of light-shielding mask lines) are shown as k·2A₁·(¼) and k·2A₁, respectively. k has the same meaning as k described in the first embodiment.

In a first line-and-space latent image (not shown) formed by the first exposure, a first line group (not shown) and a first space group (not shown) are alternately arranged, and the width of each of a plurality of first spaces constituting the first space group and the distance (pitch) between adjacent first spaces correspond to the width of each of the plurality of light-shielding mask lines constituting the mask line group 50A and the distance between adjacent light-shielding mask lines, respectively.

That is, the width of the first space is expressed by 2A₁·(¼), and the distance between adjacent first spaces is expressed by 2A₁.

In the second exposure of the first pattern formation, the mask 60 shown in FIG. 13B is used.

As shown FIG. 13B, the mask 60 has a mask line group 60A consisting of a plurality of light-shielding mask lines and a mask space group 60B consisting of a plurality of light-transmitting spaces such that a mask line and a space are alternately arranged.

Each of the plurality of light-shielding mask lines constituting the mask line group 60A has a width expressed by k·2A₁·(¾). Also, the distances between respective adjacent light-shielding mask lines (pitch of light-shielding mask lines) are equal to each other and are expressed by k·2A₁.

That is, in the mask 60, the ratio between the width of the light-shielding mask line and the width of the light-transmitting space is 3:1.

In the second exposure, the mask 60 shown in FIG. 13B is used in a state where the light-shielding mask line of the mask runs at right angles to the light-shielding mask line of the mask 50 shown in FIG. 13A.

In a second line-and-space latent image (not shown) formed by the second exposure, a second line group (not shown) and a second space group (not shown) are alternately arranged, and the width of each of a plurality of second spaces constituting the second space group and the distance (pitch) between adjacent second spaces correspond to the width of each of the plurality of light-shielding mask lines constituting the mask line group 60A and the distance between adjacent light-shielding mask lines, respectively.

That is, the width of the second space is expressed by 2A₁·(¾), and the distance between adjacent second spaces is expressed by 2A₁.

Similarly to the first embodiment, also in the first pattern formation of the pattern forming method according to the fourth embodiment, the line direction (defining also a longitudinal direction of the space) in the first line-and-space latent image (not shown) formed in the resist film by the first exposure is in orthogonal relation with the line direction (defining also a longitudinal direction of the space) in the second line-and-space latent image (not shown) formed in the resist film by the second exposure.

In the first pattern formation including these first and second exposures and the same post-exposure baking, development, etching and removal of the resist film as in the first embodiment, a first hole pattern group 15H where as shown in FIG. 13C, a plurality of first hole patterns 15A are arranged in the line and column directions is formed in the substrate (not shown).

The first exposure in the second pattern formation is performed through the mask 50 shown in FIG. 13D.

As shown in FIG. 13D, the mask 50 is the same as the mask 50 shown in FIG. 13A, but in the first exposure of the second pattern formation, the mask 50 shown in FIG. 13A in the first exposure of the first pattern formation is used in a state of being shifted in the direction perpendicular to the longitudinal direction of the light-shielding mask line by a distance corresponding to ½ of the pitch of light-shielding mask lines (half pitch), that is, by a distance expressed by (½)·k·2A₁.

The second exposure in the second pattern formation is performed through the mask 60 shown in FIG. 13E.

As shown in FIG. 13E, the mask 60 is the same as the mask 60 shown in FIG. 13B, and the status in which the mask 60 is disposed is also the same as the state in the second exposure of the first pattern formation (see, FIG. 13B).

Accordingly, similarly to the first embodiment, in the second pattern formation of the pattern forming method according to the fourth embodiment, the line direction (defining also a longitudinal direction of the space) in the first line-and-space latent image (not shown) formed in the resist film by the first exposure is in orthogonal relation with the line direction (defining also a longitudinal direction of the space) in the second line-and-space latent image (not shown) formed in the resist film by the second exposure.

In the second pattern formation including these first and second exposures and the same post-exposure baking, development, etching and removal of the resist film as in the first embodiment, a second hole pattern group 25H where as shown in FIG. 13F, a plurality of second hole patterns 25A are arranged in the line and column directions is formed in the substrate.

By performing the first and second pattern formations described above, as shown in FIG. 13G, a first hole pattern group 15H and a second hole pattern group 25H are formed in the substrate. Here, in all of a plurality of first hole patterns 15A constituting the first hole pattern group 15H and a plurality of second hole patterns 25A constituting the second hole pattern group 25H, the cross-section in the plane direction of the substrate has an elliptic profile.

As described above, in the first exposure of the second pattern formation, the mask 50 is used in a state of being shifted in the direction perpendicular to the longitudinal direction of the light-shielding mask line by a distance corresponding to ½ of the pitch of light-shielding mask lines (half pitch), that is, by a distance expressed by (½)·k·2A₁, with respect to the state in the first exposure of the first pattern formation.

Accordingly, the second resist hole pattern group (not shown) formed through development in the second pattern formation is formed such that the plurality of second resist hole patterns (not shown) constituting the group do not correspond to the plurality of first hole patterns 15A in the substrate (in other words, when viewed from the top, all of the plurality of second resist hole patterns do not overlap any of first hole patterns 15A).

In this way, all of the plurality of second hole patterns 25A formed in the substrate by the etching step in the second pattern formation are formed at positions different from all positions of the plurality of first hole patterns 15A formed in the first pattern forming step.

As a result, the above-defined center-to-center distance (pitch) of the plurality of hole patterns 15A and 25A becomes the distance A₁ between the first hole pattern 15A and the second hole pattern 14A, which are adjacent in the column direction.

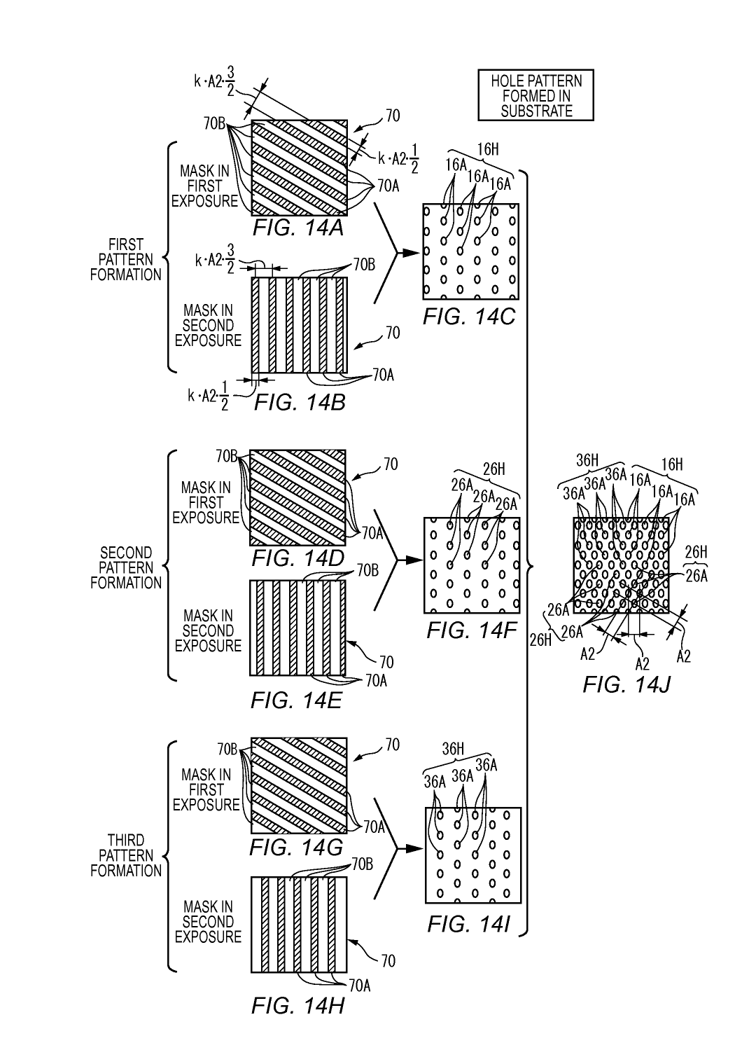

FIGS. 14A to 14J are views for explaining the pattern forming method according to a fifth embodiment of the present invention.

More specifically, each of FIGS. 14A and 14B is a schematic top view illustrating a part of the mask used in the first exposure and the second exposure of the first pattern formation, and FIG. 14C is a schematic top view partially illustrating the state after performing the first pattern formation.

Each of FIGS. 14D and 14E is a schematic top view illustrating a part of the mask used in the first exposure and the second exposure of the second pattern formation, and FIG. 14F is a schematic top view partially illustrating the state after performing the second pattern formation.

Each of FIGS. 14G and 14H is a schematic top view illustrating a part of the mask used in the first exposure and the second exposure of the third pattern formation, and FIG. 14I is a schematic top view partially illustrating the state after performing the third pattern formation.

FIG. 14J is a schematic top view partially illustrating the state after performing the first to third pattern formations.

In the pattern forming method according to the fifth embodiment of the present invention, the first pattern formation, the second pattern formation and the third pattern formation are performed in accordance with the pattern forming method of the first embodiment, except that the conditions of the mask at the exposure are changed and the number of pattern formations is changed to 3.

In the first exposure of the first pattern formation, the mask 70 shown in FIG. 14A is used.

As shown FIG. 14A, the mask 70 has a mask line group 70A consisting of a plurality of light-shielding mask lines and a mask space group 70B consisting of a plurality of light-transmitting spaces such that a mask line and a space are alternately arranged.

Each of the plurality of light-shielding mask lines constituting the mask line group 70A has a width expressed, for example, by k·A₂·(½). Also, the distances between respective adjacent light-shielding mask lines (pitch of light-shielding mask lines) are equal to each other and are expressed by k·A₂·( 3/2). Here, A₂ represents the pitch of finally obtained hole patterns. k has the same meaning as k described in the first embodiment.

That is, in the mask 70, the ratio between the width of the light-shielding mask line and the width of the light-transmitting space is, for example, 1:2.

In a first line-and-space latent image (not shown) formed by the first exposure, a first line group (not shown) and a first space group (not shown) are alternately arranged, and the width of each of a plurality of first spaces constituting the first space group and the distance (pitch) between adjacent first spaces correspond to the width of each of the plurality of light-shielding mask lines constituting the mask line group 70A and the distance between adjacent light-shielding mask lines, respectively.

That is, the width of the first space is expressed by k·A₂·(½), and the distance between adjacent first spaces is expressed by A₂·( 3/2).

In the second exposure of the first pattern formation, the mask 70 shown in FIG. 14B is used. Here, the mask 70 is used in a state of the mask 70 shown in FIG. 14A being right-rotated by 60° (in a state where the light-shielding mask line of the mask 70 shown in FIG. 14B intersects at a crossing angle of 60° with the light-shielding mask line of the mask 70 shown in FIG. 14A.

Accordingly, in the first pattern formation of the pattern forming method according to the fifth embodiment, after the second exposure, the line direction (defining also a longitudinal direction of the space) in the first line-and-space latent image (not shown) formed in the resist film by the first exposure intersects at a crossing angle of 60° with the line direction (defining also a longitudinal direction of the space) in the second line-and-space latent image (not shown) formed in the resist film.

In a second line-and-space latent image (not shown) formed by the second exposure, a second line group (not shown) and a second space group (not shown) are alternately arranged, and the width of each of a plurality of second spaces constituting the second space group and the distance (pitch) between adjacent second spaces correspond to the width of each of the plurality of light-shielding mask lines constituting the mask line group 70A and the distance between adjacent light-shielding mask lines, respectively.

That is, the width of the second space is expressed, for example, by k·A₂·(½), and the distance between adjacent second spaces is expressed by A₂·( 3/2).

In the first pattern formation including these first and second exposures and the same post-exposure baking, development, etching and removal of the resist film as in the first embodiment, a first hole pattern group 16H where as shown in FIG. 14C, a plurality of first hole patterns 16A are arranged at equal intervals is formed in the substrate (not shown).

The first exposure in the second pattern formation is performed through the mask 70 shown in FIG. 14D.

As shown in FIG. 14D, the mask 70 is the same as the mask 70 shown in FIG. 14A, but in the first exposure of the second pattern formation, the mask 70 shown in FIG. 14A in the first exposure of the first pattern formation is used in a state of being shifted in one direction (hereinafter, referred to as “first direction”) out of directions perpendicular to the longitudinal direction of the light-shielding mask line by a distance corresponding to ⅓ of the pitch of light-shielding mask lines, that is, by a distance expressed by k·A₂·(½).

The second exposure in the second pattern formation is performed through the mask 70 shown in FIG. 14E.

As shown in FIG. 14E, the mask 70 is the same as the mask 70 shown in FIG. 14B, but in the second exposure of the second pattern formation, the mask 70 shown in FIG. 14B in the second exposure of the first pattern formation is used in a state of being shifted in one direction (hereinafter, referred to as “second direction”) out of directions perpendicular to the longitudinal direction of the light-shielding mask line by a distance corresponding to ⅓ of the pitch of light-shielding mask lines, that is, by a distance expressed by k·A₂·(½).

Accordingly, similarly to the first pattern formation above, also in the second pattern formation, after the second exposure, the line direction (defining also a longitudinal direction of the space) in the first line-and-space latent image (not shown) formed in the resist film by the first exposure intersects at a crossing angle of 60° with the line direction (defining also a longitudinal direction of the space) in the second line-and-space latent image (not shown) formed in the resist film.

In the second pattern formation including these first and second exposures and the same post-exposure baking, development, etching and removal of the resist film as in the first embodiment, a second hole pattern group 26H where as shown in FIG. 14F, a plurality of second hole patterns 26A are arranged at equal intervals is formed in the substrate.

The first exposure in the third pattern formation is performed through the mask 70 shown in FIG. 14G.

As shown in FIG. 14G, the mask 70 is the same as the mask 70 shown in FIG. 14D, but in the first exposure of the third pattern formation, the mask 70 shown in FIG. 14D in the first exposure of the second pattern formation is used in a state of being shifted in the first direction by a distance corresponding to ⅓ of the pitch of light-shielding mask lines, that is, by a distance expressed by k·A₂·(½).

The second exposure in the third pattern formation is performed through the mask 70 shown in FIG. 14H.

As shown in FIG. 14H, the mask 70 is the same as the mask 70 shown in FIG. 14E, but in the second exposure of the third pattern formation, the mask 70 shown in FIG. 14E in the second exposure of the second pattern formation is used in a state of being shifted in the second direction by a distance corresponding to ⅓ of the pitch of light-shielding mask lines, that is, by a distance expressed by k·A₂·(½).

Accordingly, similarly to the first and second pattern formations above, also in the third pattern formation, after the second exposure, the line direction (defining also a longitudinal direction of the space) in the first line-and-space latent image (not shown) formed in the resist film by the first exposure intersects at a crossing angle of 60° with the line direction (defining also a longitudinal direction of the space) in the second line-and-space latent image (not shown) formed in the resist film.

In the third pattern formation including these first and second exposures and the same post-exposure baking, development, etching and removal of the resist film as in the first embodiment, a third hole pattern group 36H where as shown in FIG. 14I, a plurality of third hole patterns 36A are arranged in line and column directions is formed in the substrate.

By performing the first to third pattern formation described above, as shown in FIG. 14J, a first hole pattern group 16H, a second hole pattern group 26H, and a third hole pattern group 36H are formed in the substrate.

As described above, in each of the first exposure and the second exposure of the second pattern formation, the mask 70 is used in a state of being shifted in the direction perpendicular to the longitudinal direction of the light-shielding mask line by a distance corresponding to ⅓ of the pitch of light-shielding mask lines, that is, by a distance expressed by k·A₂·(½), with respect to the state in the first exposure and the second exposure of the first pattern formation.

Also, in each of the first exposure and the second exposure of the third pattern formation, the mask 70 is used in a state of being further shifted in the direction perpendicular to the longitudinal direction of the light-shielding mask line by a distance corresponding to ⅓ of the pitch of light-shielding mask lines, that is, by a distance expressed by (½)·k·2A₁, with respect to the state in the first exposure and the second exposure of the first pattern formation.

Accordingly, the second resist hole pattern group (not shown) formed through development in the second pattern formation is formed such that the plurality of second resist hole patterns (not shown) constituting the group do not correspond to the plurality of first hole patterns 16A in the substrate (in other words, when viewed from the top, all of the plurality of second resist hole patterns do not overlap any of first hole patterns 16A).

Similarly, the third resist hole pattern group (not shown) formed through development in the third pattern formation is formed such that the plurality of third resist hole patterns (not shown) constituting the group do not correspond to the plurality of second hole patterns 26A in the substrate (in other words, when viewed from the top, all of the plurality of third resist hole patterns do not overlap any of second hole patterns 26A).

In this way, all of the plurality of second hole patterns 26A formed in the substrate by the etching step in the second pattern formation are formed at positions different from all positions of the plurality of first hole patterns 16A formed in the first pattern forming step.

Also, all of the plurality of third hole patterns 36A formed in the substrate by the etching step in the third pattern formation are formed at positions different from all positions of the plurality of second hole patterns 26A formed in the second pattern forming step.

As a result, the above-defined center-to-center distance (pitch) of the plurality of hole patterns 16A, 26A and 36A becomes the distance A₂ between the adjacent first hole pattern 16A and second hole pattern 26A.

Incidentally, in the pattern forming method according to the fifth embodiment of the present invention, when out of a plurality of hole patterns formed in the substrate, one arbitrary hole pattern is taken note of, the distance between the center of the noted hole pattern and the center of another adjacent hole pattern is the same for all of other six hole patterns adjacent to the noted hole pattern. Accordingly, the above-defined center-to-center distance (pitch) of the plurality of hole patterns 16A, 26A and 36A is, as shown in FIG. 14J, also the distance A₂ between the first hole pattern 16A and the third hole pattern 36A adjacent to each other or the distance A₂ between the second hole pattern 26A and the third hole pattern 36A adjacent to each other.

In each pattern formation of the pattern forming method according to the fifth embodiment of the present invention, widths of a plurality of spaces constituting the first space group of the first line-and-space latent image are equal to each other and widths of a plurality of spaces constituting the second space group of the second line-and-space latent image are equal to each other.

In the pattern forming methods according to the first to fifth embodiments of the present invention, the mask is not particularly limited in its kind but is preferably a photomask selected from a binary mask (a mask where the transmittance of the light-transmitting part is 0%) and a phase-shift mask, more preferably a binary mask.

Also, as for the exposure in the step of forming the first line-and-space latent image and the step of forming the second line-and-space latent image, exposure using dipole illumination may be employed. Exposure by dipole illumination is usually exposure where an optical image is optimized in the line direction of the first line group and the line direction of the second line group.

In the photomask used in the first exposure and the second exposure of each pattern formation, the ratio between the width of the light-shielding mask line and the width of the light-transmitting space is appropriately changed according to, for example, the profile and size of the hole pattern intended to form and the pitch of the hole pattern but is preferably from 1:10 to 10:1, more preferably from 1:5 to 5:1, still more preferably from 1:5 to 1:1.

In each pattern forming step of the pattern forming method, the mask used for the first exposure and the mask used for the second exposure may be used as another mask not only when by rotating one mask, the mask shape comes to disagree with that of the other but also when agrees.

Also, a single mask where a region of a mask used for the first exposure and a region of a mask used for the second exposure are arranged as different regions may be used.

Moreover, the present invention relates to a method for manufacturing an electronic device, comprising the pattern forming method of the present invention, and an electronic device manufactured by this manufacturing method.

The electronic device of the present invention is suitably mounted on electric electronic equipment (such as home electronic device, OA•media-related device, optical device and communication device).

A chemical amplification resist composition (more specifically, a negative resist composition) containing (A) a resin capable of increasing the polarity by the action of an acid to decrease the solubility for an organic solvent-containing developer and (B) a compound capable of generating an acid upon irradiation with an actinic ray or radiation, which is used in the pattern forming method of the present invention, is described in detail below.

Incidentally, the exposed area composed of a crosslinked body tends to make it difficult to form a desired hole due to swelling even when the developer is an organic developer. On this account, the chemical amplification resist composition for use in the present invention preferably contains substantially no crosslinking agent selected from, for example, “a crosslinking agent capable of crosslinking with the resin (A) by the action of an acid to form a crosslinked body” and “a crosslinking agent capable of crosslinking with another crosslinking agent by the action of an acid to form a crosslinked body” (specifically, the content of the crosslinking agent is, based on the entire solid content of the chemical amplification resist composition, preferably 1 mol % or less, more preferably 0.5 mol % or less, ideally 0 mol %, that is, not containing a crosslinking agent).

### [1] (A) Resin Capable of Increasing the Polarity by the Action of an Acid to Decrease the Solubility for an Organic Solvent-Containing Developer

The resin capable of increasing the polarity by the action of an acid to decrease the solubility for an organic solvent-containing developer, which is used in the resist composition of the present invention, includes, for example, a resin having a group capable of decomposing by the action of an acid to produce a polar group (hereinafter sometimes referred to as an “acid-decomposable group”), on either one or both of the main and side chains of the resin (hereinafter sometimes referred to as an “acid-decomposable resin” or a “resin (A)”).

The acid-decomposable group preferably has a structure where a polar group is protected by a group capable of decomposing and leaving by the action of an acid.

The polar group is not particularly limited as long as it is a group capable of becoming sparingly soluble or insoluble in an organic solvent-containing developer, but examples thereof include a phenolic hydroxyl group, an acidic group (a group capable of dissociating in an aqueous 2.38 mass % tetramethylammonium hydroxide solution which has been conventionally used as the developer for a resist) such as carboxyl group, fluorinated alcohol group (preferably hexafluoroisopropanol group), sulfonic acid group, sulfonamide group, sulfonylimide group, (alkylsulfonyl)(alkylcarbonyl)methylene group, (alkylsulfonyl)(alkylcarbonyl)imide group, bis(alkylcarbonyl)methylene group, bis(alkylcarbonyl)imide group, bis(alkylsulfonyl)methylene group, bis(alkylsulfonyl)imide group, tris(alkylcarbonyl)methylene group and tris(alkylsulfonyl)methylene group, and an alcoholic hydroxyl group.

The alcoholic hydroxyl group is a hydroxyl group bonded to a hydrocarbon group and indicates a hydroxyl group except for a hydroxyl group directly bonded on an aromatic ring (phenolic hydroxyl group), and an aliphatic alcohol substituted with an electron-withdrawing group such as fluorine atom at the α-position (for example, a fluorinated alcohol group (e.g., hexafluoroisopropanol)) is excluded from the hydroxyl group. The alcoholic hydroxyl group is preferably a hydroxyl group having a pKa of 12 to 20.

Preferred polar groups include a carboxyl group, a fluorinated alcohol group (preferably a hexafluoroisopropanol group) and a sulfonic acid group.

The group preferred as the acid-decomposable group is a group where a hydrogen atom of the group above is substituted for by a group capable of leaving by the action of an acid.

Examples of the group capable of leaving by the action of an acid include —C(R₃₆)(R₃₇)(R₃₈), —C(R₃₆)(R₃₇)(OR₃₉) and —C(R₀₁)(R₀₂)(OR₃₉).

In the formulae, each of R₃₆ to R₃₉ independently represents an alkyl group, a cycloalkyl group, an aryl group, an aralkyl group or an alkenyl group. R₃₆ and R₃₇ may combine with each other to form a ring.

Each of R₀₁ and R₀₂ independently represents a hydrogen atom, an alkyl group, a cycloalkyl group, an aryl group, an aralkyl group or an alkenyl group.

The alkyl group of R₃₆ to R₃₉, R₀₁ and R₀₂ is preferably an alkyl group having a carbon number of 1 to 8, and examples thereof include a methyl group, an ethyl group, a propyl group, an n-butyl group, a sec-butyl group, a hexyl group and an octyl group.

The cycloalkyl group of R₃₆ to R₃₉, R₀₁ and R₀₂ may be monocyclic or polycyclic. The monocyclic cycloalkyl group is preferably a cycloalkyl group having a carbon number of 3 to 8, and examples thereof include a cyclopropyl group, a cyclobutyl group, a cyclopentyl group, a cyclohexyl group, and a cyclooctyl group. The polycyclic cycloalkyl group is preferably a cycloalkyl group having a carbon number of 6 to 20, and examples thereof include an adamantyl group, a norbornyl group, an isoboronyl group, a camphanyl group, a dicyclopentyl group, an α-pinel group, a tricyclodecanyl group, a tetracyclododecyl group, and an androstanyl group. Incidentally, at least one carbon atom in the cycloalkyl group may be substituted with a heteroatom such as oxygen atom.

The aryl group of R₃₆ to R₃₉, R₀₁ and R₀₂ is preferably an aryl group having a carbon number of 6 to 10, and examples thereof include a phenyl group, a naphthyl group, and an anthryl group.

The aralkyl group of R₃₆ to R₃₉, R₀₁ and R₀₂ is preferably an aralkyl group having a carbon number of 7 to 12, and examples thereof include a benzyl group, a phenethyl group, and a naphthylmethyl group.

The alkenyl group of R₃₆ to R₃₉, R₀₁ and R₀₂ is preferably an alkenyl group having a carbon number of 2 to 8, and examples thereof include a vinyl group, an allyl group, a butenyl group and a cyclohexenyl group.

The ring formed by combining R₃₆ and R₃₇ is preferably a cycloalkyl group (monocyclic or polycyclic). The cycloalkyl group is preferably a monocyclic cycloalkyl group such as cyclopentyl group and cyclohexyl group, or a polycyclic cycloalkyl group such as norbornyl group, tetracyclodecanyl group, tetracyclododecanyl group and adamantyl group, more preferably a monocyclic cycloalkyl group having a carbon number of 5 to 6, still more preferably a monocyclic cycloalkyl group having a carbon number of 5.

The acid-decomposable group is preferably a cumyl ester group, an enol ester group, an acetal ester group, a tertiary alkyl ester group or the like, more preferably a tertiary alkyl ester group.

The resin (A) preferably contains a repeating unit having an acid-decomposable group, and the repeating unit having an acid-decomposable group is preferably a repeating unit represented by the following formula (AI):

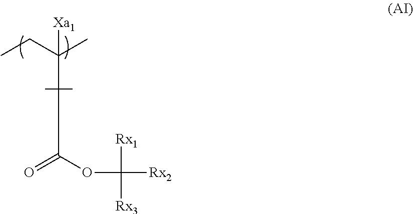

In formula (AI), Xa₁ represents a hydrogen atom, a methyl group which may have a substituent, or a group represented by —CH₂—R₉. R₉ represents a hydroxyl group or a monovalent organic group. Examples of the monovalent organic group include an alkyl group having a carbon number of 5 or less, and an acyl group having a carbon number of 5 or less. Of these, an alkyl group having a carbon number of 3 or less is preferred, and a methyl group is more preferred. Xa₁ is preferably a hydrogen atom, a methyl group, a trifluoromethyl group or a hydroxymethyl group.

T represents a single bond or a divalent linking group.

Each of Rx₁ to Rx₃ independently represents an alkyl group (linear or branched) or a cycloalkyl group (monocyclic or polycyclic).

Two members out of Rx₁ to Rx₃ may combine to form a cycloalkyl group (monocyclic or polycyclic).

Examples of the divalent linking group of T include an alkylene group, a —COO-Rt- group and a —O-Rt- group. In the formulae, Rt represents an alkylene group or a cycloalkylene group.

T is preferably a single bond or a —COO-Rt- group, more preferably a single bond. Rt is preferably an alkylene group having a carbon number of 1 to 5, more preferably a —CH₂— group, —(CH₂)₂— group or a —(CH₂)₃— group.

The alkyl group of Rx₁ to Rx₃ is preferably an alkyl group having a carbon number of 1 to 4, such as methyl group, ethyl group, n-propyl group, isopropyl group, n-butyl group, isobutyl group and tert-butyl group.

The cycloalkyl group of Rx₁ to Rx₃ is preferably a monocyclic cycloalkyl group such as cyclopentyl group and cyclohexyl group, or a polycyclic cycloalkyl group such as norbornyl group, tetracyclodecanyl group, tetracyclododecanyl group and adamantyl group.

The cycloalkyl group formed by combining two members out of Rx₁ to Rx₃ is preferably a monocyclic cycloalkyl group such as cyclopentyl group and cyclohexyl group, or a polycyclic cycloalkyl group such as norbornyl group, tetracyclodecanyl group, tetracyclododecanyl group and adamantyl group, more preferably a monocyclic cycloalkyl group having a carbon number of 5 to 6.

An embodiment where Rx₁ is a methyl group or an ethyl group and Rx₂ and Rx₃ are combined to form the above-described cycloalkyl group is also preferred.

Above all, each of Rx₁ to Rx₃ is independently, preferably a linear or branched alkyl group and is preferably a linear or branched alkyl group having a carbon number of 1 to 4, and examples thereof include a methyl group, an ethyl group, an n-propyl group, an isopropyl group, an n-butyl group, an isobutyl group, and a tert-butyl group.

In the case where each of Rx₁ to Rx₃ is independently a linear or branched alkyl group, Rx₁ is preferably a methyl group, an ethyl group, an n-propyl group or an n-butyl group, more preferably a methyl group or an ethyl group, still more preferably a methyl group. Rx₂ is preferably a methyl group, an ethyl group, an n-propyl group, an isopropyl group or an n-butyl group, more preferably a methyl group or an ethyl group, still more preferably a methyl group. Rx₃ is preferably a methyl group, an ethyl group, an n-propyl group, an isopropyl group, an n-butyl group, an isobutyl group or a tert-butyl group, more preferably a methyl group, an ethyl group, an isopropyl group or an isobutyl group, still more preferably a methyl group, an ethyl group or an isopropyl group.

In the case where T is a single bond and at the same time, each of Rx₁ to Rx₃ is independently a linear or branched alkyl group (in this case, two members out of Rx₁ to Rx₃ do not combine to form a cycloalkyl group), the pattern forming method can ensure that the roughness performance, the uniformity of local pattern dimension and the exposure latitude are more excellent and the reduction in film thickness of the pattern part formed by exposure, so-called film loss, can be more suppressed.

Each of the groups above may have a substituent, and examples of the substituent include an alkyl group (having a carbon number of 1 to 4), a halogen atom, a hydroxyl group, an alkoxy group (having a carbon number of 1 to 4), a carboxyl group, and an alkoxycarbonyl group (having a carbon number of 2 to 6). The carbon number is preferably 8 or less. Above all, from the standpoint of more enhancing the dissolution contrast for an organic solvent-containing developer between before and after acid decomposition, the substituent is preferably a group free from a heteroatom such as oxygen atom, nitrogen atom and sulfur atom (for example, preferably not an alkyl group substituted with a hydroxyl group), more preferably a group composed of only a hydrogen atom and a carbon atom, still more preferably a linear or branched alkyl group or a cycloalkyl group.

Specific preferred examples of the repeating unit having an acid-decomposable group are illustrated below, but the present invention is not limited thereto.

In specific examples, each of Rx and Xa₁ represents a hydrogen atom, CH₃, CF₃ or CH₂OH, and each of Rxa and Rxb represents an alkyl group having a carbon number of 1 to 4. Z represents a substituent, and when a plurality of Zs are present, each Z may be the same as or different from every other Z. p represents 0 or a positive integer. Specific examples and preferred examples of Z are the same as specific examples and preferred examples of the substituent which may be substituted on each of the groups such as Rx₁ to Rx₃.

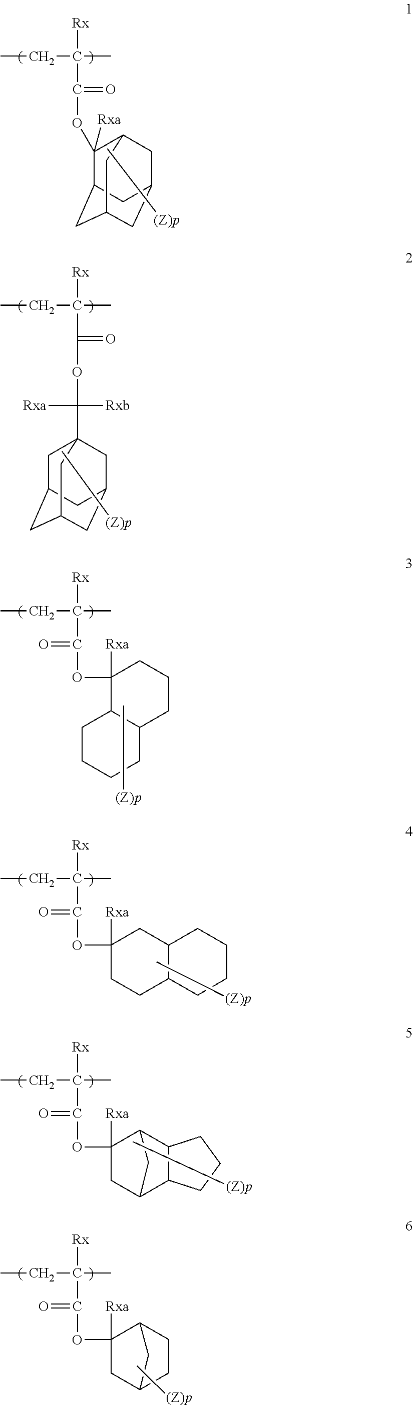

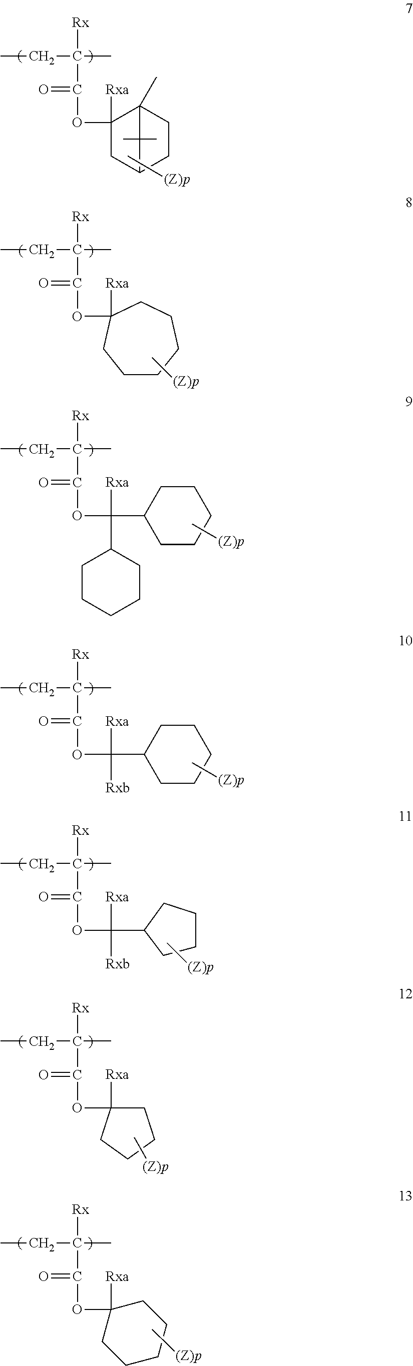

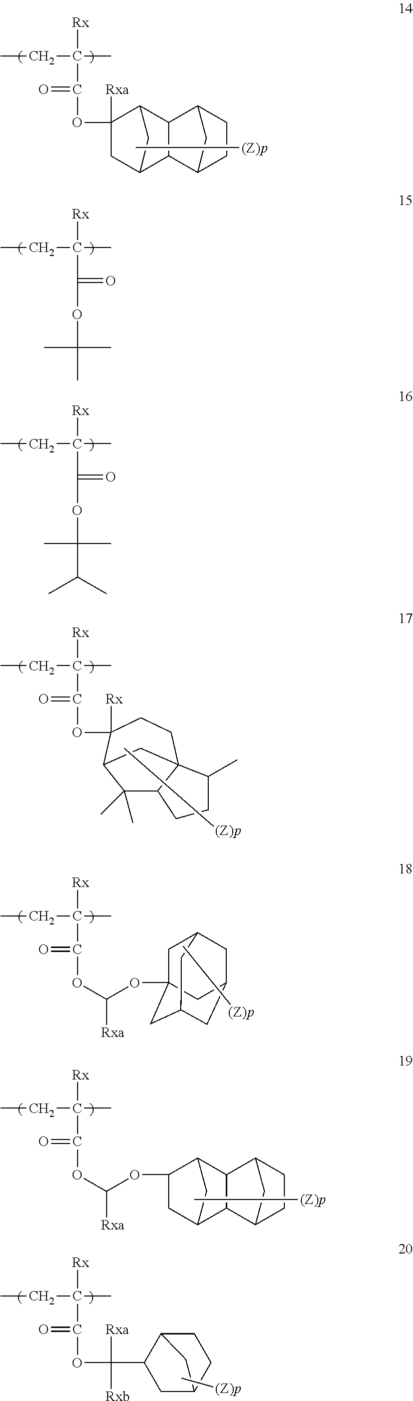

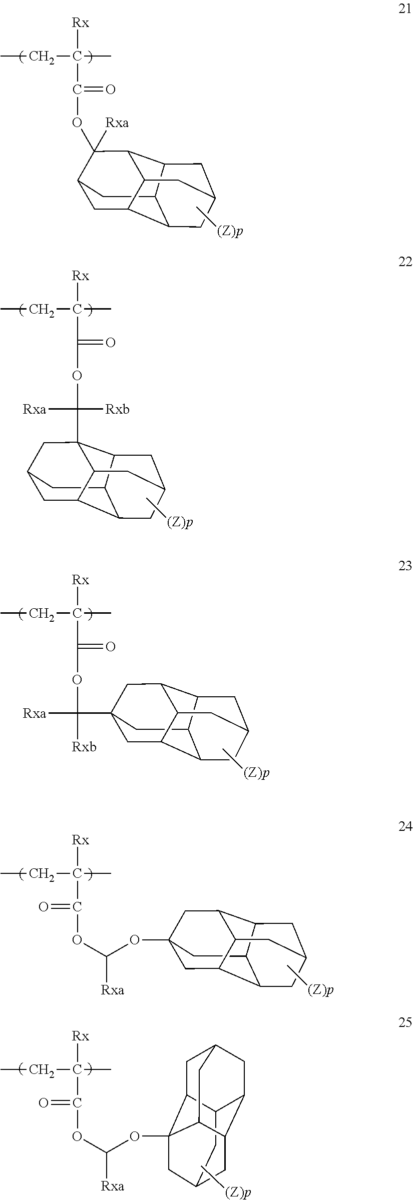

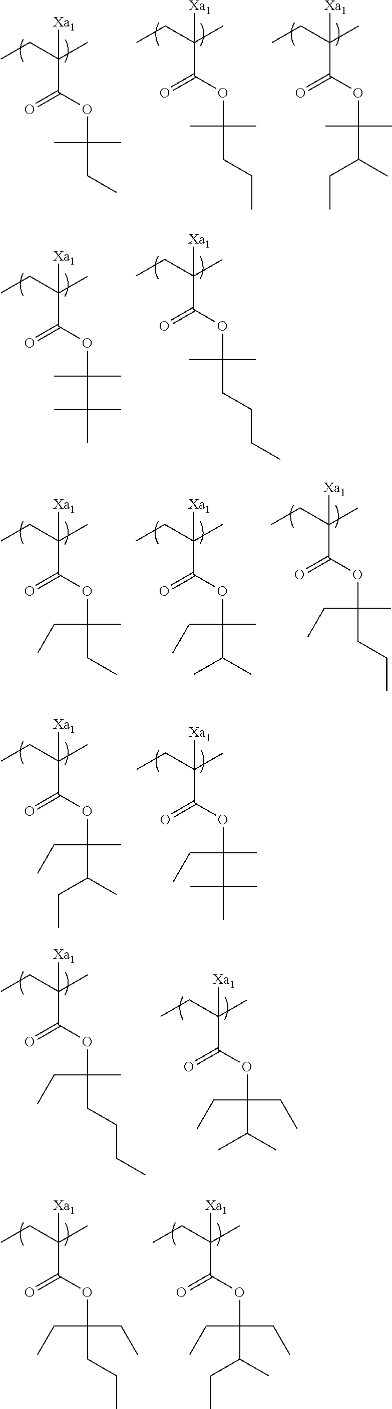

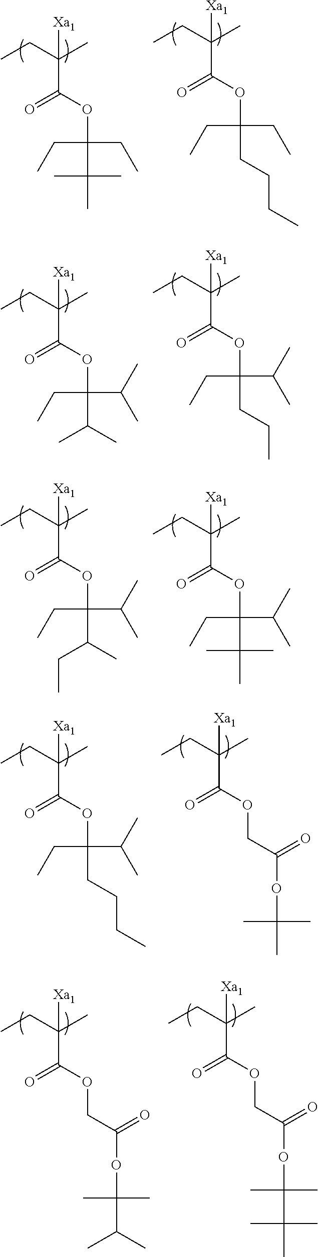

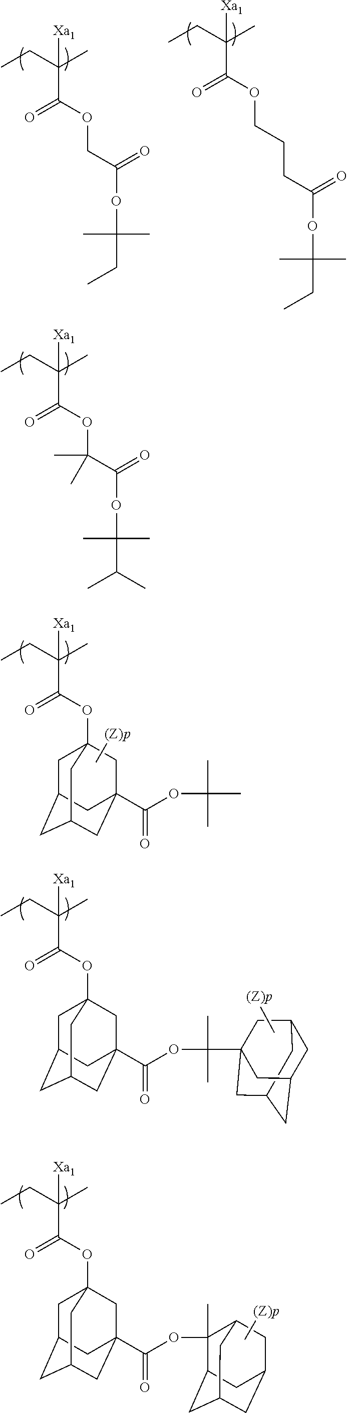

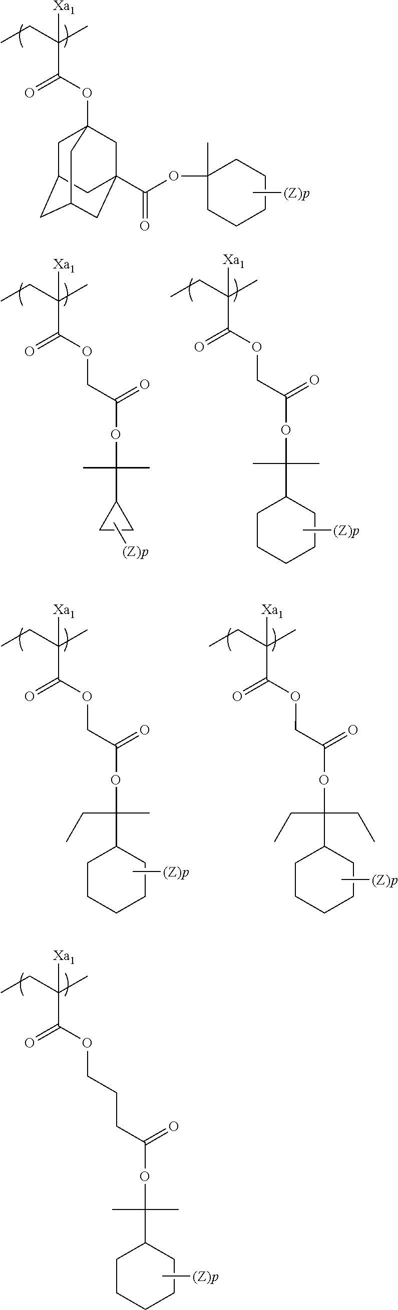

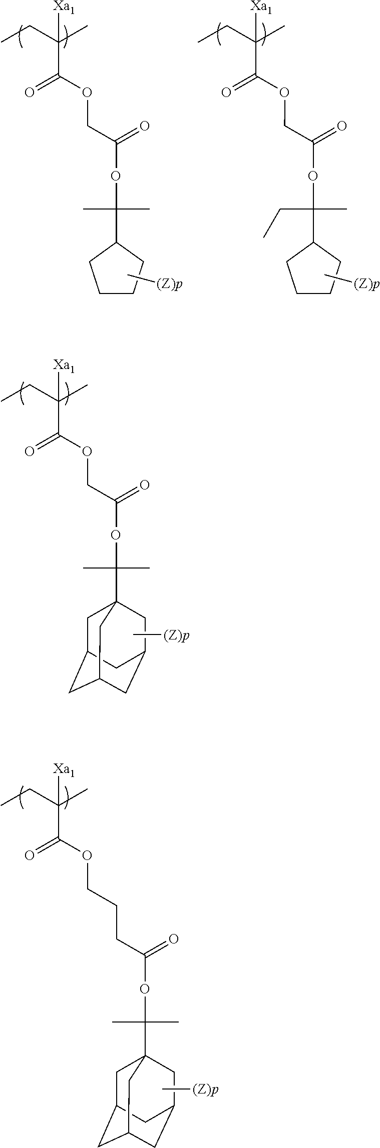

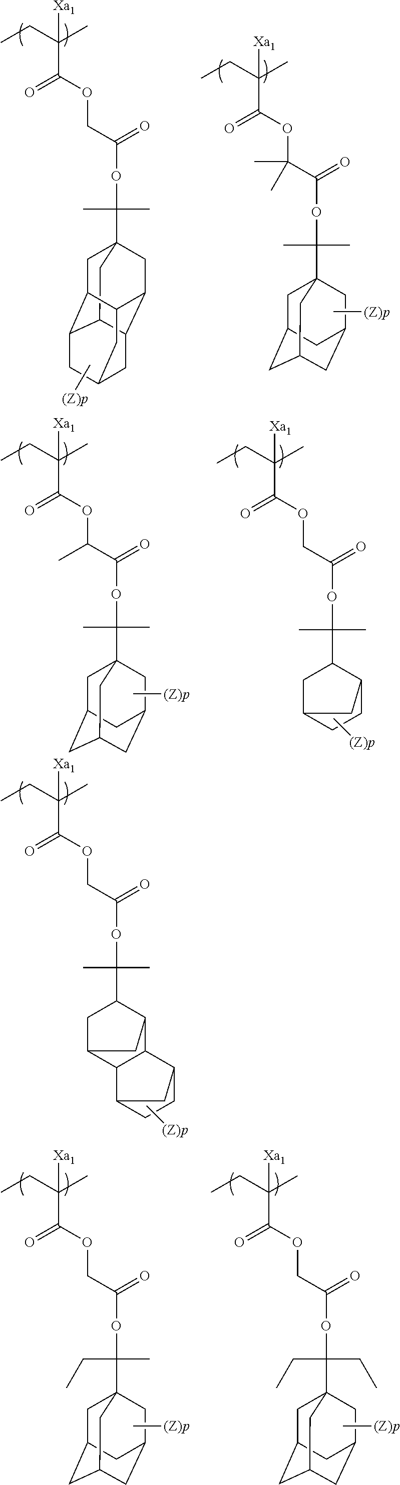

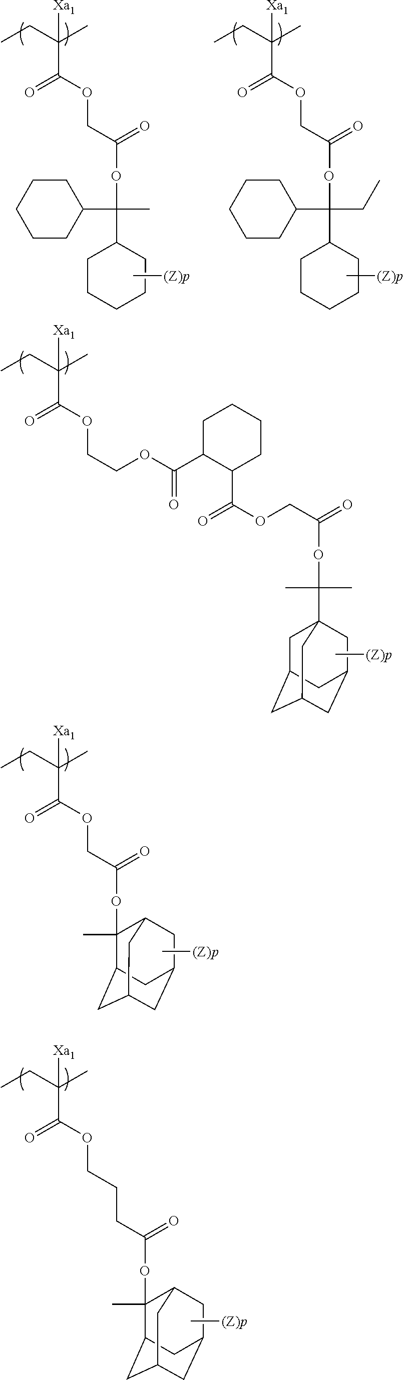

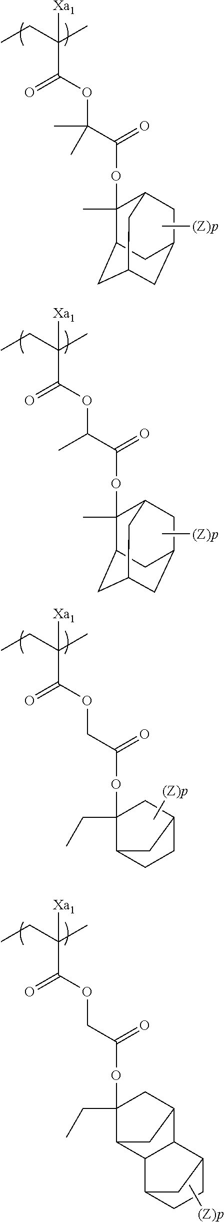

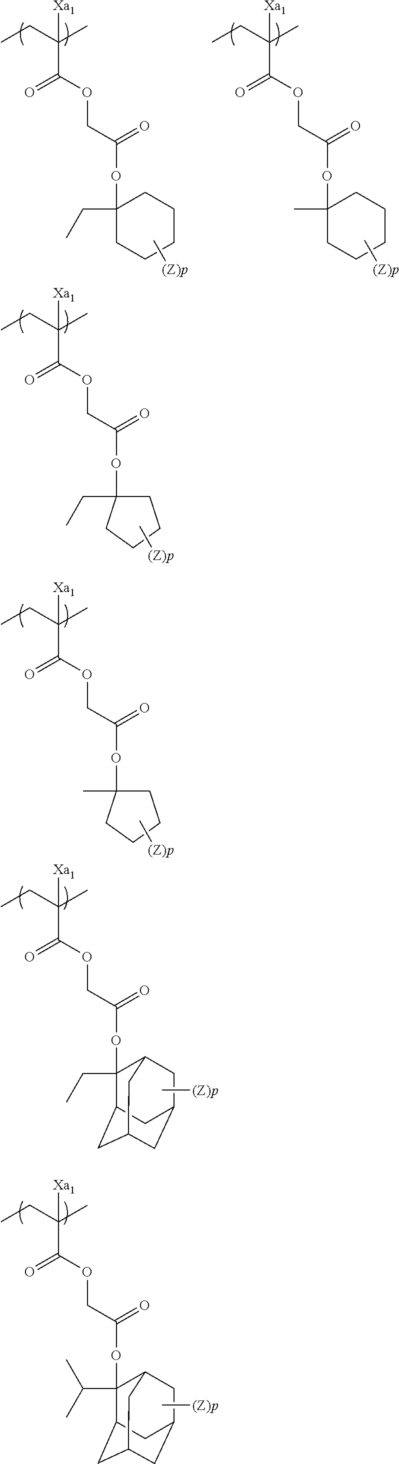

It is also preferred that the repeating unit having an acid-decomposable group is a repeating unit capable of decomposing by the action of an acid to produce a carboxyl group, represented by the following formula (I), and thanks to this configuration, the pattern forming method can ensure that the roughness performance such as line width roughness, the uniformity of local pattern dimension and the exposure latitude are more excellent and the reduction in film thickness of the pattern part formed by development, so-called film loss, is more suppressed.

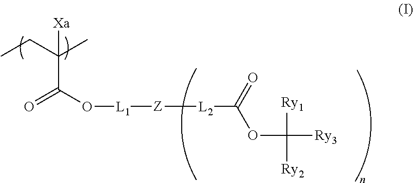

In the formula, Xa represents a hydrogen atom, an alkyl group, a cyano group or a halogen atom.

Each of Ry₁ to Ry₃ independently represents an alkyl group or a cycloalkyl group, and two members out of Ry₁ to Ry₃ may combine to form a ring.

Z represents a (n+1)-valent linking group having a polycyclic hydrocarbon structure which may have a heteroatom as a ring member.

Each of L₁ and L₂ independently represents a single bond or a divalent linking group.

n represents an integer of 1 to 3.

When n is 2 or 3, each L₂, each Ry₁, each Ry₂ and each Ry₃ may be the same as or different from every other L₂, Ry₁, Ry₂ and Ry₃, respectively.

The alkyl group of Xa may have a substituent, and examples of the substituent include a hydroxyl group and a halogen atom (preferably, fluorine atom).

The alkyl group of Xa is preferably an alkyl group having a carbon number of 1 to 4, and examples thereof include a methyl group, an ethyl group, a propyl group, a hydroxymethyl group and a trifluoromethyl group, with a methyl group being preferred.

Xa is preferably a hydrogen atom or a methyl group.

The alkyl group of Ry₁ to Ry₃ may be chain or branched and is preferably an alkyl group having a carbon number of 1 to 4, such as methyl group, ethyl group, n-propyl group, isopropyl group, n-butyl group, isobutyl group and tert-butyl group.

The cycloalkyl group of Ry₁ to Ry₃ is preferably a monocyclic cycloalkyl group such as cyclopentyl group and cyclohexyl group, or a polycyclic cycloalkyl group such as norbornyl group, tetracyclodecanyl group, tetracyclododecanyl group and adamantyl group.

The ring formed by combining two members out of Ry₁ to Ry₃ is preferably a monocyclic hydrocarbon ring such as cyclopentane ring and cyclohexane ring, or a polycyclic hydrocarbon ring such as norbornane ring, tetracyclodecane ring, tetracyclododecane ring and adamantane ring, more preferably a monocyclic hydrocarbon ring having a carbon number of 5 to 6.

Each of Ry₁ to Ry₃ is independently preferably an alkyl group, more preferably a chain or branched alkyl group having a carbon number of 1 to 4. Also, the total of the carbon numbers of the chain or branched alkyl groups as Ry₁ to Ry₃ is preferably 5 or less.

Each of Ry₁ to Ry₃ may further have a substituent, and examples of the substituent include an alkyl group (having a carbon number of 1 to 4), a cycloalkyl group (having a carbon number of 3 to 8), a halogen atom, an alkoxy group (having a carbon number of 1 to 4), a carboxyl group, and an alkoxycarbonyl group (having a carbon number of 2 to 6). The carbon number is preferably 8 or less. Above all, from the standpoint of more enhancing the dissolution contrast for an organic solvent-containing developer between before and after acid decomposition, the substituent is preferably a group free from a heteroatom such as oxygen atom, nitrogen atom and sulfur atom (for example, preferably not an alkyl group substituted with a hydroxyl group), more preferably a group composed of only a hydrogen atom and a carbon atom, still more preferably a linear or branched alkyl group or a cycloalkyl group.

The linking group having a polycyclic hydrocarbon structure of Z includes a ring-assembly hydrocarbon ring group and a crosslinked cyclic hydrocarbon ring group, and these groups include a group obtained by removing arbitrary (n+1) hydrogen atoms from a ring-assembly hydrocarbon ring and a group obtained by removing arbitrary (n+1) hydrogen atoms from a crosslinked cyclic hydrocarbon ring, respectively.

Examples of the ring-assembly hydrocarbon ring group include a bicyclohexane ring group and a perhydronaphthalene ring group. Examples of the crosslinked cyclic hydrocarbon ring group include a bicyclic hydrocarbon ring group such as pinane ring group, bornane ring group, norpinane ring group, norbornane ring group and bicyclooctane ring group (e.g., bicyclo[2.2.2]octane ring group, bicyclo[3.2.1]octane ring group), a tricyclic hydrocarbon ring group such as homobledane ring group, adamantane ring group, tricyclo[5.2.1.0^{2,6}]decane ring group and tricyclo[4.3.1.1^{2,5}]undecane ring group, and a tetracyclic hydrocarbon ring group such as tetracyclo[4.4.0.1^{2,5}.1^{1,10}]dodecane ring group and perhydro-1,4-methano-5,8-methanonaphthalene ring group. The crosslinked cyclic hydrocarbon ring group also includes a condensed cyclic hydrocarbon ring group, for example, a condensed ring group obtained by fusing a plurality of 5- to 8-membered cycloalkane ring groups, such as perhydronaphthalene (decalin) ring group, perhydroanthracene ring group, perhydrophenathrene ring group, perhydroacenaphthene ring group, perhydrofluorene ring group, perhydroindene ring group and perhydrophenalene ring group.

Preferred examples of the crosslinked cyclic hydrocarbon ring group include a norbornane ring group, an adamantane ring group, a bicyclooctane ring group and a tricycle[5,2,1,0^{2,6}]decane ring group. Of these crosslinked cyclic hydrocarbon ring groups, a norbornane ring group and an adamantane ring group are more preferred.

The linking group having a polycyclic hydrocarbon structure represented by Z may have a substituent. Examples of the substituent which may be substituted on Z include a substituent such as alkyl group, hydroxyl group, cyano group, keto group (═O), acyloxy group, —COR, —COOR, —CON(R)₂, —SO₂R, —SO₃R and —SO₂N(R)₂, wherein R represents a hydrogen atom, an alkyl group, a cycloalkyl group or an aryl group.

The alkyl group, alkylcarbonyl group, acyloxy group, —COR, —COOR, —CON(R)₂, —SO₂R, —SO₃R and —SO₂N(R)₂ as the substituent which Z may have may further have a substituent, and this substituent includes a halogen atom (preferably, fluorine atom).

In the linking group having a polycyclic hydrocarbon structure represented by Z, the carbon constituting the polycyclic ring (the carbon contributing to ring formation) may be carbonyl carbon. Also, as described above, the polycyclic ring may have, as a ring member, a heteroatom such as oxygen atom and sulfur atom.

Examples of the linking group represented by L₁ and L₂ include —COO—, —COO—, —CONH—, —NHCO—, —CO—, —O—, —S—, —SO—, —SO₂—, an alkylene group (preferably having a carbon number of 1 to 6), a cycloalkylene group (preferably having a carbon number of 3 to 10), an alkenylene group (preferably having a carbon number of 2 to 6), and a linking group formed by combining a plurality of these members, and a linking group having a total carbon number of 12 or less is preferred.

L₁ is preferably a single bond, an alkylene group, —COO—, —COO—, —CONH—, —NHCO—, -alkylene group-COO—, -alkylene group-OCO—, -alkylene group-CONH—, -alkylene group-NHCO—, —CO—, —O—, —SO₂—, or -alkylene group-O—, more preferably a single bond, an alkylene group, -alkylene group-COO—, or -alkylene group-O—.

L₂ is preferably a single bond, an alkylene group, —COO—, —COO—, —CONH—, —NHCO—, —COO-alkylene group-, —OCO-alkylene group-, —CONH-alkylene group-, —NHCO-alkylene group-, —CO—, —O—, —SO₂—, —O-alkylene group-, or —O-cycloalkylene group-, more preferably a single bond, an alkylene group, —COO-alkylene group-, —O-alkylene group-, or —O-cycloalkylene group-.

In the descriptions above, the bond “—” at the left end means to be bonded to the ester bond on the main chain side in L₁ and bonded to Z in L₂, and the bond “—” at the right end means to be bonded to Z in L₁ and bonded to the ester bond connected to the group represented by (Ry₁)(Ry₂)(Ry₃)C— in L₂.

Incidentally, L₁ and L₂ may be bonded to the same atom constituting the polycyclic ring in Z.

n is preferably 1 or 2, more preferably 1.

Specific examples of the repeating unit represented by formula (I) are illustrated below, but the present invention is not limited thereto. In specific examples, Xa represents a hydrogen atom, an alkyl group, a cyano group or a halogen atom.

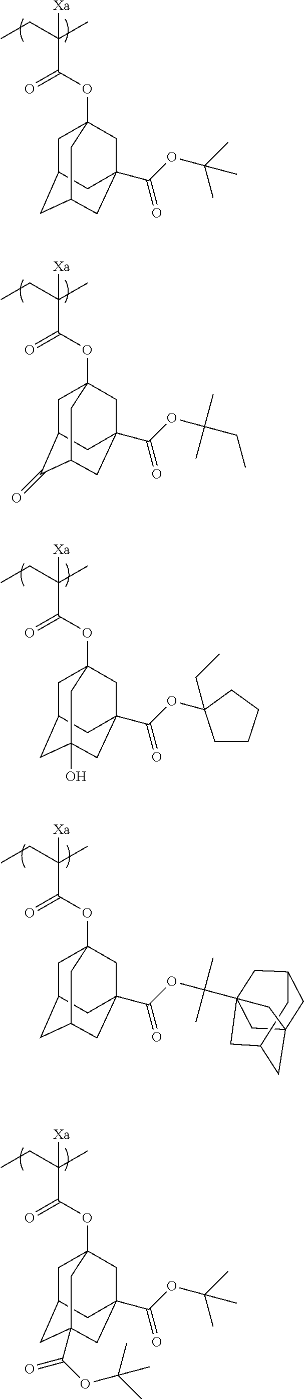

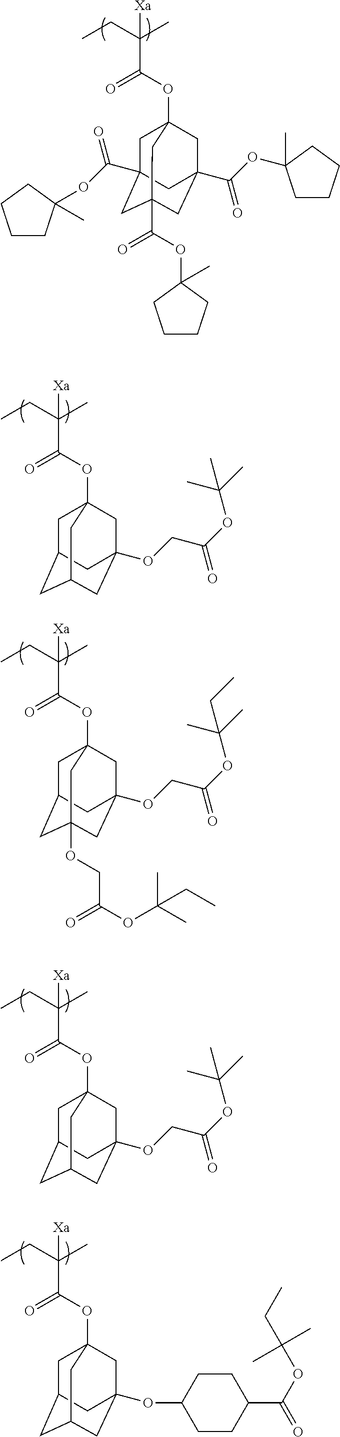

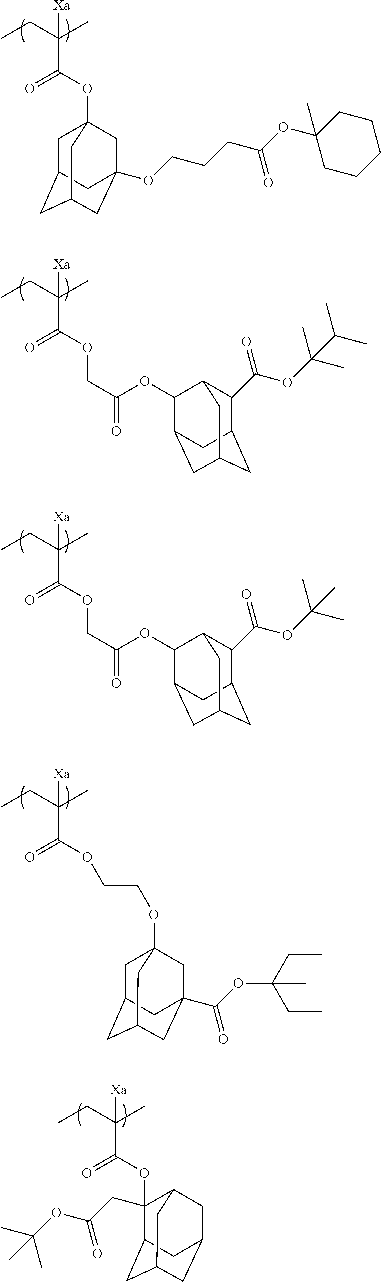

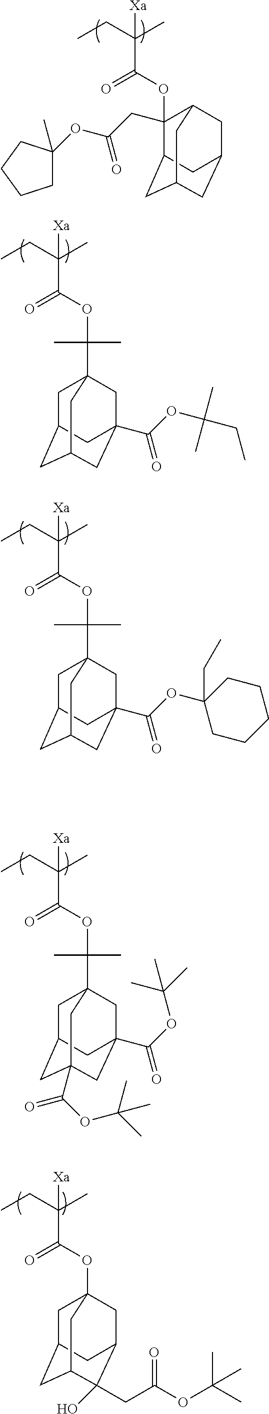

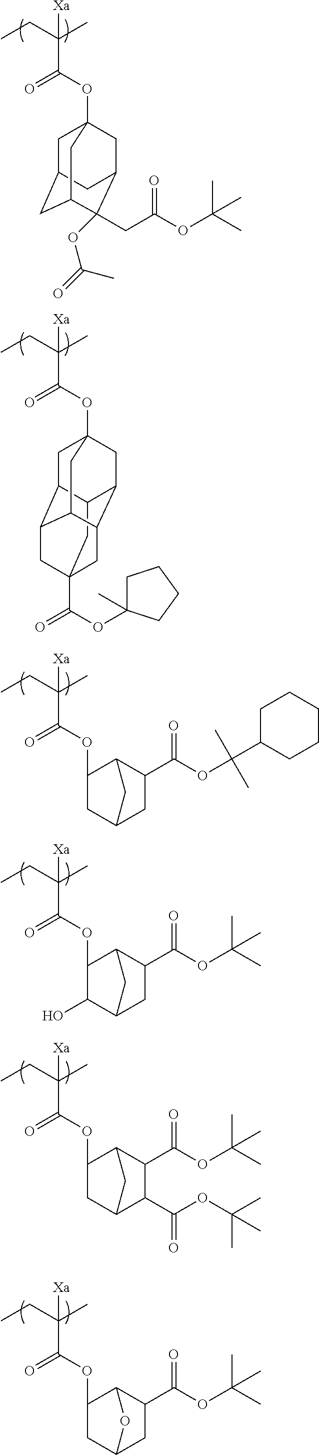

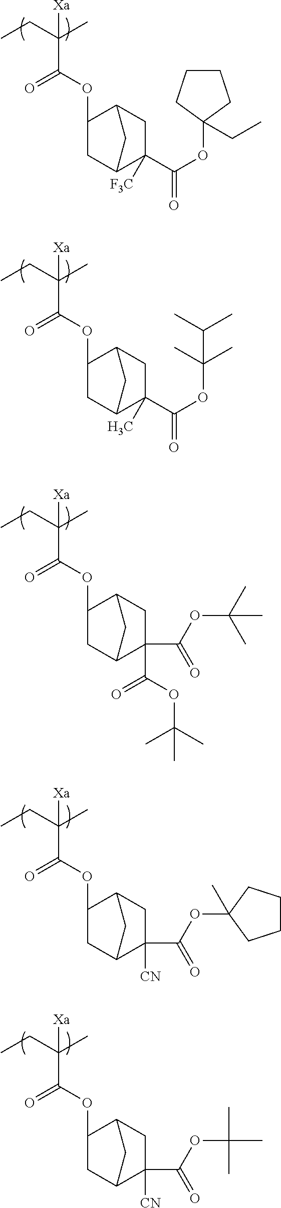

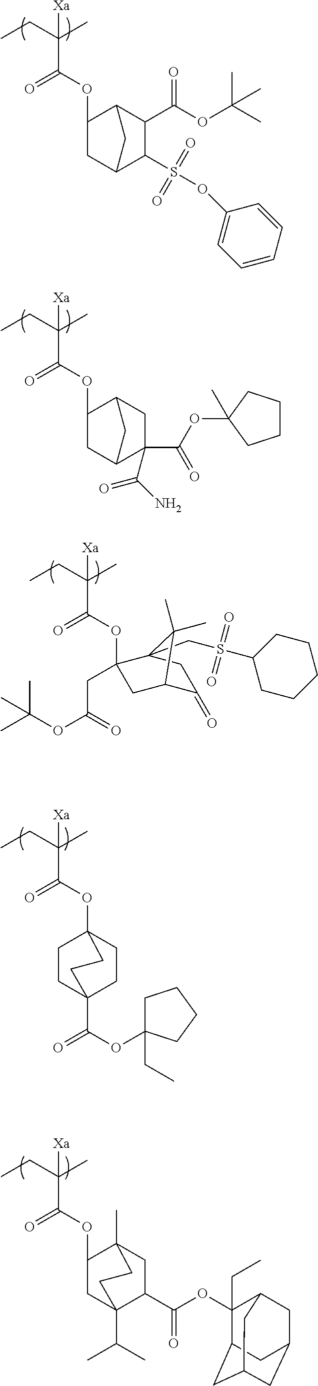

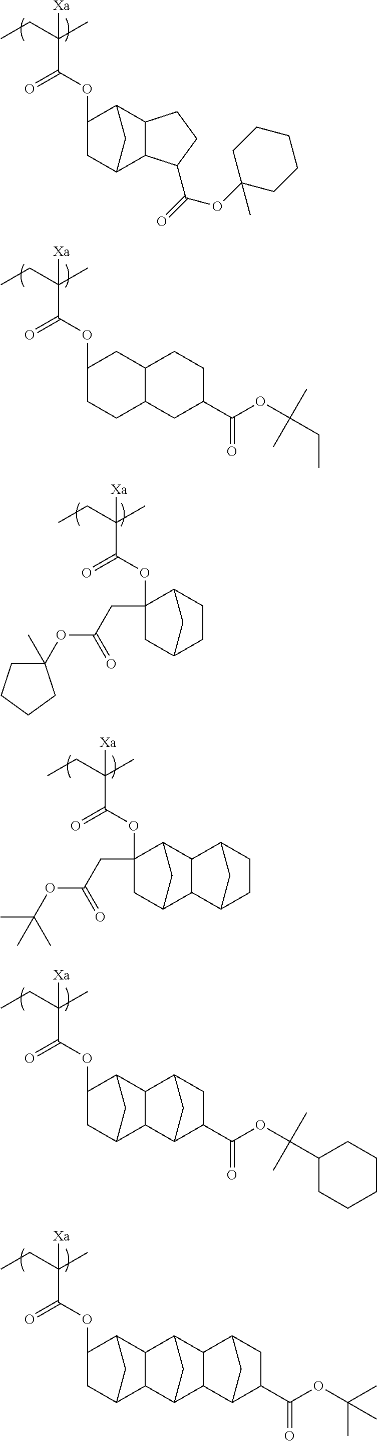

As for the acid-decomposable group-containing repeating unit of the resin (A), one kind may be used, or two or more kinds may be used in combination.

In the present invention, the resin (A) preferably contains the acid-decomposable group-containing repeating unit in which the molecular weight of the eliminated material produced by the decomposition of the group capable of decomposing by the action of an acid to produce a polar group (acid-decomposable group) (in the case of producing a plurality of kinds of eliminated materials, the weighted average value of molecular weights by molar fraction (hereinafter, sometimes referred to as a “molar average value”)) is 140 or less, in an amount of (in the case of containing a plurality of kinds of repeating units, as a total) of 50 mol % or more based on all repeating units in the resin. In the case of forming a negative image, the exposed area remains as a pattern and therefore, by letting the eliminated material have a small molecular weight, reduction in film thickness of the pattern part can be prevented.

In the present invention, the “eliminated material produced by the decomposition of an acid-decomposable group” indicates a material which corresponds to a group capable of decomposing and leaving by the action of an acid and is decomposed and eliminated by the action of an acid. For example, in the case of the later-described repeating unit (a) (in examples illustrated later, the upper leftmost repeating unit), the eliminated material indicates alkane (H₂C═C(CH₃)₂) produced by the decomposition of the tert-butyl moiety.

In the present invention, the molecular weight of the eliminated material produced by the decomposition of the acid-decomposable group (in the case of producing a plurality of kinds of eliminated materials, the molar average value) is preferably 100 or less from the standpoint of preventing reduction in film thickness of the pattern part.

The lower limit of the molecular weight of the eliminated material produced by the decomposition of the acid-decomposable group (in the case of producing a plurality of kinds of eliminated materials, the average value thereof) is not particularly limited, but from the standpoint of letting the acid-decomposable group exert its function, the lower limit is preferably 45 or more, more preferably 55 or more.

In the present invention, in the light of more reliably maintaining the film thickness of the pattern part that is the exposed area, the acid-decomposable group-containing repeating unit in which the molecular weight of the eliminated material produced by the decomposition of the acid-decomposable group is 140 or less, is more preferably contained in an amount (in the case of containing a plurality of kinds of repeating units, as a total) of 60 mol % or more, still more preferably 65 mol % or more, yet still more preferably 70 mol % or more, based on all repeating units in the resin. The upper limit is not particularly limited but is preferably 90 mol % or less, more preferably 85 mol % or less.

Specific examples of the acid-decomposable group-containing repeating unit in which the molecular weight of the eliminated material produced by the decomposition of the acid-decomposable group is 140 or less, are illustrated below, but the present invention is not limited thereto.

In specific examples, Xaₜ represents a hydrogen atom, CH₃, CF₃ or CH₂OH.

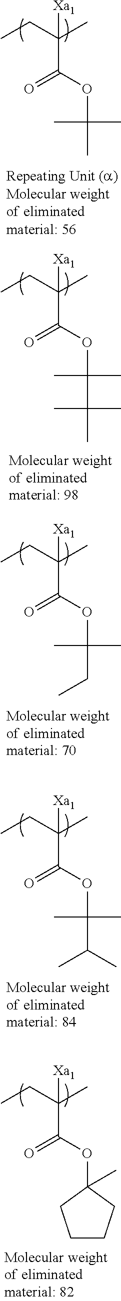

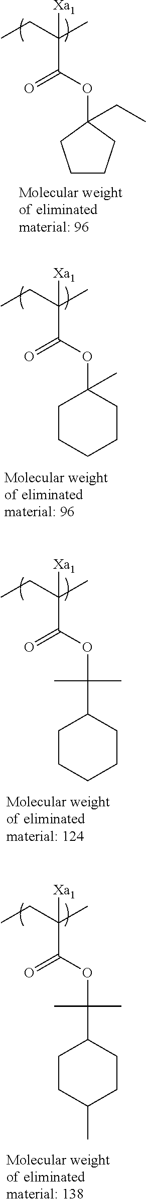

The content as a total of the repeating unit having an acid-decomposable group is preferably 20 mol % or more, more preferably 30 mol % or more, still more preferably 45 mol % or more, yet still more preferably 50 mol % or more, based on all repeating units in the resin (A).

Also, the content as a total of the repeating unit having an acid-decomposable group is preferably 90 mol % or less, more preferably 85 mol % or less, based on all repeating units in the resin (A).

In the case where the repeating unit having an acid-decomposable group is a repeating unit represented by formula (AI) and at the same time, particularly, each of Rx₁ to Rx₃ is independently a linear or branched alkyl group, the content of the repeating unit represented by formula (AI) is preferably 45 mol % or more, more preferably 50 mol % or more, still more preferably 55 mol % or more, based on all repeating units of the resin (A). The upper limit is, from the standpoint of forming a good pattern, preferably 90 mol % or less, more preferably 85 mol % or less. Within the ranges above, the pattern forming method can ensure that the roughness performance, the uniformity of local pattern dimension and the exposure latitude are more excellent and the reduction in film thickness of the pattern part formed by exposure, so-called film loss, can be more suppressed.

The resin (A) may further contain a repeating unit having a lactone structure.

As the lactone structure, any structure may be used as long as it has a lactone structure, but a 5- to 7-membered ring lactone structure is preferred, and a 5- to 7-membered ring lactone structure to which another ring structure is fused to form a bicyclo or spiro structure is preferred. It is more preferred to contain a repeating unit having a lactone structure represented by any one of the following formulae (LC1-1) to (LC1-17). The lactone structure may be bonded directly to the main chain. Among these lactone structures, (LC1-1), (LC1-4), (LC1-5), (LC1-6), (LC1-13), (LC1-14) and (LC1-17) are preferred, and the lactone structure of (LC1-4) is more preferred. By virtue of using such a specific lactone structure, LWR and development defect are improved.

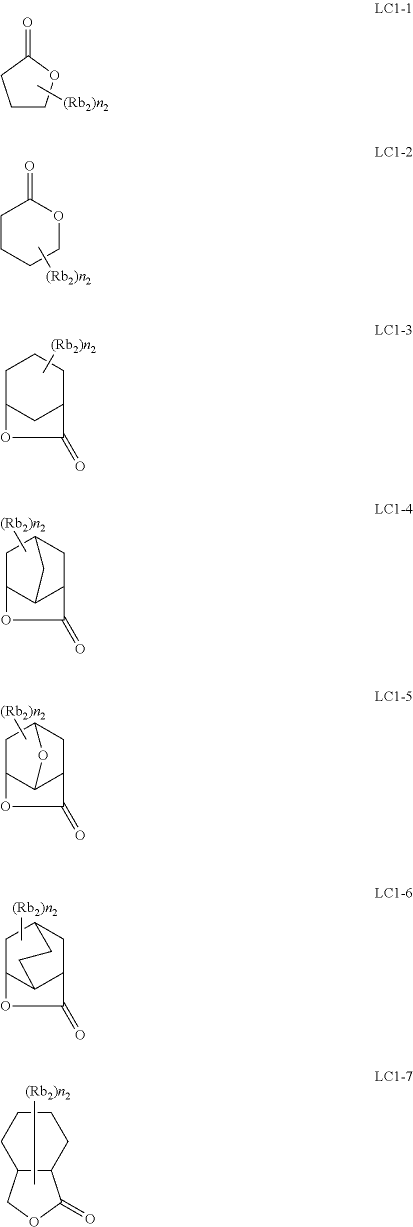

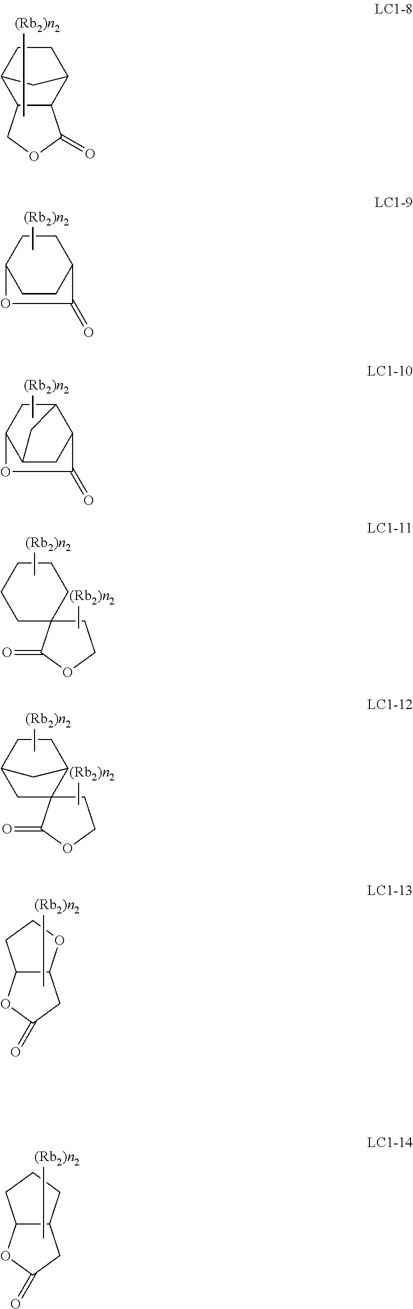

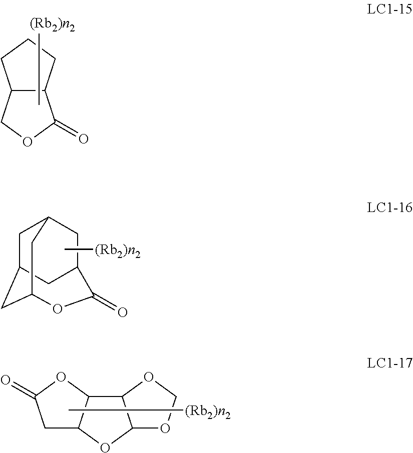

The lactone structure moiety may or may not have a substituent (Rb₂). Preferred examples of the substituent (Rb₂) include an alkyl group having a carbon number of 1 to 8, a cycloalkyl group having a carbon number of 4 to 7, an alkoxy group having a carbon number of 1 to 8, an alkoxycarbonyl group having a carbon number of 2 to 8, a carboxyl group, a halogen atom, a hydroxyl group, a cyano group and an acid-decomposable group. Among these, an alkyl group having a carbon number of 1 to 4, a cyano group and an acid-decomposable group are more preferred. n₂ represents an integer of 0 to 4. When n₂ is 2 or more, each substituent (Rb₂) may be the same as or different from every other substituents (Rb₂) and also, the plurality of substituents (Rb₂) may combine together to form a ring.

The repeating unit having a lactone group usually has an optical isomer, but any optical isomer may be used. One optical isomer may be used alone, or a mixture of a plurality of optical isomers may be used. In the case of mainly using one optical isomer, the optical purity (ee) thereof is preferably 90% or more, more preferably 95% or more.

The lactone structure-containing repeating unit is preferably a repeating unit represented by the following formula (AII):

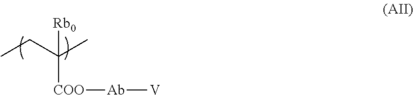

In formula (AII), Rb₀ represents a hydrogen atom, a halogen atom or an alkyl group (preferably having a carbon number of 1 to 4) which may have a substituent.

Preferred examples of the substituent which the alkyl group of Rb₀ may have include a hydroxyl group and a halogen atom. The halogen atom of Rb₀ includes a fluorine atom, a chlorine atom, a bromine atom and an iodine atom. Rb₀ is preferably a hydrogen atom, a methyl group, a hydroxymethyl group or a trifluoromethyl group, more preferably a hydrogen atom or a methyl group.

Ab represents a single bond, an alkylene group, a divalent linking group having a mono cyclic or polycyclic cycloalkyl structure, an ether bond, an ester bond, a carbonyl group, or a divalent linking group formed by combining these members. Ab is preferably a single bond or a divalent linking group represented by -Ab₁-CO₂—.

Ab₁ is a linear or branched alkylene group or a monocyclic or polycyclic cycloalkylene group and is preferably a methylene group, an ethylene group, a cyclohexylene group, an adamantylene group or a norbornylene group.

V represents a group having a lactone structure and specifically represents, for example, a group having a structure represented by any one of formulae (LC1-1) to (LC1-17).

In the case where the resin (A) contains the repeating unit having a lactone structure, the content of the repeating unit having a lactone structure is preferably from 0.5 to 80 mol %, more preferably from 1 to 65 mol %, still more preferably from 5 to 60 mol %, yet still more preferably from 3 to 50 mol %, and most preferably from 10 to 50 mol %, based on all repeating units in the resin (A).

As for the repeating unit having a lactone structure, one kind may be used, or two or more kinds may be used in combination.

Specific examples of the repeating unit having a lactone structure are illustrated below, but the present invention is not limited thereto. In the formulae, Rx represents H, CH₃, CH₂OH or CF₃.

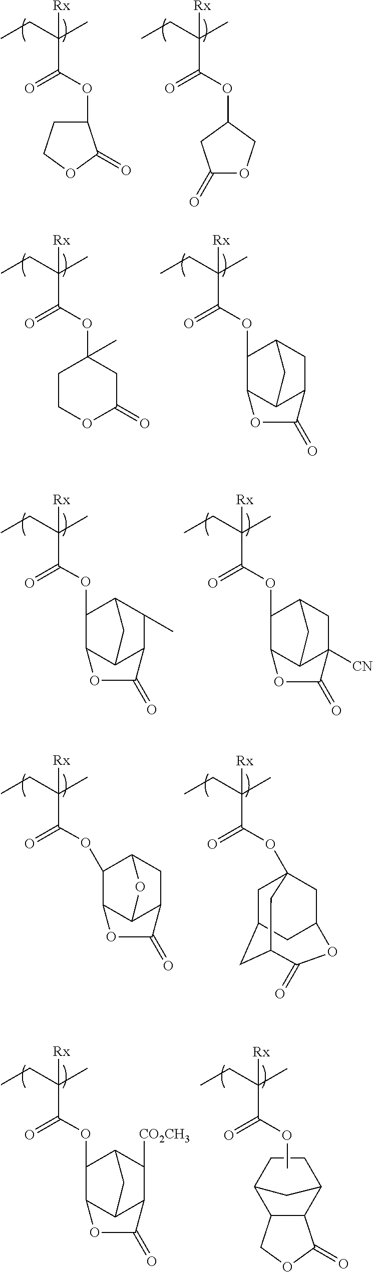

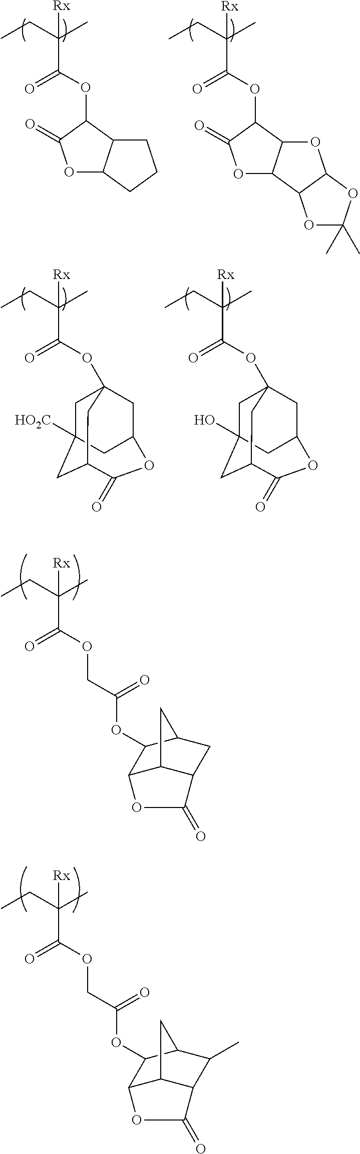

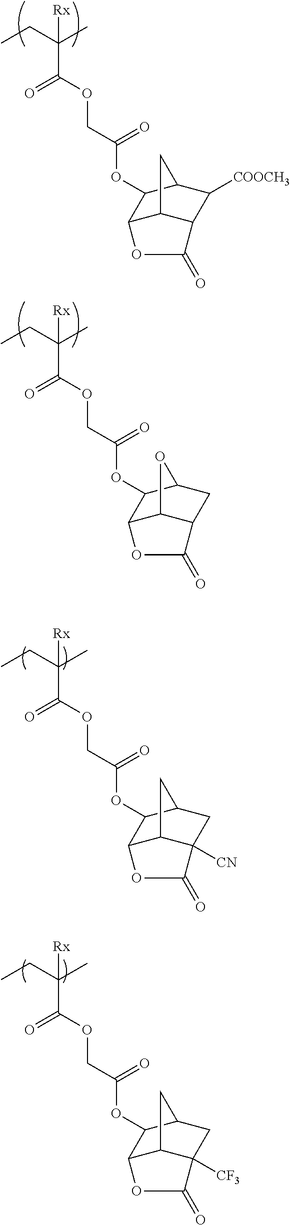

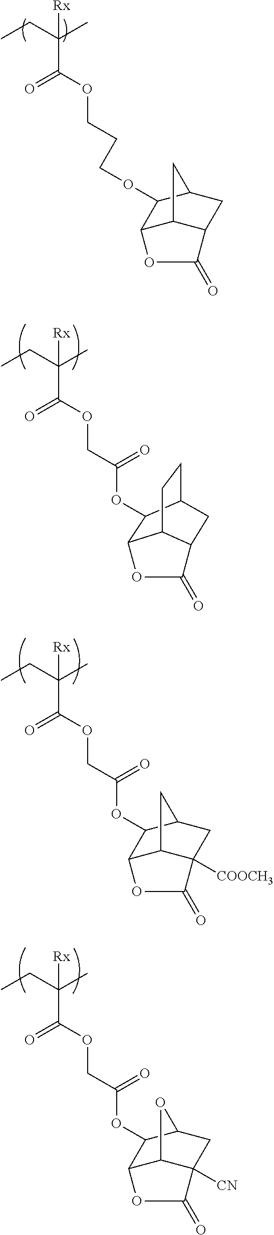

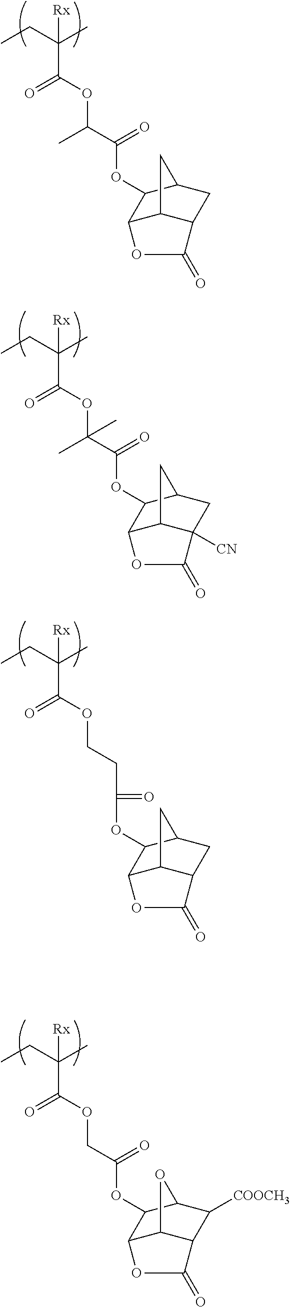

The resin (A) preferably contains a repeating unit having a hydroxyl group or a cyano group. Thanks to this repeating unit, the adherence to substrate and affinity for developer are enhanced. The repeating unit having a hydroxyl group or a cyano group is preferably a repeating unit having an alicyclic hydrocarbon structure substituted with a hydroxyl group or a cyano group and preferably has no acid-decomposable group.

Also, the repeating unit having an alicyclic hydrocarbon structure substituted with a hydroxyl group or a cyano group is preferably different from the repeating unit represented by formula (AII).

The alicyclic hydrocarbon structure in the alicyclic hydrocarbon structure substituted with a hydroxyl group or a cyano group is preferably an adamantyl group, a diamantyl group or a norbornyl group. The alicyclic hydrocarbon structure substituted with a hydroxyl group or a cyano group is preferably a partial structure represented by the following formulae (VIIa) to (VIId):

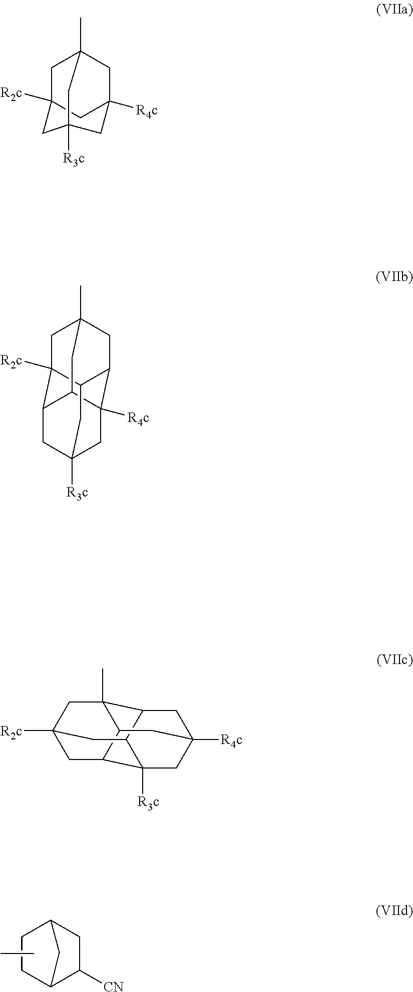

In formulae (VIIa) to (VIIc), each of R₂c to R₄c independently represents a hydrogen atom, a hydroxyl group or a cyano group, provided that at least one of R₂c to R₄c represents a hydroxyl group or a cyano group. A structure where one or two members out of R₂c to R₄c are a hydroxyl group with the remaining being a hydrogen atom is preferred. In formula (VIIa), it is more preferred that two members out of R₂c to R₄c are a hydroxyl group and the remaining is a hydrogen atom.

The repeating unit having a partial structure represented by formulae (VIIa) to (VIId) includes repeating units represented by the following formulae (AIIa) to (AIId):

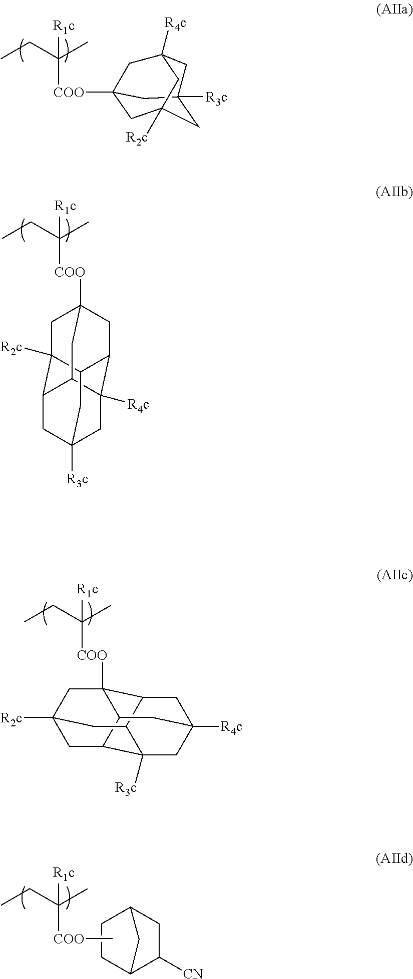

In formulae (AIIa) to (AIId), R₁c represents a hydrogen atom, a methyl group, a trifluoromethyl group or a hydroxymethyl group.

R₂c to R₄c have the same meanings as R₂c to R₄c in formulae (VIIa) to (VIIc).

The resin (A) may or may not contain a repeating unit having a hydroxyl group or a cyano group, but in the case where the resin (A) contains a repeating unit having a hydroxyl group or a cyano group, the content of the repeating unit having a hydroxyl group or a cyano group is preferably from 1 to 50 mol %, more preferably from 1 to 45 mol %, still more preferably from 3 to 45 mol %, based on all repeating units in the resin (A).

Specific examples of the repeating unit having a hydroxyl group or a cyano group are illustrated below, but the present invention is not limited thereto.

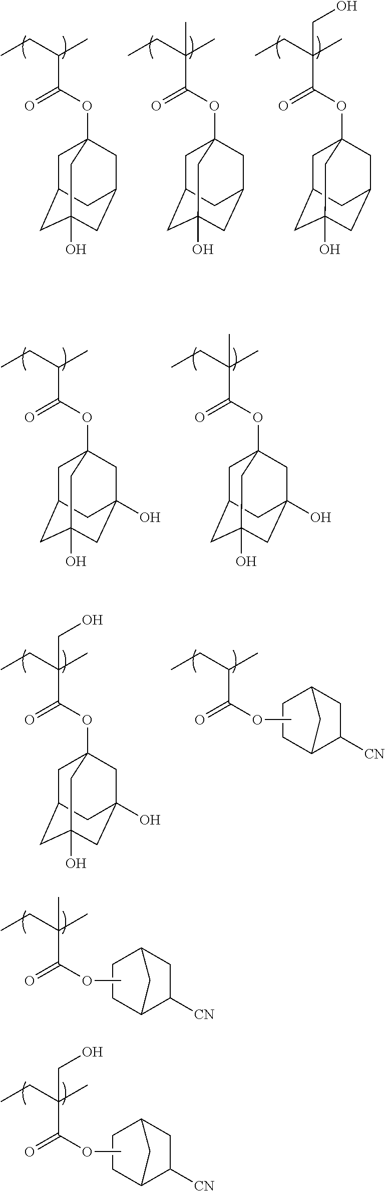

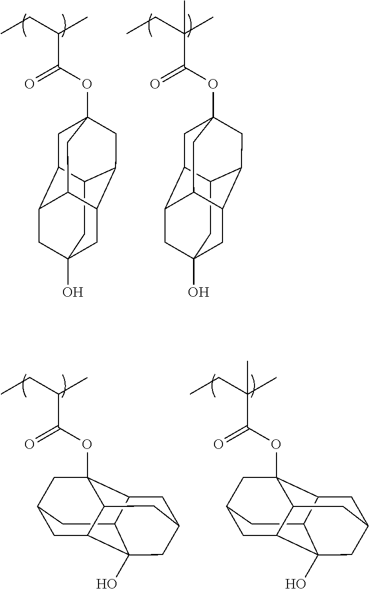

The resin (A) may contain a repeating unit having an acid group. The acid group includes a carboxyl group, a sulfonamide group, a sulfonylimide group, a bisulfonylimide group, and an aliphatic alcohol substituted with an electron-withdrawing group at the α-position (for example, hexafluoroisopropanol group), and it is preferred to contain a repeating unit having a carboxyl group. By virtue of containing a repeating unit having an acid group, the resolution increases in the usage of forming contact holes. As for the repeating unit having an acid group, all of a repeating unit where an acid group is directly bonded to the main chain of the resin, such as repeating unit by an acrylic acid or a methacrylic acid, a repeating unit where an acid group is bonded to the main chain of the resin through a linking group, and a repeating unit where an acid group is introduced into the polymer chain terminal by using an acid group-containing polymerization initiator or chain transfer agent at the polymerization, are preferred. The linking group may have a monocyclic or polycyclic cyclohydrocarbon structure. In particular, a repeating unit by an acrylic acid or a methacrylic acid is preferred.

The resin (A) may or may not contain a repeating unit having an acid group, but in the case of containing the repeating unit, the content of the repeating unit having an acid group is preferably 10 mol % or less, more preferably 5 mol % or less, based on all repeating units in the resin (A). In the case where the resin (A) contains a repeating unit having an acid group, the content of the acid group-containing repeating unit in the resin (A) is usually 1 mol % or more.

Specific examples of the repeating unit having an acid group are illustrated below, but the present invention is not limited thereto.

In specific examples, Rx represents H, CH₃, CH₂OH or CF₃.

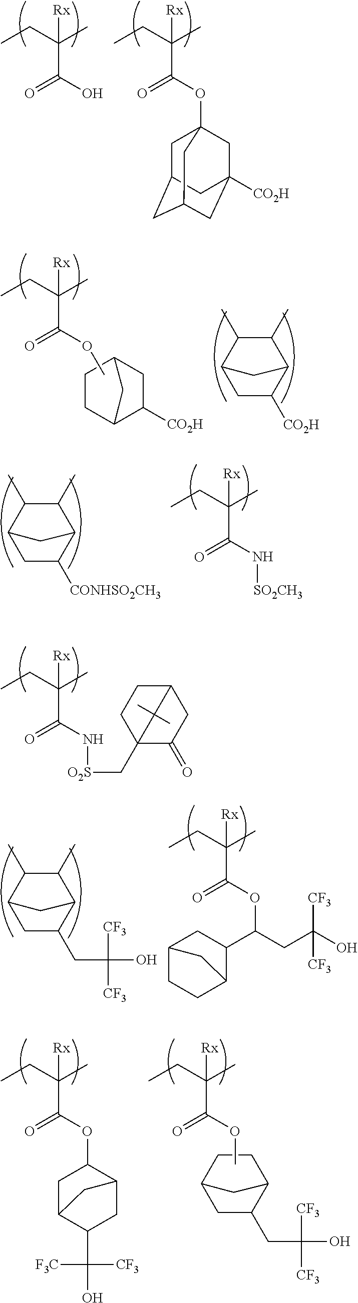

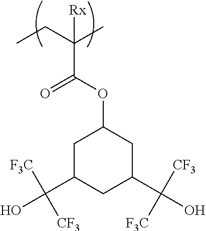

The resin (A) for use in the present invention may further contain a repeating unit having an alicyclic hydrocarbon structure free from a polar group (for example, the above-described acid group, a hydroxyl group or a cyano group) and not exhibiting acid decomposability. Thanks to this repeating unit, dissolution of a low molecular component from the resist film to the immersion liquid can be reduced at the immersion exposure and in addition, the solubility of the resin at the development using an organic solvent-containing developer can be appropriately adjusted. Such a repeating unit includes a repeating unit represented by formula (IV):

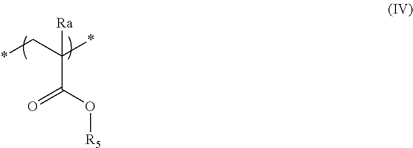

In formula (IV), R₅ represents a hydrocarbon group having at least one cyclic structure and having no polar group.

Ra represents a hydrogen atom, an alkyl group or a —CH₂—O—Ra₂ group, wherein Ra₂ represents a hydrogen atom, an alkyl group or an acyl group. Ra is preferably a hydrogen atom, a methyl group, a hydroxymethyl group or a trifluoromethyl group, more preferably a hydrogen atom or a methyl group.

The cyclic structure which R₅ has includes a monocyclic hydrocarbon group and a polycyclic hydrocarbon group. Examples of the monocyclic hydrocarbon group include a cycloalkyl group having a carbon number of 3 to 12, such as cyclopentyl group, cyclohexyl group, cycloheptyl group and cyclooctyl group, and a cycloalkenyl group having a carbon number of 3 to 12, such as cyclohexenyl group. The monocyclic hydrocarbon group is preferably a monocyclic hydrocarbon group having a carbon number of 3 to 7, more preferably a cyclopentyl group or a cyclohexyl group.

The polycyclic hydrocarbon group includes a ring-assembly hydrocarbon group and a crosslinked cyclic hydrocarbon group. Examples of the ring-assembly hydrocarbon group include a bicyclohexyl group and a perhydronaphthalenyl group. Examples of the crosslinked cyclic hydrocarbon ring include a bicyclic hydrocarbon ring such as pinane ring, bornane ring, norpinane ring, norbornane ring and bicyclooctane ring (e.g., bicyclo[2.2.2]octane ring, bicyclo[3.2.1]octane ring), a tricyclic hydrocarbon ring such as homobledane ring, adamantane ring, tricyclo[5.2.1.0^{2,6}]decane ring and tricyclo[4.3.1.1^{2,5}]undecane ring, and a tetracyclic hydrocarbon ring such as tetracyclo[4.4.0.1^{2,5}.1^{7,10}]dodecane ring and perhydro-1,4-methano-5,8-methanonaphthalene ring. The crosslinked cyclic hydrocarbon ring also includes a condensed cyclic hydrocarbon ring, for example, a condensed ring formed by fusing a plurality of 5- to 8-membered cycloalkane rings, such as perhydronaphthalene (decalin) ring, perhydroanthracene ring, perhydrophenathrene ring, perhydroacenaphthene ring, perhydrofluorene ring, perhydroindene ring and perhydrophenalene ring.

Preferred examples of the crosslinked cyclic hydrocarbon ring include a norbornyl group, an adamantyl group, a bicyclooctanyl group and a tricyclo[5,2,1,0^{2,6}]decanyl group. Among these crosslinked cyclic hydrocarbon rings, a norbornyl group and an adamantyl group are more preferred.

Such an alicyclic hydrocarbon group may have a substituent, and preferred examples of the substituent include a halogen atom, an alkyl group, a hydroxyl group with a hydrogen atom being substituted for, and an amino group with a hydrogen atom being substituted for. The halogen atom is preferably bromine atom, chlorine atom or fluorine atom, and the alkyl group is preferably a methyl group, an ethyl group, a butyl group or a tert-butyl group. This alkyl group may further have a substituent, and the substituent which may be further substituted on the alkyl group includes a halogen atom, an alkyl group, a hydroxyl group with a hydrogen atom being substituted for, and an amino group with a hydrogen atom being substituted for.

Examples of the substituent for the hydrogen atom include an alkyl group, a cycloalkyl group, an aralkyl group, a substituted methyl group, a substituted ethyl group, an alkoxycarbonyl group and an aralkyloxycarbonyl group. The alkyl group is preferably an alkyl group having a carbon number of 1 to 4; the substituted methyl group is preferably a methoxymethyl group, a methoxythiomethyl group, a benzyloxymethyl group, a tert-butoxymethyl group or a 2-methoxyethoxymethyl group; the substituted ethyl group is preferably a 1-ethoxyethyl group or a 1-methyl-1-methoxyethyl group; the acyl group is preferably an aliphatic acyl group having a carbon number of 1 to 6, such as formyl group, acetyl group, propionyl group, butyryl group, isobutyryl group, valeryl group and pivaloyl group; and the alkoxycarbonyl group is preferably an alkoxycarbonyl group having a carbon number of 1 to 4.

The resin (A) may or may not contain a repeating unit having an alicyclic hydrocarbon structure free from a polar group and not exhibiting acid decomposability, but in the case of containing this repeating unit, the content thereof is preferably from 1 to 40 mol %, more preferably from 1 to 20 mol %, based on all repeating units in the resin (A).

Specific examples of the repeating unit having an alicyclic hydrocarbon structure free from a polar group and not exhibiting acid decomposability are illustrated below, but the present invention is not limited thereto. In the formulae, Ra represents H, CH₃, CH₂OH or CF₃.

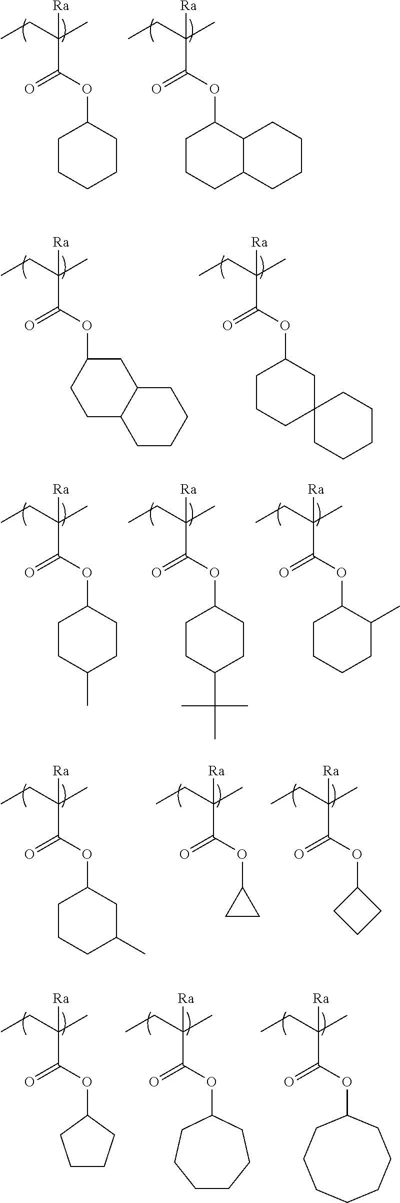

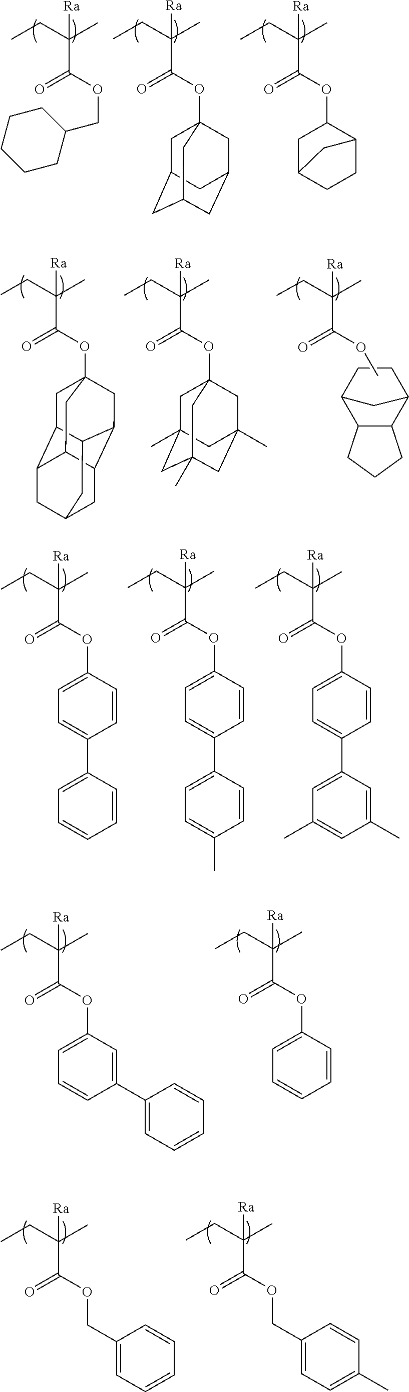

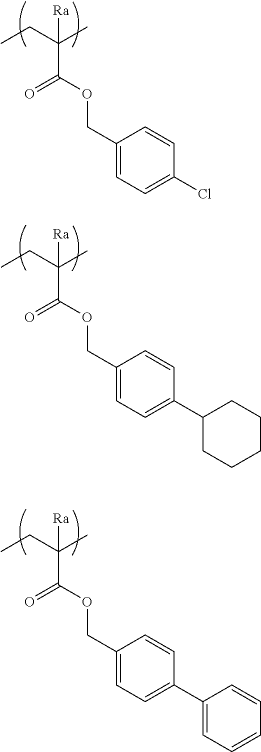

The resin (A) for use in the composition of the present invention may contain, in addition to the above-described repeating structural units, various repeating structural units for the purpose of controlling the dry etching resistance, suitability for standard developer, adherence to substrate, resist profile and properties generally required of a resist, such as resolution, heat resistance and sensitivity.

Examples of such a repeating structural unit include, but are not limited to, repeating structural units corresponding to the monomers described below.

Thanks to such a repeating structural unit, the performance required of the resin used in the composition of the present invention, particularly

(1) solubility for the coating solvent,

(2) film-forming property (glass transition point),

(3) alkali developability,

(4) film loss (selection of hydrophilic, hydrophobic or alkali-soluble group),

(5) adherence of unexposed area to substrate,

(6) dry etching resistance,

and the like, can be subtly controlled.

Examples of the monomer include a compound having one addition-polymerizable unsaturated bond selected from acrylic acid esters, methacrylic acid esters, acrylamides, methacrylamides, allyl compounds, vinyl ethers and vinyl esters.

Other than these, an addition-polymerizable unsaturated compound copolymerizable with the monomers corresponding to the above-described various repeating structural units may be copolymerized.

In the resin (A) for use in the composition of the present invention, the molar ratio of respective repeating structural units contained is appropriately set to control the dry etching resistance of resist, suitability for standard developer, adherence to substrate, resist profile and performances generally required of a resist, such as resolution, heat resistance and sensitivity.

The form of the resin (A) for use in the present invention may be any of random type, block type, comb type and star type. The resin (A) can be synthesized, for example, by radical, cationic or anionic polymerization of unsaturated monomers corresponding to respective structures. It is also possible to obtain the target resin by polymerizing unsaturated monomers corresponding to precursors of respective structures and then performing a polymer reaction.

In the case where the composition of the present invention is used for ArF exposure, in view of transparency to ArF light, the resin (A) for use in the composition of the present invention preferably has substantially no aromatic ring (specifically, the proportion of an aromatic group-containing repeating unit in the resin is preferably 5 mol % or less, more preferably 3 mol % or less, and ideally 0 mol %, that is, the resin does not have an aromatic group). The resin (A) preferably has a monocyclic or polycyclic alicyclic hydrocarbon structure.

Also, in the case where the composition of the present invention contains the later-described resin (E), the resin (A) preferably contains no fluorine atom and no silicon atom in view of compatibility with the resin (E).

The resin (A) for use in the composition of the present invention is preferably a resin where all repeating units are composed of a (meth)acrylate-based repeating unit. In this case, all repeating units may be a methacrylate-based repeating unit, all repeating units may be an acrylate-based repeating unit, or all repeating units may be composed of a methacrylate-based repeating unit and an acrylate-based repeating unit, but the content of the acrylate-based repeating unit is preferably 50 mol % or less based on all repeating units. It is also preferred that the resin is a copolymerized polymer containing from 20 to 50 mol % of an acid decomposable group-containing (meth)acrylate-based repeating unit, from 20 to 50 mol % of a lactone group-containing (meth)acrylate-based repeating unit, from 5 to 30 mol % of a (meth)acrylate-based repeating unit having an alicyclic hydrocarbon structure substituted with a hydroxyl group or a cyano group, and from 0 to 20 mol % of other (meth)acrylate-based repeating units.

In the case of irradiating the composition of the present invention with a KrF excimer laser light, an electron beam, an X-ray or a high-energy beam at a wavelength of 50 nm or less (e.g., EUV), the resin (A) preferably further contains a hydroxystyrene-based repeating unit. It is more preferred to contain a hydroxystyrene-based repeating unit, a hydroxystyrene-based repeating unit protected by an acid-decomposable group, and an acid-decomposable repeating unit such as tertiary alkyl(meth)acrylate.

Preferred examples of the hydroxystyrene-based repeating unit having an acid-decomposable group include repeating units composed of a tert-butoxycarbonyloxystyrene, a 1-alkoxyethoxystyrene and a tertiary alkyl(meth)acrylate. Repeating units composed of a 2-alkyl-2-adamantyl(meth)acrylate and a dialkyl(1-adamantyl)methyl (meth)acrylate are more preferred.

The resin (A) for use in the present invention can be synthesized by a conventional method (for example, radical polymerization). Examples of the general synthesis method include a batch polymerization method of dissolving monomer species and an initiator in a solvent and heating the solution, thereby effecting the polymerization, and a dropping polymerization method of adding dropwise a solution containing monomer species and an initiator to a heated solvent over 1 to 10 hours. A dropping polymerization method is preferred. Examples of the reaction solvent include tetrahydrofuran, 1,4-dioxane, ethers such as diisopropyl ether, ketones such as methyl ethyl ketone and methyl isobutyl ketone, an ester solvent such as ethyl acetate, an amide solvent such as dimethylformamide and dimethylacetamide, and the later-described solvent capable of dissolving the composition of the present invention, such as propylene glycol monomethyl ether acetate, propylene glycol monomethyl ether and cyclohexanone. The polymerization is more preferably performed using the same solvent as the solvent used in the photosensitive composition of the present invention. By the use of the same solvent, production of particles during storage can be suppressed.

The polymerization reaction is preferably performed in an inert gas atmosphere such as nitrogen or argon. As for the polymerization initiator, the polymerization is started using a commercially available radical initiator (e.g., azo-based initiator, peroxide). The radical initiator is preferably an azo-based initiator, and an azo-based initiator having an ester group, a cyano group or a carboxyl group is preferred. Preferred examples of the initiator include azobisisobutyronitrile, azobisdimethylvaleronitrile and dimethyl 2,2′-azobis(2-methylpropionate). The initiator is added additionally or in parts, if desired. After the completion of reaction, the reaction solution is poured in a solvent, and the desired polymer is collected by a powder, solid or other recovery method. The concentration at the reaction is from 5 to 50 mass %, preferably from 10 to 30 mass %, and the reaction temperature is usually from 10 to 150° C., preferably from 30 to 120° C., more preferably from 60 to 100° C.

After the completion of reaction, the reaction solution is allowed to cool to room temperature and purified. The purification may be performed by a normal method, for example, a liquid-liquid extraction method of applying water washing or combining it with an appropriate solvent to remove residual monomers or oligomer components; a purification method in a solution sate, such as ultrafiltration of extracting and removing only polymers having a molecular weight not more than a specific value; a reprecipitation method of adding dropwise the resin solution in a poor solvent to solidify the resin in the poor solvent and thereby remove residual monomers and the like; and a purification method in a solid state, such as washing of a resin slurry with a poor solvent after separation of the slurry by filtration. For example, the resin is precipitated as a solid by contacting the reaction solution with a solvent in which the resin is sparingly soluble or insoluble (poor solvent) and which is in a volumetric amount of 10 times or less, preferably from 10 to 5 times, the reaction solution.

The solvent used at the operation of precipitation or reprecipitation from the polymer solution (precipitation or reprecipitation solvent) may be sufficient if it is a poor solvent for the polymer, and the solvent which can be used may be appropriately selected from a hydrocarbon, a halogenated hydrocarbon, a nitro compound, an ether, a ketone, an ester, a carbonate, an alcohol, a carboxylic acid, water, a mixed solvent containing such a solvent, and the like, according to the kind of the polymer. Among these solvents, a solvent containing at least an alcohol (particularly, methanol or the like) or water is preferred as the precipitation or reprecipitation solvent.

The amount of the precipitation or reprecipitation solvent used may be appropriately selected by taking into consideration the efficiency, yield and the like, but in general, the amount used is from 100 to 10,000 parts by mass, preferably from 200 to 2,000 parts by mass, more preferably from 300 to 1,000 parts by mass, per 100 parts by mass of the polymer solution.

The temperature at the precipitation or reprecipitation may be appropriately selected by taking into consideration the efficiency or operability but is usually approximately from 0 to 50° C., preferably in the vicinity of room temperature (for example, approximately from 20 to 35° C.). The precipitation or reprecipitation operation may be performed using a commonly employed mixing vessel such as stirring tank by a known method such as batch system and continuous system.

The precipitated or reprecipitated polymer is usually subjected to commonly employed solid-liquid separation such as filtration and centrifugation, then dried and used. The filtration is performed using a solvent-resistant filter element preferably under pressure. The drying is performed under atmospheric pressure or reduced pressure (preferably under reduced pressure) at a temperature of approximately from 30 to 100° C., preferably approximately from 30 to 50° C.

Incidentally, after the resin is once precipitated and separated, the resin may be again dissolved in a solvent and then put into contact with a solvent in which the resin is sparingly soluble or insoluble. That is, there may be used a method comprising, after the completion of radical polymerization reaction, bringing the polymer into contact with a solvent in which the polymer is sparingly soluble or insoluble, to precipitate a resin (step a), separating the resin from the solution (step b), anew dissolving the resin in a solvent to prepare a resin solution A (step c), bringing the resin solution A into contact with a solvent in which the resin is sparingly soluble or insoluble and which is in a volumetric amount of less than 10 times (preferably 5 times or less) the resin solution A, to precipitate a resin solid (step d), and separating the precipitated resin (step e).

The weight average molecular weight of the resin (A) for use in the present invention is preferably from 1,000 to 200,000, more preferably from 2,000 to 20,000, still more preferably from 3,000 to 15,000, yet still more preferably from 3,000 to 10,000, in terms of polystyrene by the GPC method. When the weight average molecular weight is from 1,000 to 200,000, reduction in the heat resistance and dry etching resistance can be inhibited and at the same time, the film-forming property can be prevented from deterioration due to impairment of developability or increase in the viscosity.

The polydispersity (molecular weight distribution) is usually from 1.0 to 3.0, preferably from 1.0 to 2.6, more preferably from 1.0 to 2.0, still more preferably from 1.4 to 2.0. As the molecular weight distribution is smaller, the resolution and resist profile are more excellent, the side wall of the resist pattern is smoother, and the roughness is more improved.

In the resist composition of the present invention, the blending ratio of the resin (A) in the entire composition is preferably from 30 to 99 mass %, more preferably from 60 to 95 mass %, based on the entire solid content.

As for the resin (A) used in the present invention, one kind may be used or a plurality of kinds may be used in combination.

[2] (B) Compound Capable of Generating an Acid Upon Irradiation with an Actinic Ray or Radiation

The composition for use in the present invention contains (B) a compound capable of generating an acid upon irradiation with an actinic ray or radiation (hereinafter, sometimes referred to as an “acid generator”). The compound (B) capable of generating an acid upon irradiation with an actinic ray or radiation is preferably a compound capable of generating an organic acid upon irradiation with an actinic ray or radiation.

The acid generator which can be used may be appropriately selected from a photo-initiator for cationic photopolymerization, a photo-initiator for radical photopolymerization, a photo-decoloring agent for dyes, a photo-discoloring agent, a known compound capable of generating an acid upon irradiation with an actinic ray or radiation, which is used for microresist or the like, and a mixture thereof.

Examples thereof include a diazonium salt, a phosphonium salt, a sulfonium salt, an iodonium salt, imidosulfonate, oxime sulfonate, diazodisulfone, disulfone and o-nitrobenzyl sulfonate.

Out of the acid generators, preferred compounds include compounds represented by the following formulae (ZI), (ZII) and (ZIII):

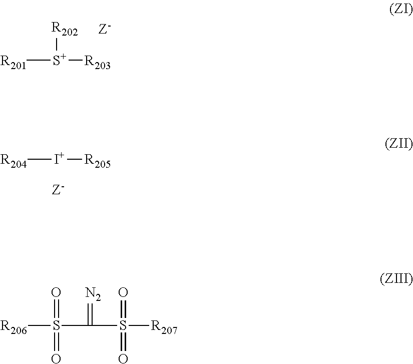

In formula (ZI), each of R₂₀₁, R₂₀₂ and R₂₀₃ independently represents an organic group.

The carbon number of the organic group as R₂₀₁, R₂₀₂ and R₂₀₃ is generally from 1 to 30, preferably from 1 to 20.

Two members out of R₂₀₁ to R₂₀₃ may combine to form a ring structure, and the ring may contain therein an oxygen atom, a sulfur atom, an ester bond, an amide bond or a carbonyl group. Examples of the group formed by combining two members out of R₂₀₁ to R₂₀₃ include an alkylene group (e.g., butylene group, pentylene group).

Z⁻ represents a non-nucleophilic anion.

Examples of the non-nucleophilic anion as Z⁻ include sulfonate anion, carboxylate anion, sulfonylimide anion, bis(alkylsulfonyl)imide anion and tris(alkylsulfonyl)methyl anion.

The non-nucleophilic anion is an anion having an extremely low ability of causing a nucleophilic reaction and this anion can suppress the decomposition with aging due to intramolecular nucleophilic reaction. Thanks to this anion, the aging stability of the resist composition is improved.

Examples of the sulfonate anion include an aliphatic sulfonate anion, an aromatic sulfonate anion, and a camphorsulfonate anion.

Examples of the carboxylate anion include an aliphatic carboxylate anion, an aromatic carboxylate anion, and an aralkylcarboxylate anion.

The aliphatic moiety in the aliphatic sulfonate anion and aliphatic carboxylate may be an alkyl group or a cycloalkyl group but is preferably an alkyl group having a carbon number of 1 to 30 or a cycloalkyl group having a carbon number of 3 to 30, and examples thereof include a methyl group, an ethyl group, a propyl group, an isopropyl group, an n-butyl group, an isobutyl group, a sec-butyl group, a pentyl group, a neopentyl group, a hexyl group, a heptyl group, an octyl group, a nonyl group, a decyl group, an undecyl group, a dodecyl group, a tridecyl group, a tetradecyl group, a pentadecyl group, a hexadecyl group, a heptadecyl group, an octadecyl group, a nonadecyl group, an eicosyl group, a cyclopropyl group, a cyclopentyl group, a cyclohexyl group, an adamantyl group, a norbornyl group and a bornyl group.

The aromatic group in the aromatic sulfonate anion and aromatic carboxylate anion is preferably an aryl group having a carbon number of 6 to 14, and examples thereof include a phenyl group, a tolyl group and a naphthyl group.

The alkyl group, cycloalkyl group and aryl group in the aliphatic sulfonate anion and aromatic sulfonate anion may have a substituent. Examples of the substituent of the alkyl group, cycloalkyl group and aryl group in the aliphatic sulfonate anion and aromatic sulfonate anion include a nitro group, a halogen atom (e.g., fluorine atom, chlorine atom, bromine atom, iodine atom), a carboxyl group, a hydroxyl group, an amino group, a cyano group, an alkoxy group (preferably having a carbon number of 1 to 15), a cycloalkyl group (preferably having a carbon number of 3 to 15), an aryl group (preferably having a carbon number of 6 to 14), an alkoxycarbonyl group (preferably having a carbon number of 2 to 7), an acyl group (preferably having a carbon number of 2 to 12), an alkoxycarbonyloxy group (preferably having a carbon number of 2 to 7), an alkylthio group (preferably having a carbon number of 1 to 15), an alkylsulfonyl group (preferably having a carbon number of 1 to 15), an alkyliminosulfonyl group (preferably having a carbon number of 1 to 15), an aryloxysulfonyl group (preferably having a carbon number of 6 to 20), an alkylaryloxysulfonyl group (preferably having a carbon number of 7 to 20), a cycloalkylaryloxysulfonyl group (preferably having a carbon number of 10 to 20), an alkyloxyalkyloxy group (preferably having a carbon number of 5 to 20), and a cycloalkylalkyloxyalkyloxy group (preferably having a carbon number of 8 to 20). The aryl group and ring structure in each group may further have, as the substituent, an alkyl group (preferably having a carbon number of 1 to 15) or a cycloalkyl group (preferably having a carbon number of 3 to 15).

The aralkyl group in the aralkylcarboxylate anion is preferably an aralkyl group having a carbon number of 7 to 12, and examples thereof include a benzyl group, a phenethyl group, a naphthylmethyl group, a naphthylethyl group and a naphthylbutyl group.

The alkyl group, cycloalkyl group, aryl group and aralkyl group in the aliphatic carboxylate anion, aromatic carboxylate anion and aralkylcarboxylate anion may have a substituent. Examples of the substituent include the same halogen atom, alkyl group, cycloalkyl group, alkoxy group and alkylthio group as those in the aromatic sulfonate anion.

Examples of the sulfonylimide anion include saccharin anion.

The alkyl group in the bis(alkylsulfonyl)imide anion and tris(alkylsulfonyl)methide anion is preferably an alkyl group having a carbon number of 1 to 5, and examples thereof include a methyl group, an ethyl group, a propyl group, an isopropyl group, an n-butyl group, an isobutyl group, a sec-butyl group, a pentyl group and a neopentyl group. Examples of the substituent on such an alkyl group include a halogen atom, a halogen atom-substituted alkyl group, an alkoxy group, an alkylthio group, an alkyloxysulfonyl group, an aryloxysulfonyl group, and a cycloalkylaryloxysulfonyl group, with a fluorine atom-substituted alkyl group being preferred.

Other examples of the non-nucleophilic anion include fluorinated phosphorus (e.g., PF₆⁻), fluorinated boron (e.g., BF₄⁻), and fluorinated antimony (e.g., SbF₆⁻).

The non-nucleophilic anion of Z⁻ is preferably an aliphatic sulfonate anion substituted with a fluorine atom at least at the α-position of sulfonic acid, an aromatic sulfonate anion substituted with a fluorine atom or a fluorine atom-containing group, a bis(alkylsulfonyl)imide anion in which the alkyl group is substituted with a fluorine atom, or a tris(alkylsulfonyl)methide anion in which the alkyl group is substituted with a fluorine atom. The non-nucleophilic anion is more preferably a perfluoroaliphatic sulfonate anion having a carbon number of 4 to 8 or a benzenesulfonate anion having a fluorine atom, still more preferably nonafluorobutanesulfonate anion, perfluorooctanesulfonate anion, pentafluorobenzenesulfonate anion or 3,5-bis(trifluoromethyl)benzenesulfonate anion.

The acid generator is preferably a compound capable of generating an acid represented by the following formula (III) or (IV) upon irradiation with an actinic ray or radiation. The compound capable of generating an acid represented by the following formula (III) or (IV) has a cyclic organic group, so that the resolution and roughness performance can be more improved.

The non-nucleophilic anion described above can be an anion capable of generating an organic acid represented by the following formula (III) or (IV):

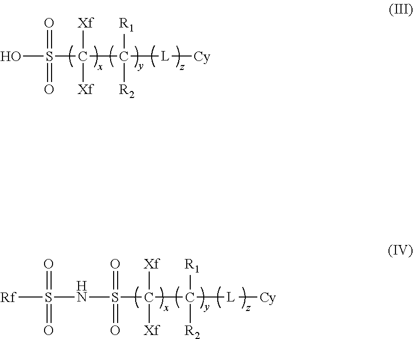

In the formulae, each Xf independently represents a fluorine atom or an alkyl group substituted with at least one fluorine atom.

Each of R₁ and R₂ independently represents a hydrogen atom, a fluorine atom or an alkyl group.

Each L independently represents a divalent linking group.

Cy represents a cyclic organic group.

Rf represents a fluorine atom-containing group.

x represents an integer of 1 to 20.

y represents an integer of 0 to 10.

z represents an integer of 0 to 10.

Xf represents a fluorine atom or an alkyl group substituted with at least one fluorine atom. The carbon number of the alkyl group is preferably from 1 to 10, more preferably from 1 to 4. Also, the alkyl group substituted with at least one fluorine atom is preferably a perfluoroalkyl group.

Xf is preferably a fluorine atom or a perfluoroalkyl group having a carbon number of 1 to 4. Specifically, Xf is preferably a fluorine atom, CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F_{S}, CH₂CH₂C₂F₅, CH₂C₃F₇, CH₂CH₂C₃F₇, CH₂C₄F₉ or CH₂CH₂C₄F₉, more preferably a fluorine atom or CF₃, and it is still more preferred that both Xf are a fluorine atom.

Each of R₁ and R₂ independently represents a hydrogen atom, a fluorine atom or an alkyl group. The alkyl group may have a substituent (preferably fluorine atom) and is preferably an alkyl group having a carbon number of 1 to 4, more preferably a perfluoroalkyl group having a carbon number of 1 to 4. Specific examples of the alkyl group having a substituent of R₁ and R₂ include CF₃, C₂F₅, C₃F₇, C₄F₉, C₅F₁₁, C₆F₁₃, C₇F₁₅, C₈F₁₇, CH₂CF₃, CH₂CH₂CF₃, CH₂C₂F₅, CH₂CH₂C₂F₅, CH₂C₃F₇, CH₂CH₂C₃F₇, CH₂C₄F₉ and CH₂CH₂C₄F₉, with CF₃ being preferred.

L represents a divalent linking group. Examples of the divalent linking group include —COO—, —COO—, —CONH—, —NHCO—, —CO—, —O—, —S—, —SO—, —SO₂—, an alkylene group (preferably having a carbon number of 1 to 6), a cycloalkylene group (preferably having a carbon number of 3 to 10), an alkenylene group (preferably having a carbon number of 2 to 6), and a divalent linking group formed by combining a plurality of these members. Among these, —COO—, —COO—, —CONH—, —NHCO—, —CO—, —O—, —SO₂—, —COO-alkylene group-, —OCO-alkylene group-, —CONH-alkylene group- and —NHCO-alkylene group- are preferred, and —COO—, —COO—, —CONH—, —SO₂—, —COO-alkylene group- and —OCO-alkylene group- are more preferred.

Cy represents a cyclic organic group. Examples of the cyclic organic group include an alicyclic group, an aryl group and a heterocyclic group

The alicyclic group may be monocyclic or polycyclic. The monocyclic alicyclic group includes, for example, a monocyclic cycloalkyl group such as cyclopentyl group, cyclohexyl group and cyclooctyl group. The polycyclic alicyclic group includes, for example, a polycyclic cycloalkyl group such as norbornyl group, tricyclodecanyl group, tetracyclodecanyl group, tetracyclododecanyl group and adamantyl group. Above all, an alicyclic group having a bulky structure with a carbon number of 7 or more, such as norbornyl group, tricyclodecanyl group, tetracyclodecanyl group, tetracyclododecanyl group and adamantyl group, is preferred from the standpoint of restraining diffusion in film during a PEB (post-exposure baking) step and improving MEEF (Mask Error Enhancement Factor).

The aryl group may be monocyclic or polycyclic. Examples of the aryl group include a phenyl group, a naphthyl group, a phenanthryl group and an anthryl group. Among these, a naphthyl group is preferred because of its relatively low light absorbance at 193 mm.

The heterocyclic group may be monocyclic or polycyclic, but a polycyclic heterocyclic group can more restrain diffusion of an acid. The heterocyclic group may have aromaticity or may not have aromaticity. Examples of the heterocyclic ring having aromaticity include a furan ring, a thiophene ring, a benzofuran ring, a benzothiophene ring, a dibenzofuran ring, a dibenzothiophene ring, and a pyridine ring. Examples of the heterocyclic ring not having aromaticity include a tetrahydropyran ring, a lactone ring and a decahydroisoquinoline ring. The heterocyclic ring in the heterocyclic group is preferably a furan ring, a thiophene ring, a pyridine ring or a decahydroisoquinoline ring. Examples of the lactone ring include lactone structures exemplified in the resin (A) above.

The above-described cyclic organic group may have a substituent, and examples of the substituent include an alkyl group (may be linear or branched, preferably having a carbon number of 1 to 12), a cycloalkyl group (may be monocyclic, polycyclic or spirocyclic, preferably having a carbon number of 3 to 20), an aryl group (preferably having a carbon number of 6 to 14), a hydroxy group, an alkoxy group, an ester group, an amide group, a urethane group, a ureido group, a thioether group, a sulfonamido group and a sulfonic acid ester group. Incidentally, the carbon constituting the cyclic organic group (the carbon contributing to ring formation) may be carbonyl carbon.

x is preferably from 1 to 8, more preferably from 1 to 4, still more preferably 1. y is preferably from 0 to 4, more preferably 0. z is preferably from 0 to 8, more preferably from 0 to 4.

The fluorine atom-containing group represented by Rf includes, for example, an alkyl group having at least one fluorine atom, a cycloalkyl group having at least one fluorine atom, and an aryl group having at least one fluorine atom

The alkyl group, cycloalkyl group and aryl group may be substituted with a fluorine atom or may be substituted with another fluorine atom-containing substituent. In the case where Rf is a cycloalkyl group having at least one fluorine atom or an aryl group having at least one fluorine atom, the another fluorine-containing substituent includes, for example, an alkyl group substituted with at last one fluorine atom.

Also, the alkyl group, cycloalkyl group and aryl group may be further substituted with a fluorine atom-free substituent. Examples of this substituent include those not containing a fluorine atom out of those described above for Cy.

Examples of the alkyl group having at least one fluorine atom represented by Rf are the same as those described above as the alkyl group substituted with at least one fluorine atom represented by Xf. Examples of the cycloalkyl group having at least one fluorine atom represented by Rf include a perfluorocyclopentyl group and a perfluorocyclohexyl group. Examples of the aryl group having at least one fluorine atom represented by Rf include a perfluorophenyl group.

The organic group represented by R₂₀₁, R₂₀₂ and R₂₀₃ includes, for example, corresponding groups in the later-described compounds (ZI-1), (ZI-2), (ZI-3) and (ZI-4).

The compound may be a compound having a plurality of structures represented by formula (ZI). For example, the compound may be a compound having a structure where at least one of R₂₀₁ to R₂₀₃ in a compound represented by formula (ZI) is bonded to at least one of R₂₀₁ to R₂₀₃ in another compound represented by formula (ZI) through a single bond or a linking group.

Compounds (ZI-1), (ZI-2), (ZI-3) and (ZI-4) described below are more preferred as the component (ZI).

The compound (ZI-1) is an arylsulfonium compound where at least one of R₂₀₁ to R₂₀₃ in formula (ZI) is an aryl group, that is, a compound having an arylsulfonium as the cation.

In the arylsulfonium compound, all of R₂₀₁ to R₂₀₃ may be an aryl group or a part of R₂₀₁ to R₂₀₃ may be an aryl group, with the remaining being an alkyl group or a cycloalkyl group.

Examples of the arylsulfonium compound include a triarylsulfonium compound, a diarylalkylsulfonium compound, an aryldialkylsulfonium compound, a diarylcycloalkylsulfonium compound, and an aryldicycloalkylsulfonium compound.

The aryl group in the arylsulfonium compound is preferably a phenyl group or a naphthyl group, more preferably a phenyl group. The aryl group may be an aryl group having a heterocyclic structure containing an oxygen atom, a nitrogen atom, a sulfur atom or the like. Examples of the heterocyclic structure include a pyrrole residue, a furan residue, a thiophene residue, an indole residue, a benzofuran residue and a benzothiophene residue. In the case where the arylsulfonium compound has two or more aryl groups, these two or more aryl groups may be the same or different.

The alkyl or cycloalkyl group which the arylsulfonium compound, if desired, has is preferably a linear or branched alkyl group having a carbon number of 1 to 15 or a cycloalkyl group having a carbon number of 3 to 15, and examples thereof include a methyl group, an ethyl group, a propyl group, an n-butyl group, a sec-butyl group, a tert-butyl group, a cyclopropyl group, a cyclobutyl group, and a cyclohexyl group.

The aryl group, alkyl group and cycloalkyl group of R₂₀₁ to R₂₀₃ may have, as the substituent, an alkyl group (for example, having a carbon number of 1 to 15), a cycloalkyl group (for example, having a carbon number of 3 to 15), an aryl group (for example, having a carbon number of 6 to 14), an alkoxy group (for example, having a carbon number of 1 to 15), a halogen atom, a hydroxyl group or a phenylthio group. The substituent is preferably a linear or branched alkyl group having a carbon number of 1 to 12, a cycloalkyl group having a carbon number of 3 to 12, or a linear, branched or cyclic alkoxy group having a carbon number of 1 to 12, more preferably an alkyl group having a carbon number of 1 to 4, or an alkoxy group having a carbon number of 1 to 4. The substituent may be substituted on any one of three members R₂₀₁ to R₂₀₃ or may be substituted on all of these three members. In the case where R₂₀₁ to R₂₀₃ are an aryl group, the substituent is preferably substituted on the p-position of the aryl group.

The compound (ZI-2) is described below.

The compound (ZI-2) is a compound where each of R₂₀₁ to R₂₀₃ in formula (ZI) independently represents an aromatic ring-free organic group. The aromatic ring as used herein encompasses an aromatic ring containing a heteroatom.

The aromatic ring-free organic group as R₂₀₁ to R₂₀₃ has a carbon number of generally from 1 to 30, preferably from 1 to 20.

Each of R₂₀₁ to R₂₀₃ is independently, preferably an alkyl group, a cycloalkyl group, an allyl group or a vinyl group, more preferably a linear or branched 2-oxoalkyl group, a 2-oxocycloalkyl group or an alkoxycarbonylmethyl group, still more preferably a linear or branched 2-oxoalkyl group.

The alkyl group and cycloalkyl group of R₂₀₁ to R₂₀₃ are preferably a linear or branched alkyl group having a carbon number of 1 to 10 (e.g., a methyl group, an ethyl group, a propyl group, a butyl group, a pentyl group) and a cycloalkyl group having a carbon number of 3 to 10 (e.g., a cyclopentyl group, a cyclohexyl group, a norbornyl group). The alkyl group is more preferably a 2-oxoalkyl group or an alkoxycarbonylmethyl group. The cycloalkyl group is more preferably a 2-oxocycloalkyl group.

The 2-oxoalkyl group may be either linear or branched and is preferably a group having >C═O at the 2-position of the above-described alkyl group.

The 2-oxocycloalkyl group is preferably a group having >C═O at the 2-position of the above-described cycloalkyl group.

The alkoxy group in the alkoxycarbonylmethyl group is preferably an alkoxy group having a carbon number of 1 to 5 (e.g., a methoxy group, an ethoxy group, a propoxy group, a butoxy group, a pentoxy group).

R₂₀₁ to R₂₀₃ may be further substituted with a halogen atom, an alkoxy group (for example, having a carbon number of 1 to 5), a hydroxyl group, a cyano group or a nitro group.

The compound (ZI-3) is described below.

The compound (ZI-3) is a compound represented by the following formula (ZI-3), and this is a compound having a phenacylsulfonium salt structure.

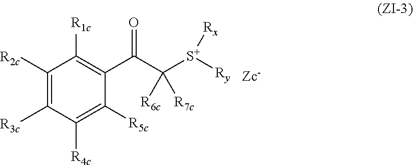

In formula (ZI-3), each of R_{1c} to R_{5c} independently represents a hydrogen atom, an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group, or an arylthio group.

Each of R_{6c} and R_{7c} independently represents a hydrogen atom, an alkyl group, a cycloalkyl group, a halogen atom, a cyano group, or an aryl group.

Each of Rₓ and R_{y} independently represents an alkyl group, a cycloalkyl group, a 2-oxoalkyl group, a 2-oxocycloalkyl group, an alkoxycarbonylalkyl group, an allyl group, or a vinyl group.

Any two or more members out of R_{1c} to R_{5c}, a pair of R_{5c} and R_{6c}, a pair of R_{6c} and R_{7c}, a pair of R_{5c} and Rₓ, or a pair of Rₓ and R_{y} may combine together to form a ring structure. This ring structure may contain an oxygen atom, a sulfur atom, a ketone group, an ester bond or an amide bond.

The ring structure above includes an aromatic or non-aromatic hydrocarbon ring, an aromatic or non-aromatic heterocyclic ring, and a polycyclic condensed ring formed by combining two or more of these rings. The ring structure includes a 3- to 10-membered ring and is preferably a 4- to 8-membered ring, more preferably a 5- or 6-membered ring.

Examples of the group formed by combining any two or more members of R_{1c} to R_{5c}, a pair of R_{6c} and R_{7c}, or a pair of Rₓ and R_{y} include a butylene group and a pentylene group.

The group formed by combining a pair of R_{5c} and R_{6c} or a pair of R_{5c} and Rₓ is preferably a single bond or an alkylene group, and examples of the alkylene group include a methylene group and an ethylene group.

Zc⁻ represents a non-nucleophilic anion, and examples thereof are the same as those of the non-nucleophilic anion of Z⁻ in formula (ZI).

The alkyl group as R_{1c} to R_{7c} may be either linear or branched and is, for example, an alkyl group having a carbon number of 1 to 20, preferably a linear or branched alkyl group having a carbon number of 1 to 12 (such as a methyl group, an ethyl group, a linear or branched propyl group, a linear or branched butyl group, or a linear or branched pentyl group). The cycloalkyl group includes, for example, a cycloalkyl group having a carbon number of 3 to 10 (e.g., a cyclopentyl group, a cyclohexyl group).

The aryl group as R_{1c} to R_{5c} is preferably an aryl group having a carbon number of 5 to 15, and examples thereof include a phenyl group and a naphthyl group.

The alkoxy group as R_{1c} to R_{5c} may be linear, branched or cyclic and is, for example, an alkoxy group having a carbon number of 1 to 10, preferably a linear or branched alkoxy group having a carbon number of 1 to 5 (such as a methoxy group, an ethoxy group, a linear or branched propoxy group, a linear or branched butoxy group, or a linear or branched pentoxy group), or a cyclic alkoxy group having a carbon number of 3 to 10 (such as a cyclopentyloxy group or a cyclohexyloxy group).

Specific examples of the alkoxy group in the alkoxycarbonyl group as R_{1c} to R_{5c} are the same as specific examples of the alkoxy group of R_{1c} to R_{5c}.

Specific examples of the alkyl group in the alkylcarbonyloxy group and alkylthio group as R_{1c} to R_{5c} are the same as specific examples of the alkyl group of R_{1c} to R_{5c}.

Specific examples of the cycloalkyl group in the cycloalkylcarbonyloxy group as R_{1c} to R_{5c} are the same as specific examples of the cycloalkyl group of R_{1c} to R_{5c}.

Specific examples of the aryl group in the aryloxy group and arylthio group as R_{1c} to R_{5c} are the same as specific examples of the aryl group of R_{1c} to R_{5c}.

A compound where any one of R_{1c} to R_{5c} is a linear or branched alkyl group, a cycloalkyl group, or a linear, branched or cyclic alkoxy group is preferred, and a compound where the sum of carbon numbers of R_{1c} to R_{5c} is from 2 to 15 is more preferred. Thanks to such a compound, the solvent solubility is more enhanced and production of particles during storage can be suppressed.

The ring structure which may be formed by combining any two or more members of R_{1c} to R_{5c} with each other is preferably a 5- or 6-membered ring, more preferably a 6-membered ring (such as a phenyl ring).

The ring structure which may be formed by combining R_{5c} and R_{6c} with each other includes a 4-membered or greater membered ring (preferably a 5- or 6-membered ring) formed together with the carbonyl carbon atom and carbon atom in formula (I) by combining R_{5c} and R_{6c} with each other to constitute a single bond or an alkylene group (such as a methylene group or an ethylene group).

The aryl group as R_{6c} and R_{7c} is preferably an aryl group having a carbon number of 5 to 15, and examples thereof include a phenyl group and a naphthyl group.

An embodiment where both of R_{6c} and R_{7c} are an alkyl group is preferred, an embodiment where each of R_{6c} and R_{7c} is a linear or branched alkyl group having a carbon number of 1 to 4 is more preferred, and an embodiment where both are a methyl group is still more preferred.

In the case where R_{6c} and R_{7c} are combined to form a ring, the group formed by combining R_{6c} and R_{7c} is preferably an alkylene group having a carbon number of 2 to 10, and examples thereof include an ethylene group, a propylene group, a butylene group, a pentylene group and a hexylene group. Also, the ring formed by combining R_{6c} and R_{7c} may contain a heteroatom such as oxygen atom in the ring.

Examples of the alkyl group and cycloalkyl group as Rₓ and R_{y} are the same as those of the alkyl group and cycloalkyl group in R_{1c} to R_{7c}.

Examples of the 2-oxoalkyl group and 2-oxocycloalkyl group as Rₓ and R_{y} include a group having >C═O at the 2-position of the alkyl group or cycloalkyl group as R_{1c} to R_{7c}.

Examples of the alkoxy group in the alkoxycarbonylalkyl group as Rₓ and R_{y} are the same as those of the alkoxy group in R_{1c} to R_{5c}. The alkyl group is, for example, an alkyl group having a carbon number of 1 to 12, preferably a linear alkyl group having a carbon number of 1 to 5 (such as a methyl group or an ethyl group).

The allyl group as Rₓ and R_{y} is not particularly limited but is preferably an unsubstituted allyl group or an allyl group substituted with a monocyclic or polycyclic cycloalkyl group (preferably a cycloalkyl group having a carbon number of 3 to 10).

The vinyl group as Rₓ and R_{y} is not particularly limited but is preferably an unsubstituted vinyl group or a vinyl group substituted with a monocyclic or polycyclic cycloalkyl group (preferably a cycloalkyl group having a carbon number of 3 to 10).

The ring structure which may be formed by combining R_{5c} and Rₓ with each other includes a 5-membered or greater membered ring (preferably a 5-membered ring) formed together with the sulfur atom and carbonyl carbon atom in formula (I) by combining R_{5c} and Rₓ with each other to constitute a single bond or an alkylene group (such as a methylene group or an ethylene group).

The ring structure which may be formed by combining Rₓ and R_{y} with each other includes a 5- or 6-membered ring, preferably a 5-membered ring (that is, tetrahydrothiophene ring), formed by divalent Rₓ and R_{y} (for example, a methylene group, an ethylene group, or a propylene group) together with the sulfur atom in formula (ZI-3).

Each of Rₓ and R_{y} is preferably an alkyl or cycloalkyl group having a carbon number of 4 or more, more preferably 6 or more, still more preferably 8 or more.

Each of R_{1c} to R_{7c}, Rₓ and R_{y} may further have a substituent, and examples of such a substituent include a halogen atom (e.g., a fluorine atom), a hydroxyl group, a carboxyl group, a cyano group, a nitro group, an alkyl group, a cycloalkyl group, an aryl group, an alkoxy group, an aryloxy group, an acyl group, an arylcarbonyl group, an alkoxyalkyl group, an aryloxyalkyl group, an alkoxycarbonyl group, an aryloxycarbonyl group, an alkoxycarbonyloxy group, and an aryloxycarbonyloxy group.

In formula (ZI-3) above, it is more preferred that each of R_{1c}, R_{2c}, R_{4c} and R_{5c} independently represents a hydrogen atom and R_{3c} represents a group except for a hydrogen atom, that is, represents an alkyl group, a cycloalkyl group, an aryl group, an alkoxy group, an aryloxy group, an alkoxycarbonyl group, an alkylcarbonyloxy group, a cycloalkylcarbonyloxy group, a halogen atom, a hydroxyl group, a nitro group, an alkylthio group or an arylthio group.

Examples of the cation in the compound (ZI-2) or (ZI-3) for use in the present invention include the cations described in paragraphs [0130] to [0134] of JP-A-2010-256842 and paragraphs [0136] to [0140] of JP-A-2011-76056.

The compound (ZI-4) is described below.

The compound (ZI-4) is represented by the following formula (ZI-4):

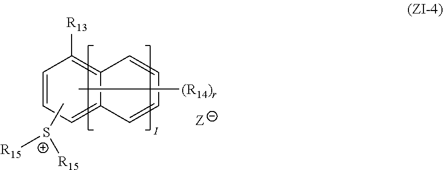

In formula (ZI-4), R₁₃ represents a hydrogen atom, a fluorine atom, a hydroxyl group, an alkyl group, a cycloalkyl group, an alkoxy group, an alkoxycarbonyl group, or a group having a cycloalkyl group. These groups may have a substituent.

When a plurality of R₁₄s are present, each R₁₄ independently represents, a hydroxyl group, an alkyl group, a cycloalkyl group, an alkoxy group, an alkoxycarbonyl group, an alkylcarbonyl group, an alkylsulfonyl group, a cycloalkylsulfonyl group, or a group having a cycloalkyl group. These groups may have a substituent.

Each R₁₅ independently represents an alkyl group, a cycloalkyl group, or a naphthyl group. Two R₁₅s may combine with each other to form a ring. These groups may have a substituent.

l represents an integer of 0 to 2.

r represents an integer of 0 to 8.

Z⁻ represents a non-nucleophilic anion, and examples thereof are the same as those of the nucleophilic anion of Z⁻ in formula (ZI).

In formula (ZI-4), the alkyl group of R₁₃, R₁₄ and R₁₅ is a linear or branched alkyl group preferably having a carbon number of 1 to 10, and preferred examples thereof include a methyl group, an ethyl group, an n-butyl group and a tert-butyl group.

The cycloalkyl group of R₁₃, R₁₄ and R₁₅ includes a monocyclic or polycyclic cycloalkyl group (preferably a cycloalkyl group having a carbon number of 3 to 20) and is preferably cyclopropyl, cyclopentyl, cyclohexyl, cycloheptyl, or cyclooctyl, among others.

The alkoxy group of R₁₃ and R₁₄ is a linear or branched alkoxy group preferably having a carbon number of 1 to 10, and preferred examples thereof include a methoxy group, an ethoxy group, an n-propoxy group and an n-butoxy group.

The alkoxycarbonyl group of R₁₃ and R₁₄ is a linear or branched alkoxycarbonyl group preferably having a carbon number of 2 to 11, and preferred examples thereof include a methoxycarbonyl group, an ethoxycarbonyl group and an n-butoxycarbonyl group.

The group having a cycloalkyl group of R₁₃ and R₁₄ includes a monocyclic or polycyclic cycloalkyl group (preferably a cycloalkyl group having a carbon number of 3 to 20), and examples thereof include a monocyclic or polycyclic cycloalkyloxy group and an alkoxy group having a monocyclic or polycyclic cycloalkyl group. These groups may further have a substituent.

The monocyclic or polycyclic cycloalkyloxy group of R₁₃ and R₁₄ preferably has a total carbon number of 7 or more, more preferably a total carbon number of 7 to 15, and preferably has a monocyclic cycloalkyl group. The monocyclic cycloalkyloxy group having a total carbon number of 7 or more indicates a monocyclic cycloalkyloxy group where a cycloalkyloxy group such as cyclopropyloxy group, cyclobutyloxy group, cyclopentyloxy group, cyclohexyloxy group, cycloheptyloxy group, cyclooctyloxy group and cyclododecanyloxy group arbitrarily has a substituent such as alkyl group (e.g., a methyl group, an ethyl group, a propyl group, a butyl group, a pentylgroup, a hexyl group, a heptyl group, an octyl group, a dodecyl group, a 2-ethylhexyl group, an isopropyl group, a sec-butyl group, a tert-butyl group, an isoamyl group), a hydroxyl group, a halogen atom (e.g., fluorine, chlorine, bromine, iodine), a nitro group, a cyano group, an amido group, a sulfonamido group, an alkoxy group (e.g., a methoxy group, an ethoxy group, a hydroxyethoxy group, a propoxy group, a hydroxypropoxy group, a butoxy group), an alkoxycarbonyl group (e.g., a methoxycarbonyl group, an ethoxycarbonyl group), an acyl group (e.g., a formyl group, an acetyl group, a benzoyl group), an acyloxy group (e.g., an acetoxy group, a butyryloxy group) and a carboxy group and where the total carbon number inclusive of the carbon number of an arbitrary substituent on the cycloalkyl group is 7 or more.

Moreover, examples of the polycyclic cycloalkyloxy group having a total carbon number of 7 or more include a norbornyloxy group, a tricyclodecanyloxy group, a tetracyclodecanyloxy group, and an adamantyloxy group.

The alkoxy group having a monocyclic or polycyclic cycloalkyl group of R₁₃ and R₁₄ preferably has a total carbon number of 7 or more, more preferably a total carbon number of 7 to 15, and is preferably an alkoxy group having a monocyclic cycloalkyl group. The alkoxy group having a total carbon number of 7 or more and having a monocyclic cycloalkyl group indicates an alkoxy group where the above-described monocyclic cycloalkyl group which may have a substituent is substituted on an alkoxy group such as methoxy, ethoxy, propoxy, butoxy, pentyloxy, hexyloxy, heptoxy, octyloxy, dodecyloxy, 2-ethylhexyloxy, isopropoxy, sec-butoxy, tert-butoxy and isoamyloxy and where the total carbon number inclusive of the carbon number of the substituent is 7 or more. Examples thereof include a cyclohexylmethoxy group, a cyclopentylethoxy group, and a cyclohexylethoxy group, with a cyclohexylmethoxy group being preferred.

Examples of the alkoxy group having a total carbon number of 7 or more and having a polycyclic cycloalkyl group include a norbornylmethoxy group, a norbornylethoxy group, a tricyclodecanylmethoxy group, a tricyclodecanylethoxy group, a tetracyclodecanylmethoxy group, a tetracyclodecanylethoxy group, an adamantylmethoxy group, and an adamantylethoxy group, with a norbornylmethoxy group and a norbornylethoxy group being preferred.

Specific examples of the alkyl group in the alkylcarbonyl group of R₁₄ are the same as those of the alkyl group of R₁₃ to R₁₅.

The alkylsulfonyl or cycloalkylsulfonyl group of R₁₄ is a linear, branched or cyclic alkylsulfonyl group preferably having a carbon number of 1 to 10, and preferred examples thereof include a methanesulfonyl group, an ethanesulfonyl group, an n-propanesulfonyl group, an n-butanesulfonyl group, a cyclopentanesulfonyl group, and a cyclohexanesulfonyl group.

Examples of the substituent which may be substituted on each of the groups above include a halogen atom (e.g., a fluorine atom), a hydroxyl group, a carboxyl group, a cyano group, a nitro group, an alkoxy group, an alkoxyalkyl group, an alkoxycarbonyl group, and an alkoxycarbonyloxy group.

Examples of the alkoxy group include a linear, branched or cyclic alkoxy group having a carbon number of 1 to 20, such as a methoxy group, an ethoxy group, an n-propoxy group, an i-propoxy group, an n-butoxy group, a 2-methylpropoxy group, a 1-methylpropoxy group, a tert-butoxy group, a cyclopentyloxy group and a cyclohexyloxy group.

Examples of the alkoxyalkyl group include a linear, branched or cyclic alkoxyalkyl group having a carbon number of 2 to 21, such as a methoxymethyl group, an ethoxymethyl group, a 1-methoxyethyl group, a 2-methoxyethyl group, a 1-ethoxyethyl group and a 2-ethoxyethyl group.

Examples of the alkoxycarbonyl group include a linear, branched or cyclic alkoxycarbonyl group having a carbon number of 2 to 21, such as a methoxycarbonyl group, an ethoxycarbonyl group, an n-propoxycarbonyl group, an i-propoxycarbonyl group, an n-butoxycarbonyl group, a 2-methylpropoxycarbonyl group, a 1-methylpropoxycarbonyl group, a tert-butoxycarbonyl group, a cyclopentyloxycarbonyl group and a cyclohexyloxycarbonyl group.

Examples of the alkoxycarbonyloxy group include a linear, branched or cyclic alkoxycarbonyloxy group having a carbon number of 2 to 21, such as a methoxycarbonyloxy group, an ethoxycarbonyloxy group, an n-propoxycarbonyloxy group, an i-propoxycarbonyloxy group, an n-butoxycarbonyloxy group, a tert-butoxycarbonyloxy group, a cyclopentyloxycarbonyloxy group and a cyclohexyloxycarbonyloxy group.

The ring structure which may be formed by combining two R₁₅s with each other includes a 5- or 6-membered ring, preferably a 5-membered ring (that is, tetrahydrothiophene ring), formed by two R₁₅s together with the sulfur atom in formula (ZI-4) and may be fused with an aryl group or a cycloalkyl group. The divalent R₁₅ may have a substituent, and examples of the substituent include a hydroxyl group, a carboxyl group, a cyano group, a nitro group, an alkyl group, a cycloalkyl group, an alkoxy group, an alkoxyalkyl group, an alkoxycarbonyl group, and an alkoxycarbonyloxy group. As for the substituent on the ring structure, a plurality of substituents may be present, and they may combine with each other to form a ring (an aromatic or non-aromatic hydrocarbon ring, an aromatic or non-aromatic heterocyclic ring, or a polycyclic condensed ring formed by combining two or more of these rings).

In formula (ZI-4), R₁₅ is preferably, for example, a methyl group, an ethyl group, a naphthyl group, or a divalent group capable of forming a tetrahydrothiophene ring structure together with the sulfur atom when two R₁₅s are combined.

The substituent which may be substituted on R₁₃ and R₁₄ is preferably a hydroxyl group, an alkoxy group, an alkoxycarbonyl group, or a halogen atom (particularly a fluorine atom).

l is preferably 0 or 1, more preferably 1.

r is preferably from 0 to 2.

Examples of the cation in the compound represented by formula (ZI-4) for use in the present invention include the cations described in paragraphs [0121], [0123] and [0124] of JP-A-2010-256842 and paragraphs [0127], [0129] and [0130] of JP-A-2011-76056.

Formulae (ZII) and (ZIII) are described below.

In formulae (ZII) and (ZIII), each of R₂₀₄ to R₂₀₇ independently represents an aryl group, an alkyl group or a cycloalkyl group.

The aryl group of R₂₀₄ to R₂₀₇ is preferably a phenyl group or a naphthyl group, more preferably a phenyl group. The aryl group of R₂₀₄ to R₂₀₇ may be an aryl group having a heterocyclic structure containing an oxygen atom, a nitrogen atom, a sulfur atom or the like. Examples of the framework of the aryl group having a heterocyclic structure include pyrrole, furan, thiophene, indole, benzofuran, and benzothiophene.

The alkyl or cycloalkyl group in R₂₀₄ to R₂₀₇ is preferably a linear or branched alkyl group having a carbon number of 1 to 10 (e.g., a methyl group, an ethyl group, a propyl group, a butyl group, a pentyl group) or a cycloalkyl group having a carbon number of 3 to 10 (e.g., a cyclopentyl group, a cyclohexyl group, a norbornyl group).

The aryl group, alkyl group and cycloalkyl group of R₂₀₄ to R₂₀₇ may have a substituent. Examples of the substituent which the aryl group, alkyl group and cycloalkyl group of R₂₀₄ to R₂₀₇ may have include an alkyl group (for example, having a carbon number of 1 to 15), a cycloalkyl group (for example, having a carbon number of 3 to 15), an aryl group (for example, having a carbon number of 6 to 15), an alkoxy group (for example, having a carbon number of 1 to 15), a halogen atom, a hydroxyl group, and a phenylthio group.

Z⁻ represents a non-nucleophilic anion, and examples thereof are the same as those of the non-nucleophilic anion of Z⁻ in formula (ZI).

Other examples of the acid generator include compounds represented by the following formulae (ZIV), (ZV) and (ZVI):

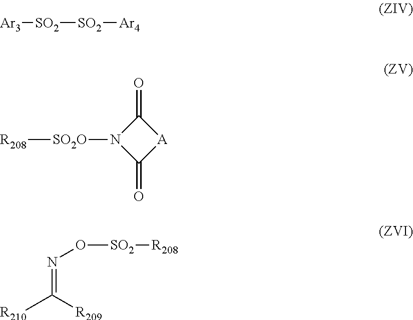

In formulae (ZIV) to (ZVI), each of Ar₃ and Ar₄ independently represents an aryl group.

Each of R₂₀₈, R₂₀₉ and R₂₁₀ independently represents an alkyl group, a cycloalkyl group, or an aryl group.

A represents an alkylene group, an alkenylene group, or an arylene group.

Specific examples of the aryl group of Ar₃, Ar₄, R₂₀₈, R₂₀₉ and R₂₁₀ are the same as specific examples of the aryl group as R₂₀₁, R₂₀₂ and R₂₀₃ in formula (ZI-1).

Specific examples of the alkyl group and cycloalkyl group of R₂₀₈, R₂₀₉ and R₂₁₀ are the same as specific examples of the alkyl group and cycloalkyl group of R₂₀₁, R₂₀₂ and R₂₀₃ in formula (ZI-2).

The alkylene group of A includes an alkylene group having a carbon number of 1 to 12 (e.g., a methylene group, an ethylene group, a propylene group, an isopropylene group, a butylenes group, an isobutylene group); the alkenylene group of A includes an alkenylene group having a carbon number of 2 to 12 (e.g., an ethenylene group, a propenylene group, a butenylene group); and the arylene group of A includes an arylene group having a carbon number of 6 to 10 (e.g., a phenylene group, a tolylene group, a naphthylene group).

Among the acid generators, more preferred are the compounds represented by formulae (ZI) to (ZIII).

Also, the acid generator is preferably a compound that generates an acid having one sulfonic acid group or imide group, more preferably a compound that generates a monovalent perfluoroalkanesulfonic acid, a compound that generates an aromatic sulfonic acid substituted with a monovalent fluorine atom or a fluorine atom-containing group, or a compound that generates an imide acid substituted with a monovalent fluorine atom or a fluorine atom-containing group, still more preferably a sulfonium salt of fluoro-substituted alkanesulfonic acid, fluorine-substituted benzenesulfonic acid, fluorine-substituted imide acid or fluorine-substituted methide acid. In particular, the acid generator which can be used is preferably a compound that generates a fluoro-substituted alkanesulfonic acid, a fluoro-substituted benzenesulfonic acid or a fluoro-substituted imide acid, where pKa of the acid generated is −1 or less, and in this case, the sensitivity is enhanced.

Among the acid generators, particularly preferred examples are illustrated below.

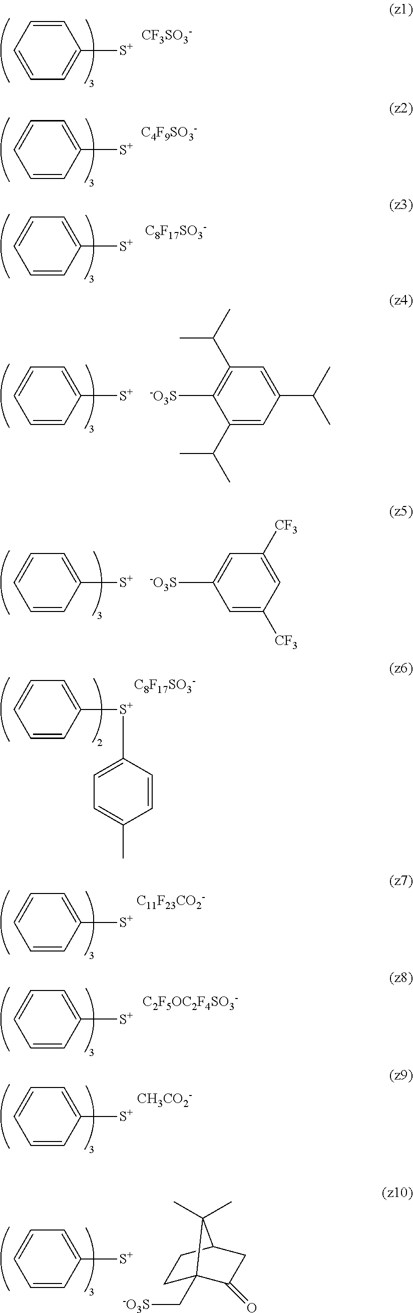

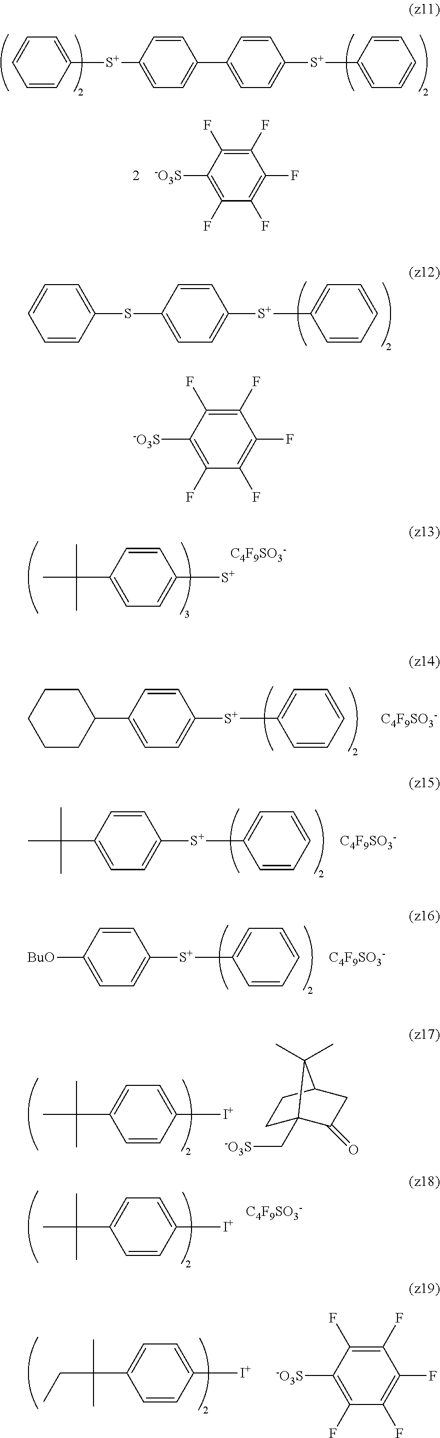

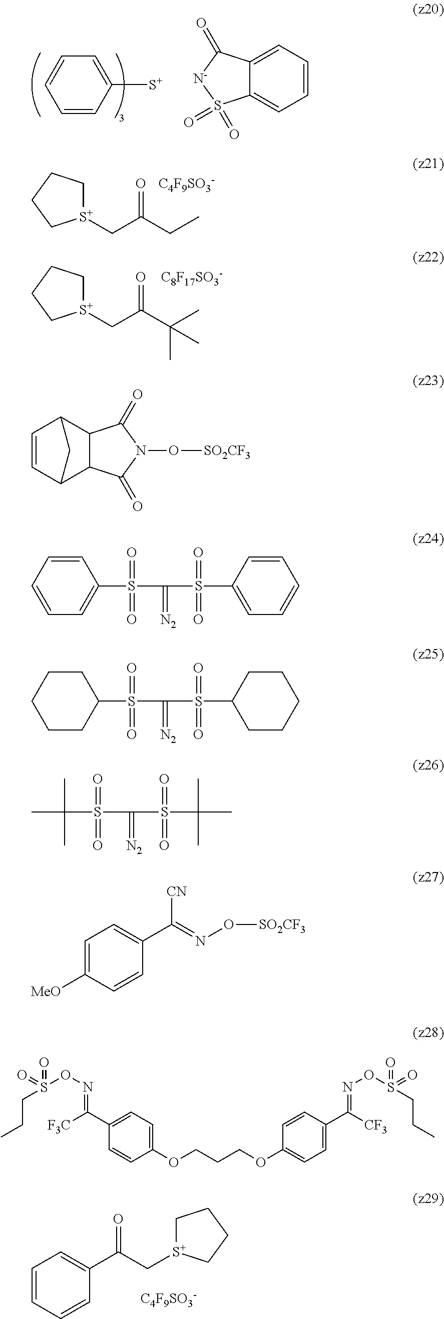

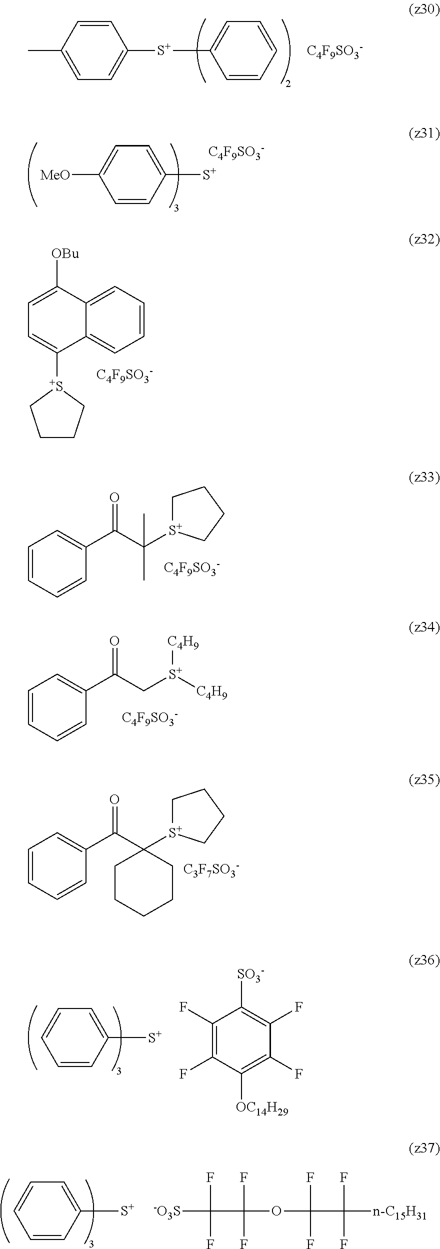

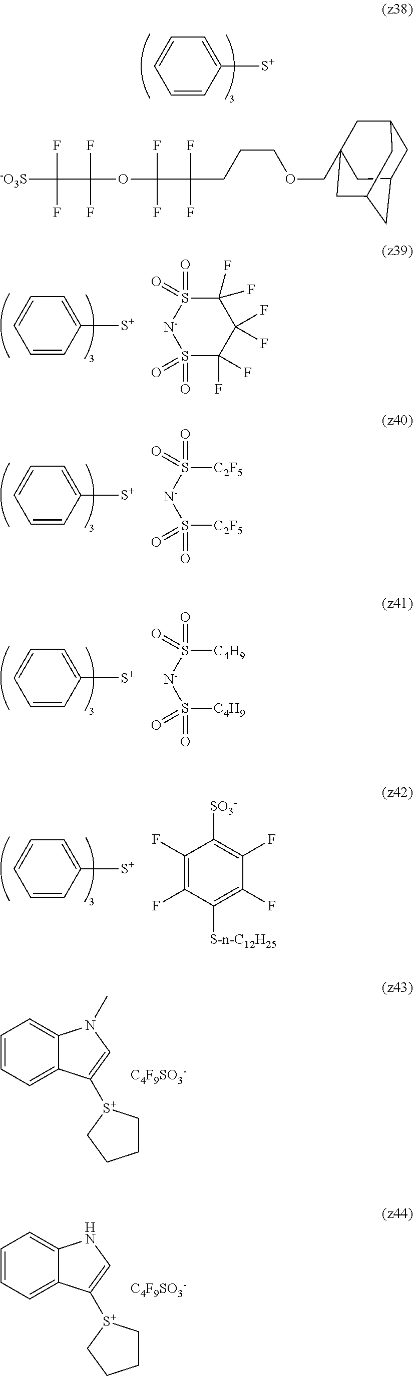

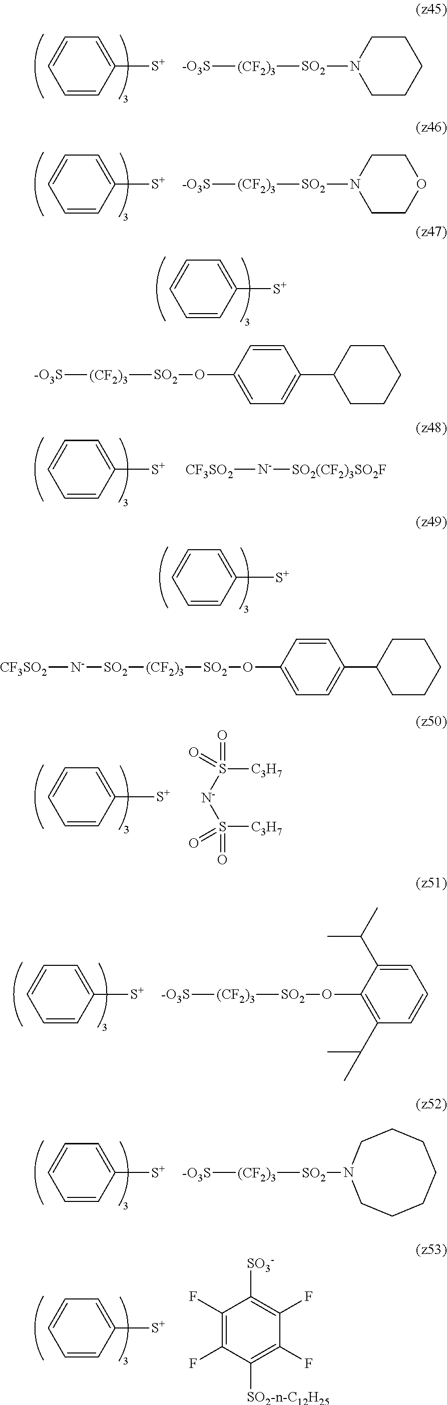

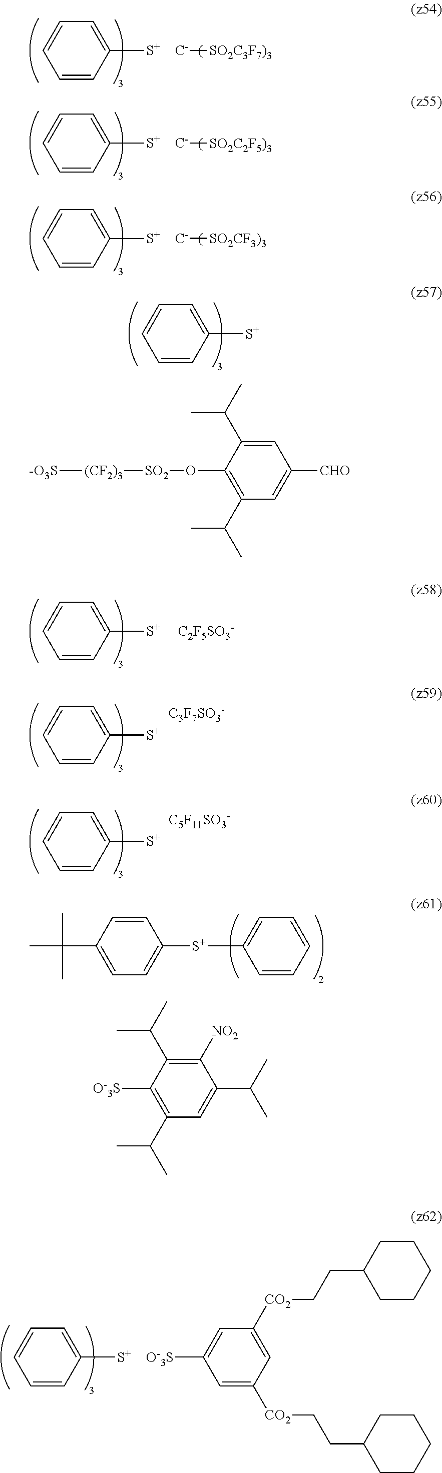

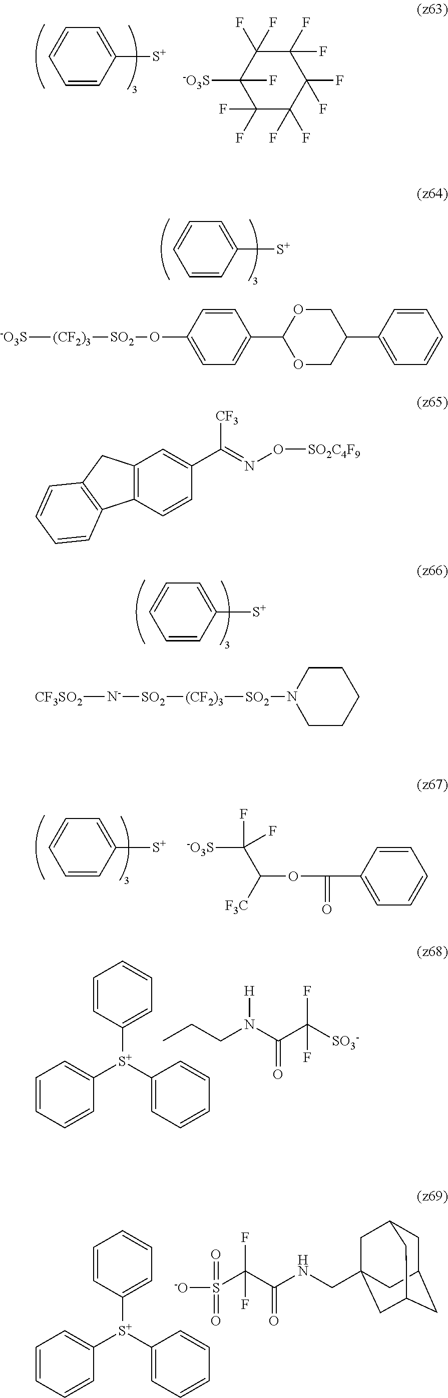

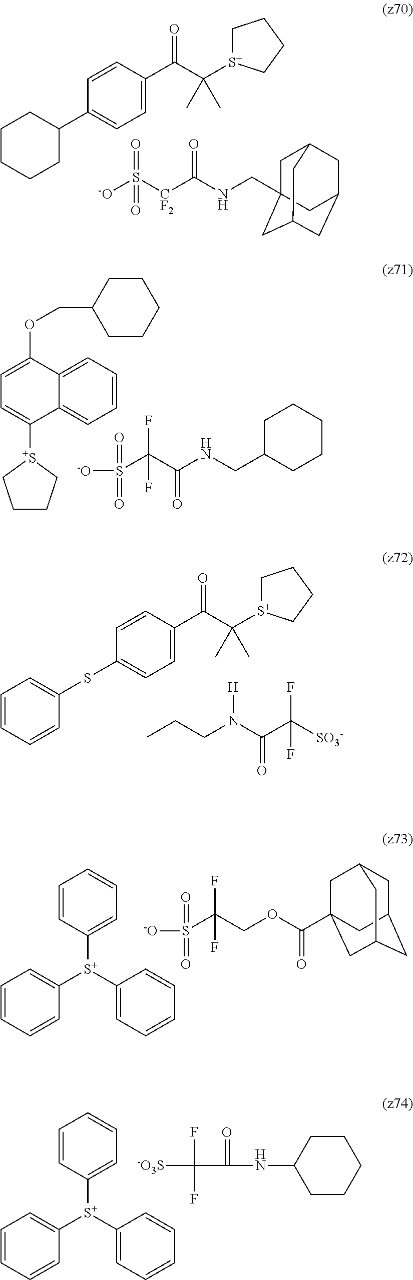

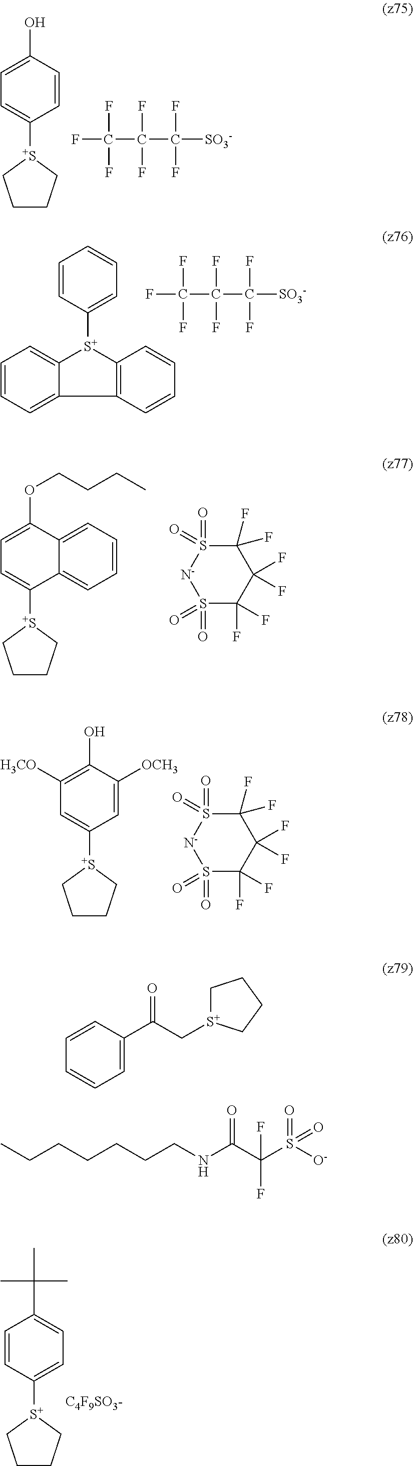

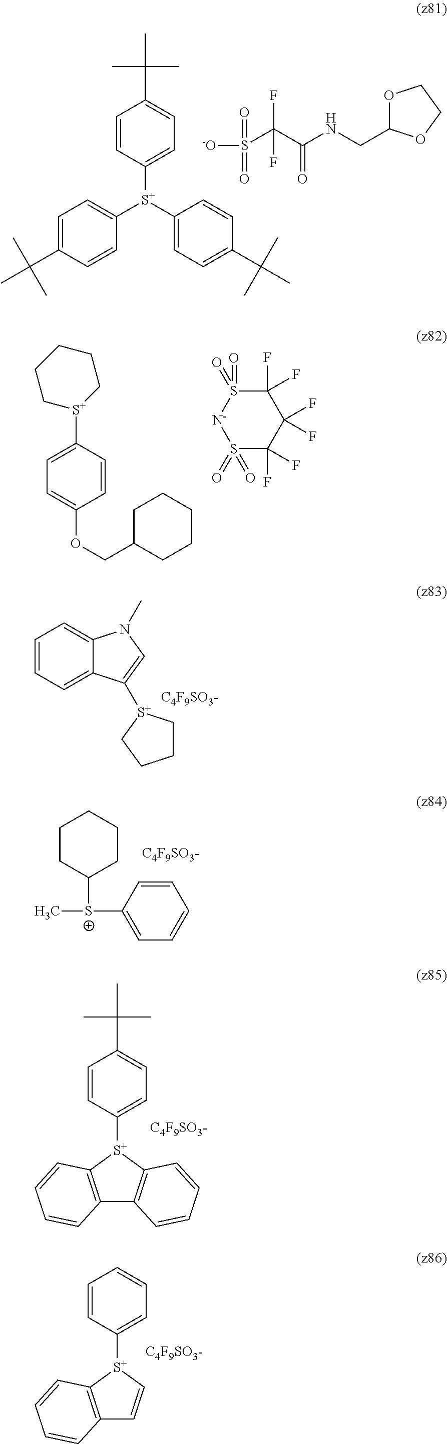

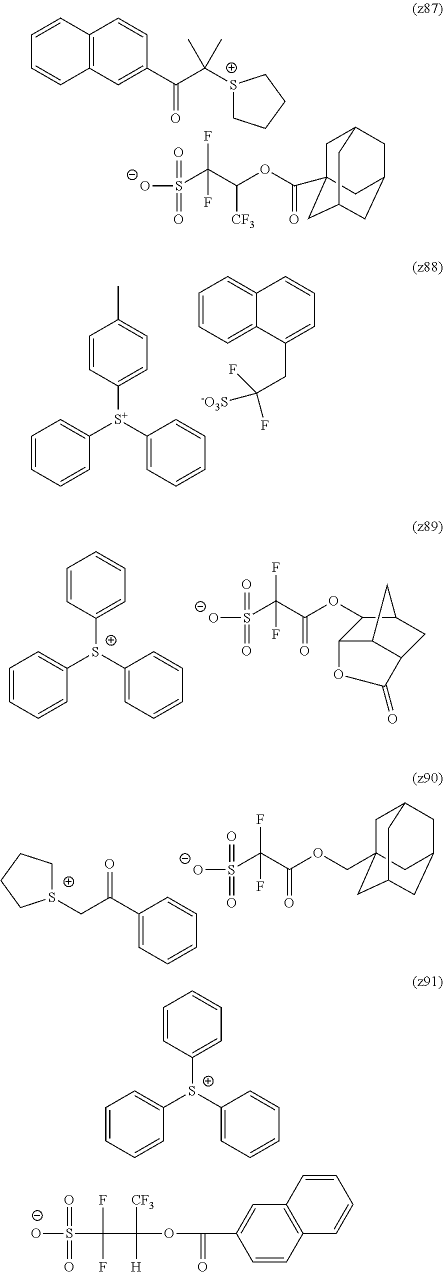

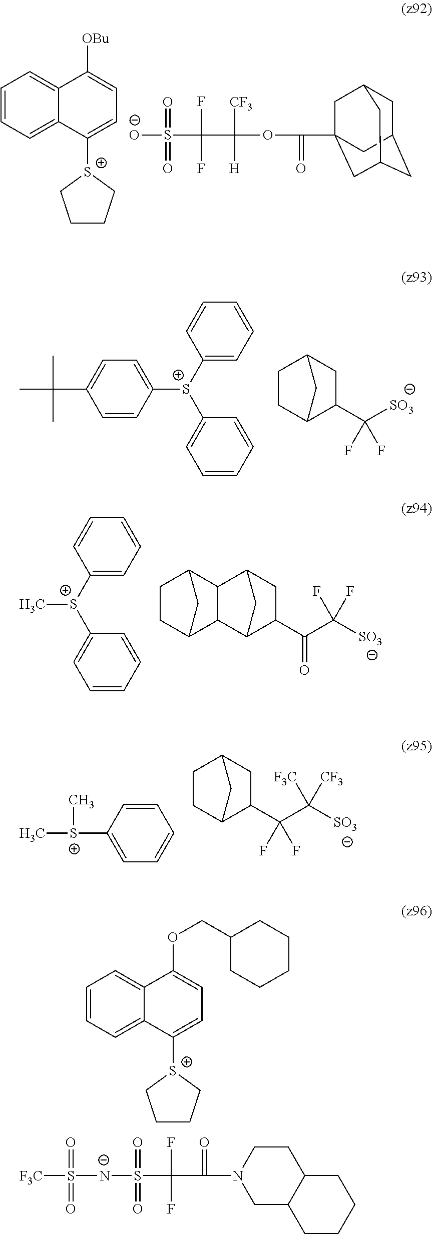

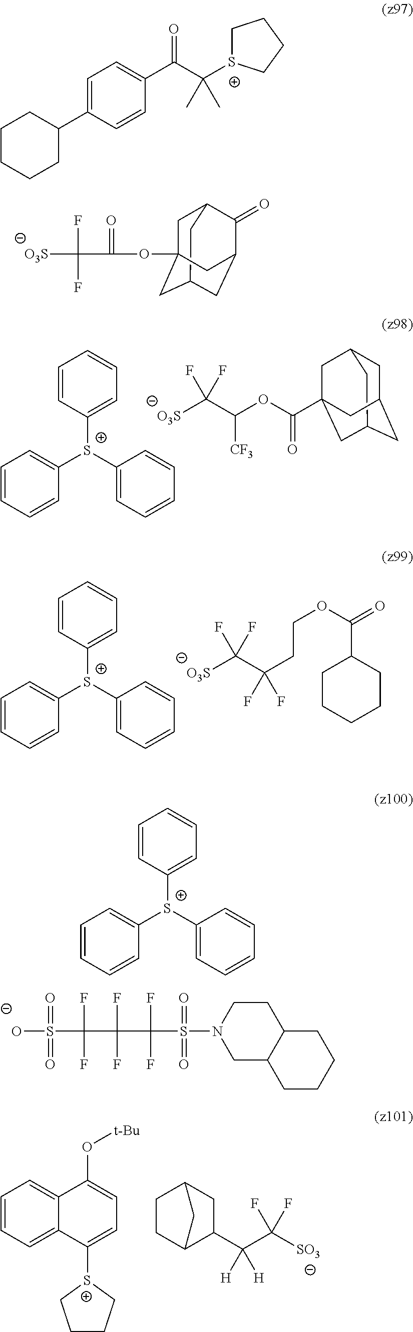

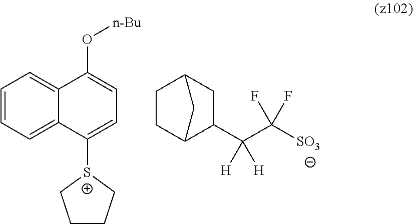

The acid generator can be synthesized by a known method, for example, can be synthesized in accordance with the method described in JP-A-2007-161707.

As for the acid generator, one kind may be used alone, or two or more kinds may be used in combination.

The content of the compound capable of generating an acid upon irradiation with an actinic ray or radiation in the composition is preferably from 0.1 to 30 mass %, more preferably from 0.5 to 25 mass %, still more preferably from 3 to 20 mass %, yet still more preferably from 3 to 15 mass %, based on the entire solid content of the chemical amplification resist composition.

In the case where the acid generator is represented by formula (ZI-3) or (ZI-4), the content thereof is preferably from 5 to 35 mass %, more preferably from 8 to 30 mass %, still more preferably from 9 to 30 mass %, yet still more preferably from 9 to 25 mass %, based on the entire solid content of the composition.

[3-1] (C) Basic Compound or Ammonium Salt Compound Whose Basicity Decreases Upon Irradiation with an Actinic Ray or Radiation

The chemical amplification resist composition for use in the present invention preferably contains a basic compound or ammonium salt compound whose basicity decreases upon irradiation with an actinic ray or radiation (hereinafter, sometimes referred to as a “compound (C)”).

The compound (C) is preferably (C-1) a compound having a basic functional group or an ammonium group and a group capable of generating an acidic functional group upon irradiation with an actinic ray or radiation. That is, the compound (C) is preferably a basic compound having a basic functional group and a group capable of generating an acidic functional group upon irradiation with an actinic ray or radiation, or an ammonium salt compound having an ammonium group and a group capable of generating an acidic functional group upon irradiation with an actinic ray or radiation.

The compound which is generated due to decomposition of the compound (C) or (C-1) upon irradiation with an actinic ray or radiation and decreased in the basicity includes compounds represented by the following formulae (PA-I), (PA-II) and (PA-III), and from the standpoint that excellent effects can be attained at a high level in terms of all of LWR, uniformity of local pattern dimension and DOF, compounds represented by formulae (PA-II) and (PA-III) are preferred.

The compound represented by formula (PA-I) is described below.

Q-A₁-(Xₙ—B—R (PA-I)

In formula (PA-I), A₁ represents a single bond or a divalent linking group.

Q represents —SO₃H or —CO₂H. Q corresponds to an acidic functional group that is generated upon irradiation with an actinic ray or radiation.

X represents —SO₂— or —CO—.

n represents 0 or 1.

B represents a single bond, an oxygen atom or —N(Rx)-.

Rx represents a hydrogen atom or a monovalent organic group.

R represents a monovalent organic group having a basic functional group, or a monovalent organic group having an ammonium group.

The divalent linking group in A₁ is preferably a divalent linking group having a carbon number of 2 to 12, and examples thereof include an alkylene group and a phenylene group. An alkylene group having at least one fluorine atom is more preferred, and the carbon number thereof is preferably from 2 to 6, more preferably from 2 to 4. The alkylene chain may contain a linking group such as oxygen atom and sulfur atom. The alkylene group is preferably an alkylene group where from 30 to 100% by number of hydrogen atoms are substituted for by a fluorine atom, more preferably an alkylene group where the carbon atom bonded to the Q moiety has a fluorine atom, still more preferably a perfluoroalkylene group, yet still more preferably a perfluoroethylene group, a perfluoropropylene group or a perfluorobutylene group.

The monovalent organic group in Rx is preferably a monovalent organic group having a carbon number of 4 to 30, and examples thereof include an alkyl group, a cycloalkyl group, an aryl group, an aralkyl group, and an alkenyl group.

The alkyl group in Rx may have a substituent and is preferably a linear or branched alkyl group having a carbon number of 1 to 20, and the alkyl chain may contain an oxygen atom, a sulfur atom or a nitrogen atom.

Incidentally, the alkyl group having a substituent particularly includes a group where a cycloalkyl group is substituted on a linear or branched alkyl group (for example, an adamantylmethyl group, an adamantylethyl group, a cyclohexylethyl group and a camphor residue).

The cycloalkyl group in Rx may have a substituent and is preferably a cycloalkyl group having a carbon number of 3 to 20, and the cycloalkyl group may contain an oxygen atom in the ring.

The aryl group in Rx may have a substituent and is preferably an aryl group having a carbon number of 6 to 14.

The aralkyl group in Rx may have a substituent and is preferably an aralkyl group having a carbon number of 7 to 20.

The alkenyl group in Rx may have a substituent and includes, for example, a group having a double bond at an arbitrary position of the alkyl group described as Rx.

Preferred examples of the partial structure of the basic functional group include a crown ether structure, a primary to tertiary amine structure, and a nitrogen-containing heterocyclic structure (e.g., a pyridine, an imidazole, a pyrazine).

Preferred examples of the partial structure of the ammonium group include a primary to tertiary ammonium structure, a pyridinium structure, an imidazolinium structure, and a pyrazinium structure.

The basic functional group is preferably a functional group having a nitrogen atom, more preferably a structure having a primary to tertiary amino group, or a nitrogen-containing heterocyclic structure. In these structures, from the standpoint of enhancing the basicity, it is preferred that all atoms adjacent to nitrogen atom contained in the structure are a carbon atom or a hydrogen atom. Also, in view of enhancing the basicity, an electron-withdrawing functional group (such as a carbonyl group, a sulfonyl group, a cyano group and a halogen atom) is preferably not bonded directly to the nitrogen atom.

The monovalent organic group in the monovalent organic group (group R) containing such a structure is preferably an organic group having a carbon number of 4 to 30, and examples thereof include an alkyl group, a cycloalkyl group, an aryl group, an aralkyl group, and an alkenyl group. Each of these groups may have a substituent.

The alkyl group, cycloalkyl group, aryl group, aralkyl group and alkenyl group in the basic functional group- or ammonium group-containing alkyl, cycloalkyl, aryl, aralkyl and alkenyl groups of R are the same as the alkyl group, cycloalkyl group, aryl group, aralkyl group and alkenyl group described for Rx.

Examples of the substituent which each of the groups above may have include a halogen atom, a hydroxyl group, a nitro group, a cyano group, a carboxy group, a carbonyl group, a cycloalkyl group (preferably having a carbon number of 3 to 10), an aryl group (preferably having a carbon number of 6 to 14), an alkoxy group (preferably having a carbon number of 1 to 10), an acyl group (preferably having a carbon number of 2 to 20), an acyloxy group (preferably having a carbon number of 2 to 10), an alkoxycarbonyl group (preferably having a carbon number of 2 to 20), and an aminoacyl group (preferably having a carbon number of 2 to 20). The cyclic structure in the aryl group, cycloalkyl group and the like may further have an alkyl group (preferably having a carbon number of 1 to 20) as the substituent. The aminoacyl group may further have one or two alkyl groups (preferably having a carbon number of 1 to 20) as the substituent.

In the case where B is —N(Rx)-, R and Rx preferably combine together to form a ring. By virtue of forming a ring structure, the stability is enhanced and the composition using this compound is also enhanced in the storage stability. The number of carbons constituting the ring is preferably from 4 to 20, and the ring may be monocyclic or polycyclic and may contain an oxygen atom, a sulfur atom or a nitrogen atom.

Examples of the monocyclic structure include a 4- to 8-membered ring containing a nitrogen atom. Examples of the polycyclic structure include a structure composed of a combination of two monocyclic structures or three or more monocyclic structures. The mono cyclic structure and polycyclic structure may have a substituent, and preferred examples of the substituent include a halogen atom, a hydroxyl group, a cyano group, a carboxy group, a carbonyl group, a cycloalkyl group (preferably having a carbon number of 3 to 10), an aryl group (preferably having a carbon number of 6 to 14), an alkoxy group (preferably having a carbon number of 1 to 10), an acyl group (preferably having a carbon number of 2 to 15), an acyloxy group (preferably having a carbon number of 2 to 15), an alkoxycarbonyl group (preferably having a carbon number of 2 to 15), and an aminoacyl group (preferably having a carbon number of 2 to 20). The cyclic structure in the aryl group, cycloalkyl group and the like may further have an alkyl group (preferably having a carbon number of 1 to 15) as the substituent. The aminoacyl group may have one or two alkyl groups (preferably having a carbon number of 1 to 15) as the substituent.

Out of the compounds represented by formula (PA-I), a compound where the Q moiety is a sulfonic acid can be synthesized using a general sulfonamidation reaction. For example, this compound can be obtained by a method of selectively reacting one sulfonyl halide moiety of a bis-sulfonyl halide compound with an amine compound to form a sulfonamide bond and then hydrolyzing the other sulfonyl halide moiety, or a method of ring-opening a cyclic sulfonic anhydride through reaction with an amine compound.

The compound represented by formula (PA-II) is described below.

Q₁-X₁—NH—X₂-Q₂ (PA-II)

In formula (PA-II), each of Q₁ and Q₂ independently represents a monovalent organic group, provided that either one of Q₁ and Q₂ has a basic functional group. It is also possible that Q₁ and Q₂ combine together to form a ring and the ring formed has a basic functional group.

Each of X₁ and X₂ independently represents —CO— or —SO₂—.

Here, —NH— corresponds to the acidic functional group generated upon irradiation with an actinic ray or radiation.

The monovalent organic group as Q₁ and Q₂ in formula (PA-II) is preferably a monovalent organic group having a carbon number of 1 to 40, and examples thereof include an alkyl group, a cycloalkyl group, an aryl group, an aralkyl group, and an alkenyl group.

The alkyl group in Q₁ and Q₂ may have a substituent and is preferably a linear or branched alkyl group having a carbon number of 1 to 30, and the alkyl chain may contain an oxygen atom, a sulfur atom or a nitrogen atom.

The cycloalkyl group in Q₁ and Q₂ may have a substituent and is preferably a cycloalkyl group having a carbon number of 3 to 20, and the cycloalkyl group may contain an oxygen atom or a nitrogen atom in the ring.

The aryl group in Q₁ and Q₂ may have a substituent and is preferably an aryl group having a carbon number of 6 to 14.

The aralkyl group in Q₁ and Q₂ may have a substituent and is preferably an aralkyl group having a carbon number of 7 to 20.

The alkenyl group in Q₁ and Q₂ may have a substituent and includes a group having a double bond at an arbitrary position of the alkyl group above.

Examples of the substituent which each of these groups may have include a halogen atom, a hydroxyl group, a nitro group, a cyano group, a carboxy group, a carbonyl group, a cycloalkyl group (preferably having a carbon number of 3 to 10), an aryl group (preferably having a carbon number of 6 to 14), an alkoxy group (preferably having a carbon number of 1 to 10), an acyl group (preferably having a carbon number of 2 to 20), an acyloxy group (preferably having a carbon number of 2 to 10), an alkoxycarbonyl group (preferably having a carbon number of 2 to 20), and an amino acyl group (preferably having a carbon number of 2 to 10). The cyclic structure in the aryl group, cycloalkyl group and the like may further have an alkyl group (preferably having a carbon number of 1 to 10) as the substituent. The aminoacyl group may further have an alkyl group (preferably having a carbon number of 1 to 10) as the substituent. The alkyl group having a substituent includes, for example, a perfluoroalkyl group such as a perfluoromethyl group, a perfluoroethyl group, a perfluoropropyl group and a perfluorobutyl group.

Preferred partial structures of the basic functional group contained in at least either Q₁ or Q₂ are the same as those of the basic functional group contained in R of formula (PA-I).

The structure where Q₁ and Q₂ combine together to form a ring and the ring formed has a basic functional group includes, for example, a structure where the organic groups of Q₁ and Q₂ are bonded further through an alkylene group, an oxy group, an imino group or the like.

In formula (PA-II), at least either one of X₁ and X₂ is preferably —SO₂—.

The compound represented by formula (PA-III) is described below.

Q₁-X₁—NH—X₂-A₂-(X₃)ₘ—B-Q₃ (PA-III)

In formula (PA-III), each of Q₁ and Q₃ independently represents a monovalent organic group, provided that either one of Q₁ and Q₃ has a basic functional group. It is also possible that Q₁ and Q₃ combine together to form a ring and the ring formed has a basic functional group.

Each of X₁, X₂ and X₃ independently represents —CO— or —SO₂—.

A₂ represents a divalent linking group.

B represents a single bond, an oxygen atom, or —N(Qx)-.

Qx represents a hydrogen atom or a monovalent organic group.

In the case where B is —N(Qx)-, Q₃ and Qx may combine to form a ring.

m represents 0 or 1.

Here, —NH— corresponds to the acidic functional group generated upon irradiation with an actinic ray or radiation.

Q₁ has the same meaning as Q₁ in formula (PA-II).

Examples of the organic group of Q₃ are the same as those of the organic group of Q₁ and Q₂ in formula (PA-II).

The structure where Q₁ and Q₃ combine to form a ring and the ring formed has a basic functional group includes, for example, a structure where the organic groups of Q₁ and Q₃ are bonded further through an alkylene group, an oxy group, an imino group or the like.

The divalent linking group in A₂ is preferably a divalent linking group having a carbon number of 1 to 8 and containing a fluorine atom, and examples thereof include a fluorine atom-containing alkylene group having a carbon number of 1 to 8, and a fluorine atom-containing phenylene group. A fluorine atom-containing alkylene group is more preferred, and the carbon number thereof is preferably from 2 to 6, more preferably from 2 to 4. The alkylene chain may contain a linking group such as oxygen atom and sulfur atom. The alkylene group is preferably an alkylene group where from 30 to 100% by number of hydrogen atoms are substituted for by a fluorine atom, more preferably a perfluoroalkylene group, still more preferably a perfluoroalkylene group having a carbon number of 2 to 4.

The monovalent organic group in Qx is preferably an organic group having a carbon number of 4 to 30, and examples thereof include an alkyl group, a cycloalkyl group, an aryl group, an aralkyl group and an alkenyl group. Examples of the alkyl group, cycloalkyl group, aryl group, aralkyl group and alkenyl group are the same as those for Rx in formula (PA-I).

In formula (PA-III), each of X₁, X₂ and X₃ is preferably —SO₂—.

The compound (C) is preferably a sulfonium salt compound of the compound represented by formula (PA-I), (PA-II) or (PA-III), or an iodonium salt compound of the compound represented by formula (PA-I), (PA-II) or (PA-III), more preferably a compound represented by the following formula (PA1) or (PA2):

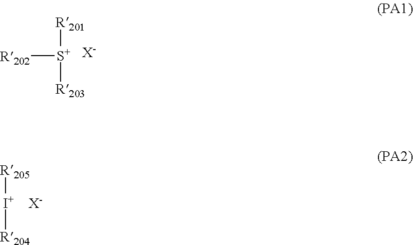

In formula (PA1), each of R′₂₀₁, R′₂₀₂ and R′₂₀₃ independently represents an organic group, and specific examples thereof are the same as those for R₂₀₁, R₂₀₂ and R₂₀₃ of formula Z1 in the component (B).

X⁻ represents a sulfonate or carboxylate anion resulting from elimination of a hydrogen atom in the —SO₃H moiety or —COOH moiety of the compound represented by formula (PA-I), or an anion resulting from elimination of a hydrogen atom in the —NH— moiety of the compound represented by formula (PA-II) or (PA-III).

In formula (PA2), each of R′₂₀₄ and R′₂₀₅ independently represents an aryl group, an alkyl group or a cycloalkyl group, and specific examples thereof are the same as those for R₂₀₄ and R₂₀₅ of formula ZII in the component (B).

X⁻ represents a sulfonate or carboxylate anion resulting from elimination of a hydrogen atom in the —SO₃H moiety or —COOH moiety of the compound represented by formula (PA-I), or an anion resulting from elimination of a hydrogen atom in the —NH— moiety of the compound represented by formula (PA-II) or (PA-III).

The compound (C) decomposes upon irradiation with an actinic ray or radiation to generate, for example, a compound represented by formula (PA-I), (PA-II) or (PA-III).

The compound represented by formula (PA-I) is a compound having a sulfonic or carboxylic acid group together with a basic functional group or an ammonium group and thereby being reduced in or deprived of the basicity or changed from basic to acidic as compared with the compound (C).

The compound represented by formula (PA-II) or (PA-III) is a compound having an organic sulfonylimino or organic carbonylimino group together with a basic functional group and thereby being reduced in or deprived of the basicity or changed from basic to acidic as compared with the compound (C).

In the present invention, the expression “reduced in the basicity upon irradiation with an actinic ray or radiation” means that the acceptor property for a proton (an acid generated upon irradiation with an actinic ray or radiation) of the compound (C) is decreased by the irradiation with an actinic ray or radiation. The expression “the acceptor property is decreased” means that when an equilibrium reaction of letting a noncovalent bond complex as a proton adduct be produced from a basic functional group-containing compound and a proton takes place or when an equilibrium reaction of letting the counter cation of the ammonium group-containing compound be exchanged with a proton takes place, the equilibrium constant in the chemical equilibrium decreases.

In this way, the compound (C) whose basicity decreases upon irradiation with an actinic ray or radiation is contained in the resist film, so that in the unexposed area, the acceptor property of the compound (C) can be sufficiently brought out and an unintended reaction between an acid diffused from the exposed area or the like and the resin (A) can be inhibited, whereas in the exposed area, the acceptor property of the compound (C) decreases and the intended reaction of an acid with the resin (A) unfailingly occurs. Such an operation mechanism is considered to contribute to obtaining a pattern excellent in terms of line width variation (LWR), uniformity of local pattern dimension, focus latitude (DOF) and pattern profile.

Incidentally, the basicity can be confirmed by measuring the pH, or a calculated value can be computed using a commercially available software.

Specific examples of the compound (C) capable of generating a compound represented by formula (PA-I) upon irradiation with an actinic ray or radiation are illustrated below, but the present invention is not limited thereto.

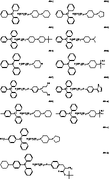

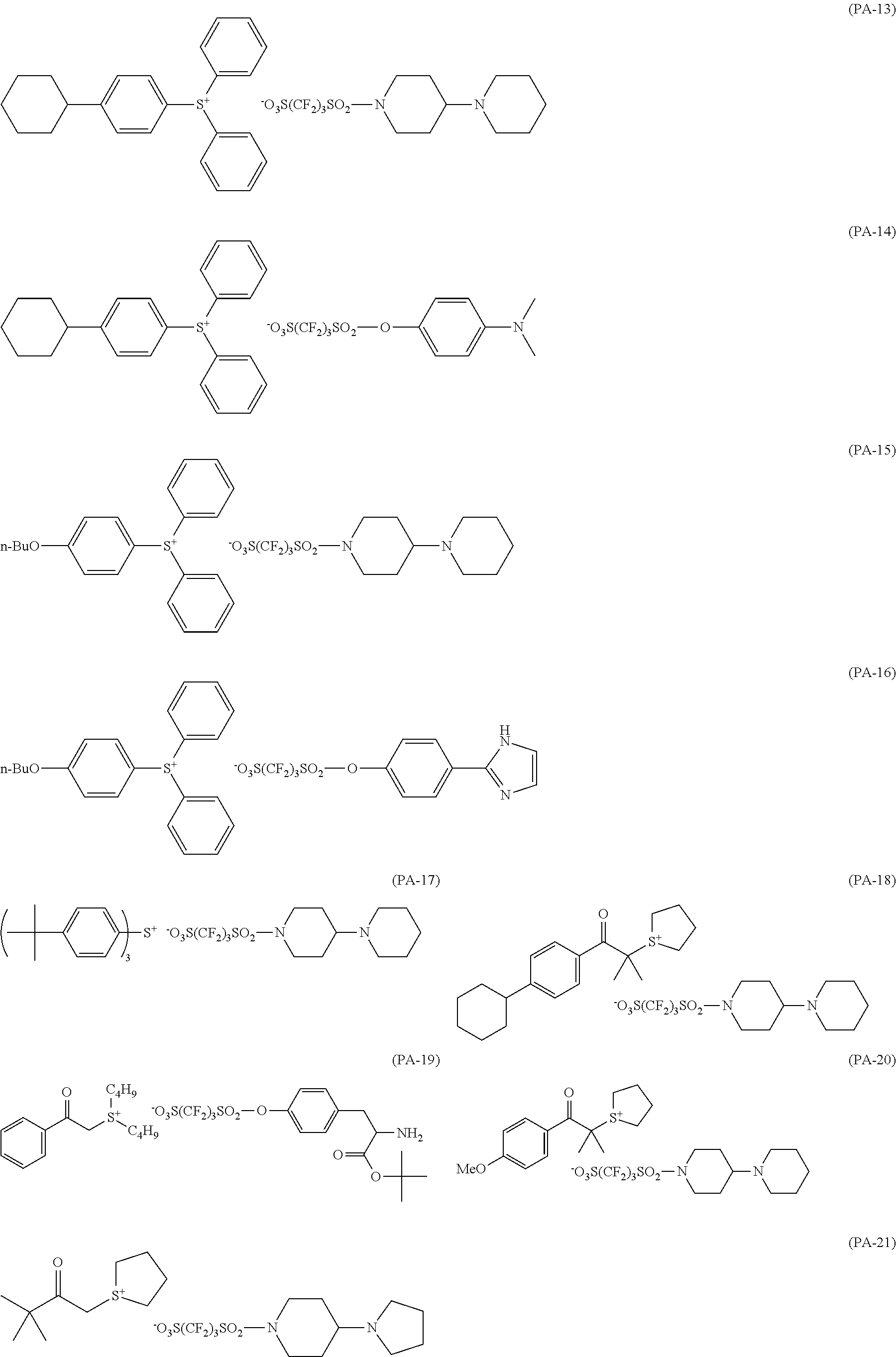

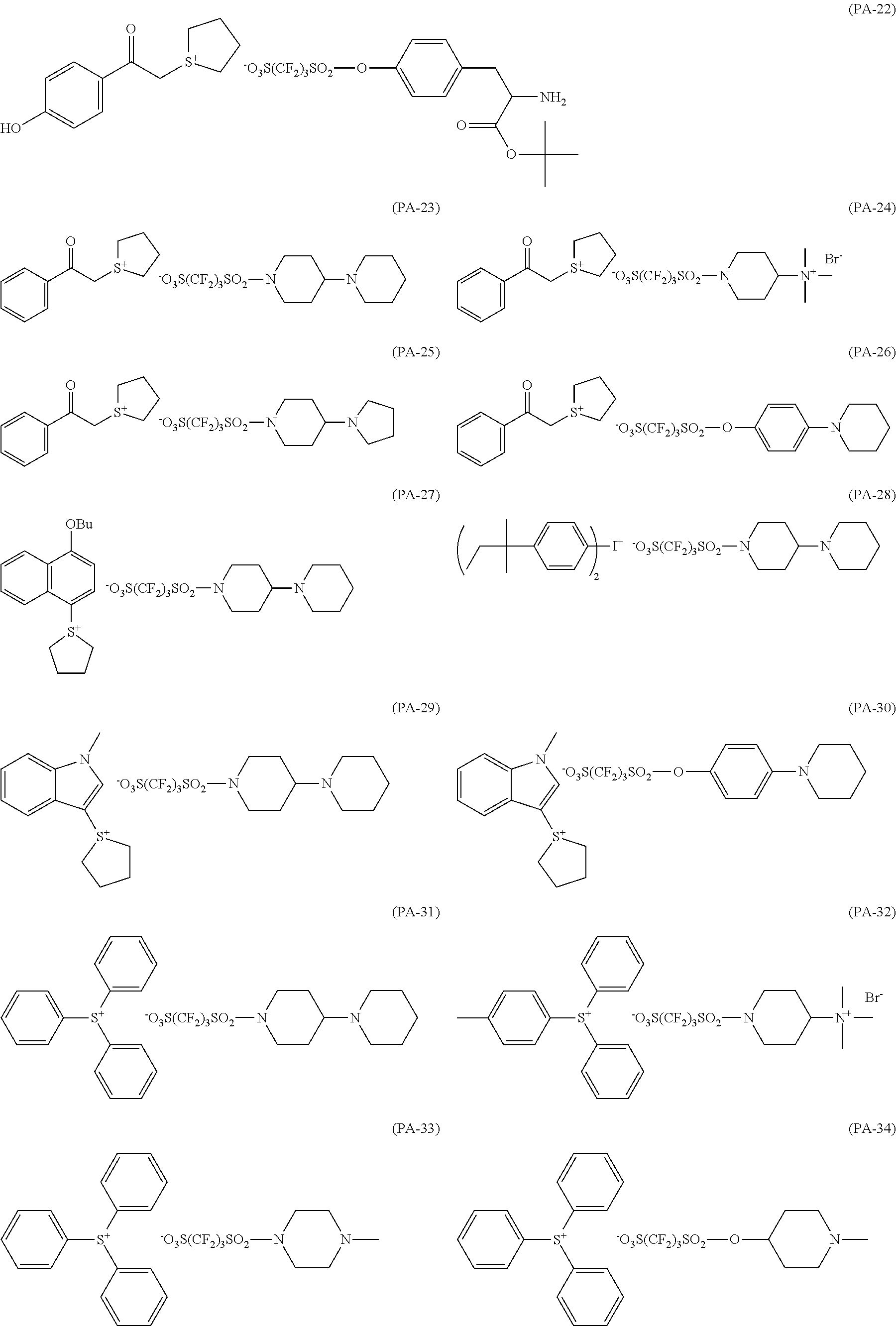

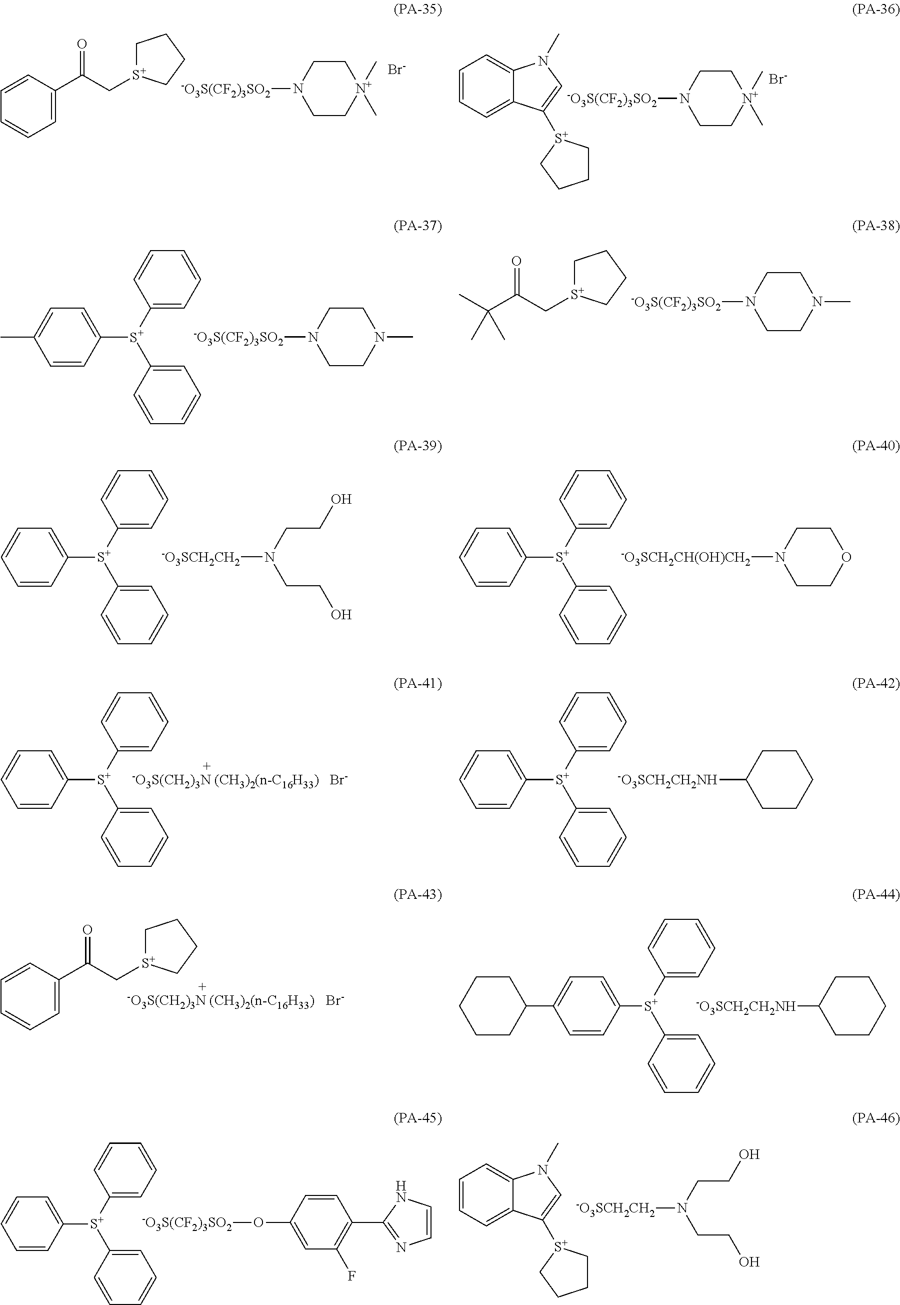

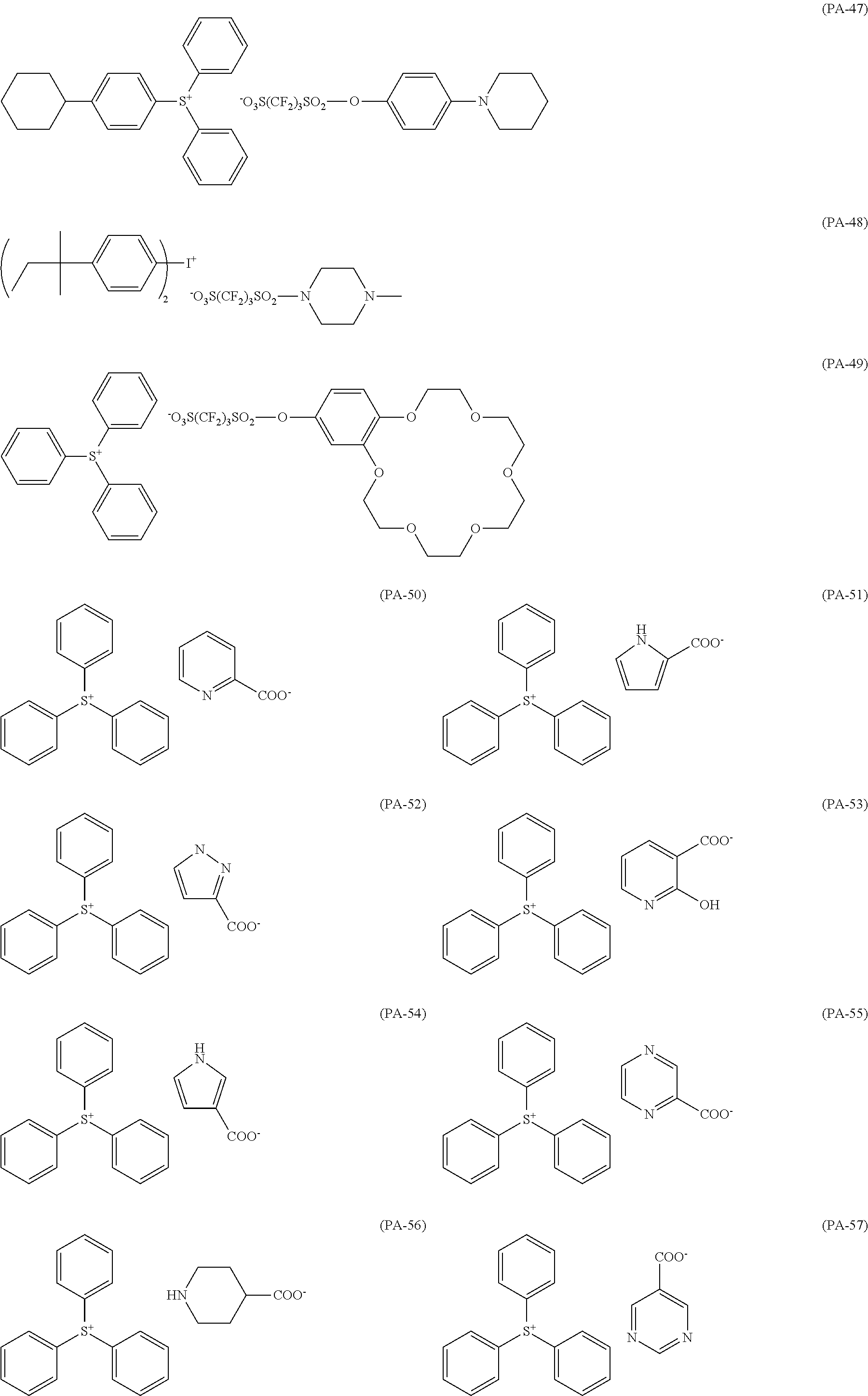

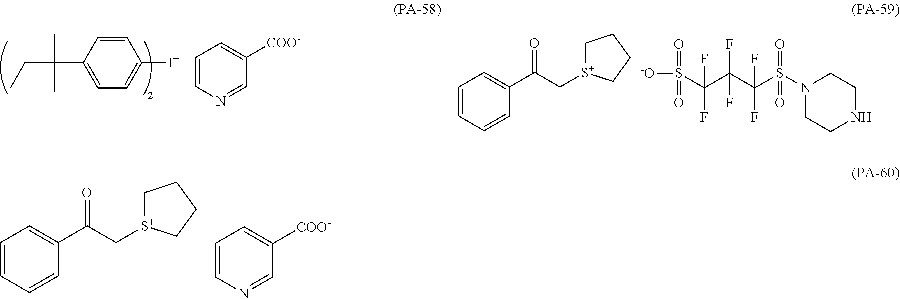

These compounds can be easily synthesized from a compound represented by formula (PA-I) or a lithium, sodium or potassium salt thereof and a hydroxide, bromide, chloride or the like of iodonium or sulfonium, by utilizing the salt exchange method described in JP-T-11-501909 (the term “JP-T” as used herein means a “published Japanese translation of a PCT patent application”) or JP-A-2003-246786. The synthesis may be also performed in accordance with the synthesis method described in JP-A-7-333851.

Specific examples of the compound (C) capable of generating a compound represented by formula (PA-II) or (PA-III) upon irradiation with an actinic ray or radiation are illustrated below, but the present invention is not limited thereto.

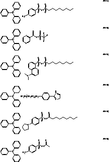

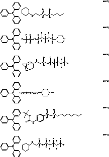

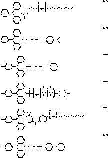

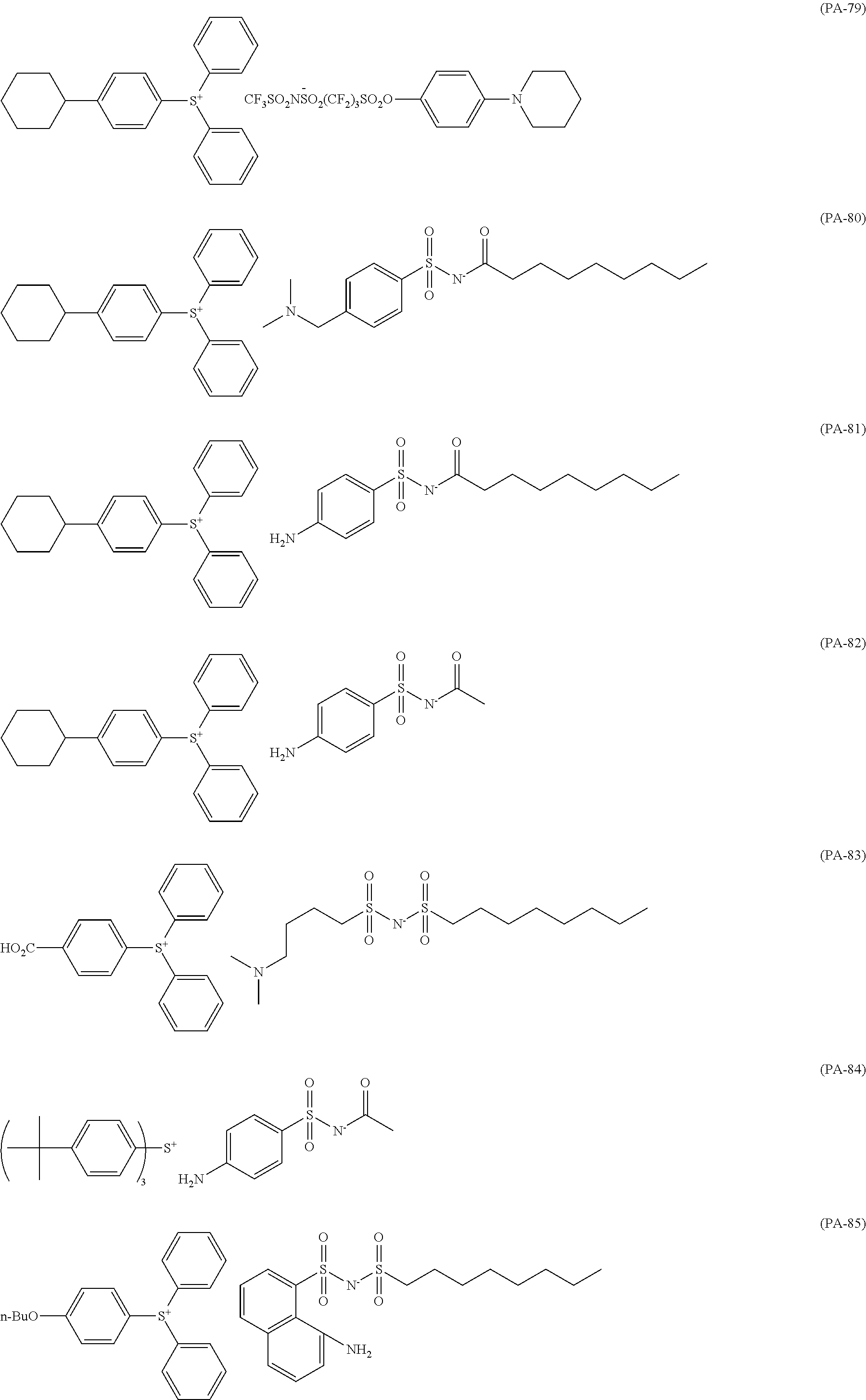

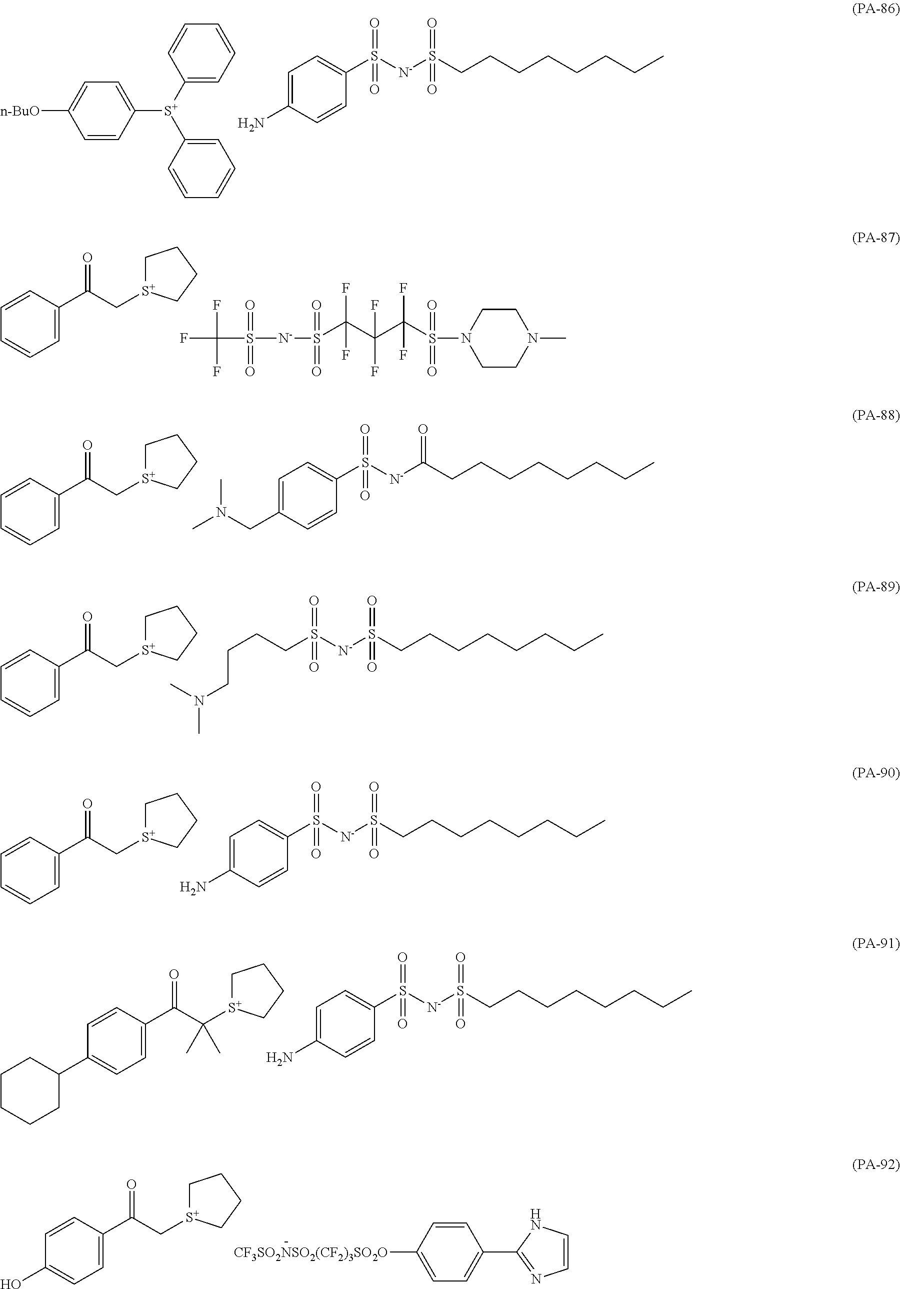

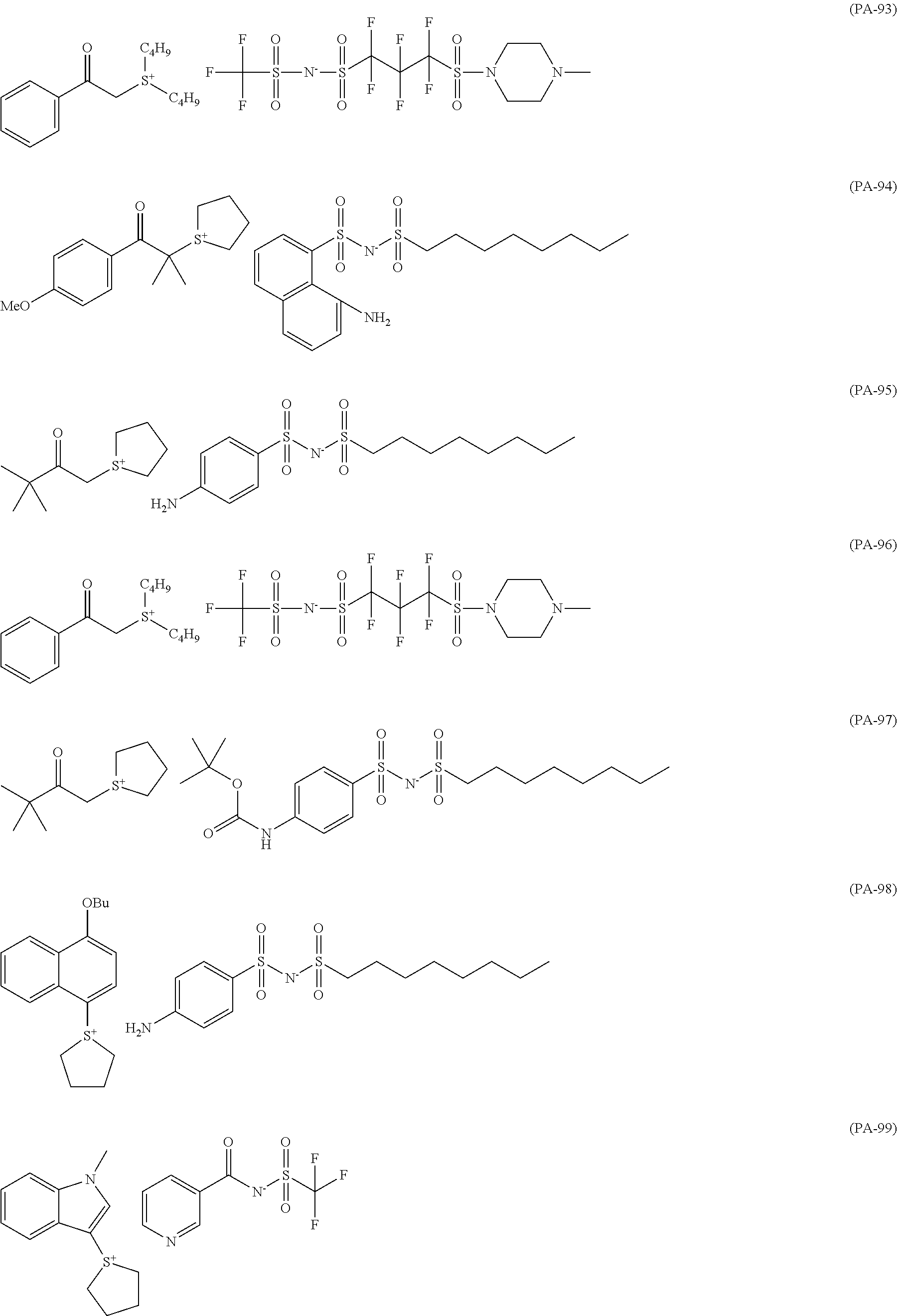

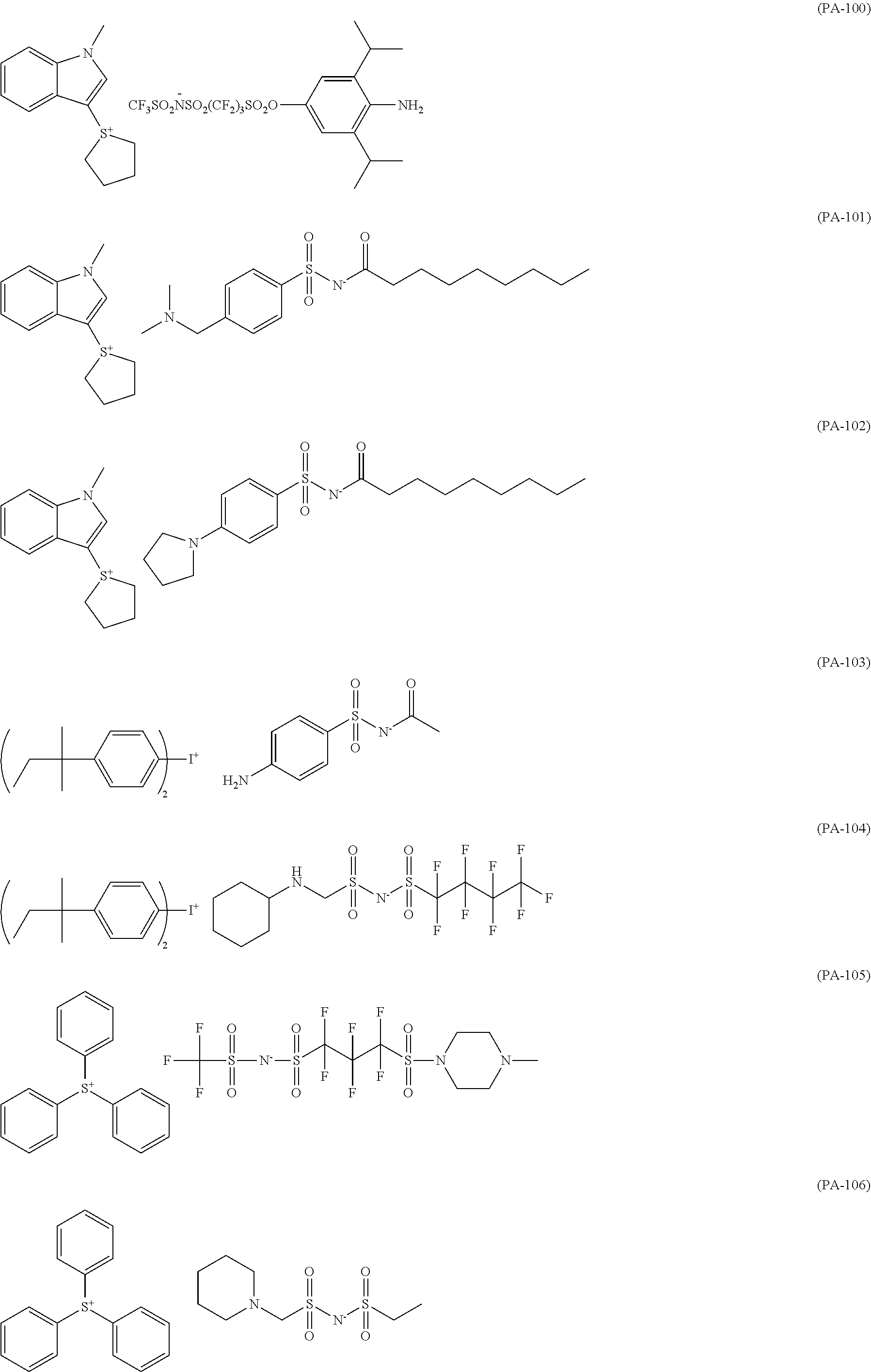

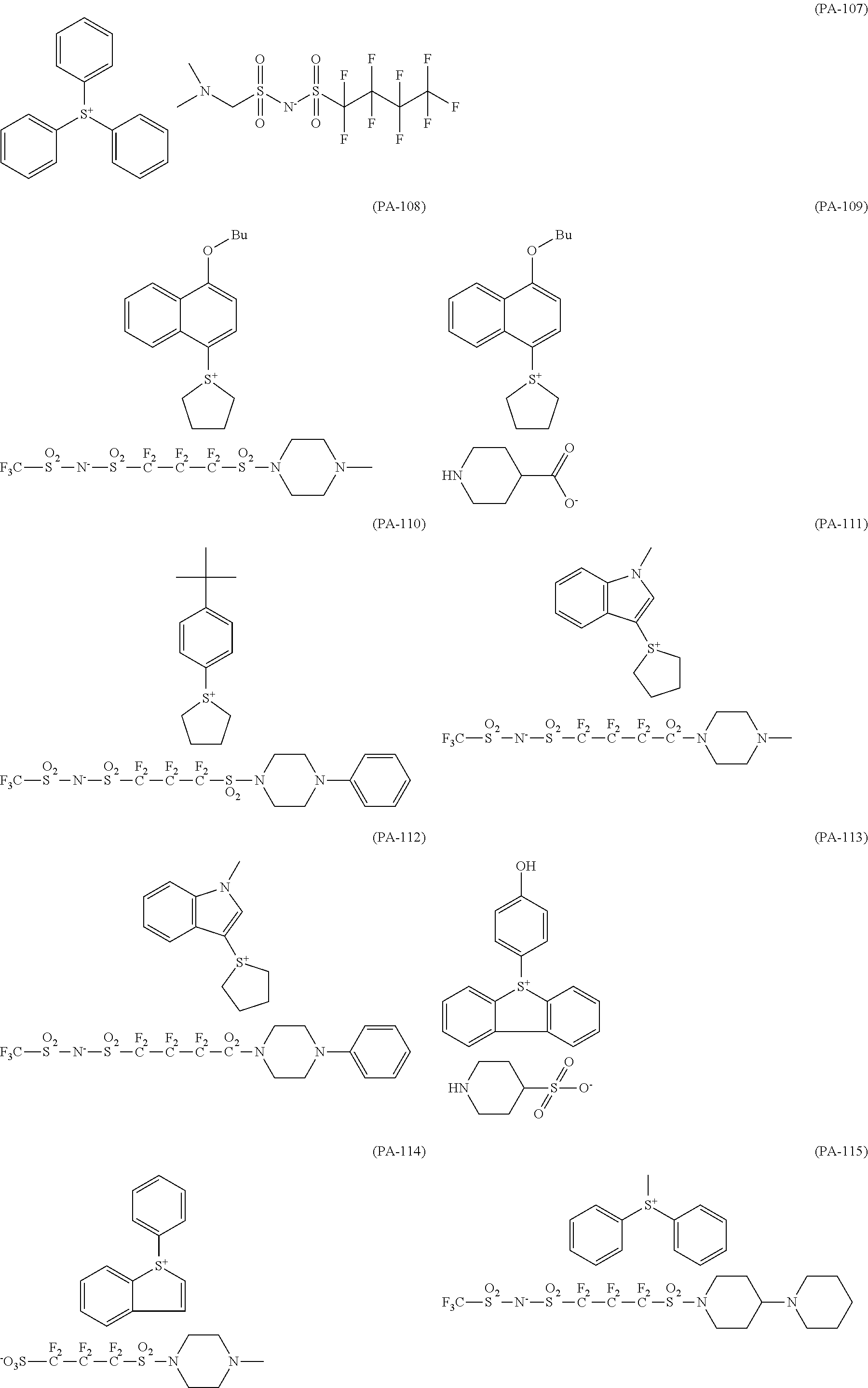

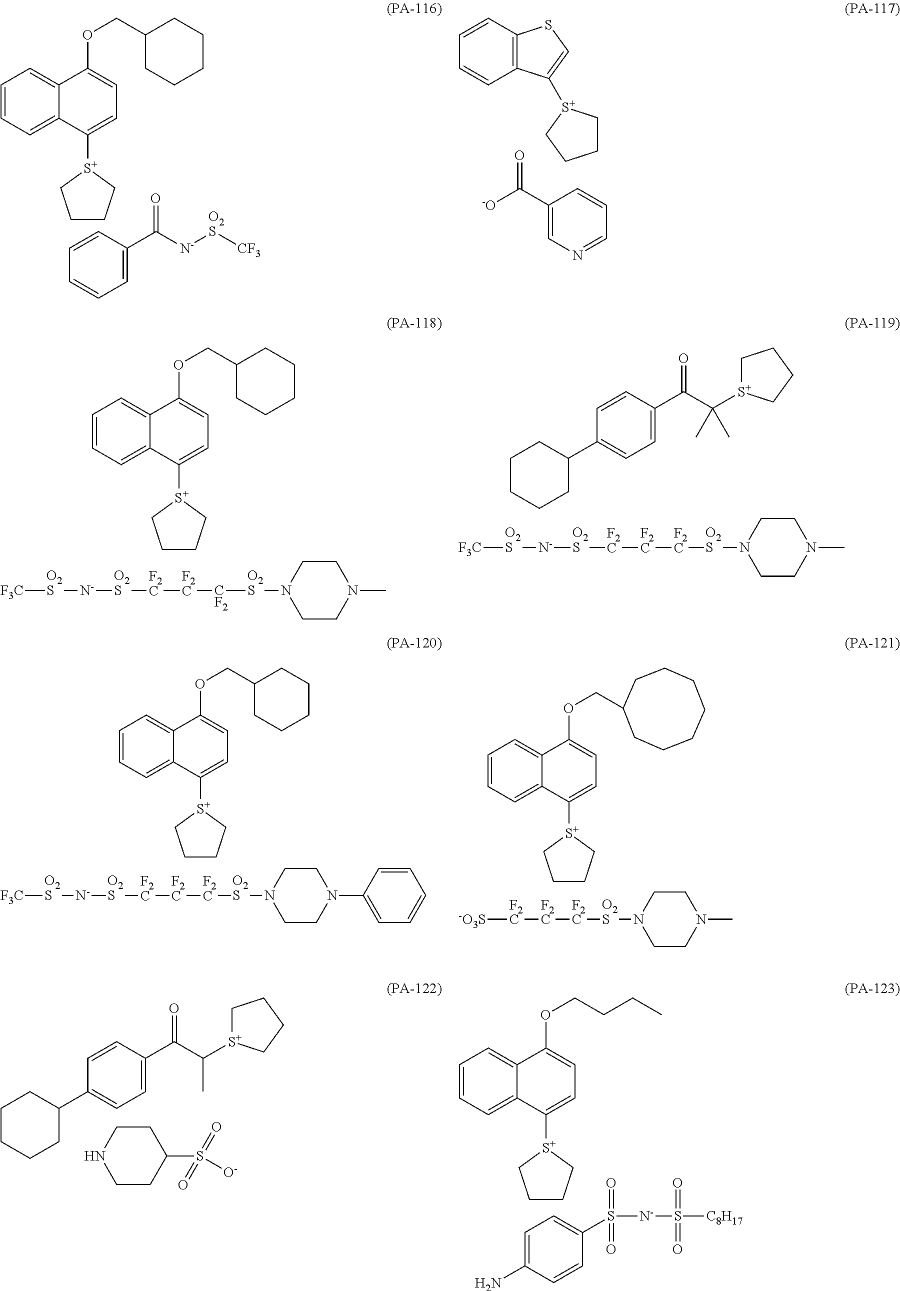

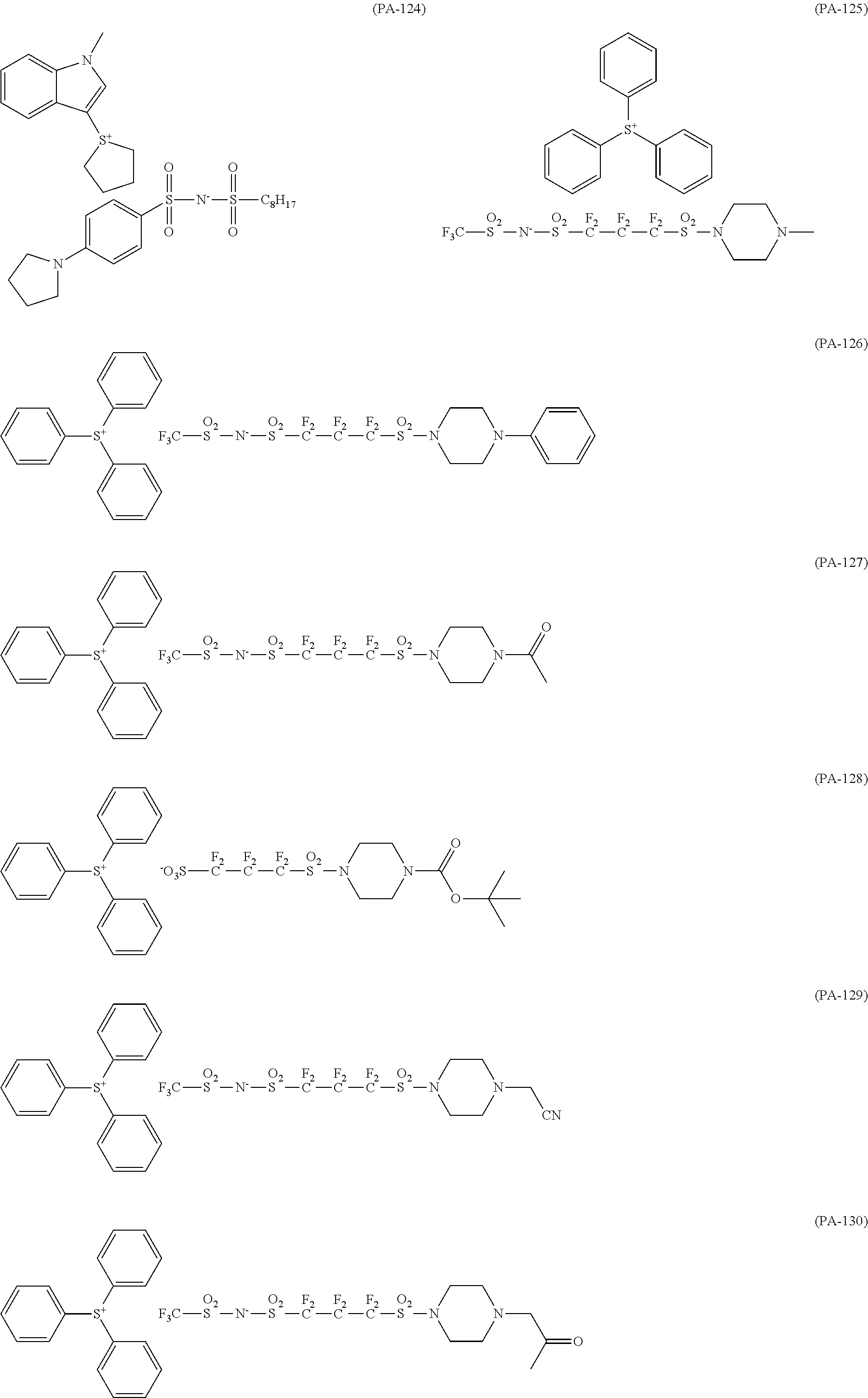

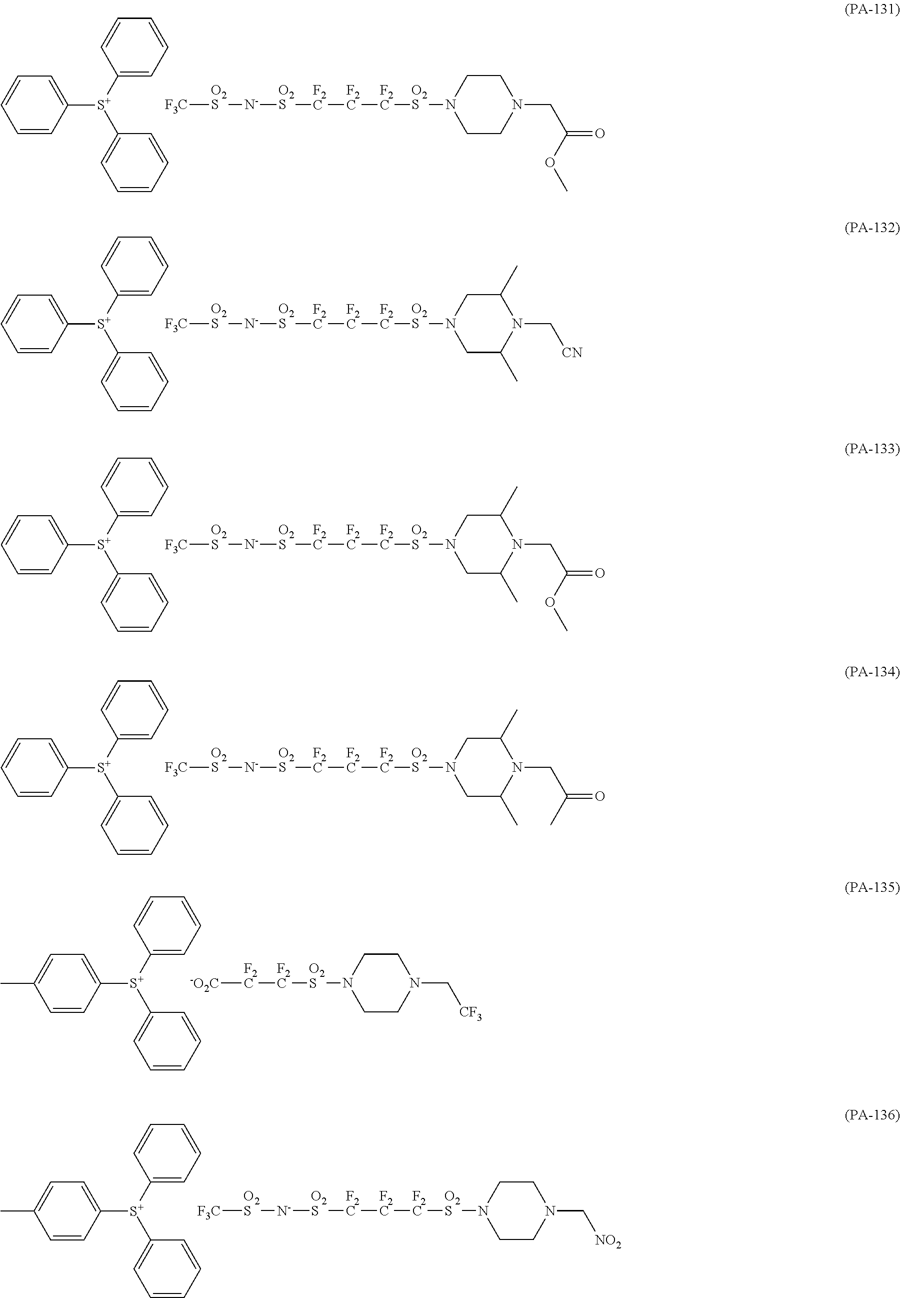

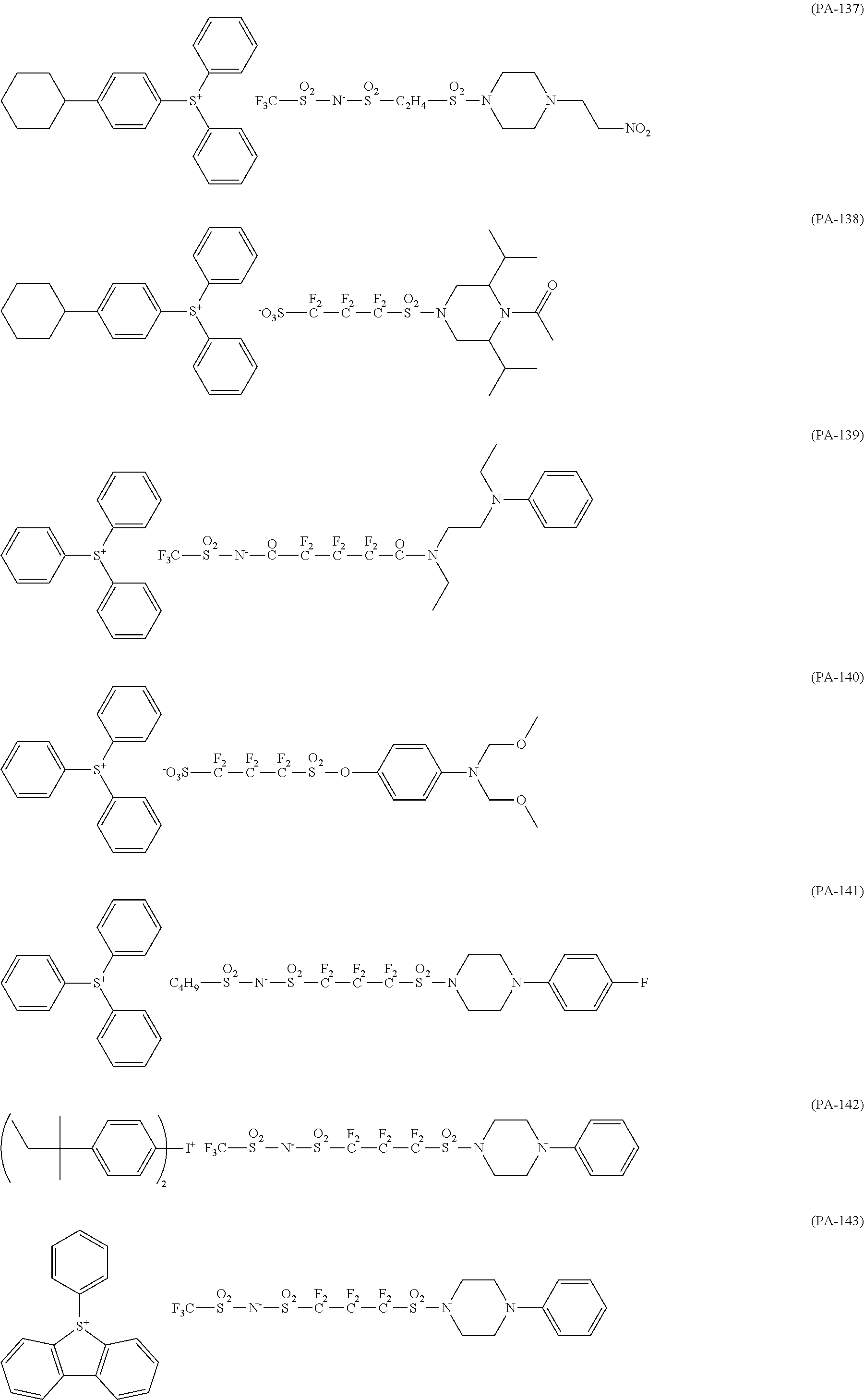

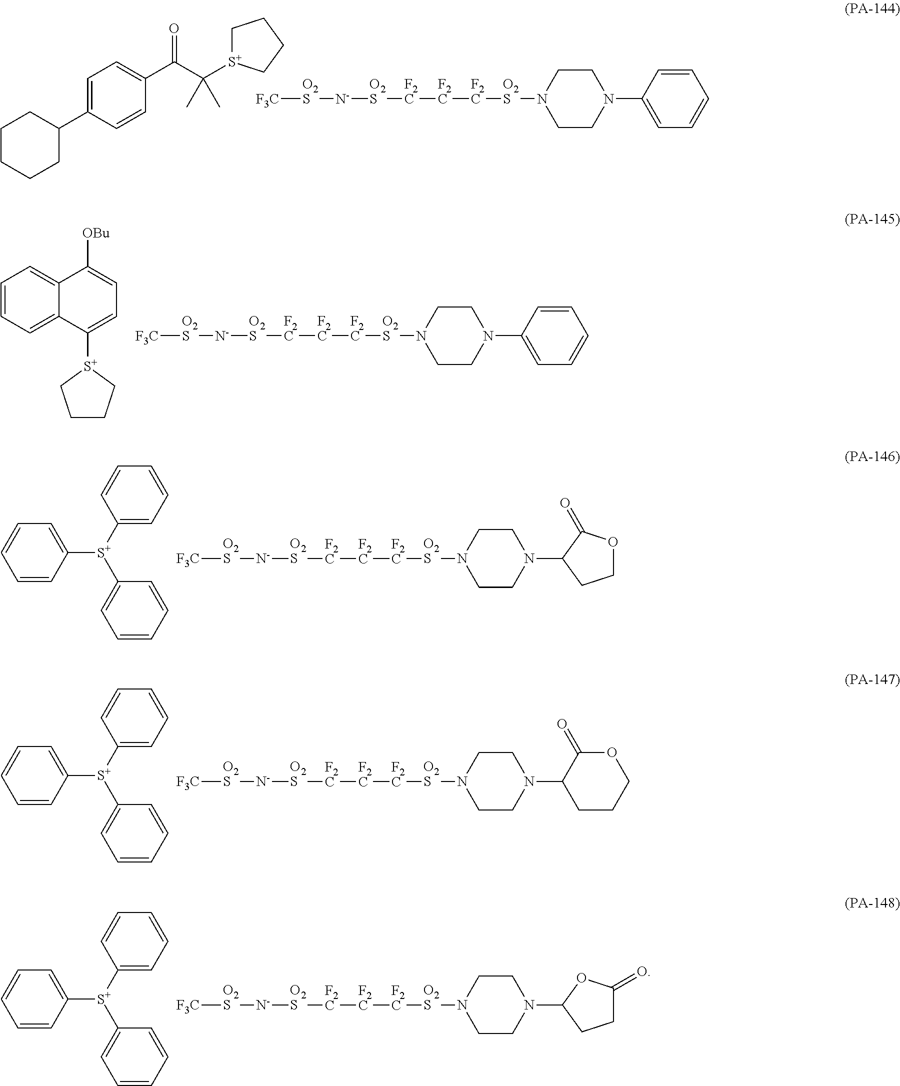

These compounds can be easily synthesized using a general sulfonic acid esterification reaction or sulfonamidation reaction. For example, the compound may be obtained by a method of selectively reacting one sulfonyl halide moiety of a bis-sulfonyl halide compound with an amine, alcohol or the like containing a partial structure represented by formula (PA-II) or (PA-III) to form a sulfonamide bond or a sulfonic acid ester bond and then hydrolyzing the other sulfonyl halide moiety, or a method of ring-opening a cyclic sulfonic anhydride by an amine or alcohol containing a partial structure represented by formula (PA-II). The amine or alcohol containing a partial structure represented by formula (PA-II) or (PA-III) can be synthesized by reacting an amine or an alcohol with an anhydride (e.g., (R′O₂C)₂O, (R′SO₂)₂O) or an acid chloride compound (e.g., R′O₂CCl, R′SO₂Cl) (R′ is, for example, a methyl group, an n-octyl group, or a trifluoromethyl group) under basic conditions.

In particular, the synthesis of the compound (C) may be performed in accordance with synthesis examples and the like in JP-A-2006-330098 and JP-A-2011-100105.

The molecular weight of the compound (C) is preferably from 500 to 1,000.

The chemical amplification resist composition for use in the present invention may or may not contain the compound (C), but in the case of containing the compound (C), the content thereof is preferably from 0.1 to 20 mass %, more preferably from 0.1 to 10 mass %, based on the solid content of the chemical amplification resist composition.

### [3-2] (C′) Basic Compound

The chemical amplification resist composition for use in the present invention may contain a basic compound (C′) so as to reduce the change in performance with aging from exposure to heating.

Preferred basic compounds include compounds having a structure represented by the following formulae (A) to (E):

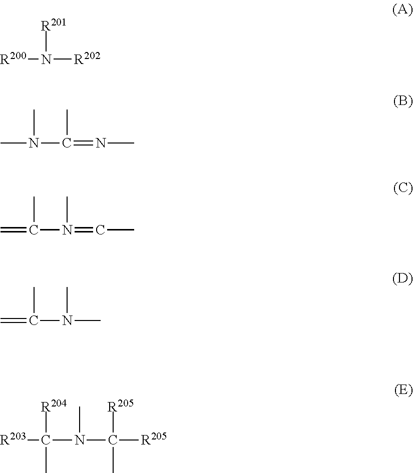

In formulae (A) and (E), each of R²⁰⁰, R²⁰¹ and R²⁰², which may be the same or different, represents a hydrogen atom, an alkyl group (preferably having a carbon number of 1 to 20), a cycloalkyl group (preferably having a carbon number of 3 to 20) or an aryl group (having a carbon number of 6 to 20), and R²⁰¹ and R²⁰² may combine together to form a ring. Each of R²⁰³, R²⁰⁴, R²⁰⁵ and R²⁰⁶, which may be the same or different, represents an alkyl group having a carbon number of 1 to 20.

As for the alkyl group, the alkyl group having a substituent is preferably an aminoalkyl group having a carbon number of 1 to 20, a hydroxyalkyl group having a carbon number of 1 to 20, or a cyanoalkyl group having a carbon number of 1 to 20.

The alkyl group in formulae (A) and (E) is more preferably unsubstituted.

Preferred examples of the compound include guanidine, aminopyrrolidine, pyrazole, pyrazoline, piperazine, aminomorpholine, aminoalkylmorpholine, and piperidine. More preferred examples of the compound include a compound having an imidazole structure, a diazabicyclo structure, an onium hydroxide structure, an onium carboxylate structure, a trialkylamine structure, an aniline structure or a pyridine structure; an alkylamine derivative having a hydroxyl group and/or an ether bond; and an aniline derivative having a hydroxyl group and/or an ether bond.

Examples of the compound having an imidazole structure include imidazole, 2,4,5-triphenylimidazole, and benzimidazole. Examples of the compound having a diazabicyclo structure include 1,4-diazabicyclo[2,2,2]octane, 1,5-diazabicyclo[4,3,0]non-5-ene, and 1,8-diazabicyclo[5,4,0]undec-7-ene. Examples of the compound having an onium hydroxide structure include a triarylsulfonium hydroxide, a phenacylsulfonium hydroxide, and a sulfonium hydroxide having a 2-oxoalkyl group, specifically, triphenylsulfonium hydroxide, tris(tert-butylphenyl)sulfonium hydroxide, bis(tert-butylphenyl)iodonium hydroxide, phenacylthiophenium hydroxide and 2-oxopropylthiophenium hydroxide. The compound having an onium carboxylate structure is a compound where the anion moiety of the compound having an onium hydroxide structure becomes a carboxylate, and examples thereof include an acetate, an adamantane-1-carboxylate, and a perfluoroalkyl carboxylate. Examples of the compound having a trialkylamine structure include tri(n-butyl)amine and tri(n-octyl)amine. Examples of the compound having an aniline structure include 2,6-diisopropylaniline, N,N-dimethylaniline, N,N-dibutylaniline, and N,N-dihexylaniline. Examples of the alkylamine derivative having a hydroxyl group and/or an ether bond include ethanolamine, diethanolamine, triethanolamine, and tris(methoxyethoxyethyl)amine. Examples of the aniline derivative having a hydroxyl group and/or an ether bond include N,N-bis(hydroxyethyl)aniline.

Other preferred basic compounds include a phenoxy group-containing amine compound, a phenoxy group-containing ammonium salt compound, a sulfonic acid ester group-containing amine compound, and a sulfonic acid ester group-containing ammonium salt compound.

In the phenoxy group-containing amine compound, phenoxy group-containing ammonium salt compound, sulfonic acid ester group-containing amine compound and sulfonic acid ester group-containing ammonium salt compound, at least one alkyl group is preferably bonded to the nitrogen atom and also, the alkyl chain preferably contains an oxygen atom therein to form an oxyalkylene group. The number of oxyalkylene groups in the molecule is 1 or more, preferably from 3 to 9, more preferably from 4 to 6. Among oxyalkylene groups, those having a structure of —CH₂CH₂O—, —CH(CH₃)CH₂O— or —CH₂CH₂CH₂O— are preferred.

Specific examples of the phenoxy group-containing amine compound, phenoxy group-containing ammonium salt compound, sulfonic acid ester group-containing amine compound and sulfonic acid ester group-containing ammonium salt compound include, but are not limited to, Compounds (C1-1) to (C3-3) illustrated in paragraph [0066] of U.S. Patent Application Publication 2007/0224539.

A nitrogen-containing organic compound having a group capable of leaving by the action of an acid may be also used as a kind of the basic compound. Examples of this compound include a compound represented by the following formula (F). Incidentally, the compound represented by the following formula (F) exhibits an effective basicity in the system as a result of elimination of the group capable of leaving by the action of an acid.

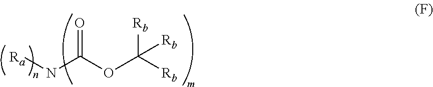

In formula (F), each Ra independently represents a hydrogen atom, an alkyl group, a cycloalkyl group, an aryl group, or an aralkyl group. Also, when n=2, two Ra's may be the same or different, and two Ra's may combine with each other to form a divalent heterocyclic hydrocarbon group (preferably having a carbon number of 20 or less) or a derivative thereof.

Each Rb independently represents a hydrogen atom, an alkyl group, a cycloalkyl group, an aryl group, or an aralkyl group, provided that in —C(Rb)(Rb)(Rb), when one or more Rb's are a hydrogen atom, at least one of remaining Rb's is a cyclopropyl group or a 1-alkoxyalkyl group.

At least two Rb's may combine to form an alicyclic hydrocarbon group, an aromatic hydrocarbon group, a heterocyclic hydrocarbon group, or a derivative thereof.

n represents an integer of 0 to 2, m represents an integer of 1 to 3, and n+m=3.

In formula (F), each of the alkyl group, cycloalkyl group, aryl group and aralkyl group represented by Ra and Rb may be substituted with a functional group such as hydroxyl group, cyano group, amino group, pyrrolidino group, piperidino group, morpholino group and oxo group, an alkoxy group, or a halogen atom.

Specific examples of the compound represented by formula (F) are illustrated below, but the present invention is not limited thereto.

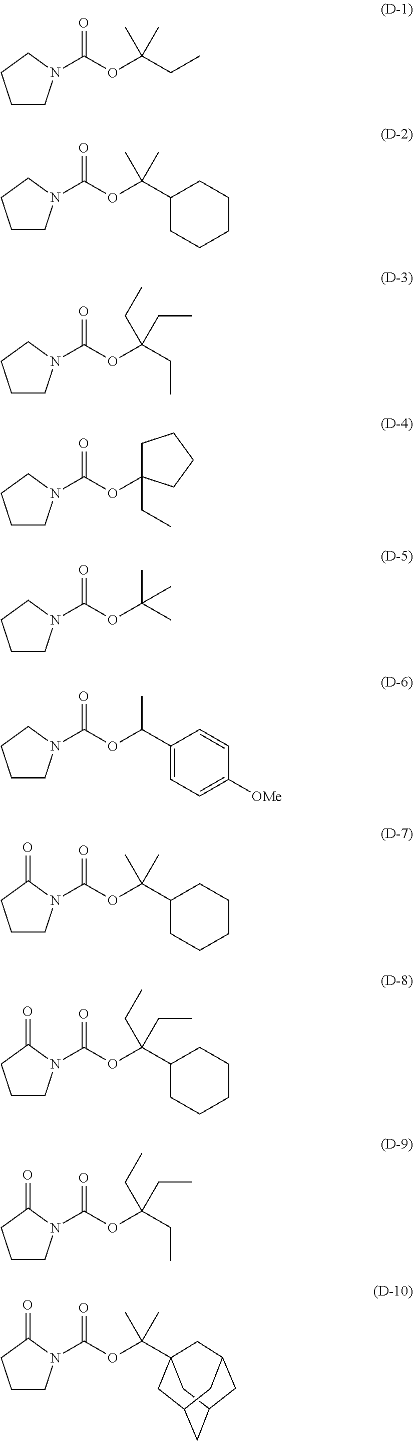

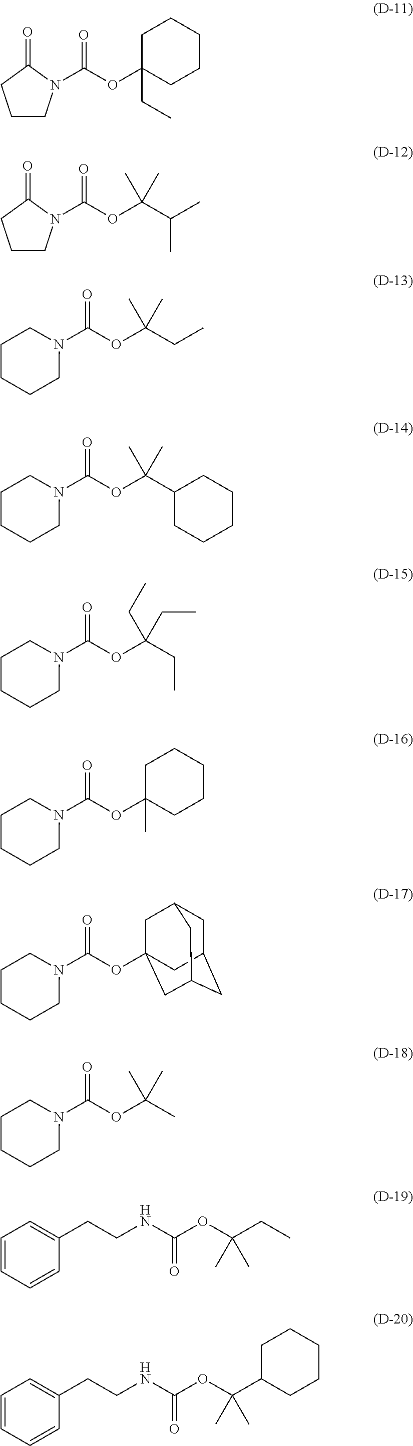

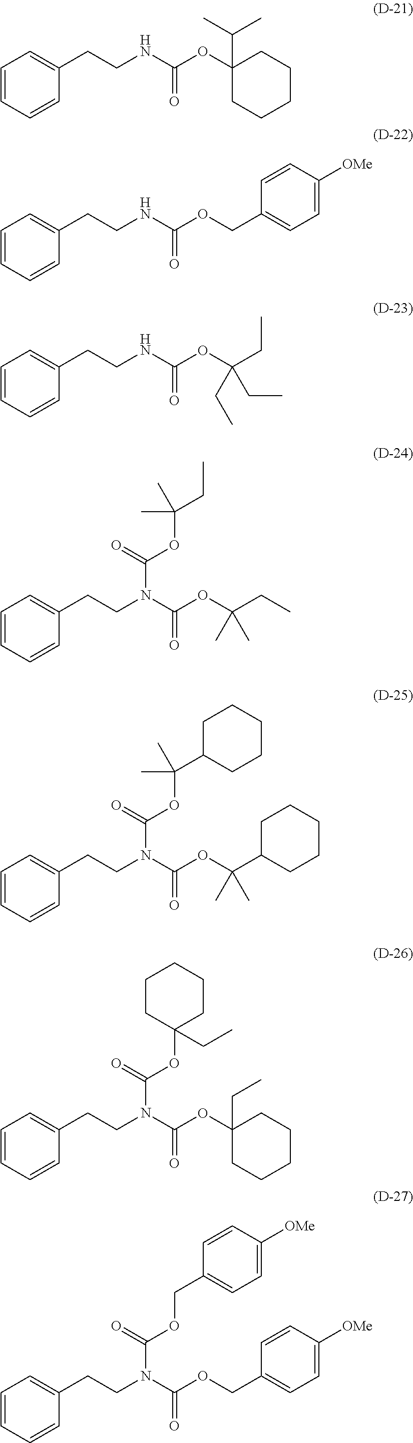

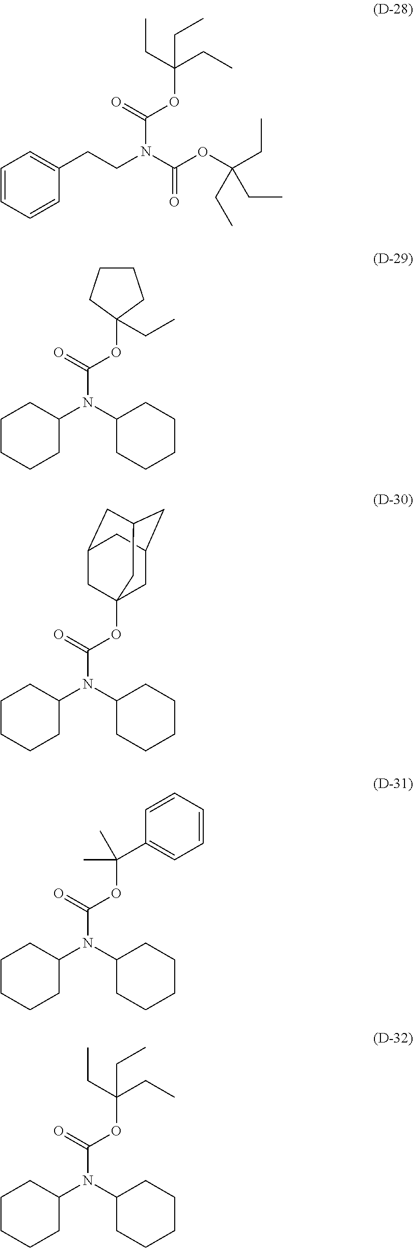

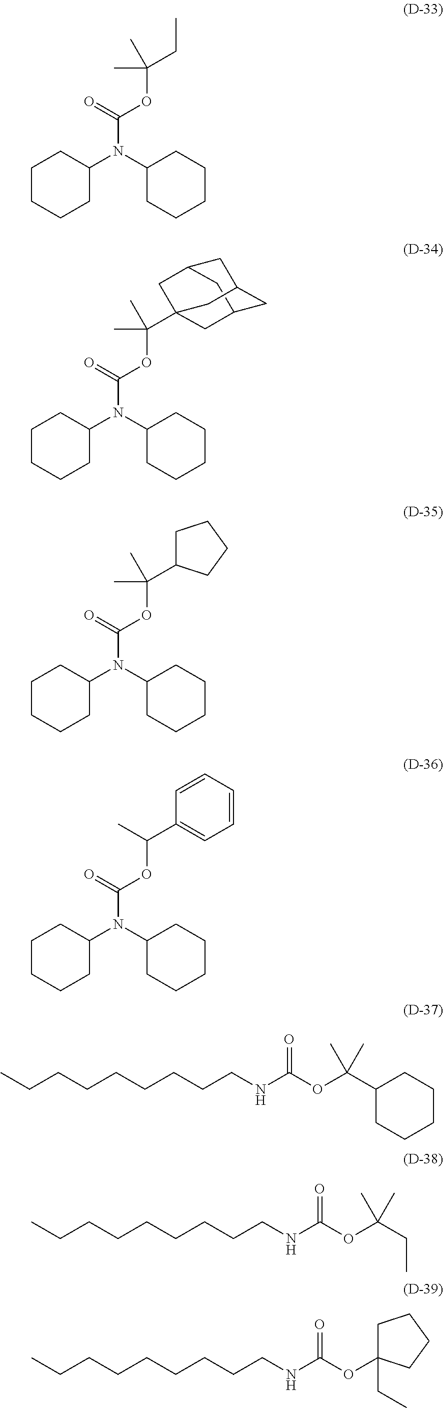

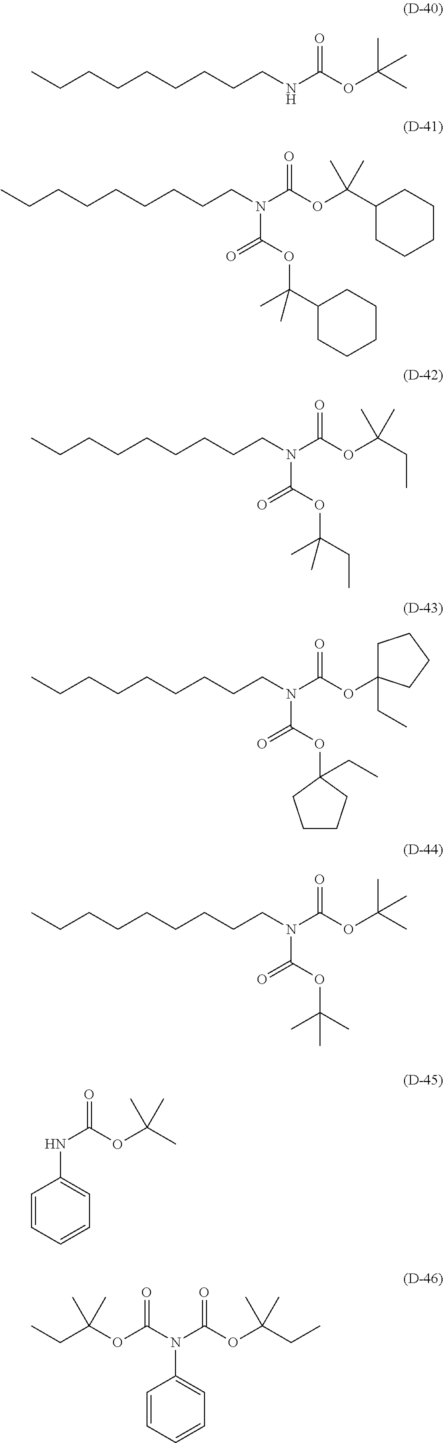

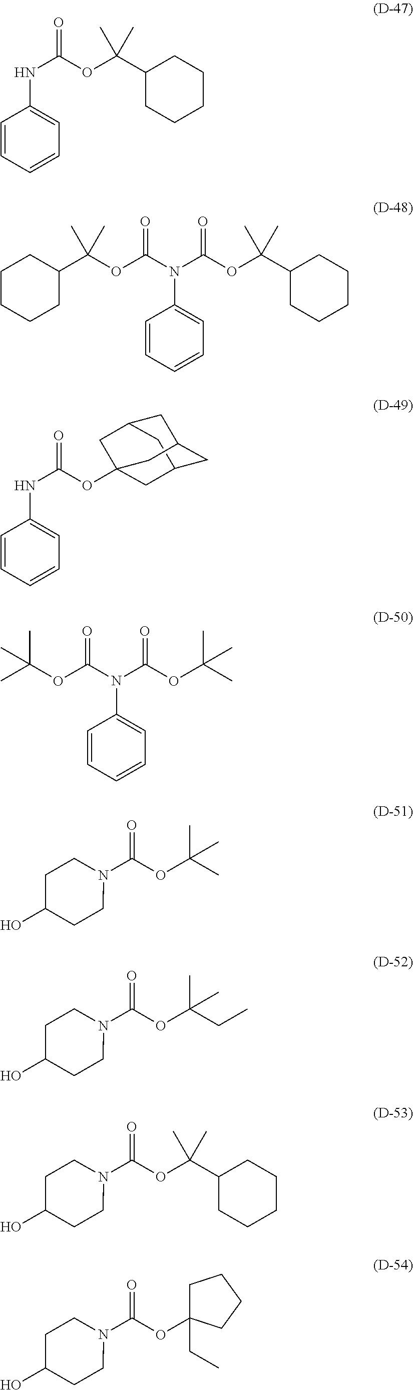

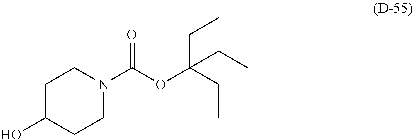 [SMILES: CCC(CC)(CC)OC(=O)N1CCC(O)CC1]

The compound represented by formula (F) can be synthesized by referring to, for example, JP-A-2009-199021.

The molecular weight of the basic compound (C′) is preferably from 250 to 2,000, more preferably from 400 to 1,000. In view of more reduction of LWR and uniformity of local pattern dimension, the molecular weight of the basic compound is preferably 400 or more, more preferably 500 or more, still more preferably 600 or more.

Such a basic compound (C′) may be used in combination with the compound (C), and one basic compound is used alone, or two or more basic compounds are used in combination.

The chemical amplification resist composition for use in the present invention may or may not contain the basic compound (C′), but in the case of containing the basic compound, the amount used thereof is usually from 0.001 to 10 mass %, preferably from 0.01 to 5 mass %, based on the solid content of the chemical amplification resist composition.

The ratio between the acid generator and the basic compound used in the composition is preferably acid generator/basic compound (molar ratio)=from 2.5 to 300. That is, the molar ratio is preferably 2.5 or more in view of sensitivity and resolution and is preferably 300 or less from the standpoint of suppressing the reduction in resolution due to thickening of the resist pattern with aging after exposure until heat treatment. The acid generator/basic compound (molar ratio) is more preferably from 5.0 to 200, still more preferably from 7.0 to 150.

### [4] (D) Solvent

Examples of the solvent which can be used at the preparation of the chemical amplification resist composition for use in the present invention include an organic solvent such as alkylene glycol monoalkyl ether carboxylate, alkylene glycol monoalkyl ether, alkyl lactate, alkyl alkoxypropionate, cyclic lactone (preferably having a carbon number of 4 to 10), monoketone compound (preferably having a carbon number of 4 to 10) which may have a ring, alkylene carbonate, alkyl alkoxyacetate and alkyl pyruvate.

Specific examples of these solvents include those described in paragraphs [0441] to of U.S. Patent Application Publication No. 2008/0187860.

In the present invention, a mixed solvent prepared by mixing a solvent containing a hydroxyl group in the structure and a solvent not containing a hydroxyl group may be used as the organic solvent.

The solvent containing a hydroxyl group and the solvent not containing a hydroxyl group may be appropriately selected from the compounds exemplified above, but the solvent containing a hydroxyl group is preferably an alkylene glycol monoalkyl ether, an alkyl lactate or the like, more preferably propylene glycol monomethyl ether (PGME, another name: 1-methoxy-2-propanol) or ethyl lactate. The solvent not containing a hydroxyl group is preferably an alkylene glycol monoalkyl ether acetate, an alkyl alkoxypropionate, a monoketone compound which may contain a ring, a cyclic lactone, an alkyl acetate or the like, more preferably propylene glycol monomethyl ether acetate (PGMEA, another name: 1-methoxy-2-acetoxypropane), ethyl ethoxypropionate, 2-heptanone, γ-butyrolactone, cyclohexanone or butyl acetate, and most preferably propylene glycol monomethyl ether acetate, ethyl ethoxypropionate or 2-heptanone.

The mixing ratio (by mass) of the solvent containing a hydroxyl group to the solvent not containing a hydroxyl group is from 1/99 to 99/1, preferably from 10/90 to 90/10, more preferably from 20/80 to 60/40. A mixed solvent in which the solvent not containing a hydroxyl group is contained in a ratio of 50 mass % or more is particularly preferred in view of coating uniformity.

The solvent preferably contains propylene glycol monomethyl ether acetate and is preferably a solvent composed of propylene glycol monomethyl ether acetate alone or a mixed solvent of two or more kinds of solvents containing propylene glycol monomethyl acetate.

### [5] (E) Hydrophobic Resin

The chemical amplification resist composition for use in the present invention may contain a hydrophobic resin having at least either a fluorine atom or a silicon atom (hereinafter, sometimes referred to as a “hydrophobic resin (E)” or simply a “resin (E)”) particularly when the composition is applied to immersion exposure. The hydrophobic resin (E) is unevenly distributed to the surface layer of the film, whereby when the immersion medium is water, the static/dynamic contact angle of the resist film surface for water as well as the followability of immersion liquid can be enhanced.

The hydrophobic resin (E) is preferably designed to, as described above, be unevenly distributed to the interface but unlike a surfactant, need not have necessarily a hydrophilic group in the molecule and may not contribute to uniform mixing of polar/nonpolar substances.

The hydrophobic resin (E) typically contains a fluorine atom and/or a silicon atom. The fluorine atom and/or silicon atom in the hydrophobic resin (E) may be contained in the main chain of the resin or may be contained in the side chain.

In the case where the hydrophobic resin (E) contains a fluorine atom, the resin preferably contains, as the fluorine atom-containing partial structure, a fluorine atom-containing alkyl group, a fluorine atom-containing cycloalkyl group or a fluorine atom-containing aryl group.

The fluorine atom-containing alkyl group (preferably having a carbon number of 1 to 10, more preferably a carbon number of 1 to 4) is a linear or branched alkyl group with at least one hydrogen atom being substituted for by a fluorine atom and may further have a substituent other than fluorine atom.

The fluorine atom-containing cycloalkyl group is a monocyclic or polycyclic cycloalkyl group with at least one hydrogen atom being substituted for by a fluorine atom and may further have a substituent other than fluorine atom.

The fluorine atom-containing aryl group is an aryl group such as phenyl group or naphthyl group with at least one hydrogen atom being substituted for by a fluorine atom and may further have a substituent other than fluorine atom.

Preferred fluorine atom-containing alkyl group, fluorine atom-containing cycloalkyl group and fluorine atom-containing aryl group include groups represented by the following formulae (F2) to (F4), but the present invention is not limited thereto.

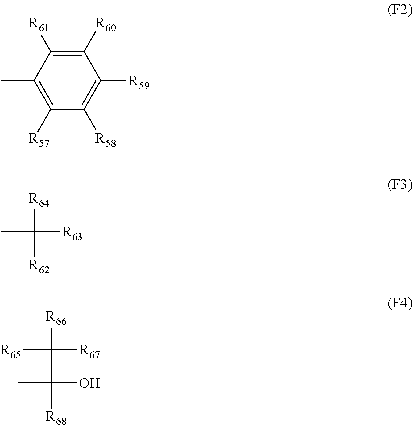

In formulae (F2) to (F4), each of R₅₇ to R₆₈ independently represents a hydrogen atom, a fluorine atom, or an alkyl group (linear or branched), provided that at least one of R₅₇ to R₆₁, at least one of R₆₂ to R₆₄, and at least one of R₆₅ to R₆₈ each independently represents a fluorine atom or an alkyl group (preferably having a carbon number of 1 to 4) with at least one hydrogen atom being substituted for by a fluorine atom.

It is preferred that all of R₅₇ to R₆₁ and R₆₅ to R₆₇ are a fluorine atom. Each of R₆₂, R₆₃ and R₆₈ is preferably an alkyl group (preferably having a carbon number of 1 to 4) with at least one hydrogen atom being substituted for by a fluorine atom, more preferably a perfluoroalkyl group having a carbon number of 1 to 4. R₆₂ and R₆₃ may combine with each other to form a ring.

Specific examples of the group represented by formula (F2) include p-fluorophenyl group, pentafluorophenyl group, and 3,5-di(trifluoromethyl)phenyl group.

Specific examples of the group represented by formula (F3) include a trifluoromethyl group, a pentafluoropropyl group, a pentafluoroethyl group, a heptafluorobutyl group, a hexafluoroisopropyl group, a heptafluoroisopropyl group, a hexafluoro(2-methyl)isopropyl group, a nonafluorobutyl group, an octafluoroisobutyl group, a nonafluorohexyl group, a nonafluoro-tert-butyl group, a perfluoroisopentyl group, a perfluoroctyl group, a perfluoro(trimethyl)hexyl group, a 2,2,3,3-tetrafluorocyclobutyl group, and a perfluorocyclohexyl group. A hexafluoroisopropyl group, a heptafluoroisopropyl group, a hexafluoro(2-methyl)isopropyl group, an octafluoroisobutyl group, a nonafluoro-tert-butyl group and a perfluoroisopentyl group are preferred, and a hexafluoroisopropyl group and a heptafluoroisopropyl group are more preferred.

Specific examples of the group represented by formula (F4) include —C(CF₃)₂OH, —C(C₂F₅)₂OH, —C(CF₃)(CH₃)OH and —CH(CF₃)OH, with —C(CF₃)₂OH being preferred.

The fluorine atom-containing partial structure may be bonded directly to the main chain or may be bonded to the main chain through a group selected from the group consisting of an alkylene group, a phenylene group, an ether bond, a thioether bond, a carbonyl group, an ester bond, an amide bond, a urethane bond and a ureylene bond, or a group formed by combining two or more of these groups and bonds.

Suitable repeating units having a fluorine atom include the followings.

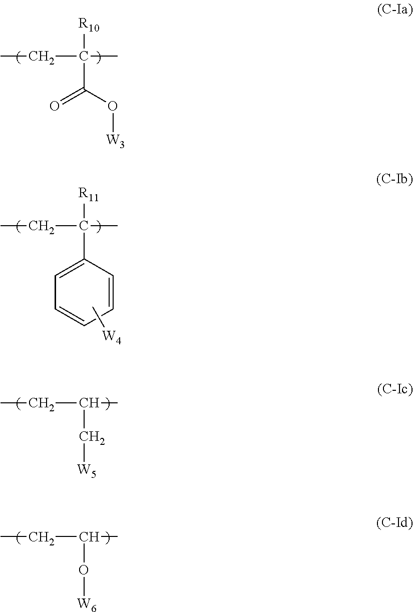

In the formulae, each of R₁₀ and R₁₁ independently represents a hydrogen atom, a fluorine atom, or an alkyl group. The alkyl group is preferably a linear or branched alkyl group having a carbon number of 1 to 4 and may have a substituent, and the alkyl group having a substituent includes, in particular, a fluorinated alkyl group.

Each of W₃ to W₆ independently represents an organic group having at least one or more fluorine atoms, and the group specifically includes the atomic groups of (F2) to (F4).

Other than these, the hydrophobic resin (E) may contain a unit shown below as the repeating unit having a fluorine atom.

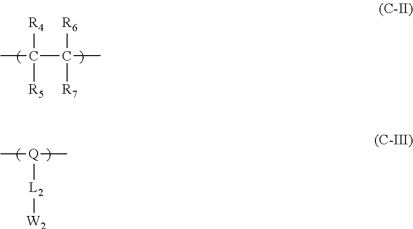

In the formulae, each of R₄ to R₇ independently represents a hydrogen atom, a fluorine atom, or an alkyl group. The alkyl group is preferably a linear or branched alkyl group having a carbon number of 1 to 4 and may have a substituent, and the alkyl group having a substituent includes, in particular, a fluorinated alkyl group.

However, at least one of R₄ to R₇ represents a fluorine atom. R₄ and R₅, or R₆ and R₇ may form a ring.

W₂ represents an organic group having at least one fluorine atom, and the group specifically includes the atomic groups of (F2) to (F4).

L₂ represents a single bond or a divalent linking group. The divalent linking group is a substituted or unsubstituted arylene group, a substituted or unsubstituted alkylene group, a substituted or unsubstituted cycloalkylene group, —O—, —SO₂—, —CO—, —N(R)— (wherein R represents a hydrogen atom or an alkyl group), —NHSO₂—, or a divalent linking group formed by combining a plurality of these groups.

Q represents an alicyclic structure. The alicyclic structure may have a substituent and may be monocyclic or polycyclic, and in the case of a polycyclic structure, the structure may be a crosslinked structure. The monocyclic structure is preferably a cycloalkyl group having a carbon number of 3 to 8, and examples thereof include a cyclopentyl group, a cyclohexyl group, a cyclobutyl group, and a cyclooctyl group. Examples of the polycyclic structure include a group having a bicyclo, tricyclo or tetracyclo structure with a carbon number of 5 or more. A cycloalkyl group having a carbon number of 6 to 20 is preferred, and examples thereof include an adamantyl group, a norbornyl group, a dicyclopentyl group, a tricyclodecanyl group, and a tetracyclododecyl group. A part of carbon atoms in the cycloalkyl group may be substituted with a heteroatom such as oxygen atom. Above all, Q is preferably, for example, a norbornyl group, a tricyclodecanyl group, or a tetracyclododecyl group.

Specific examples of the repeating unit having a fluorine atom are illustrated below, but the present invention is not limited thereto.

In specific examples, X₁ represents a hydrogen atom, —CH₃, —F or —CF₃. X₂ represents —F or —CF₃.

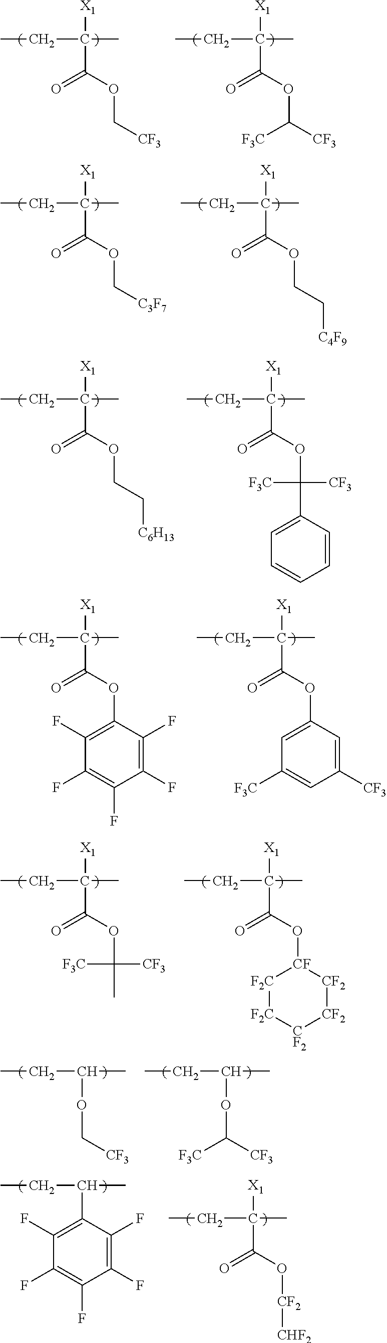

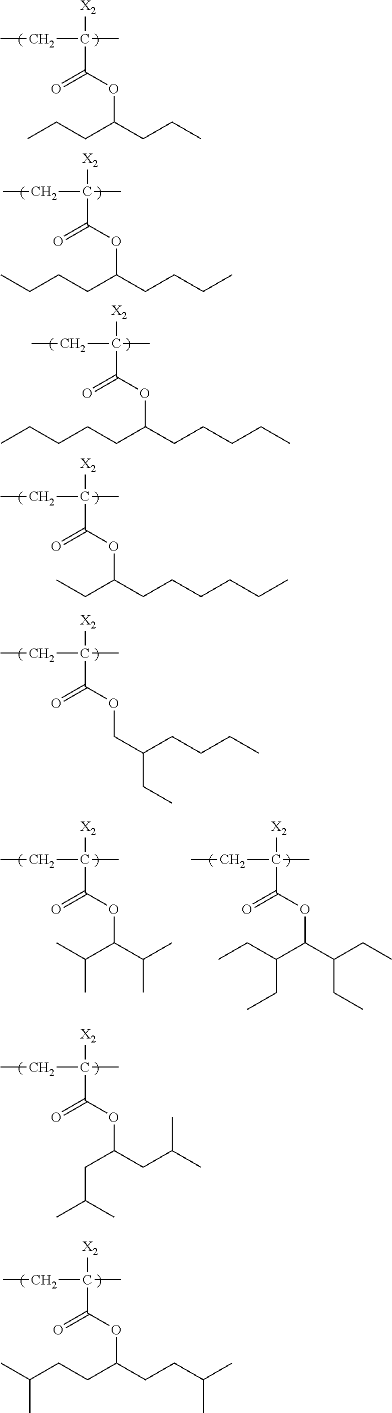

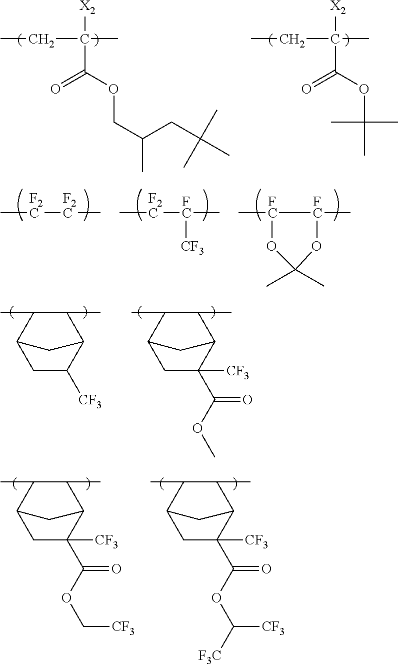

The hydrophobic resin (E) may contain a silicon atom. The resin preferably has, as the silicon atom-containing partial structure, an alkylsilyl structure (preferably a trialkylsilyl group) or a cyclic siloxane structure.

Specific examples of the alkylsilyl structure and cyclic siloxane structure include groups represented by the following formulae (CS-1) to (CS-3):

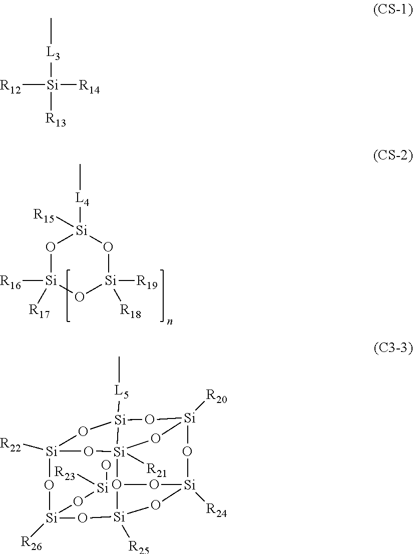

In formulae (CS-1) to (CS-3), each of R₁₂ to R₂₆ independently represents a linear or branched alkyl group (preferably having a carbon number of 1 to 20) or a cycloalkyl group (preferably having a carbon number of 3 to 20).

Each of L₃ to L₅ represents a single bond or a divalent linking group. The divalent linking group is a sole member or a combination of two or more members (preferably having a total carbon number of 12 or less), selected from the group consisting of an alkylene group, a phenylene group, an ether bond, a thioether bond, a carbonyl group, an ester bond, an amide bond, a urethane bond and a urea bond.

n represents an integer of 1 to 5. n is preferably an integer of 2 to 4.

Specific examples of the repeating unit having a group represented by formulae (CS-1) to (CS-3) are illustrated below, but the present invention is not limited thereto. In specific examples, X₁ represents a hydrogen atom, —CH₃, —F or —CF₃.

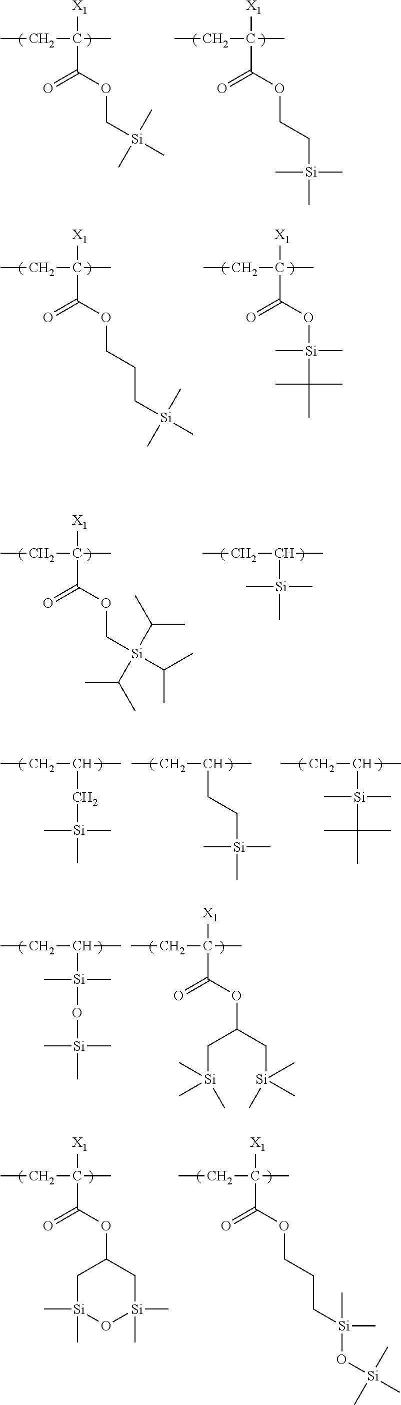

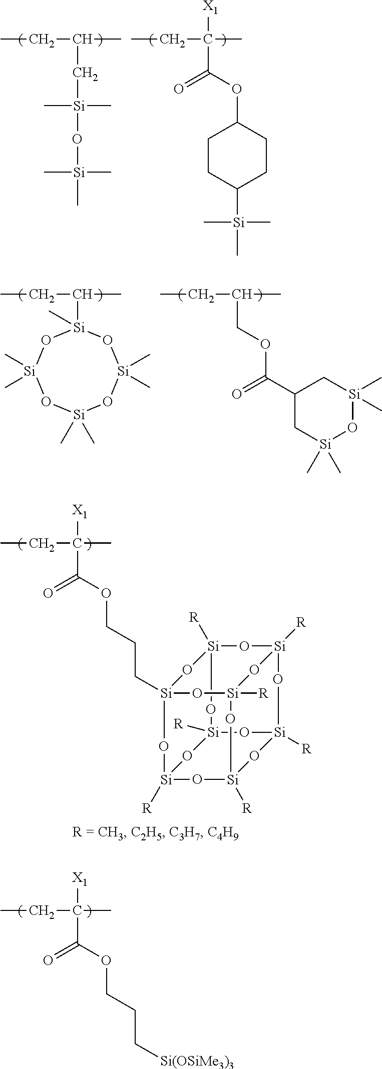

Furthermore, the hydrophobic resin (E) may contain at least one group selected from the group consisting of the following (x) to (z):

(x) an acid group,

(y) a lactone structure-containing group, an acid anhydride group, or an acid imide group, and

(z) a group capable of decomposing by the action of an acid.

Examples of the acid group (x) include a phenolic hydroxyl group, a carboxylic acid group, a fluorinated alcohol group, a sulfonic acid group, a sulfonamide group, a sulfonylimide group, an (alkylsulfonyl)(alkylcarbonyl)methylene group, an (alkylsulfonyl)(alkylcarbonyl)imide group, a bis(alkylcarbonyl)methylene group, a bis(alkylcarbonyl)imide group, a bis(alkylsulfonyl)methylene group, a bis(alkylsulfonyl)imide group, a tris(alkylcarbonyl)methylene group, and a tris(alkylsulfonyl)methylene group.

Preferred acid groups are a fluorinated alcohol group (preferably hexafluoroisopropanol), a sulfonimide group and a bis(alkylcarbonyl)methylene group.

The repeating unit having (x) an acid group includes, for example, a repeating unit where the acid group is directly bonded to the main chain of the resin, such as repeating unit by an acrylic acid or a methacrylic acid, and a repeating unit where the acid group is bonded to the main chain of the resin through a linking group, and the acid group may be also introduced into the terminal of the polymer chain by using an acid group-containing polymerization initiator or chain transfer agent at the polymerization. All of these cases are preferred. The repeating unit having (x) an acid group may have at least either a fluorine atom or a silicon atom.

The content of the repeating unit having (x) an acid group is preferably from 1 to 50 mol %, more preferably from 3 to 35 mol %, still more preferably from 5 to 20 mol %, based on all repeating units in the hydrophobic resin (E).

Specific examples of the repeating unit having (x) an acid group are illustrated below, but the present invention is not limited thereto. In the formulae, Rx represents a hydrogen atom, CH₃, CF₃ or CH₂OH.

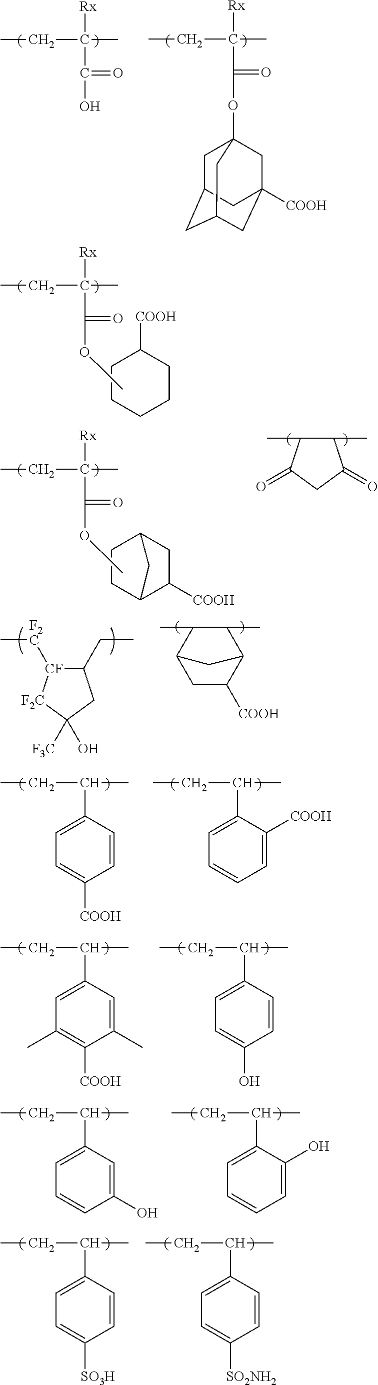

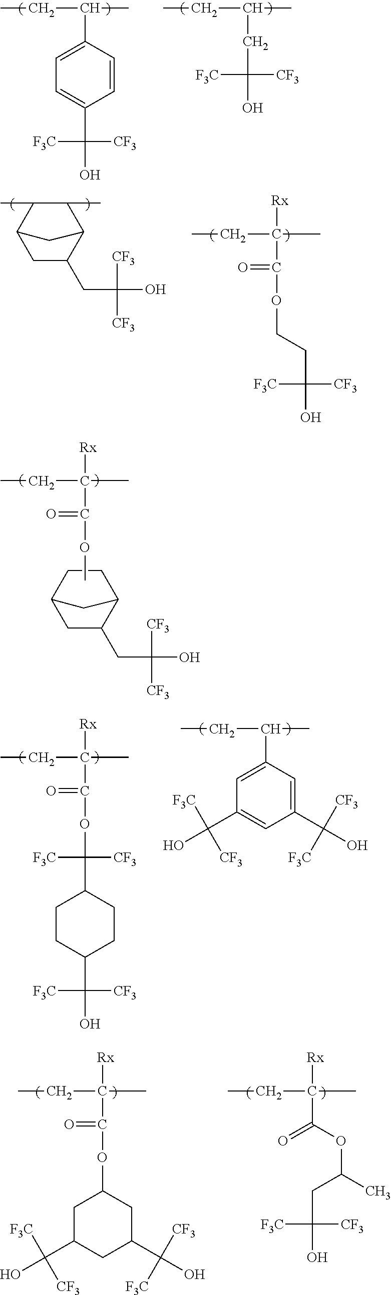

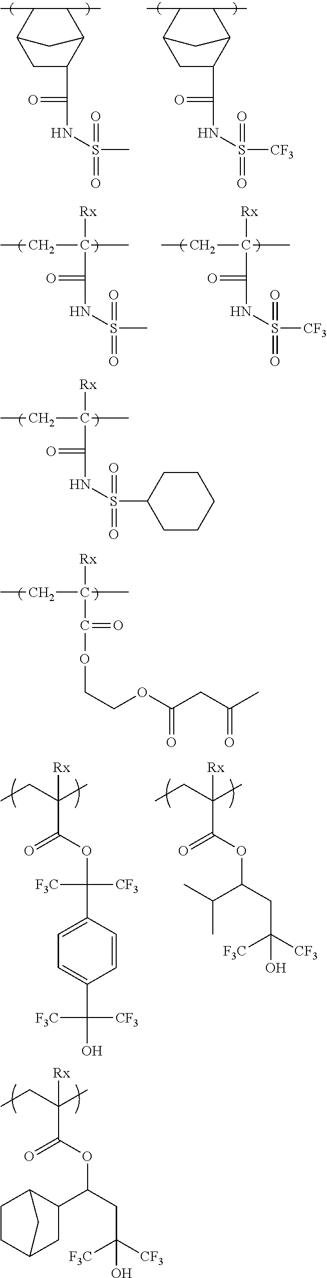

The (y) lactone structure-containing group, acid anhydride group or acid imide group is preferably a lactone structure-containing group.

The repeating unit containing such a group is, for example, a repeating unit where the group is directly bonded to the main chain of the resin, such as repeating unit by an acrylic acid ester or a methacrylic acid ester. This repeating unit may be a repeating unit where the group is bonded to the main chain of the resin through a linking group. Alternatively, in this repeating unit, the group may be introduced into the terminal of the resin by using a polymerization initiator or chain transfer agent containing the group at the polymerization.

Examples of the repeating unit having a lactone structure-containing group are the same as those of the repeating unit having a lactone structure described above in the paragraph of the acid-decomposable resin (A).

The content of the repeating unit having a lactone structure-containing group, an acid anhydride group or an acid imide group is preferably from 1 to 100 mol %, more preferably from 3 to 98 mol %, still more preferably from 5 to 95 mol %, based on all repeating units in the hydrophobic resin

Examples of the repeating unit having (z) a group capable of decomposing by the action of an acid, contained in the hydrophobic resin (E), are the same as those of the repeating unit having an acid-decomposable group described for the resin (A). The repeating unit having (z) a group capable of decomposing by the action of an acid may contain at least either a fluorine atom or a silicon atom. In the hydrophobic resin (E), the content of the repeating unit having (z) a group capable of decomposing by the action of an acid is preferably from 1 to 80 mol %, more preferably from 10 to 80 mol %, still more preferably from 20 to 60 mol %, based on all repeating units in the resin (E).

The hydrophobic resin (E) may further contain a repeating unit represented by the following formula (III):

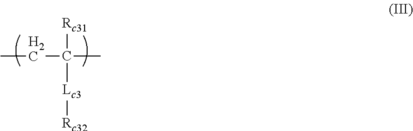

In formula (III), R_{c31} represents a hydrogen atom, an alkyl group (which may be substituted with a fluorine atom or the like), a cyano group, or a —CH₂—O—R_{ac2} group, wherein R_{ac2} represents a hydrogen atom, an alkyl group, or an acyl group. R_{c31} is preferably a hydrogen atom, a methyl group, a hydroxymethyl group or a trifluoromethyl group, more preferably a hydrogen atom or a methyl group.

R_{c32} represents a group having an alkyl group, a cycloalkyl group, an alkenyl group, a cycloalkenyl group or an aryl group. These groups may be substituted with a fluorine atom or a silicon atom-containing group.

L_{c3} represents a single bond or a divalent linking group.

In formula (III), the alkyl group of R_{c32} is preferably a linear or branched alkyl group having a carbon number of 3 to 20.

The cycloalkyl group is preferably a cycloalkyl group having a carbon number of 3 to 20.

The alkenyl group is preferably an alkenyl group having a carbon number of 3 to 20.

The cycloalkenyl group is preferably a cycloalkenyl group having a carbon number of 3 to 20.

The aryl group is preferably an aryl group having a carbon number of 6 to 20, more preferably a phenyl group or a naphthyl group, and these groups may have a substituent.

R_{c32} is preferably an unsubstituted alkyl group or a fluorine atom-substituted alkyl group.

The divalent linking group of L_{c3} is preferably an alkylene group (preferably having a carbon number of 1 to 5), an ether bond, a phenylene group, or an ester bond (a group represented by —COO—).

The content of the repeating unit represented by formula (III) is preferably from 1 to 100 mol %, more preferably from 10 to 90 mol %, still more preferably from 30 to 70 mol %, based on all repeating units in the hydrophobic resin.

It is also preferred that the hydrophobic resin (E) further contains a repeating unit represented by the following formula (CII-AB):

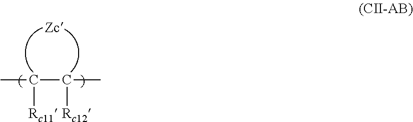

In formula (CII-AB), each of R_{c11}′ and R_{c12}′ independently represents a hydrogen atom, a cyano group, a halogen atom, or an alkyl group.

Z_{c}′ represents an atomic group for forming an alicyclic structure containing two carbon atoms (C—C) to which Z_{c}′ is bonded.

The content of the repeating unit represented by formula (CII-AB) is preferably from 1 to 100 mol %, more preferably from 10 to 90 mol %, still more preferably from 30 to 70 mol %, based on all repeating units in the hydrophobic resin.

Specific examples of the repeating units represented by formulae (III) and (CII-AB) are illustrated below, but the present invention is not limited thereto. In the formulae, Ra represents H, CH₃, CH₂OH, CF₃ or CN.

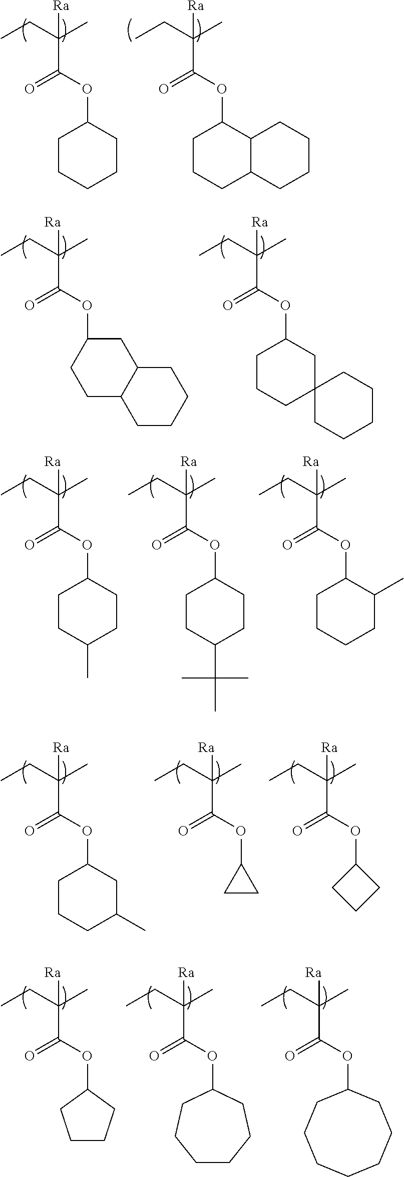

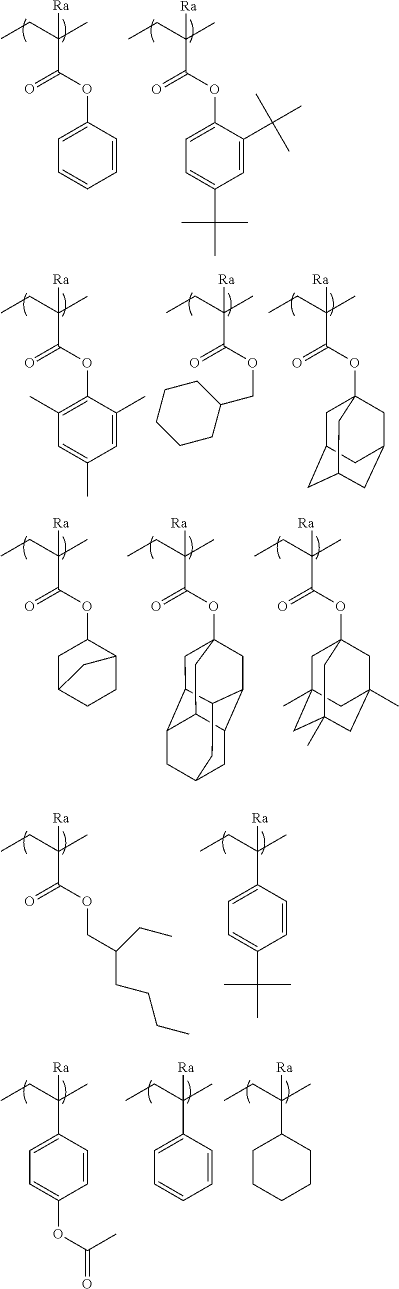

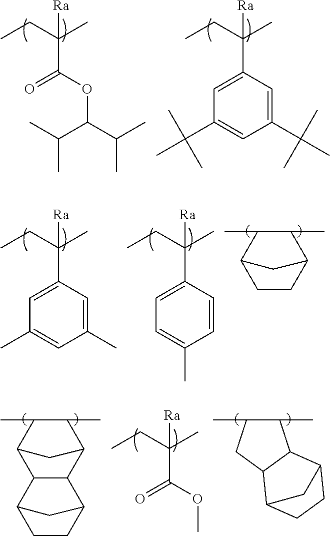

In the case where the hydrophobic resin (E) contains a fluorine atom, the fluorine atom content is preferably from 5 to 80 mass %, more preferably from 10 to 80 mass %, based on the weight average molecular weight of the hydrophobic resin (E). Also, the fluorine atom-containing repeating unit preferably accounts for 10 to 100 mol %, more preferably from 30 to 100 mol %, based on all repeating units contained in the hydrophobic resin (E).

In the case where the hydrophobic resin (E) contains a silicon atom, the silicon atom content is preferably from 2 to 50 mass %, more preferably from 2 to 30 mass %, based on the weight average molecular weight of the hydrophobic resin (E). Also, the silicon atom-containing repeating unit preferably accounts for 10 to 100 mol %, more preferably from 20 to 100 mol %, based on all repeating units contained in the hydrophobic resin (E).

The standard polystyrene-equivalent weight average molecular of the hydrophobic resin (E) is preferably from 1,000 to 100,000, more preferably from 1,000 to 50,000, still more preferably from 2,000 to 15,000.

As for the hydrophobic resin (E), one kind may be used, or a plurality of kinds may be used in combination.

The content of the hydrophobic resin (E) in the composition is preferably from 0.01 to 10 mass %, more preferably from 0.05 to 8 mass %, still more preferably from 0.1 to 5 mass %, based on the entire solid content in the composition for use in the present invention.

In the hydrophobic resin (E), similarly to the resin (A), it is of course preferred that the content of impurities such as metal is small, but the content of residual monomers or oligomer components is also preferably from 0.01 to 5 mass %, more preferably from 0.01 to 3 mass %, still more preferably from 0.05 to 1 mass %. Thanks to the content in this range, a chemical amplification resist composition free from in-liquid extraneous substances and change with aging of sensitivity and the like can be obtained. Furthermore, in view of resolution, resist profile, side wall of resist pattern, roughness and the like, the molecular weight distribution (Mw/Mn, sometimes referred to as “polydispersity”) is preferably from 1 to 5, more preferably from 1 to 3, still more preferably from 1 to 2.

As the hydrophobic resin (E), various commercially products may be used, or the resin may be synthesized by a conventional method (for example, radical polymerization). Examples of the general synthesis method include a batch polymerization method of dissolving monomer species and an initiator in a solvent and heating the solution, thereby effecting the polymerization, and a dropping polymerization method of adding dropwise a solution containing monomer species and an initiator to a heated solvent over 1 to 10 hours. A dropping polymerization method is preferred.

The reaction solvent, the polymerization initiator, the reaction conditions (e.g., temperature, concentration) and the purification method after reaction are the same as those described for the resin (A), but in the synthesis of the hydrophobic resin (E), the concentration at the reaction is preferably from 30 to 50 mass %.

Specific examples of the hydrophobic resin (E) are illustrated below. Also, the molar ratio of repeating units (corresponding to repeating units starting from the left), weight average molecular weight and polydispersity of each resin are shown in Tables 4 and 5 later.

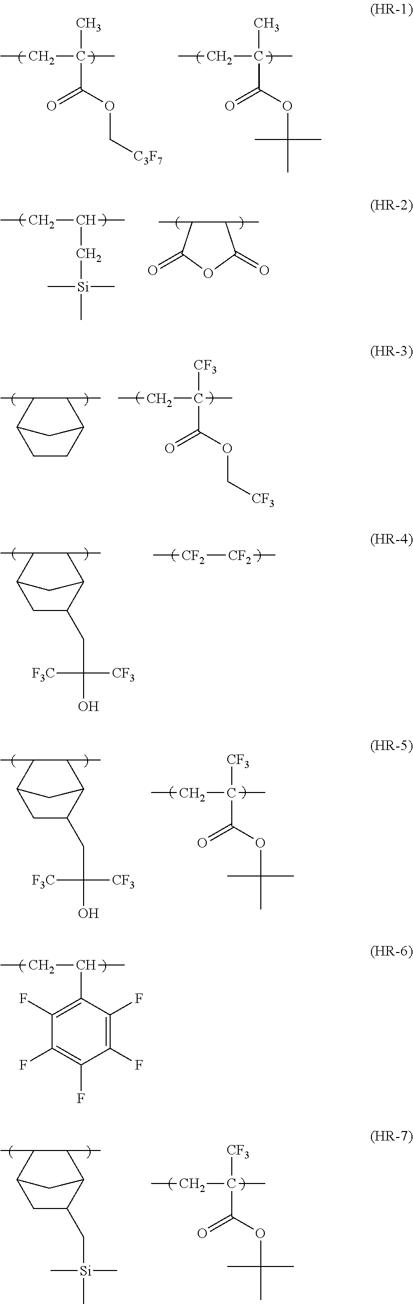

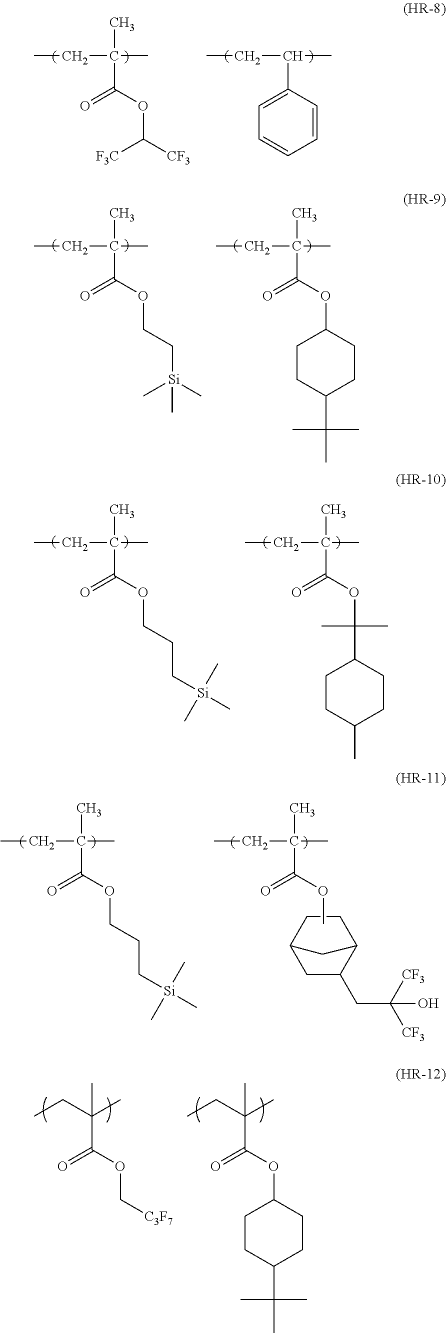

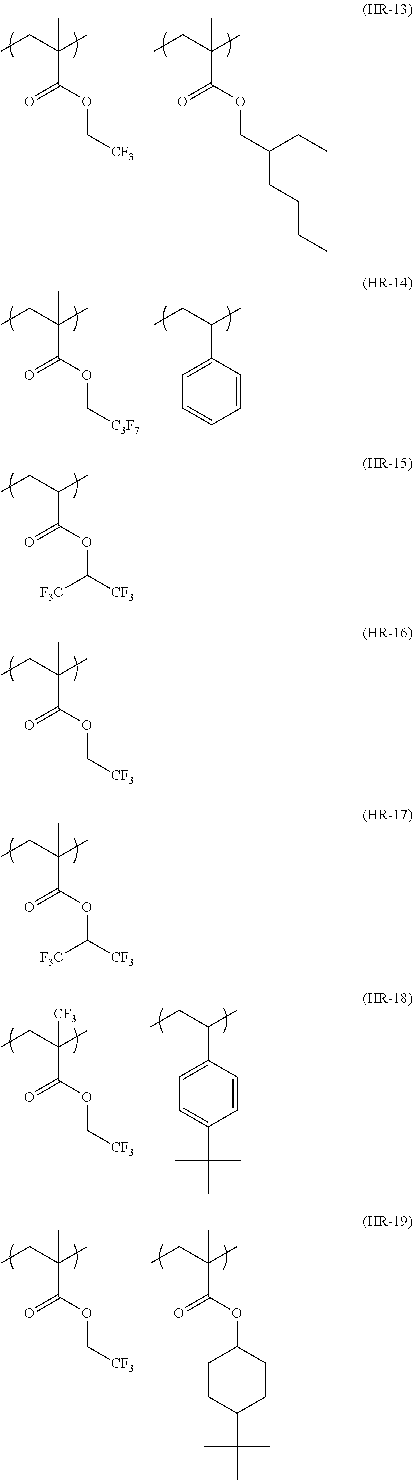

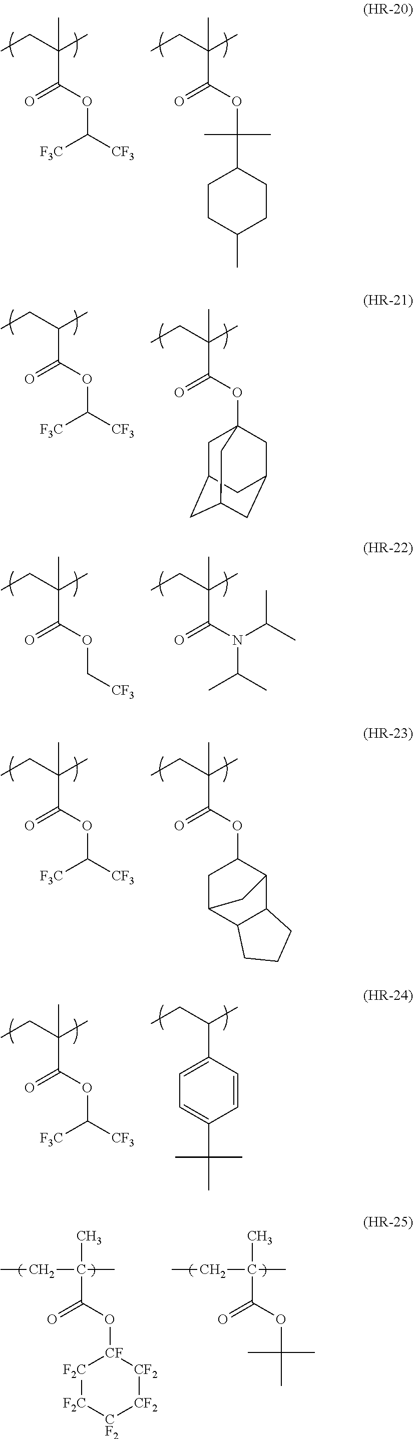

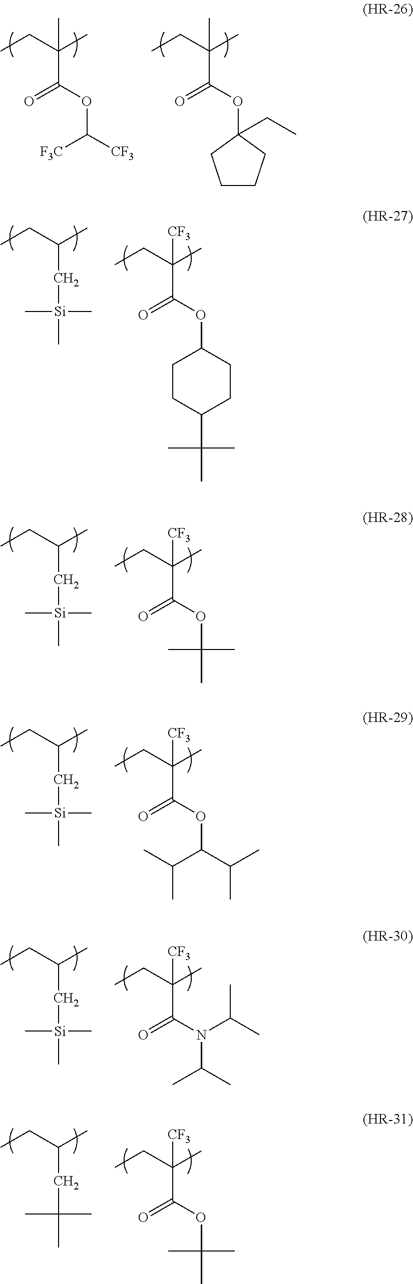

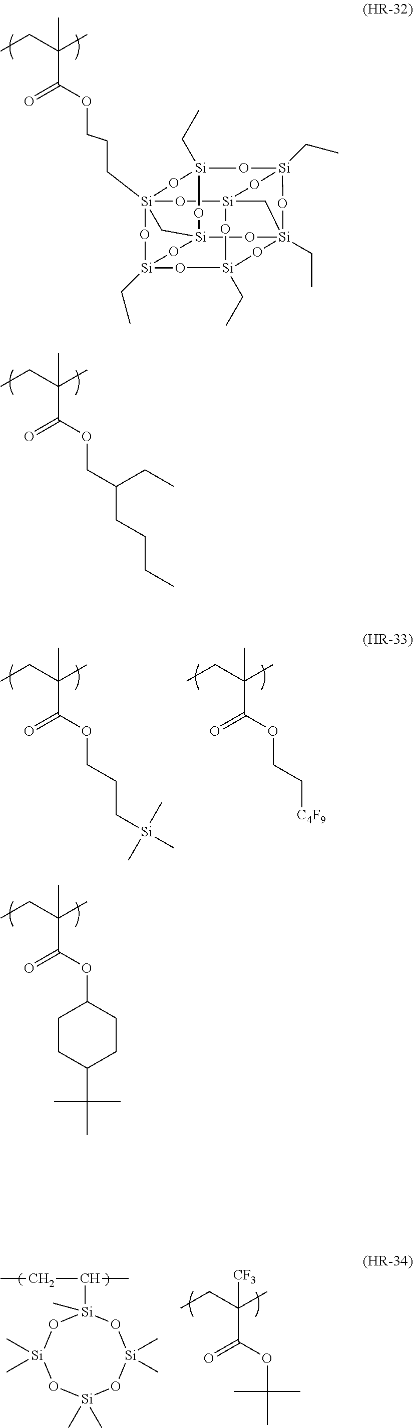

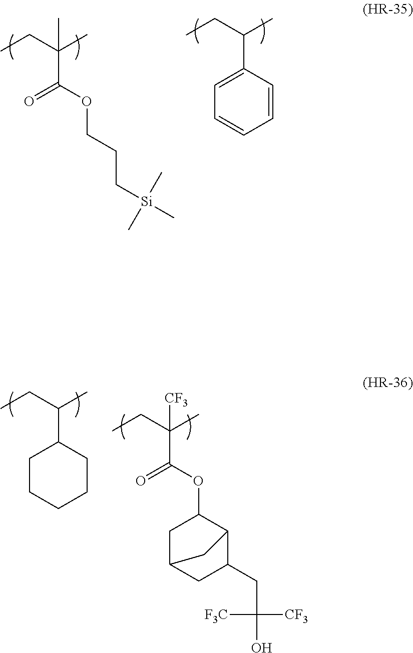

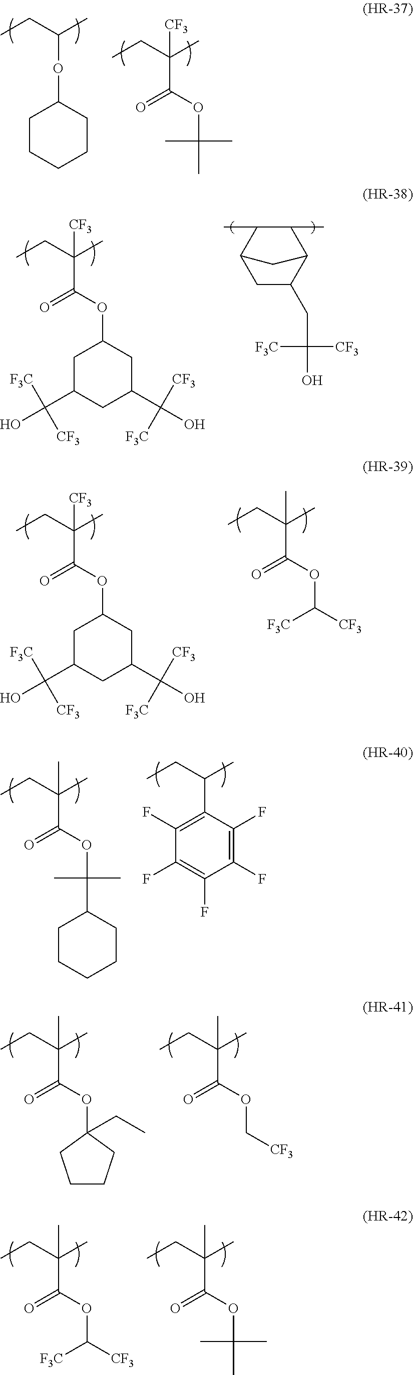

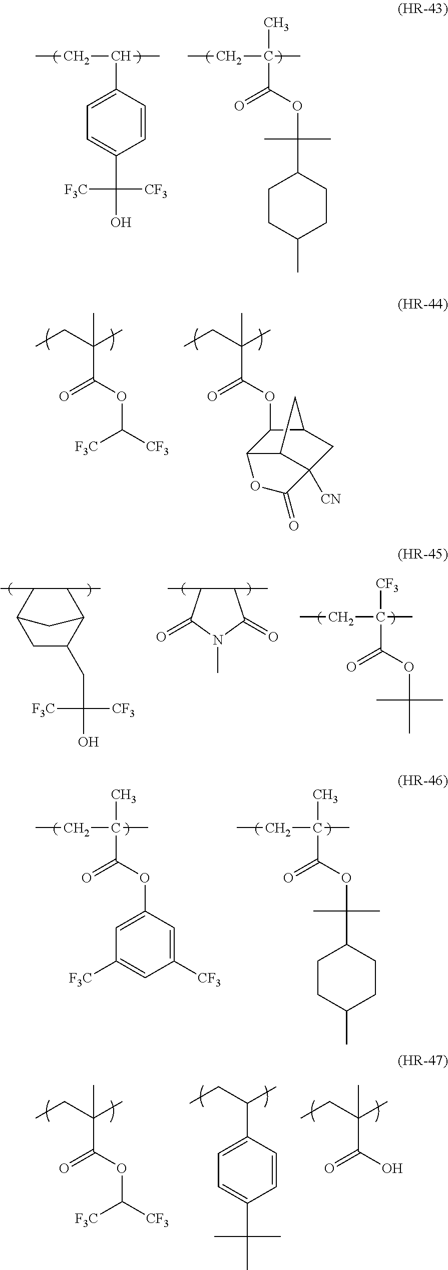

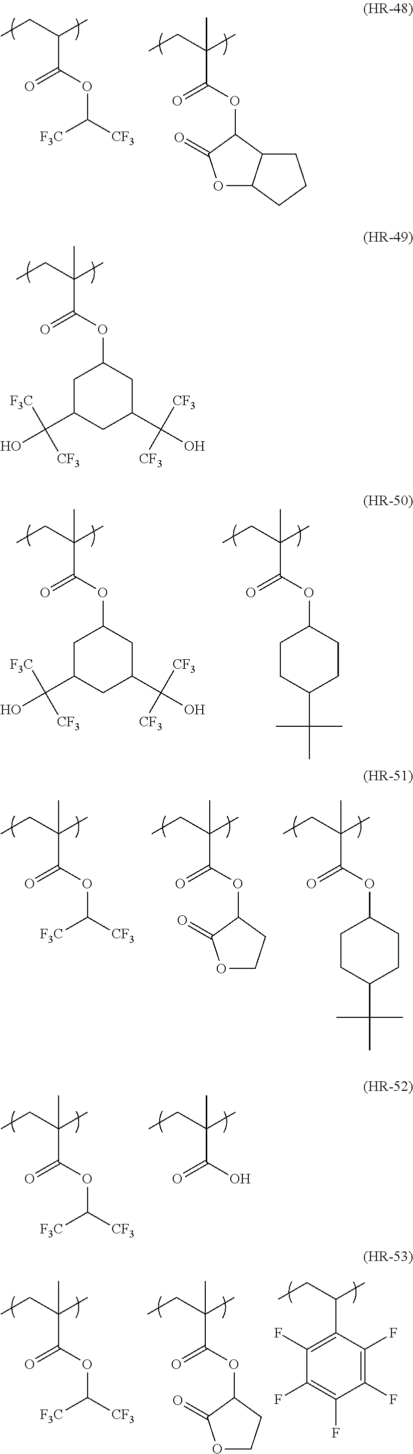

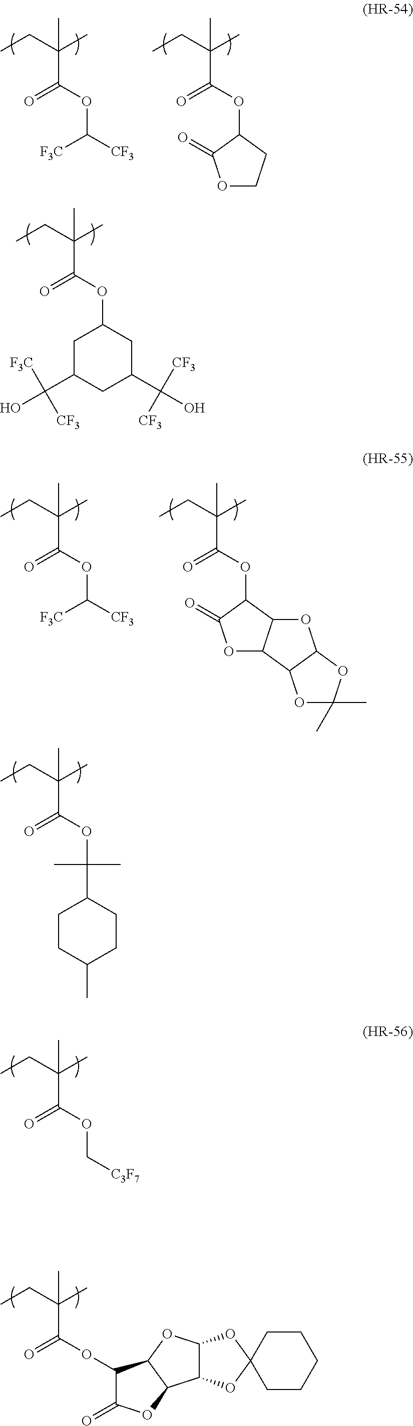

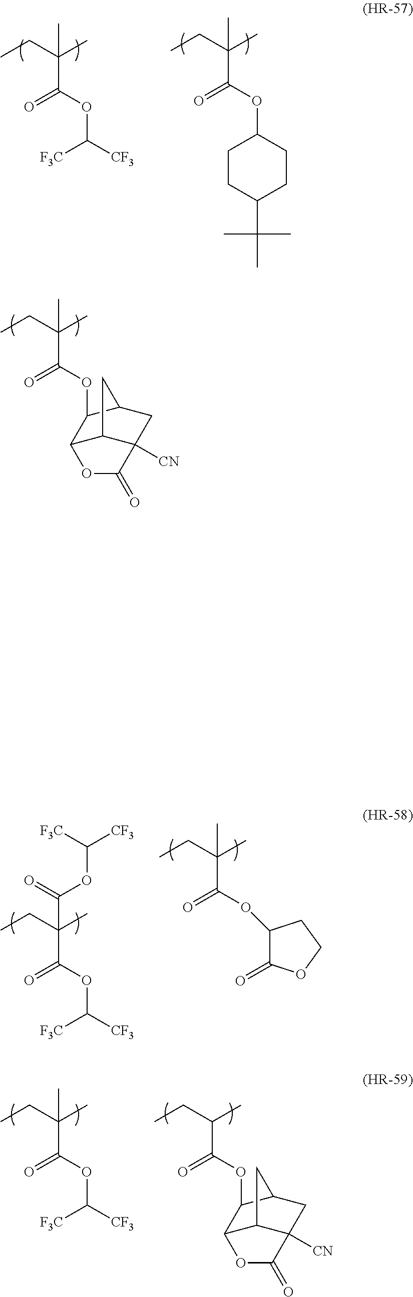

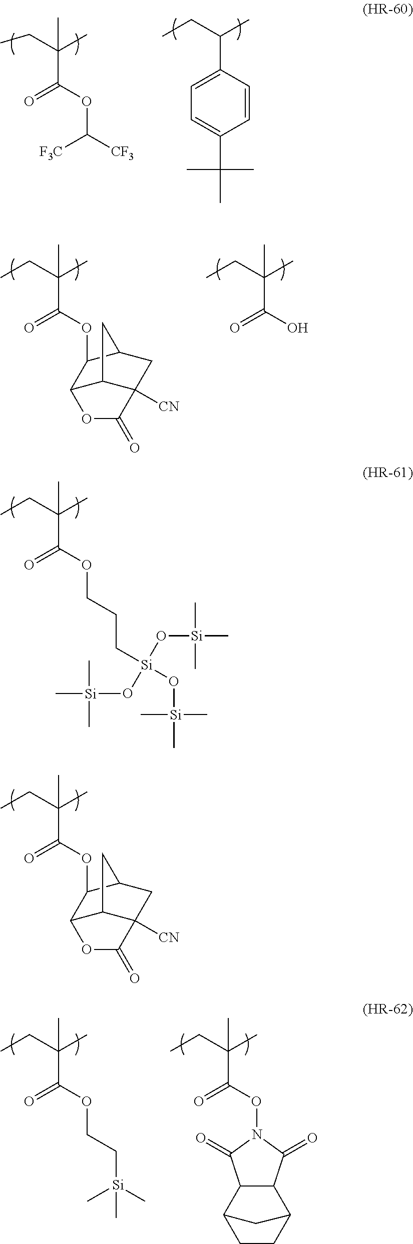

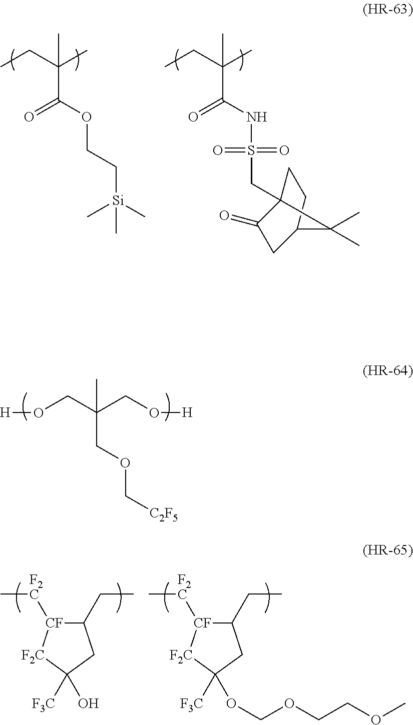

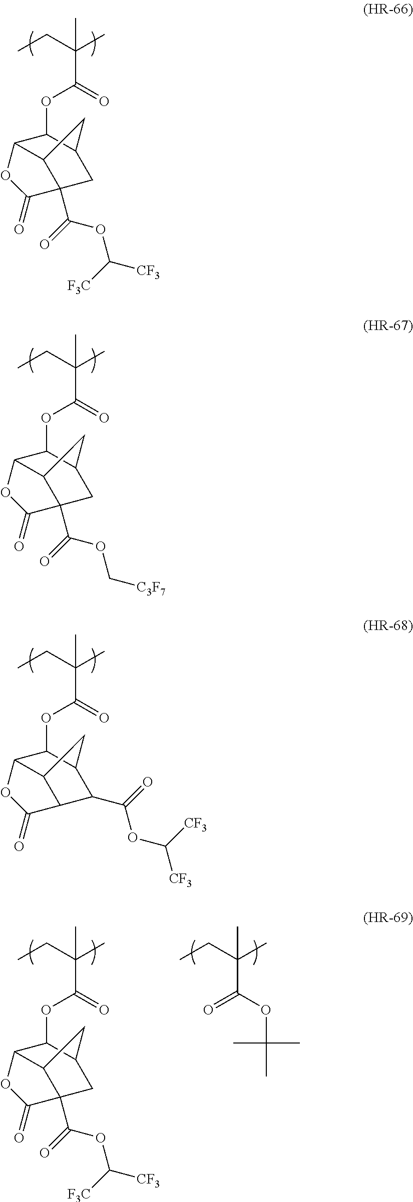

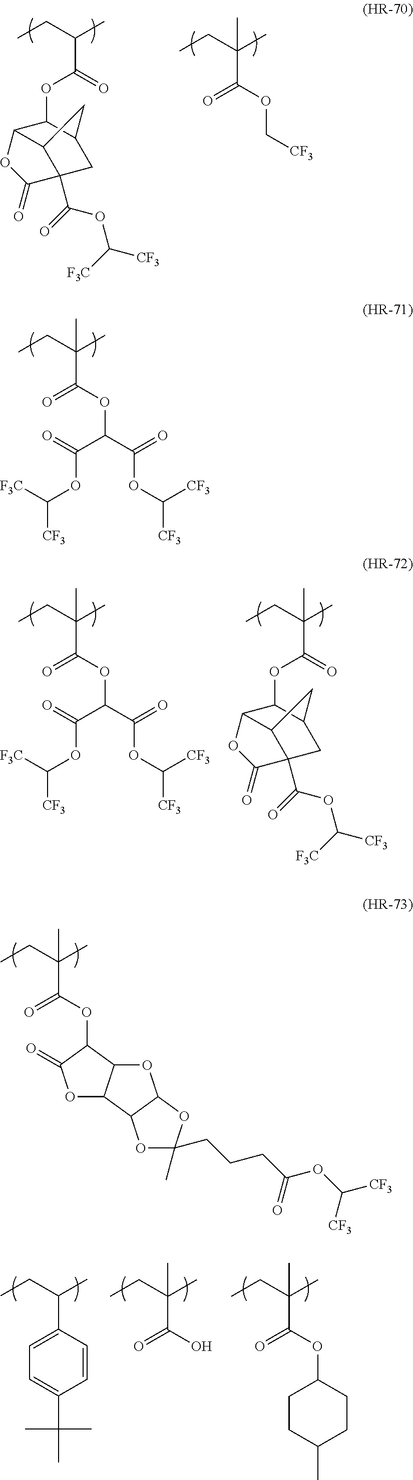

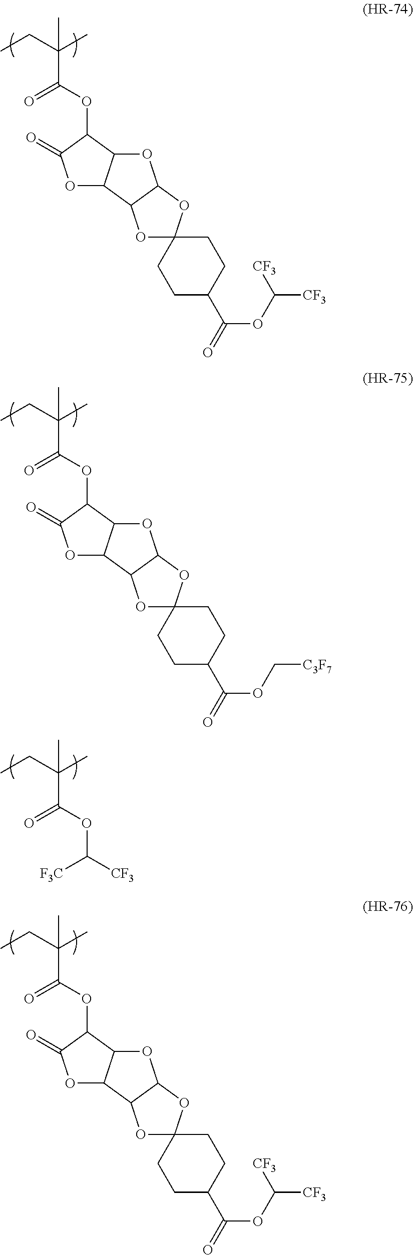

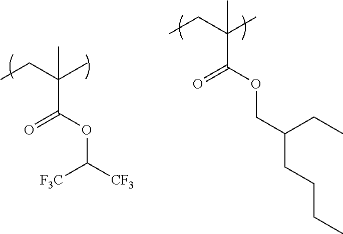

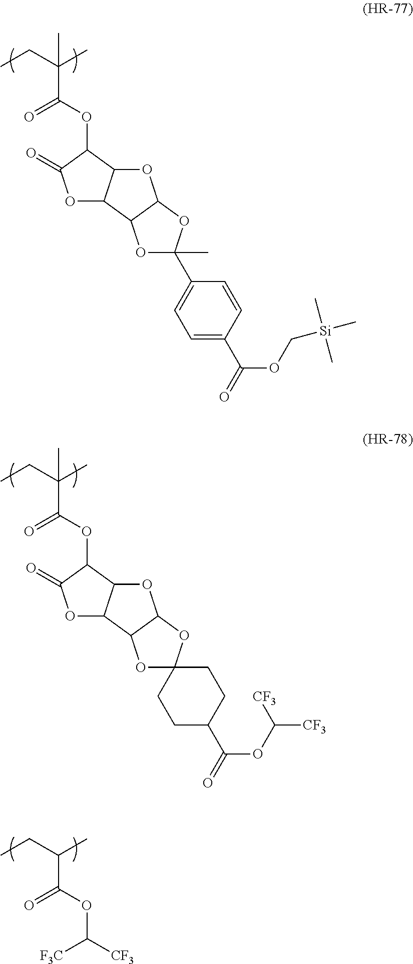

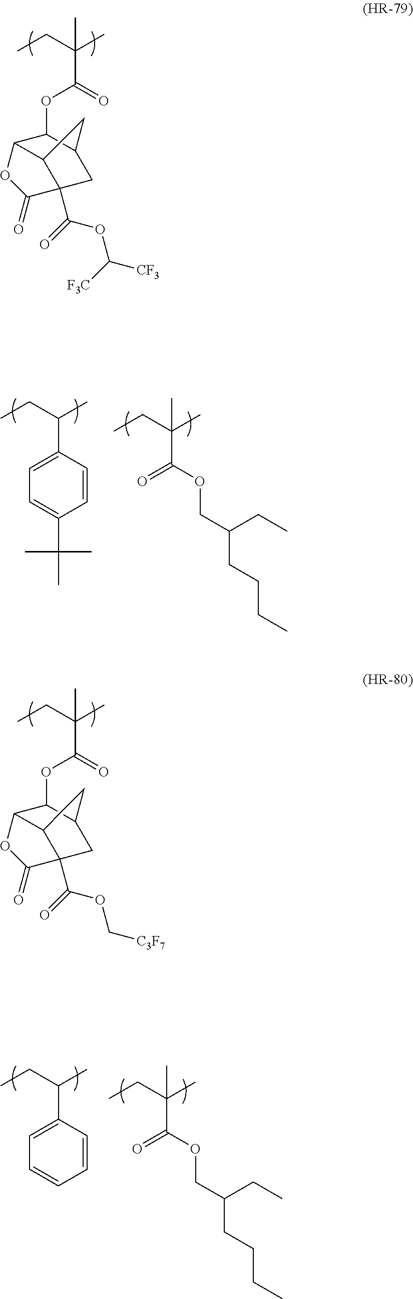

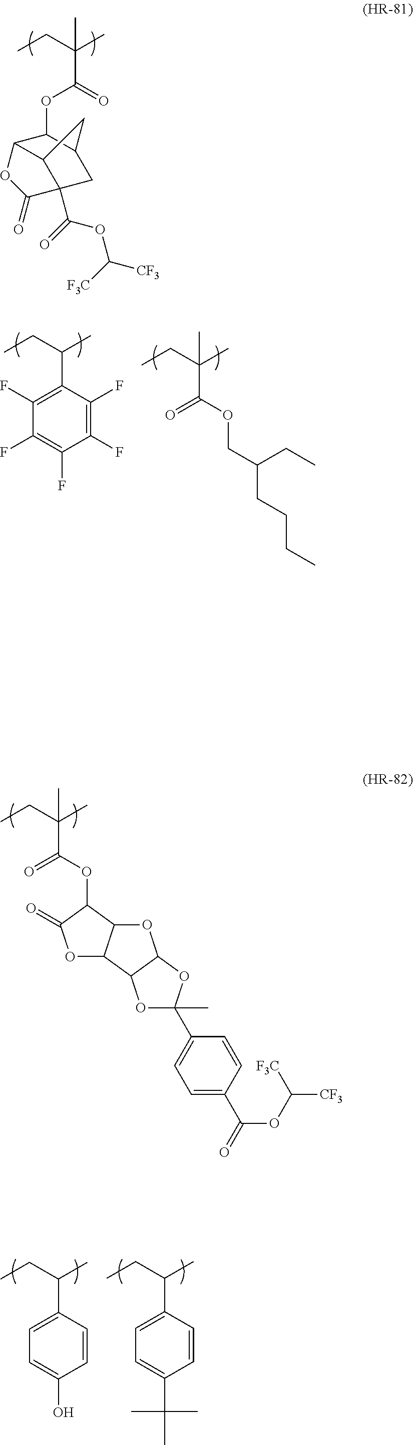

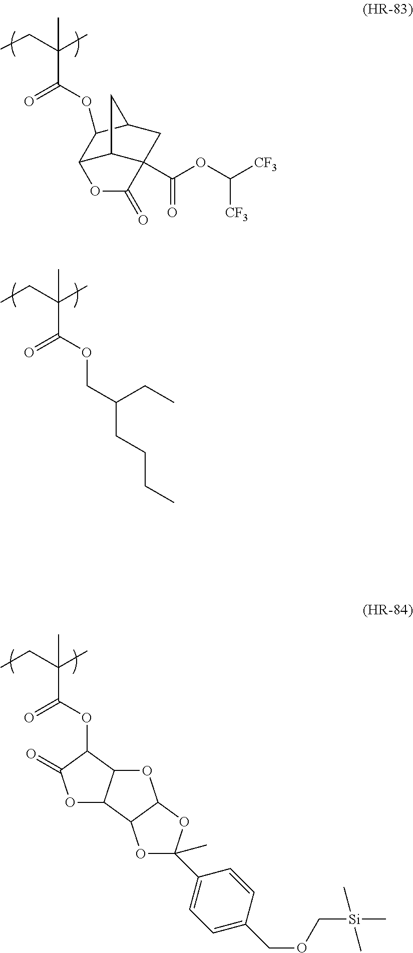

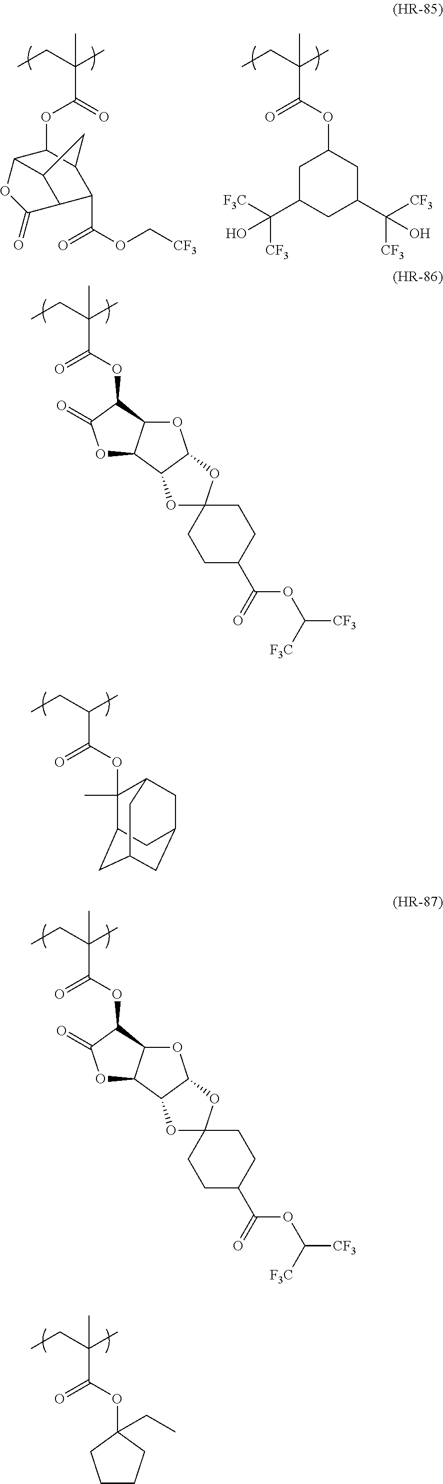

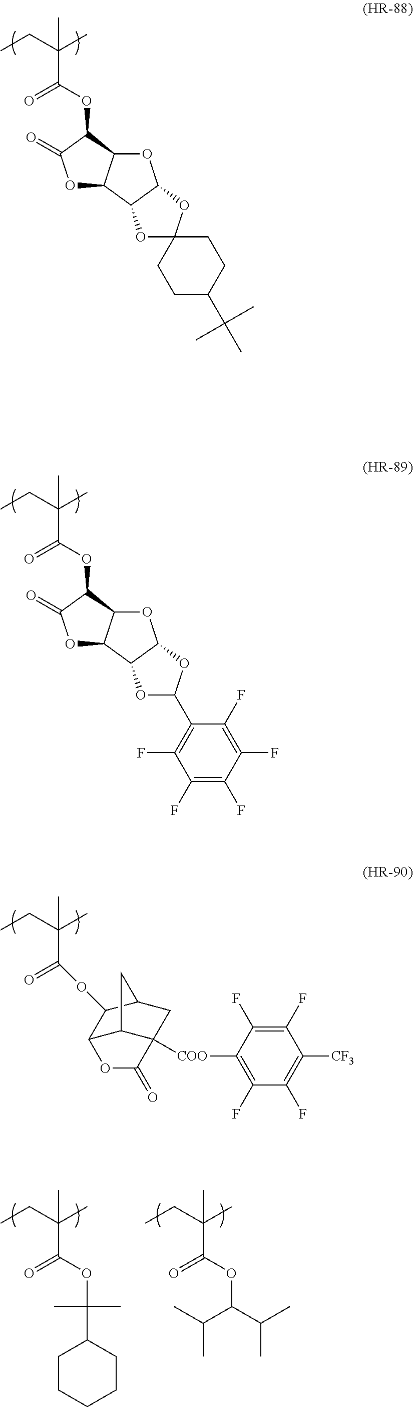

TABLE 4

| Resin | Composition | Mw | Mw/Mn |
|---|---|---|---|
| HR-1 | 50/50 | 4900 | 1.4 |
| HR-2 | 50/50 | 5100 | 1.6 |
| HR-3 | 50/50 | 4800 | 1.5 |
| HR-4 | 50/50 | 5300 | 1.6 |
| HR-5 | 50/50 | 4500 | 1.4 |
| HR-6 | 100 | 5500 | 1.6 |
| HR-7 | 50/50 | 5800 | 1.9 |
| HR-8 | 50/50 | 4200 | 1.3 |
| HR-9 | 50/50 | 5500 | 1.8 |
| HR-10 | 40/60 | 7500 | 1.6 |
| HR-11 | 70/30 | 6600 | 1.8 |
| HR-12 | 40/60 | 3900 | 1.3 |
| HR-13 | 50/50 | 9500 | 1.8 |
| HR-14 | 50/50 | 5300 | 1.6 |
| HR-15 | 100 | 6200 | 1.2 |
| HR-16 | 100 | 5600 | 1.6 |
| HR-17 | 100 | 4400 | 1.3 |
| HR-18 | 50/50 | 4300 | 1.3 |
| HR-19 | 50/50 | 6500 | 1.6 |
| HR-20 | 30/70 | 6500 | 1.5 |
| HR-21 | 50/50 | 6000 | 1.6 |
| HR-22 | 50/50 | 3000 | 1.2 |
| HR-23 | 50/50 | 5000 | 1.5 |
| HR-24 | 50/50 | 4500 | 1.4 |
| HR-25 | 30/70 | 5000 | 1.4 |
| HR-26 | 50/50 | 5500 | 1.6 |
| HR-27 | 50/50 | 3500 | 1.3 |
| HR-28 | 50/50 | 6200 | 1.4 |
| HR-29 | 50/50 | 6500 | 1.6 |
| HR-30 | 50/50 | 6500 | 1.6 |
| HR-31 | 50/50 | 4500 | 1.4 |
| HR-32 | 30/70 | 5000 | 1.6 |
| HR-33 | 30/30/40 | 6500 | 1.8 |
| HR-34 | 50/50 | 4000 | 1.3 |
| HR-35 | 50/50 | 6500 | 1.7 |
| HR-36 | 50/50 | 6000 | 1.5 |
| HR-37 | 50/50 | 5000 | 1.6 |
| HR-38 | 50/50 | 4000 | 1.4 |
| HR-39 | 20/80 | 6000 | 1.4 |
| HR-40 | 50/50 | 7000 | 1.4 |
| HR-41 | 50/50 | 6500 | 1.6 |
| HR-42 | 50/50 | 5200 | 1.6 |
| HR-43 | 50/50 | 6000 | 1.4 |
| HR-44 | 70/30 | 5500 | 1.6 |
| HR-45 | 50/20/30 | 4200 | 1.4 |
| HR-46 | 30/70 | 7500 | 1.6 |
| HR-47 | 40/58/2 | 4300 | 1.4 |
| HR-48 | 50/50 | 6800 | 1.6 |
| HR-49 | 100 | 6500 | 1.5 |
| HR-50 | 50/50 | 6600 | 1.6 |
| HR-51 | 30/20/50 | 6800 | 1.7 |
| HR-52 | 95/5 | 5900 | 1.6 |
| HR-53 | 40/30/30 | 4500 | 1.3 |
| HR-54 | 50/30/20 | 6500 | 1.8 |
| HR-55 | 30/40/30 | 7000 | 1.5 |
| HR-56 | 60/40 | 5500 | 1.7 |
| HR-57 | 40/40/20 | 4000 | 1.3 |
| HR-58 | 60/40 | 3800 | 1.4 |
| HR-59 | 80/20 | 7400 | 1.6 |
| HR-60 | 40/40/15/5 | 4800 | 1.5 |
| HR-61 | 60/40 | 5600 | 1.5 |
| HR-62 | 50/50 | 5900 | 2.1 |
| HR-63 | 80/20 | 7000 | 1.7 |
| HR-64 | 100 | 5500 | 1.8 |
| HR-65 | 50/50 | 9500 | 1.9 |

TABLE 5

| Resin | Composition | Mw | Mw/Mn |
|---|---|---|---|
| HR-66 | 100 | 6000 | 1.5 |
| HR-67 | 100 | 6000 | 1.4 |
| HR-68 | 100 | 9000 | 1.5 |
| HR-69 | 60/40 | 8000 | 1.3 |
| HR-70 | 80/20 | 5000 | 1.4 |
| HR-71 | 100 | 9500 | 1.5 |
| HR-72 | 40/60 | 8000 | 1.4 |
| HR-73 | 55/30/5/10 | 8000 | 1.3 |
| HR-74 | 100 | 13000 | 1.4 |
| HR-75 | 70/30 | 8000 | 1.3 |
| HR-76 | 50/40/10 | 9500 | 1.5 |
| HR-77 | 100 | 9000 | 1.6 |
| HR-78 | 80/20 | 3500 | 1.4 |
| HR-79 | 90/8/2 | 13000 | 1.5 |
| HR-80 | 85/10/5 | 5000 | 1.5 |
| HR-81 | 80/18/2 | 6000 | 1.5 |
| HR-82 | 50/20/30 | 5000 | 1.3 |
| HR-83 | 90/10 | 8000 | 1.4 |
| HR-84 | 100 | 9000 | 1.6 |
| HR-85 | 80/20 | 15000 | 1.6 |
| HR-86 | 70/30 | 4000 | 1.42 |
| HR-87 | 60/40 | 8000 | 1.32 |
| HR-88 | 100 | 3800 | 1.29 |
| HR-89 | 100 | 6300 | 1.35 |
| HR-90 | 50/40/10 | 8500 | 1.51 |

### [6] (F) Surfactant

The chemical amplification resist composition for use in the present invention may or may not further contain a surfactant, but in the case of containing a surfactant, it is preferred to contain any one of fluorine-containing and/or silicon-containing surfactants (a fluorine-containing surfactant, a silicon-containing surfactant and a surfactant containing both a fluorine atom and a silicon atom), or two or more thereof.

By containing a surfactant, the chemical amplification resist composition for use in the present invention can give a resist pattern improved in the sensitivity, resolution and adherence and reduced in the development defect when using an exposure light source with a wavelength of 250 nm or less, particularly 220 nm or less.

Examples of the fluorine-containing and/or silicon-containing surfactants include the surfactants described in paragraph [0276] of U.S. Patent Application Publication No. 2008/0248425, such as EFtop EF301 and EF303 (produced by Shin-Akita Kasei K.K.); Florad FC430, 431 and 4430 (produced by Sumitomo 3M Inc.); Megaface F171, F173, F176, F189, F113, F110, F177, F120 and R08 (produced by DIC Corporation); Surflon S-382, SC101, 102, 103, 104, 105 and 106 and KH-20 (produced by Asahi Glass Co., Ltd.); Troysol S-366 (produced by Troy Chemical); GF-300 and GF-150 (produced by Toagosei Chemical Industry Co., Ltd.); SurfIon S-393 (produced by Seimi Chemical Co., Ltd.); EFtop EF121, EF122A, EF122B, RF122C, EF125M, EF135M, EF351, EF352, EF801, EF802 and EF601 (produced by JEMCO Inc.); PF636, PF656, PF6320 and PF6520 (produced by OMNOVA); and FTX-204G, 208G, 218G, 230G, 204D, 208D, 212D, 218D and 222D (produced by NEOS Co., Ltd.). In addition, polysiloxane polymer KP-341 (produced by Shin-Etsu Chemical Co., Ltd.) may be also used as the silicon-containing surfactant.

Other than those known surfactants, a surfactant using a polymer having a fluoro-aliphatic group derived from a fluoro-aliphatic compound which is produced by a telomerization process (also called a telomer process) or an oligomerization process (also called an oligomer process), may be used. The fluoro-aliphatic compound can be synthesized by the method described in JP-A-2002-90991.

Examples of the surfactant coming under the surfactant above include Megaface F178, F-470, F-473, F-475, F-476 and F-472 (produced by DIC Corporation); a copolymer of a C₆F₁₃ group-containing acrylate (or methacrylate) with a (poly(oxyalkylene)) acrylate (or methacrylate); and a copolymer of a C₃F₇ group-containing acrylate (or methacrylate) with a (poly(oxyethylene)) acrylate (or methacrylate) and a (poly(oxypropylene)) acrylate (or methacrylate).

In the present invention, a surfactant other than the fluorine-containing and/or silicon-containing surfactants, described in paragraph [0280] of U.S. Patent Application Publication No. 2008/0248425, may be also used.

One of these surfactants may be used alone, or some of them may be used in combination.

In the case where the chemical amplification resist composition contains a surfactant, the amount of the surfactant used is preferably from 0.0001 to 2 mass %, more preferably from 0.0005 to 1 mass %, based on the entire amount of the chemical amplification resist composition (excluding the solvent).

On the other hand, by setting the amount added of the surfactant to 10 ppm or less based on the entire amount of the chemical amplification resist composition (excluding the solvent), the hydrophobic resin is more unevenly distributed to the surface, so that the resist film surface can be made more hydrophobic and the followability of water at the immersion exposure can be enhanced.

### [7] (G) Other Additives

The chemical amplification resist composition for use in the present invention may contain an onium carboxylate, a low molecular dissolution inhibitor and the like for the purpose of adjusting the performance, in addition to the components described above.

From the standpoint of enhancing the resolution, the chemical amplification resist composition for use in the present invention is preferably used in a film thickness of 30 to 250 nm, more preferably from 30 to 200 nm. Such a film thickness can be obtained by setting the solid content concentration in the composition to an appropriate range, thereby imparting an appropriate viscosity and enhancing the coatability and film-forming property.

The solid content concentration of the chemical amplification resist composition for use in the present invention is usually from 1.0 to 10 mass %, preferably from 2.0 to 5.7 mass %, more preferably from 2.0 to 5.3 mass %. By setting the solid content concentration to the range above, the resist solution can be uniformly coated on a substrate and furthermore, a resist pattern with excellent performance in terms of line width roughness can be formed. The reason therefor is not clearly known, but it is considered that by virtue of setting the solid content concentration to 10 mass % or less, preferably 5.7 mass % or less, aggregation of materials, particularly a photoacid generator, in the resist solution is inhibited, as a result, a uniform resist film can be formed.

The solid content concentration is a weight percentage of the weight of resist components excluding the solvent, based on the total weight of the chemical amplification resist composition.

The chemical amplification resist composition for use in the present invention is used by dissolving the components above in a predetermined organic solvent, preferably in the above-described mixed solvent, filtering the solution through a filter, and coating it on a predetermined support (substrate). The filter used for filtration is preferably a polytetrafluoroethylene-, polyethylene- or nylon-made filter having a pore size of 0.1 μm or less, more preferably 0.05 μm or less, still more preferably 0.03 μm or less. In the filtration through a filter, as described, for example, in JP-A-2002-62667, circulating filtration may be performed, or the filtration may be performed by connecting a plurality of kinds of filters in series or in parallel. Also, the composition may be filtered a plurality of times. Furthermore, a deaeration treatment or the like may be applied to the composition before and after the filtration through a filter.

Specific preferred examples of the chemical amplification resist composition of for use in the present invention include Resist Compositions R1 to R12 shown below, but as long as the chemical resist composition contains (A) a resin capable of increasing the polarity by the action of an acid to decrease the solubility for an organic solvent-containing developer and (B) a compound capable of generating an acid upon irradiation with an actinic ray or radiation, the present invention is not limited to these resins as specific examples.

More specifically, Resist Compositions R1 to R12 are prepared and obtained by dissolving the components shown in Table 6 below in the solvent shown in the same Table to a concentration of 3.8 mass % in terms of entire solid content, and filtering the solution through a polyethylene filter having a pore size of 0.1 μm.

TABLE 6

| | Composition | | | | | |
|---|---|---|---|---|---|---|
| | | Acid | | Compound (C) | | Hydrophobic |
| Resist | Resin (A) | Generation | Solvent | or Compound | Surfactant | Resin (E) |
| Composition | (0.3 g) | (B) (mg) | (mass ratio) | (C′) (mg) | (F) (mg) | (mg) |
| R1 | P-1 | PAG3 | SL-1/SL-3 | PTB-2 | — | IMA-1 |
| | | (19) | (70/30) | (24) | | (3) |
| R2 | P-2 | PAG4 | SL-1/SL-4 | PTB-1 | W-1 | IMA-1 |
| | | (17) | (95/5) | (26) | (1) | (3) |
| R3 | P-3 | PAG3 | SL-1/SL-2 | PTB-1 | — | IMA-1 |
| | | (19) | (60/40) | (26) | | (3) |
| R4 | P-4 | PAG1 | SL-1/SL-2/SL-4 | PTB-2 | — | IMA-1 |
| | | (18) | (80/15/5) | (24) | | (3) |
| R5 | P-5 | PAG3 | SL-1/SL-3 | PTB-1 | W-1 | IMA-1 |
| | | (19) | (70/30) | (26) | (1) | (3) |
| R6 | P-6 | PAG1 | SL-1/SL-3 | PTB-1 | — | IMA-1 |
| | | (18) | (70/30) | (26) | | (3) |
| R7 | P-7 | PAG4 | SL-1/SL-4 | N-1 | — | IMA-1 |
| | | (25) | (95/5) | (15) | | (3) |
| R8 | P-8 | PAG1/PAG2 | SL-1/SL-2 | PTB-2 | — | IMA-1 |
| | | (10/18) | (60/40) | (24) | | (3) |
| R9 | P-9 | PAG3 | SL-1/SL-2/SL-4 | PTB-1 | W-1 | IMA-1 |
| | | (19) | (80/15/5) | (26) | (1) | (3) |
| R10 | P-10 | PAG1 | SL-1/SL-2 | PTB-2 | — | IMA-1 |
| | | (18) | (60/40) | (24) | | (3) |
| R11 | P-1/P-11 | PAG1 | SL-1/SL-3 | PTB-2 | — | IMA-1 |
| | (0.15 g/0.15 g) | (18) | (50/50) | (24) | | (3) |
| R12 | P-2/P-4 | PAG4 | SL-1/SL-2 | N-1 | — | IMA-1 |
| | (0.09 g/0.21 g) | (25) | (60/40) | (15) | | (3) |

### <Resin (A)>

With respect to Resins (P-1) to (P-11) in Table 7, the repeating units constituting the resin, the molar ratio of repeating units, the weight average molecular weight and the polydispersity are shown. The repeating units in the molar ratio correspond to respective monomers starting from the left.

TABLE 7

| | | | | | | Weight | |
|---|---|---|---|---|---|---|---|
| | Repeating Unit | | | | Compositional | Average | |
| Resin | First | Second | Third | Fourth | Ratio | Molecular | |
| (A) | Component | Component | Component | Component | (molar ratio) | Weight | Polydispersity |
| P-1 | LA-1 | PU-4 | — | — | 40/60 | 18720 | 1.36 |
| P-2 | LA-1 | PU-5 | — | — | 30/70 | 19440 | 1.38 |
| P-3 | LA-1 | PX-3 | — | — | 50/50 | 17280 | 1.53 |
| P-4 | LA-1 | PU-3 | PX-1 | — | 40/35/25 | 19440 | 1.49 |
| P-5 | LA-1 | PU-2 | PX-1 | — | 45/45/10 | 18720 | 1.37 |
| P-6 | LA-1 | PU-4 | PX-1 | — | 40/50/10 | 18000 | 1.51 |
| P-7 | LA-1 | PU-3 | PX-2 | — | 40/30/30 | 18000 | 1.44 |
| P-8 | LA-1 | PU-4 | PX-3 | — | 40/10/50 | 18900 | 1.52 |
| P-9 | LA-1 | PU-4 | PX-3 | HM-1 | 40/10/45/5 | 13500 | 1.56 |
| P-10 | LA-1 | PU-1 | PX-2 | HM-1 | 40/10/40/10 | 17640 | 1.43 |
| P-11 | LA-1 | PU-4 | — | — | 45/55 | 17940 | 1.33 |

The repeating units in Table 7 are as follows.

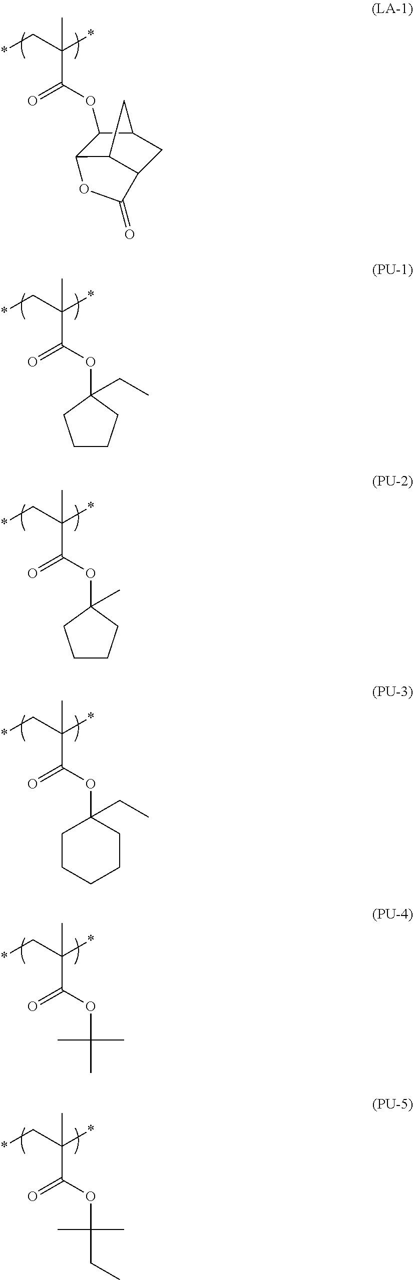

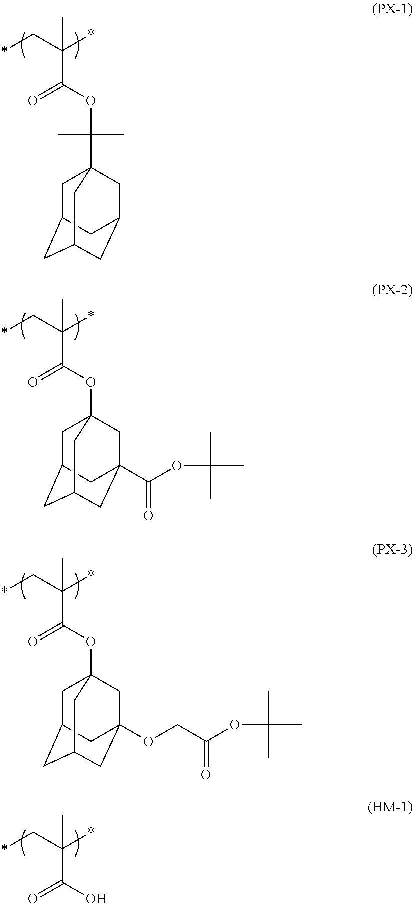

### <Acid Generator (B)>

The acid generators are as follows.

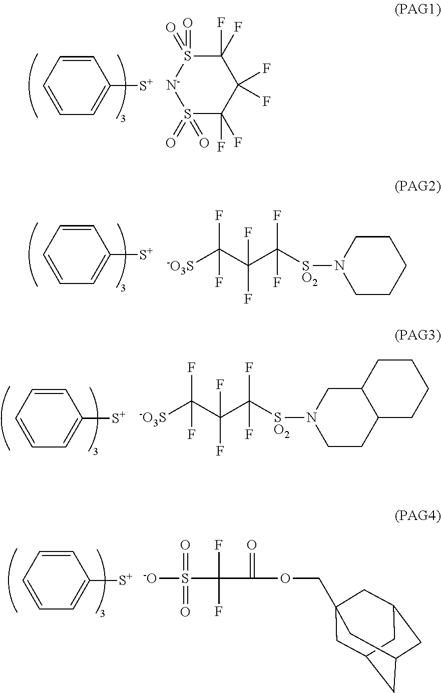

<Basic Compound (C) Whose Basicity Decreases Upon Irradiation with an Actinic Ray or Radiation and Basic Compound (C′)>

The basic compound whose basicity decreases upon irradiation with an actinic ray or radiation, and the basic compound are as follows.

### N-1: 2-Phenylbenzimidazole

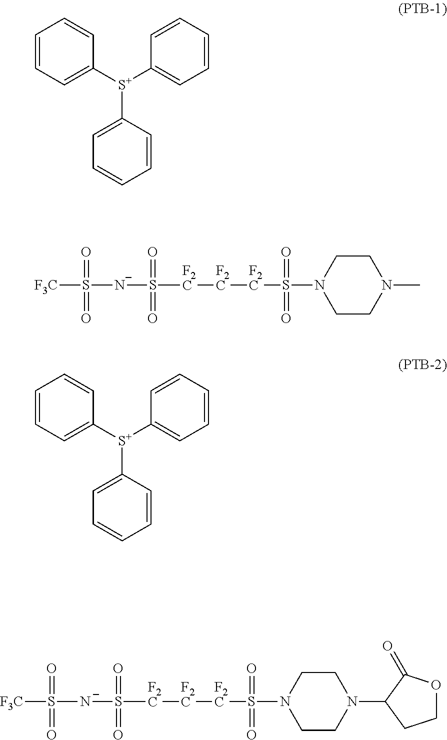 [SMILES: c1ccc([S+](c2ccccc2)c2ccccc2)cc1 ; CN1CCN(S(=O)(=O)C(F)(F)C(F)(F)C(F)(F)S(=O)(=O)[N-]S(=O)(=O)C(F)(F)F)CC1 ; c1ccc([S+](c2ccccc2)c2ccccc2)cc1 ; O=C1OCCC1N1CCN(S(=O)(=O)C(F)(F)C(F)(F)C(F)(F)S(=O)(=O)[N-]S(=O)(=O)C(F)(F)F)CC1]

### <Hydrophobic Resin (E)>

The hydrophobic resins are as follows.

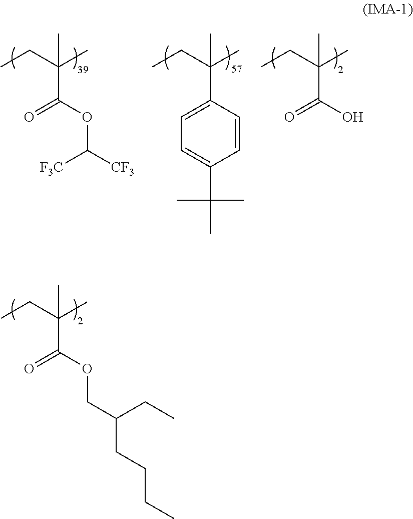

Weight average molecular weight: 4180 Dispersion: 1.35

### <Surfactant>

The surfactants are as follows.

W-1: Megaface F176 (produced by DIC Corp.; fluorine-containing)

### <Solvent>

The solvents are as follows.

SL-1: Propylene glycol monomethyl ether acetate (PGMEA)
SL-2: Propylene glycol monomethyl ether (PGME)

### SL-3: Cyclohexanone

### SL-4: γ-Butyrolactone

The pattern forming method of the present invention (for example, the pattern forming methods according to the first to fifth embodiments of the present invention using ArF immersion exposure) is performed using each of Resist Compositions R1 to R12 described above, whereby a plurality of hole patterns can be successfully and easily formed in a substrate with an ultrafine (for example, 80 nm or less) pitch.

### INDUSTRIAL APPLICABILITY

According to the present invention, a pattern forming method capable of successfully and easily forming a plurality of hole patterns in a substrate with an ultrafine (for example, 80 nm or less) pitch, a method for manufacturing an electronic device by using the same, and an electronic device, can be provided.

This application is based on a Japanese patent application filed on Jun. 17, 2011 (Japanese Patent Application No. 2011-135777), and the contents thereof are incorporated herein by reference.

### REFERENCE SIGNS LIST

10, 11, 12 Substrate
14A, 15A, 16A First hole pattern
14H, 15H, 16H First hole pattern group
20, 21, 22, 23, 31, 32, 33 Resist film
21A, 31A First space group
21B, 31B First line group
21L, 31L First line-and-space latent image
22A, 32A Second space group
22B, 32B Second line group
22C, 32C Unexposed area
22L, 32L Second line-and-space latent image
23A First resist hole pattern
23H First resist hole pattern group
24A, 25A, 26A Second hole pattern
24H, 25H, 26H Second hole pattern group
33A Second resist hole pattern
33H Second resist hole pattern group
36A Third hole pattern
36H Third hole pattern group

1. A pattern forming method for forming a plurality of hole patterns in a substrate,
wherein the pattern forming method comprises a plurality of pattern forming steps each including, in order, the following steps (1) to (6):
(1) a step of forming a resist film on the substrate by using a chemical amplification resist composition containing:
(A) a resin capable of increasing the polarity by the action of an acid to decrease the solubility for an organic solvent-containing developer and,
(B) a compound capable of generating an acid upon irradiation with an actinic ray or radiation,
(2) a step of performing an exposure of the resist film to form a first line-and-space latent image wherein a first line group and a first space group are alternately arranged,
(3) a step of performing an exposure of the resist film that the first line-and-space latent image is formed to form a second line-and-space latent image wherein a second line group and a second space group are alternately arranged, such that the line direction of the second line-and-space intersects the line direction in the first line-and-space latent image,
(4) a step of developing the resist film wherein the first and second line-and-space latent images are formed, by using an organic solvent-containing developer to form a hole pattern group in the resist film,
(5) a step of applying an etching treatment to the substrate with the resist film that the hole pattern group is formed to form a hole pattern group in the substrate at the position corresponding to the hole pattern group in the resist film, and
(6) a step of removing the resist film wherein the hole pattern group is formed,
wherein in each of the plurality of pattern forming steps, all of the hole patterns constituting the hole pattern group formed in the substrate are formed at positions different from all positions of the hole patterns constituting the hole pattern group formed in other pattern forming steps.

2. The pattern forming method according to claim 1, wherein in each of the step of forming the first line-and-space latent image and the step of forming the second line-and-space latent image, an ArF excimer laser is used and the resist film is exposed through an immersion liquid.

3. The pattern forming method according to claim 1, wherein each center-to-center distance of the plurality of hole patterns formed in the substrate through the plurality of pattern forming steps is 80 nm or less.

4. The pattern forming method according to claim 3, wherein each center-to-center distance of the plurality of hole patterns formed in the substrate through the plurality of pattern forming steps is 70 nm or less.

5. The pattern forming method according to claim 1, wherein the widths of the plurality of spaces constituting the first space group are equal to each other and the widths of the plurality of spaces constituting the second space group are equal to each other.

6. The pattern forming method according to claim 5, wherein in the step of forming the second line-and-space latent image, the second line-and-space latent image is formed such that the line direction of the second line-and-space runs at right angles to the line direction in the first line-and-space latent image.

7. The pattern forming method according to claim 5, wherein the width of the space in the first space group is the same as the width of the space in the second space group.

8. The pattern forming method according to claim 7, wherein in each of the plurality of hole patterns formed in the substrate through the plurality of pattern forming steps, the diameter of the circular cross-section in the plane direction of the substrate is 28 nm or less.

9. The pattern forming method according to claim 8, wherein in each of the plurality of hole patterns formed in the substrate through the plurality of pattern forming steps, the diameter of the circular cross-section in the plane direction of the substrate is 25 nm or less.

10. The pattern forming method according to claim 5, wherein in the step of forming the second line-and-space latent image, the second line-and-space latent image is formed such that the line direction of the second line-and-space obliquely intersects the line direction in the first line-and-space latent image.

11. The pattern forming method according to claim 1, comprising:
performing the pattern forming step three or more times.

12. The pattern forming method according to claim 1, wherein the exposure in each of the step of forming the first line-and-space latent image and the step of forming the second line-and-space latent image is an exposure using dipole illumination.

13. The pattern forming method according to claim 1, wherein the exposure in each of the step of forming the first line-and-space latent image and the step of forming said second line-and-space latent image is an exposure using a photomask selected from a binary mask and a phase shift mask.

14. A manufacturing method of an electronic device, comprising:
the pattern forming method according to claim 1.

15. An electronic device manufactured by the manufacturing method of an electronic device according to claim 14.
